(19) United States
(12) Patent Application Publication
(10) Pub. No.: US 2025/0081849 A1
(43) Pub. Date: Mar. 6, 2025

(54) LIGHT EMITTING ELEMENT, FUSED POLYCYCLIC COMPOUND FOR THE SAME, AND DISPLAY DEVICE INCLUDING THE SAME

(71) Applicant: Samsung Display Co., Ltd., Yongin-si (KR)

(72) Inventors: TAEIL KIM, Yongin-si (KR); Hirokazu MIYASHITA, Yongin-si (KR); SUN YOUNG PAK, Yongin-si (KR); MinJae SUNG, Yongin-si (KR); MUN-KI SIM, Yongin-si (KR); MINJUNG JUNG, Yongin-si (KR); Seonhyoung HUR, Yongin-si (KR)

(21) Appl. No.: 18/761,184

(22) Filed: Jul. 1, 2024

(30) Foreign Application Priority Data
Aug. 17, 2023 (KR) 10-2023-0107437
Feb. 19, 2024 (KR) 10-2024-0023702

(51) Int. Cl. H10K 85/60; C07F 5/02; C09K 11/06; H10K 50/12; H10K 101/00

(52) U.S. Cl. CPC H10K 85/658; C07F 5/027; C09K 11/06; C07B 2200/05; C09K 2211/1018; H10K 50/12; H10K 2101/90

(57) ABSTRACT

A light emitting element is provided, the light emitting element including a first electrode, a second electrode provided on the first electrode, and an emission layer which is provided between the first electrode and the second electrode and includes a first compound represented by Formula 1 below:

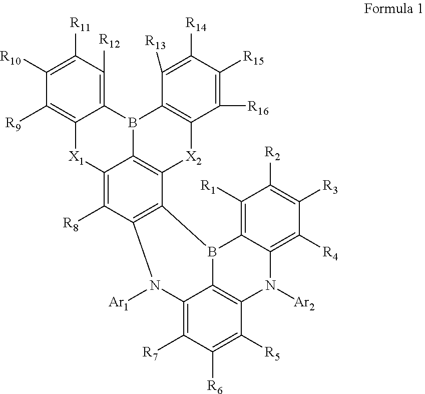

### CROSS-REFERENCE TO RELATED APPLICATION

This application claims priority to and the benefit of Korean Patent Application No. 10-2023-0107437, filed on Aug. 17, 2023, in the Korean Intellectual Property Office, and Korean Patent Application No. 10-2024-0023702, filed on Feb. 19, 2024, in the Korean Intellectual Property Office, the entire content of each of which is hereby incorporated by reference.

### BACKGROUND

### 1. Field

The present disclosure herein relates to a light emitting element, a fused polycyclic compound utilized in the light emitting element, and a display device including the light emitting element.

### 2. Description of the Related Art

Recently, the development of an organic electroluminescence display device, e.g., as an image display device, is being actively conducted. Unlike liquid crystal display devices and/or the like, the organic electroluminescence display device is a so-called “self-luminescent” display device in which holes and electrons injected, respectively, from a first electrode and a second electrode combine in an emission layer of the display device. Subsequently, a luminescent material including an organic compound in the emission layer (e.g., light emitting layer) emits light to implement display (e.g., of an image).

The application of an organic electroluminescence element to a display device requires, or there is a desire or demand for an organic electroluminescence element having a relatively low driving voltage, high luminous efficiency, and a long service life, and/or the like. Therefore, the need or desire exists for the development of materials, for an organic electroluminescence element, capable of stably attaining such desired characteristics, and such development is being continuously pursued.

In recent years, two areas of research being conducted to implement a highly efficient organic electroluminescence element, include technologies pertaining to phosphorescence emission, utilizing triplet state energy, and fluorescence utilizing triplet-triplet annihilation (TTA) (e.g., in which singlet excitons are generated by collision of triplet excitons). Another area of research being developed is thermally activated delayed fluorescence (TADF) materials utilizing delayed fluorescence phenomenon.

### SUMMARY

One or more aspects of embodiments of the present disclosure are directed toward a light emitting element in which luminous efficiency and an element service life are improved.

One or more aspects of embodiments of the present disclosure are directed toward a fused polycyclic compound capable of improving luminous efficiency and an element service life of a light emitting element.

One or more aspects of embodiments of the present disclosure are directed toward a display device including the light emitting element in which the luminous efficiency and service life are improved, thereby having excellent or suitable display quality.

Additional aspects will be set forth in part in the description which follows and, in part, will be apparent from the description, or may be learned by practice of the presented embodiments of the disclosure.

One or more embodiments of the present disclosure provides a light emitting element including a first electrode, a second electrode arranged on the first electrode, and an emission layer which is arranged between the first electrode and the second electrode and includes a first compound represented by Formula 1:

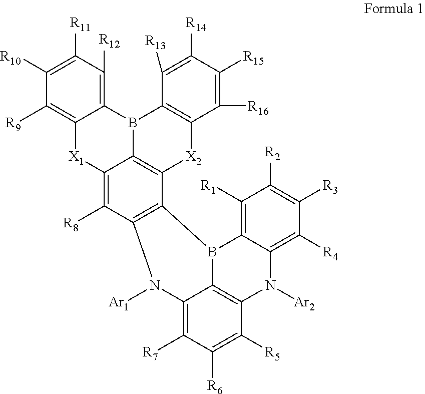

In Formula 1, X₁ may be NR₁₇, O, S, Se, or Te, X₂ may be O, S, or Se, R₁ to R₇ may each independently be a hydrogen atom, a deuterium atom, a halogen atom, a cyano group, a nitro group, a substituted or unsubstituted silyl group, a substituted or unsubstituted germanium group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, R₈ to R₁₆ may each independently be a hydrogen atom, a deuterium atom, a halogen atom, a cyano group, a nitro group, a substituted or unsubstituted silyl group, a substituted or unsubstituted germanium group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, R₁₇ may be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms, and at least one of Ar₁ or Ar₂ may be represented by Formula S:

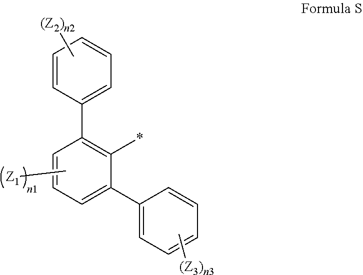

In Formula S, Z₁ to Z₃ may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, n1 may be an integer of 0 to 3, n2 and n3 may each independently be an integer of 0 to 5, and -* may be a position linked to Formula 1.

In one or more embodiments, in Formula 1, at least one selected from among R₁ to R₇ may be a substituted or unsubstituted alkyl group having 1 to 10 carbon atoms, or may be represented by at least one selected from among Formula A-1 to Formula A-4:

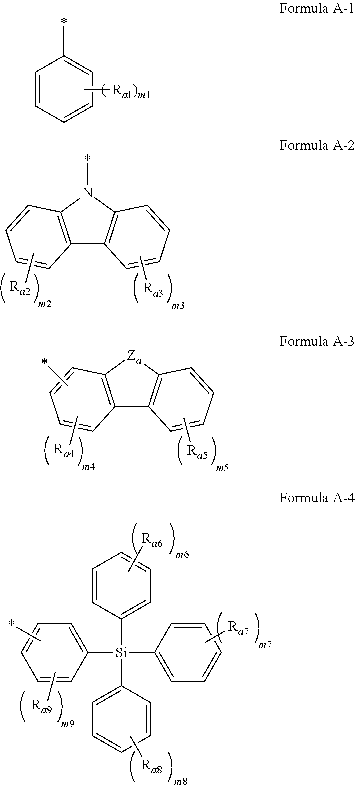

In Formula A-1 to Formula A-4, Zₐ may be NRₐ₁₀, O, S, or Se, Rₐ₁ to Rₐ₁₀ may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, m1 and m6 to m8 may each independently be an integer of 0 to 5, m2, m3, m5, and m9 may each independently be an integer of 0 to 4, and m4 may be an integer of 0 to 3.

In one or more embodiments, in Formula 1, at least one of Ar₁ or Ar₂ may be represented by Formula S, and the other (e.g., any remaining Ar₁ or Ar₂) may be represented by at least (e.g., any) one selected from among Formula B-1 to Formula B-3:

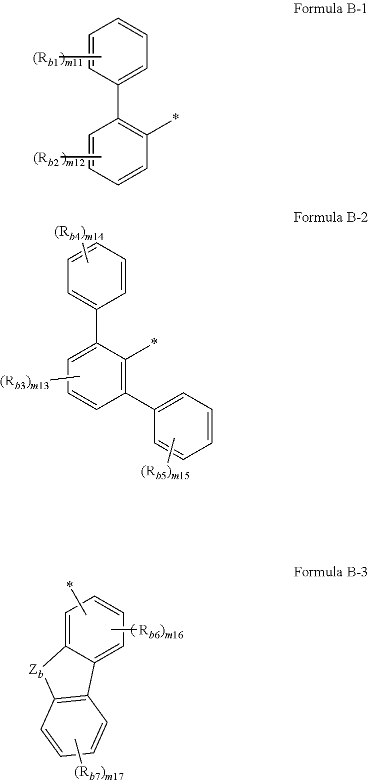

In Formula B-1 to Formula B-3, Z_{b} may be NR_{b8}, O, S, or Se, R_{b1} to R_{b7} may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, R_{b8} may be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, m11, m14 and m15 may each independently be an integer of 0 to 5, m12 and m17 may each independently be an integer of 0 to 4, m13 and m16 may each independently be an integer of 0 to 3, and [symbol] may be a position linked to Formula 1.

In one or more embodiments, the first compound represented by Formula 1 may be represented by Formula 2-1 or Formula 2-2:

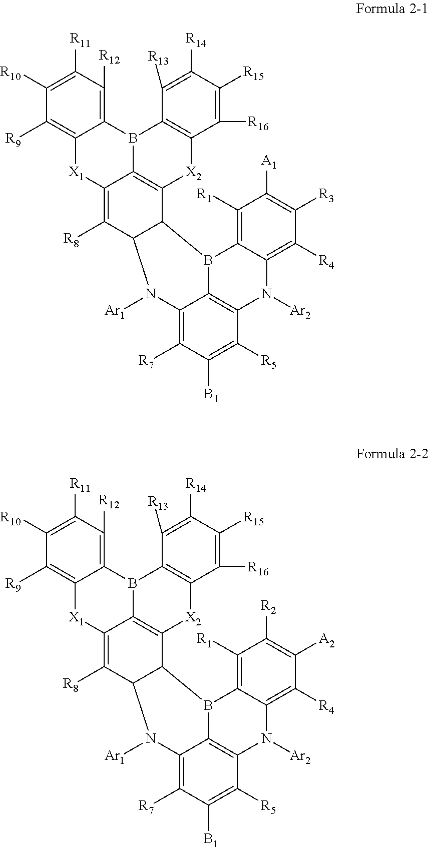

In Formula 2-1 and Formula 2-2, A₁ and A₂ may each independently be represented by any (e.g., at least) one selected from among Formula A-1 to Formula A-4, and B₁ may be a substituted or unsubstituted alkyl group having 1 to 10 carbon atoms.

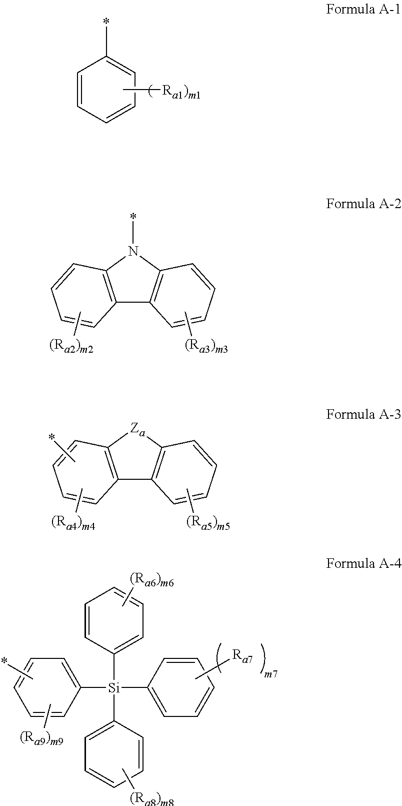

In Formula A-1 to Formula A-4, Zₐ may be NRₐ₁₀, O, S, or Se, Rₐ₁ to Rₐ₁₀ may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, m1 and m6 to m8 may each independently be an integer of 0 to 5, m2, m3, m5, and m9 may each independently be an integer of 0 to 4, and m4 may be an integer of 0 to 3.

In Formula 2-1 and Formula 2-2, the definitions in Formula 1 may be applied to X₁, X₂, Ar₁, Ar₂, R₁ to R₅, and R₇ to R₁₆.

In one or more embodiments, the first compound represented by Formula 1 may be represented by any (e.g., at least) one selected from among Formula 3-1 to Formula 3-3:

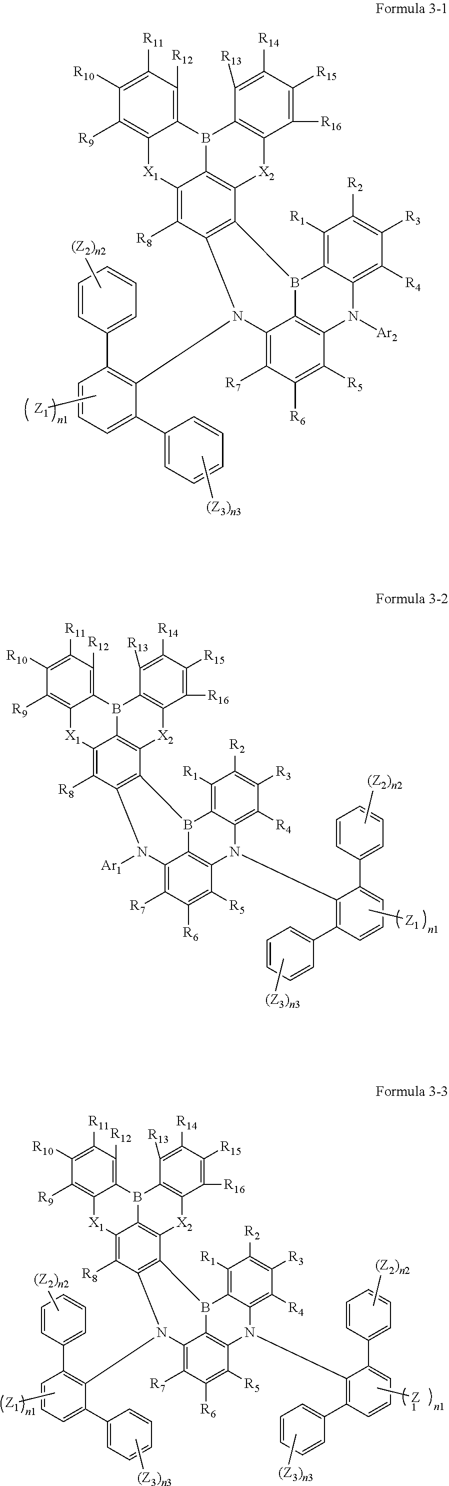

In Formula 3-1 to Formula 3-3, Z₄ to Z₆ may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, n4 may be an integer of 0 to 3, and n5 and n6 may each independently be an integer of 0 to 5.

In Formula 3-1 to Formula 3-3, the definitions in Formula 1 and Formula S may be applied to X₁, X₂, Ar₁, Ar₂, R₁ to R₁₆, Z₁ to Z₃, and n1 to n3.

In one or more embodiments, the first compound represented by Formula 1 may be represented by any (e.g., at least) one selected from among Formula 4-1 to Formula 4-5:

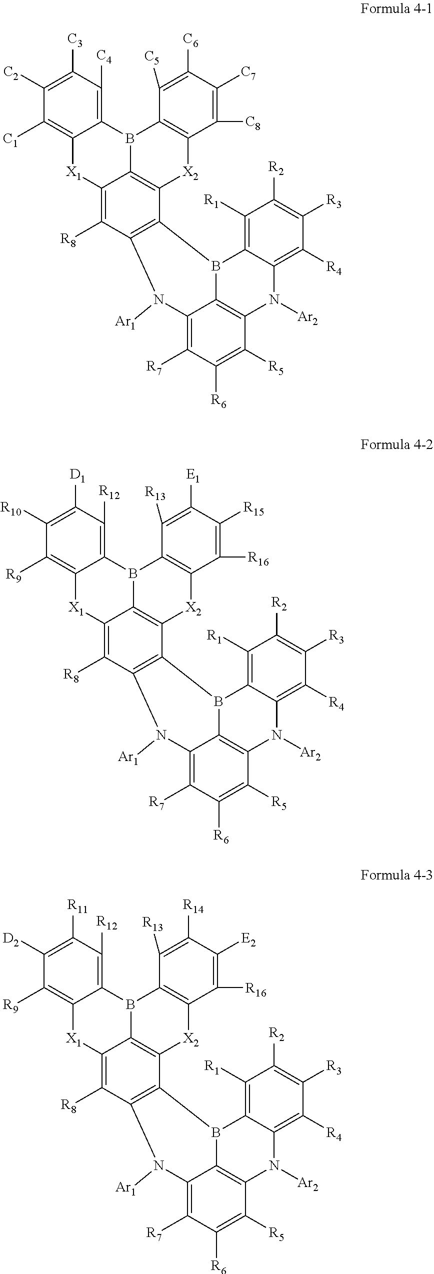

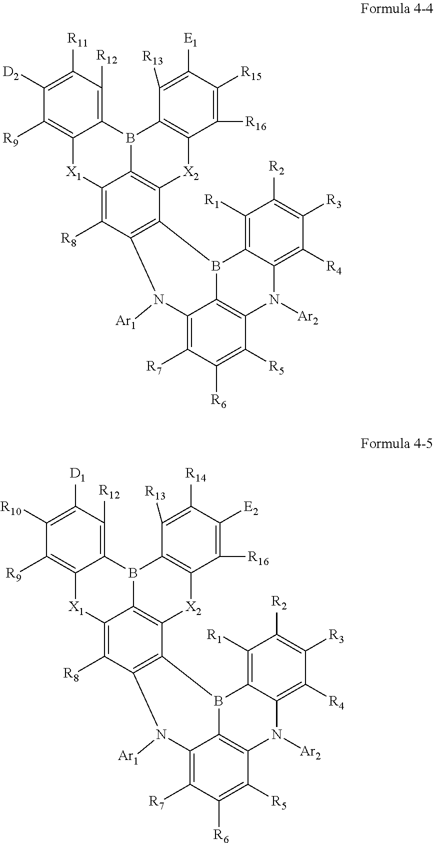

In Formula 4-1 to Formula 4-4, C₁ to C₈ may each independently be a hydrogen atom or a deuterium atom, and D₁, D₂, E₁, and E₂ may each independently be a substituted or unsubstituted alkyl group having 1 to 10 carbon atoms or represented by any (e.g., at least) one selected from among Formula C-1 to Formula C-5:

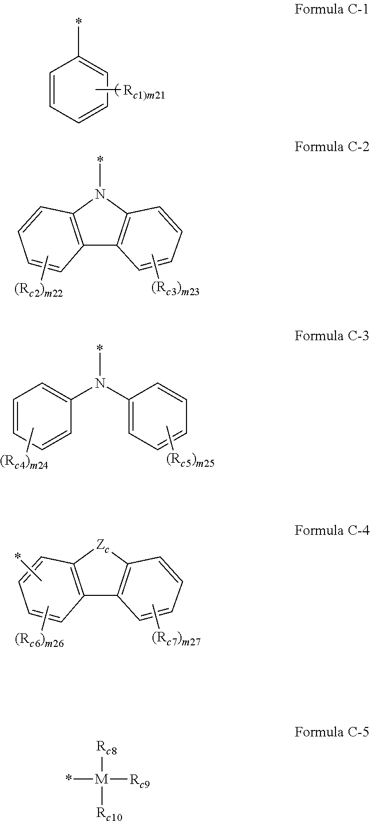

In Formula C-1 to Formula C-5, Z_{c} may be NR_{c11}, O, S, or Se, M may be Si or Ge, R_{c1} to R_{c7} may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, R_{c8} to R_{c11} may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, m21, m24 and m25 may each independently be an integer of 0 to 5, m22, m23, and m27 may each independently be an integer of 0 to 4, and m26 may be an integer of 0 to 3.

In Formula 4-1 to Formula 4-5, the definitions in Formula 1 may be applied to X₁, X₂, Ar₁, Ar₂, and R₁ to R₁₆.

In one or more embodiments, the first compound represented by Formula 1 may be represented by any (e.g., at least) one selected from among Formula 5-1 to Formula 5-3:

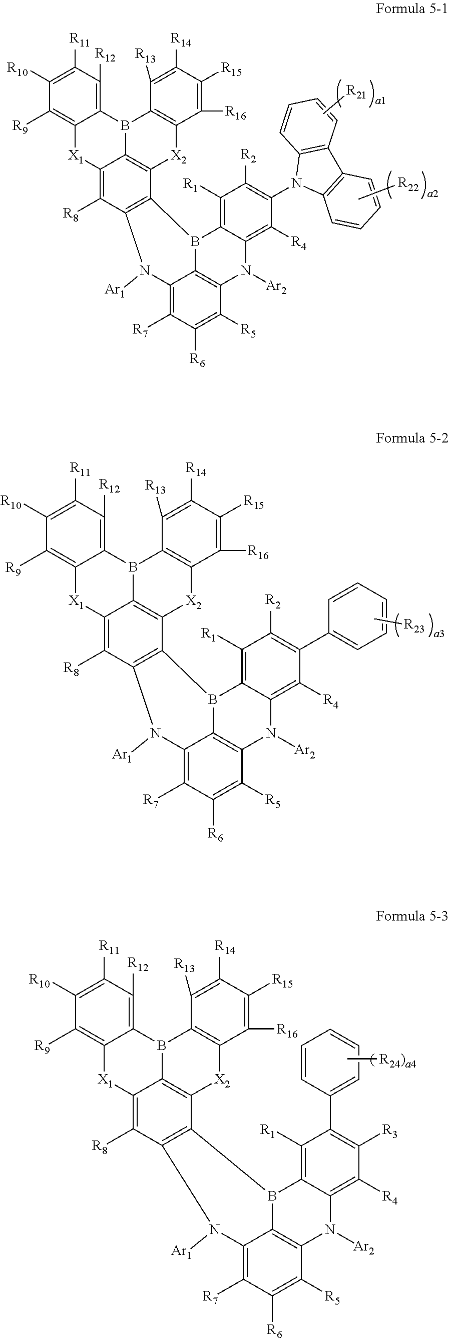

In Formula 5-1 to Formula 5-3, R₂₁ to R₂₄ may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, a1 and a2 may each independently be an integer of each independently 0 to 4, and a3 and a4 may each independently be an integer of 0 to 5.

In Formula 5-1 to Formula 5-3, the definitions in Formula 1 may be applied to X₁, X₂, Ar₁, Ar₂, and R₁ to R₁₆.

In one or more embodiments, the first compound represented by Formula 1 may be represented by any (e.g., at least) one selected from among Formula 6-1 to Formula 6-3:

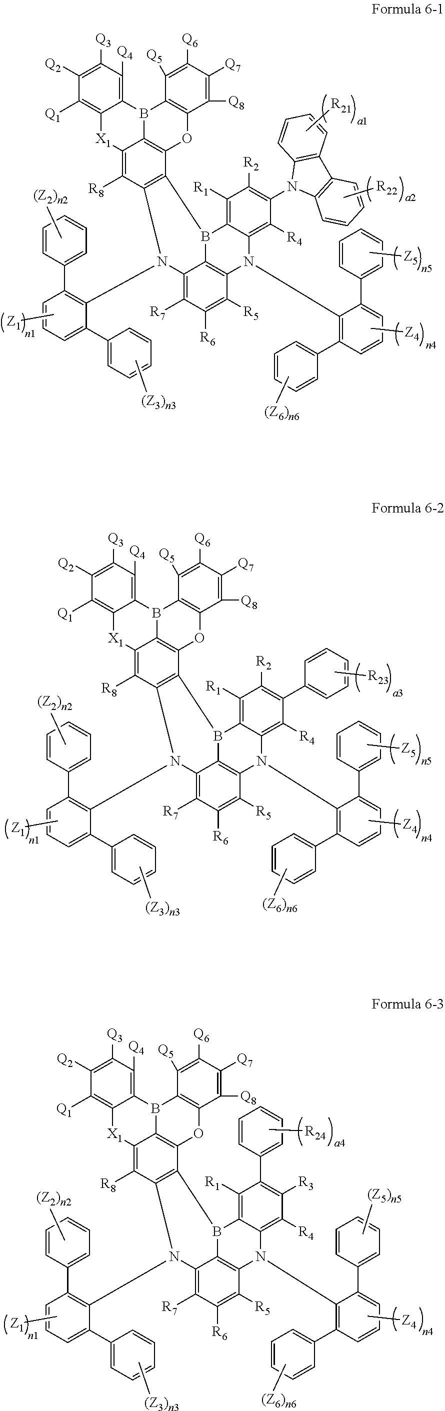

In Formula 6-1 to Formula 6-3, R₂₁ to R₂₄ may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, Z₄ to Z₆ may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, a1 and a2 may each independently be an integer of 0 to 4, a3, a4, n5, and n6 may each independently be an integer of 0 to 5, n4 may be an integer of 0 to 3, and at least one selected from among Q₁ to Q₅ may be represented by any (e.g., at least) one (e.g., one) selected from among Formula C-1 to Formula C-5, and the rest (e.g., any remaining selected from among Q₁ to Q₈) may be hydrogen atoms or deuterium atoms.

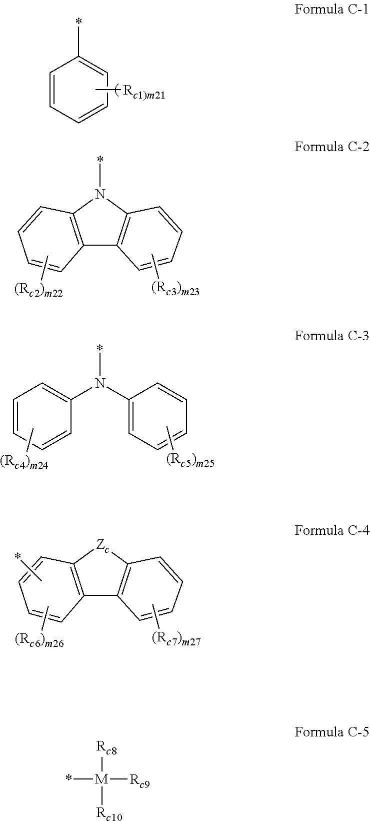

In Formula C-1 to Formula C-5, Z_{c} may be NR_{c11}, O, S, or Se, M may be Si or Ge, R_{c1} to R_{c7} may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, R_{c8} to R_{c11} may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, m21, m24 and m25 may each independently be an integer of 0 to 5, m22, m23, and m27 may each independently be an integer of 0 to 4, and m26 may be an integer of 0 to 3.

In Formula 6-1 to Formula 6-3, the definitions in Formula 1 and Formula S may be applied to X₁, R₁ to R₈, Z₁ to Z₃, and n1 to n3.

In one or more embodiments, at least one selected from among R₁ to R₁₆ may be (e.g., may each be any one) selected from among Substituent Group 1:

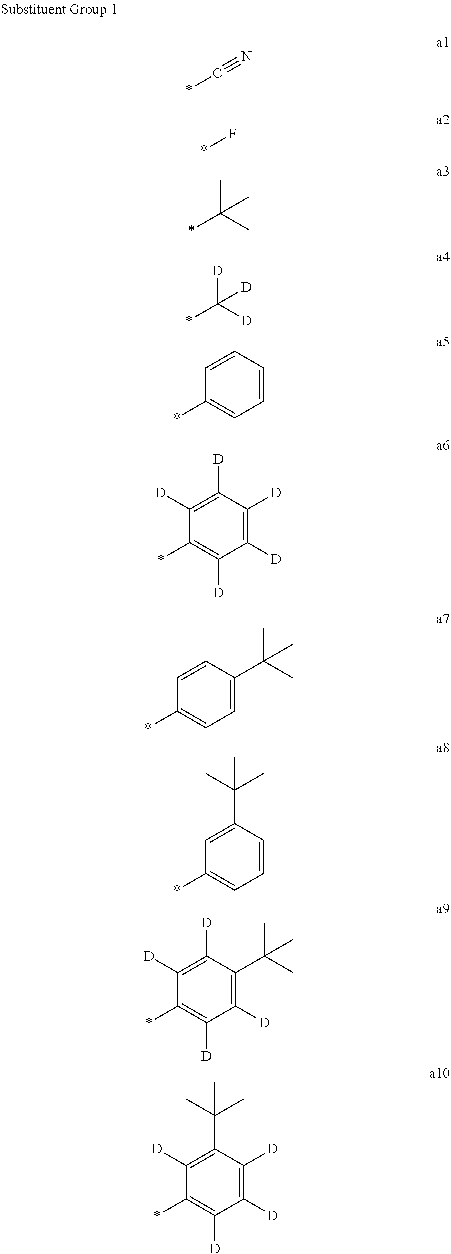

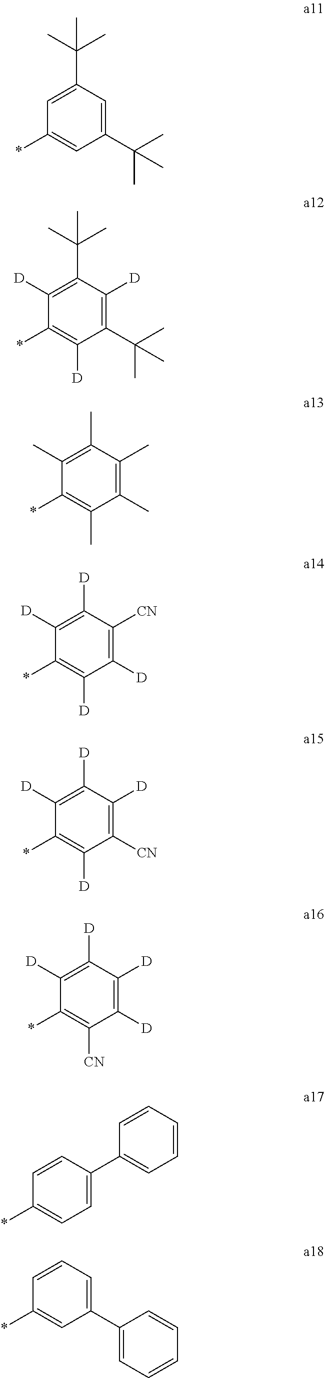

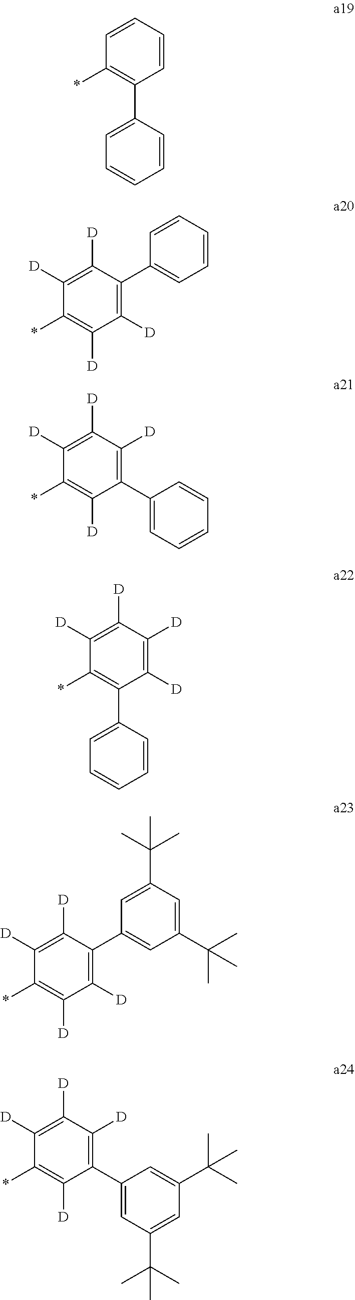

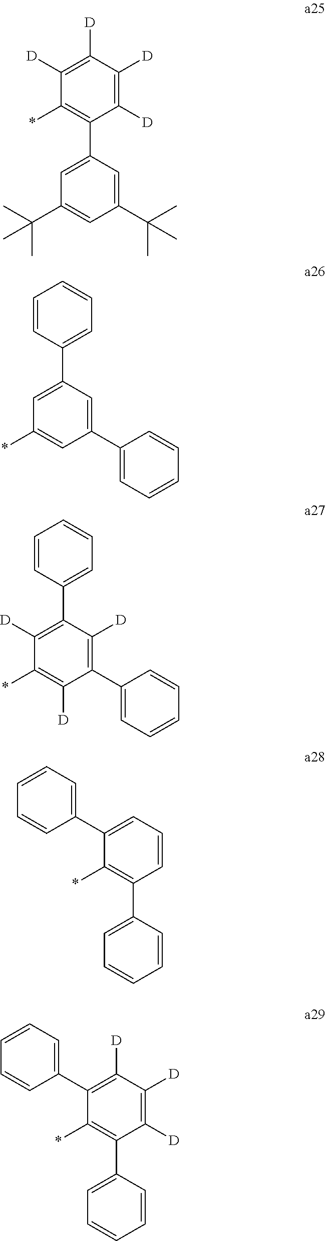

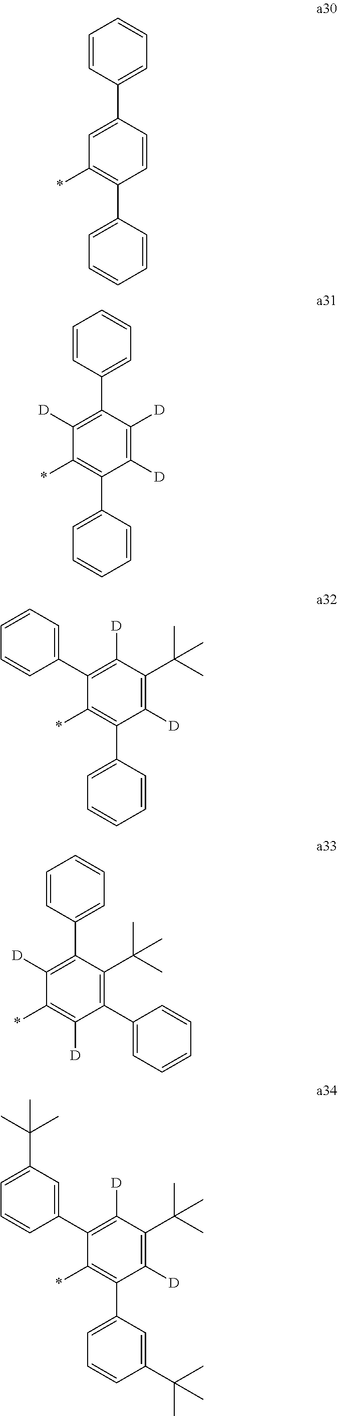

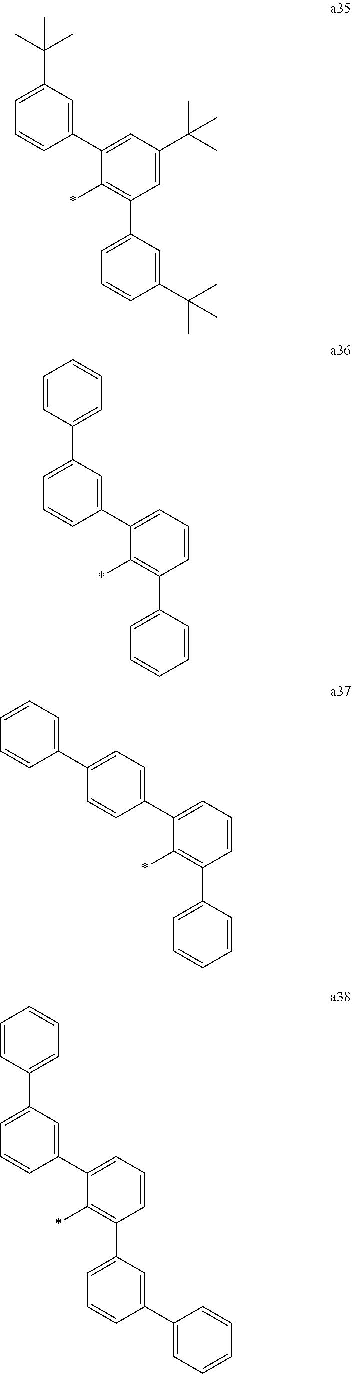 [SMILES: *c1c(-c2cccc(C(C)(C)C)c2)cc(C(C)(C)C)cc1-c1cccc(C(C)(C)C)c1 ; *c1c(-c2ccccc2)cccc1-c1cccc(-c2ccccc2)c1 ; *c1c(-c2ccccc2)cccc1-c1ccc(-c2ccccc2)cc1 ; *c1c(-c2cccc(-c3ccccc3)c2)cccc1-c1cccc(-c2ccccc2)c1]

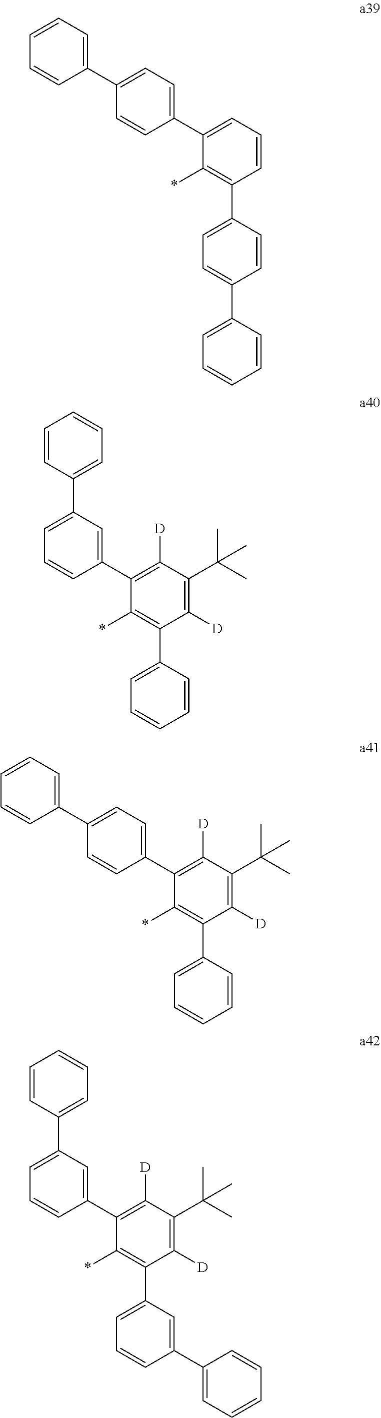 [SMILES: *c1c(-c2ccc(-c3ccccc3)cc2)cccc1-c1ccc(-c2ccccc2)cc1 ; *c1c(-c2ccccc2)c([2H])c(C(C)(C)C)c([2H])c1-c1cccc(-c2ccccc2)c1 ; *c1c(-c2ccccc2)c([2H])c(C(C)(C)C)c([2H])c1-c1ccc(-c2ccccc2)cc1 ; *c1c(-c2cccc(-c3ccccc3)c2)c([2H])c(C(C)(C)C)c([2H])c1-c1cccc(-c2ccccc2)c1]

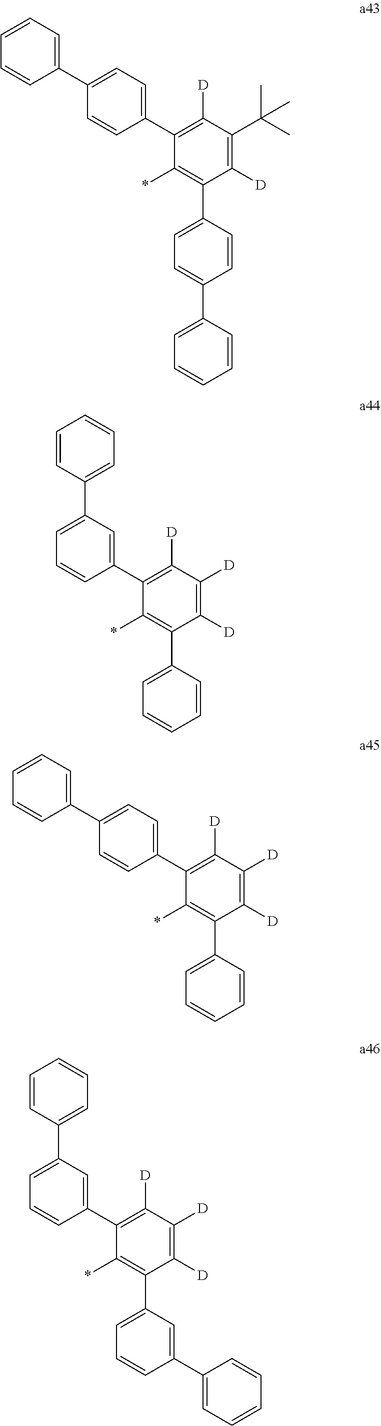 [SMILES: *c1c(-c2ccc(-c3ccccc3)cc2)c([2H])c(C(C)(C)C)c([2H])c1-c1ccc(-c2ccccc2)cc1 ; *c1c(-c2ccccc2)c([2H])c([2H])c([2H])c1-c1cccc(-c2ccccc2)c1 ; *c1c(-c2ccccc2)c([2H])c([2H])c([2H])c1-c1ccc(-c2ccccc2)cc1 ; *c1c(-c2cccc(-c3ccccc3)c2)c([2H])c([2H])c([2H])c1-c1cccc(-c2ccccc2)c1]

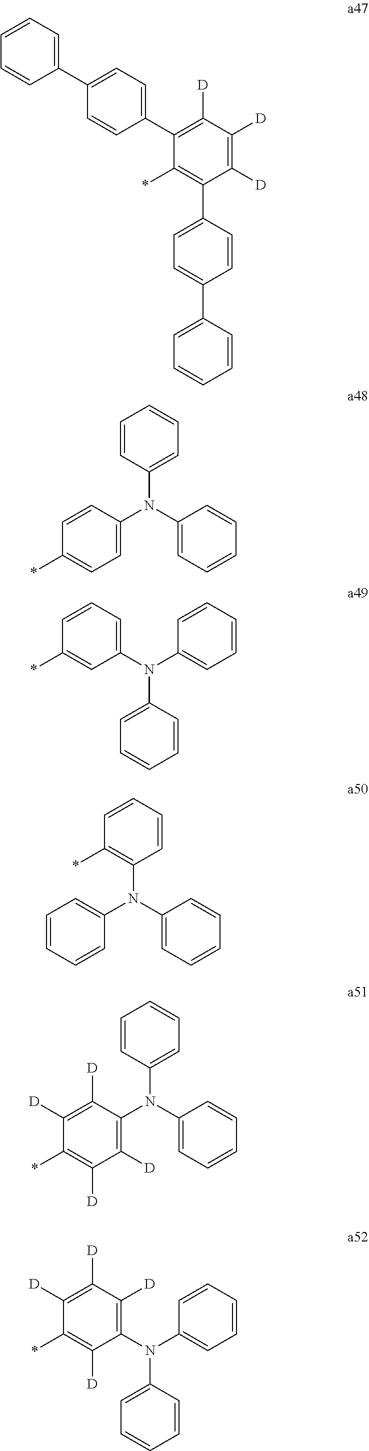

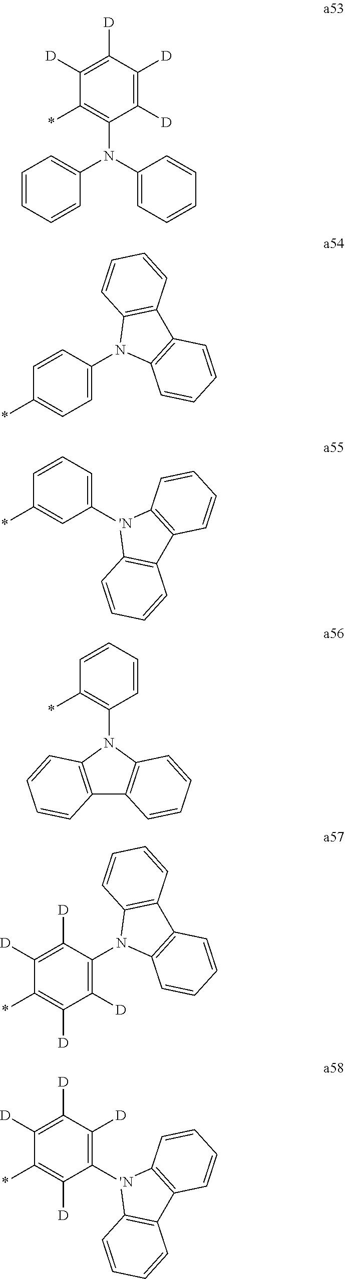

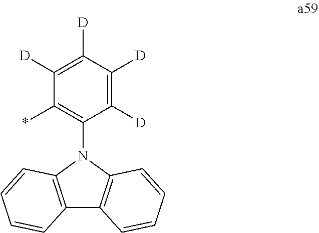 [SMILES: *c1c([2H])c([2H])c([2H])c([2H])c1-n1c2ccccc2c2ccccc21]

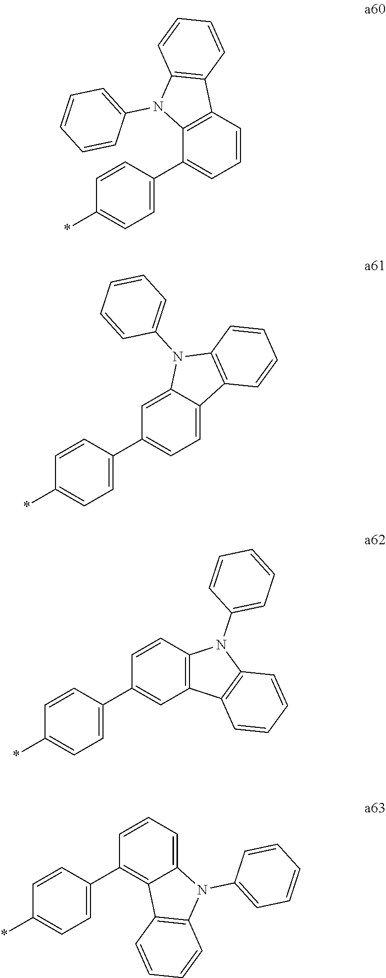 [SMILES: *c1ccc(-c2cccc3c4ccccc4n(-c4ccccc4)c23)cc1 ; *c1ccc(-c2ccc3c4ccccc4n(-c4ccccc4)c3c2)cc1 ; *c1ccc(-c2ccc3c(c2)c2ccccc2n3-c2ccccc2)cc1 ; *c1ccc(-c2cccc3c2c2ccccc2n3-c2ccccc2)cc1]

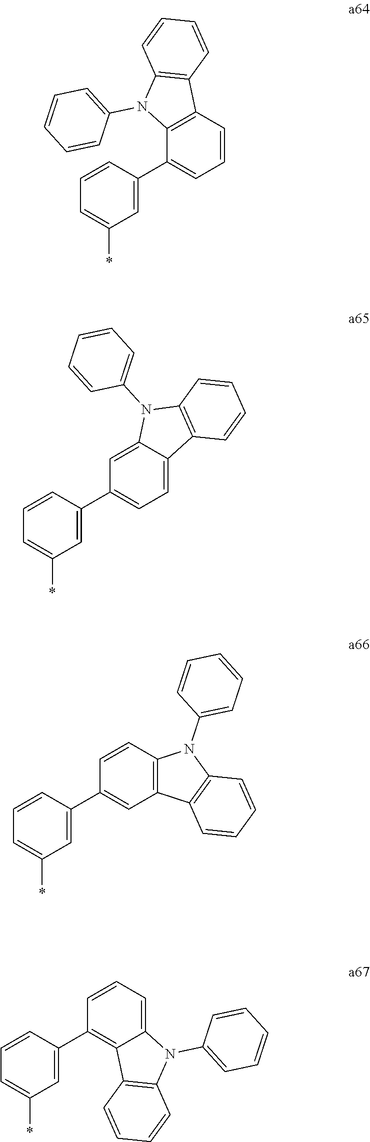 [SMILES: *c1cccc(-c2cccc3c4ccccc4n(-c4ccccc4)c23)c1 ; *c1cccc(-c2ccc3c4ccccc4n(-c4ccccc4)c3c2)c1 ; *c1cccc(-c2ccc3c(c2)c2ccccc2n3-c2ccccc2)c1 ; *c1cccc(-c2cccc3c2c2ccccc2n3-c2ccccc2)c1]

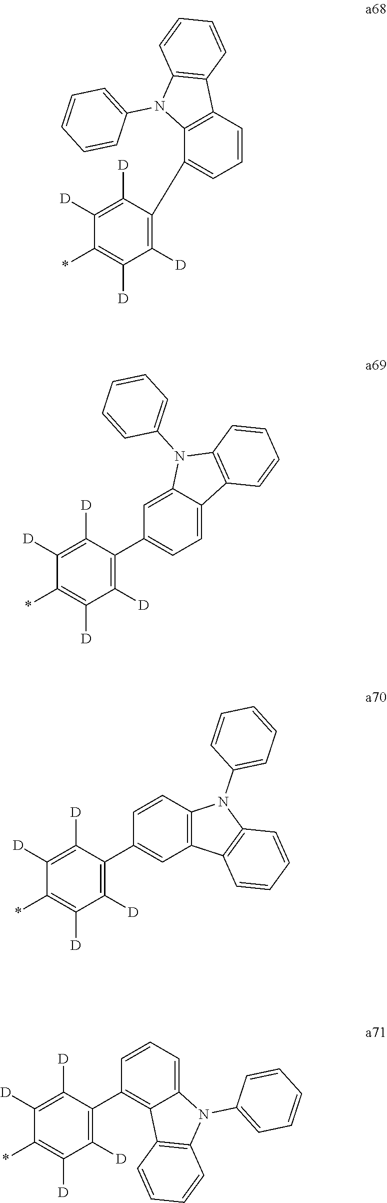 [SMILES: *c1c([2H])c([2H])c(-c2cccc3c4ccccc4n(-c4ccccc4)c23)c([2H])c1[2H] ; *c1c([2H])c([2H])c(-c2ccc3c4ccccc4n(-c4ccccc4)c3c2)c([2H])c1[2H] ; *c1c([2H])c([2H])c(-c2ccc3c(c2)c2ccccc2n3-c2ccccc2)c([2H])c1[2H] ; *c1c([2H])c([2H])c(-c2cccc3c2c2ccccc2n3-c2ccccc2)c([2H])c1[2H]]

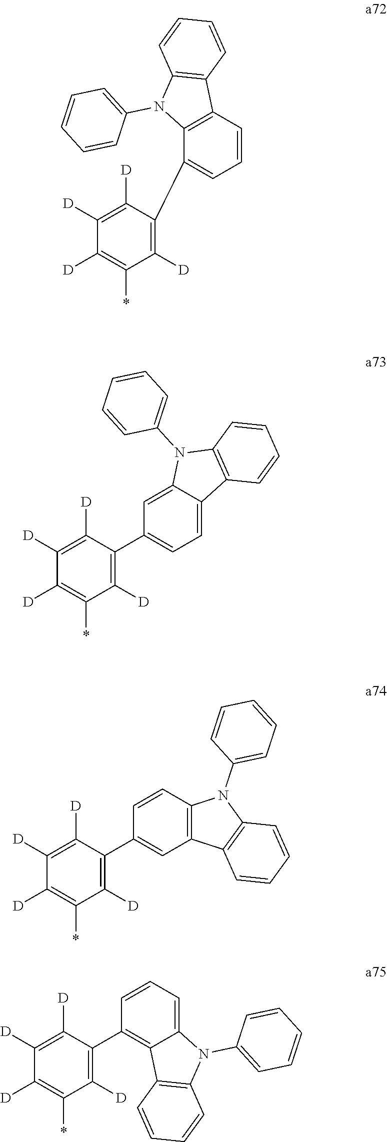 [SMILES: *c1c([2H])c([2H])c([2H])c(-c2cccc3c4ccccc4n(-c4ccccc4)c23)c1[2H] ; *c1c([2H])c([2H])c([2H])c(-c2ccc3c4ccccc4n(-c4ccccc4)c3c2)c1[2H] ; *c1c([2H])c([2H])c([2H])c(-c2ccc3c(c2)c2ccccc2n3-c2ccccc2)c1[2H] ; *c1c([2H])c([2H])c([2H])c(-c2cccc3c2c2ccccc2n3-c2ccccc2)c1[2H]]

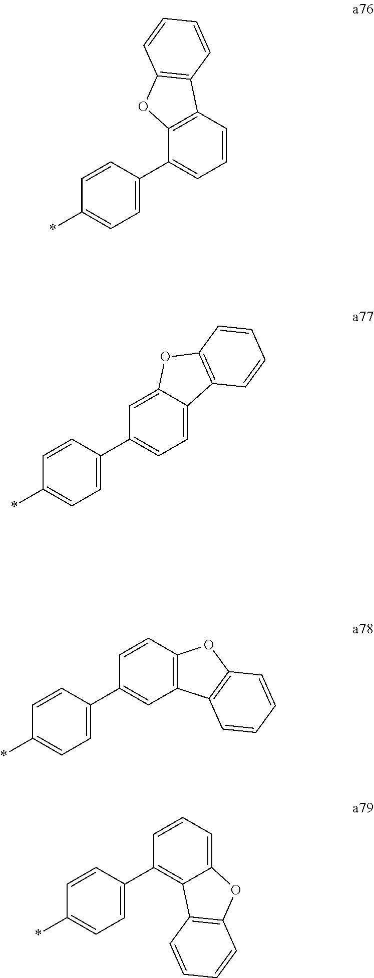 [SMILES: *c1ccc(-c2cccc3c2oc2ccccc23)cc1 ; *c1ccc(-c2ccc3c(c2)oc2ccccc23)cc1 ; *c1ccc(-c2ccc3oc4ccccc4c3c2)cc1 ; *c1ccc(-c2cccc3oc4ccccc4c23)cc1]

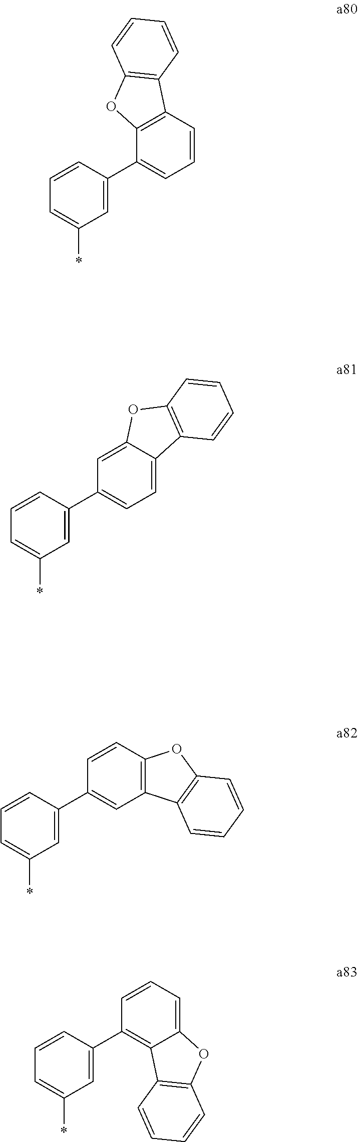 [SMILES: *c1cccc(-c2cccc3c2oc2ccccc23)c1 ; *c1cccc(-c2ccc3c(c2)oc2ccccc23)c1 ; *c1cccc(-c2ccc3oc4ccccc4c3c2)c1 ; *c1cccc(-c2cccc3oc4ccccc4c23)c1]

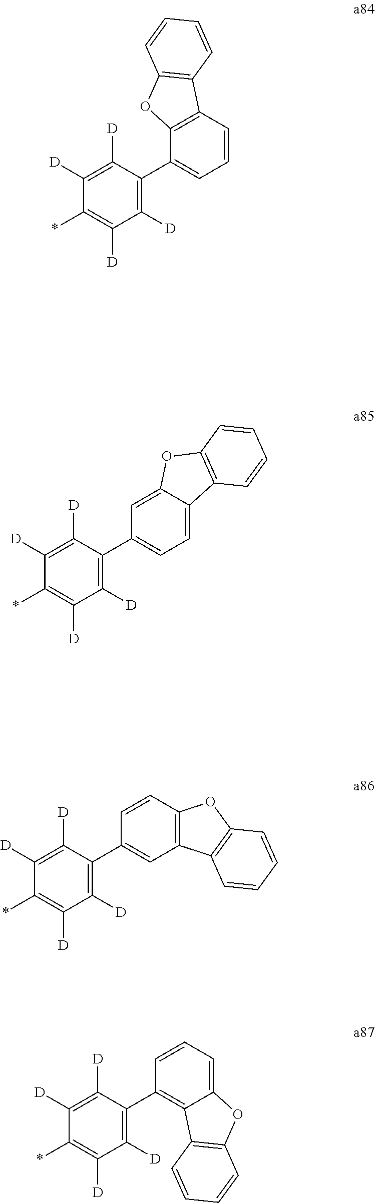 [SMILES: *c1c([2H])c([2H])c(-c2cccc3c2oc2ccccc23)c([2H])c1[2H] ; *c1c([2H])c([2H])c(-c2ccc3c(c2)oc2ccccc23)c([2H])c1[2H] ; *c1c([2H])c([2H])c(-c2ccc3oc4ccccc4c3c2)c([2H])c1[2H] ; *c1c([2H])c([2H])c(-c2cccc3oc4ccccc4c23)c([2H])c1[2H]]

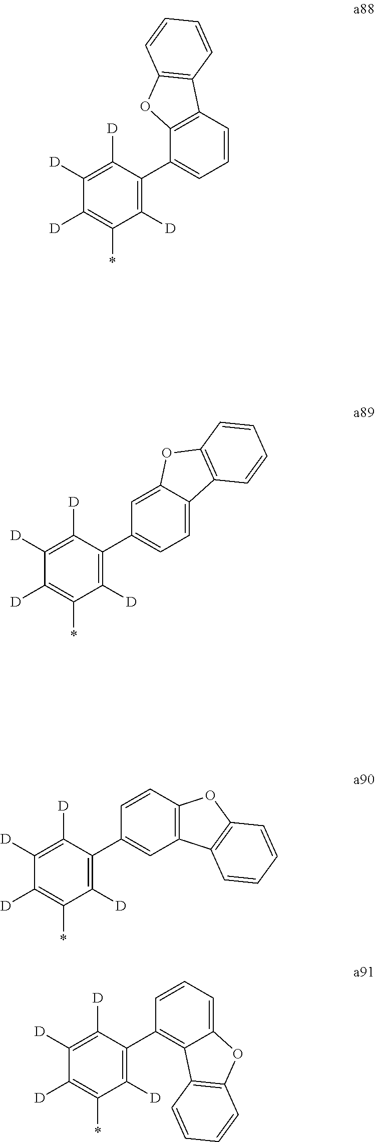 [SMILES: *c1c([2H])c([2H])c([2H])c(-c2cccc3c2oc2ccccc23)c1[2H] ; *c1c([2H])c([2H])c([2H])c(-c2ccc3c(c2)oc2ccccc23)c1[2H] ; *c1c([2H])c([2H])c([2H])c(-c2ccc3oc4ccccc4c3c2)c1[2H] ; *c1c([2H])c([2H])c([2H])c(-c2cccc3oc4ccccc4c23)c1[2H]]

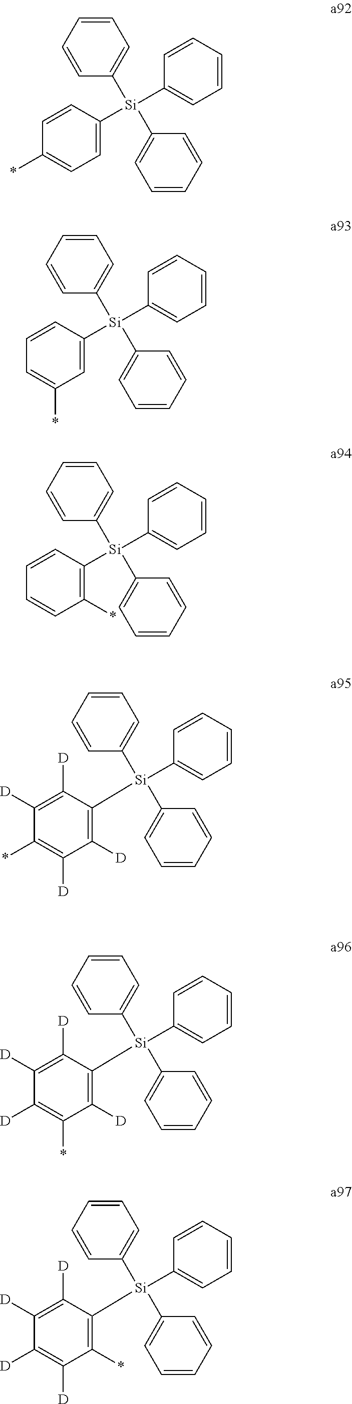

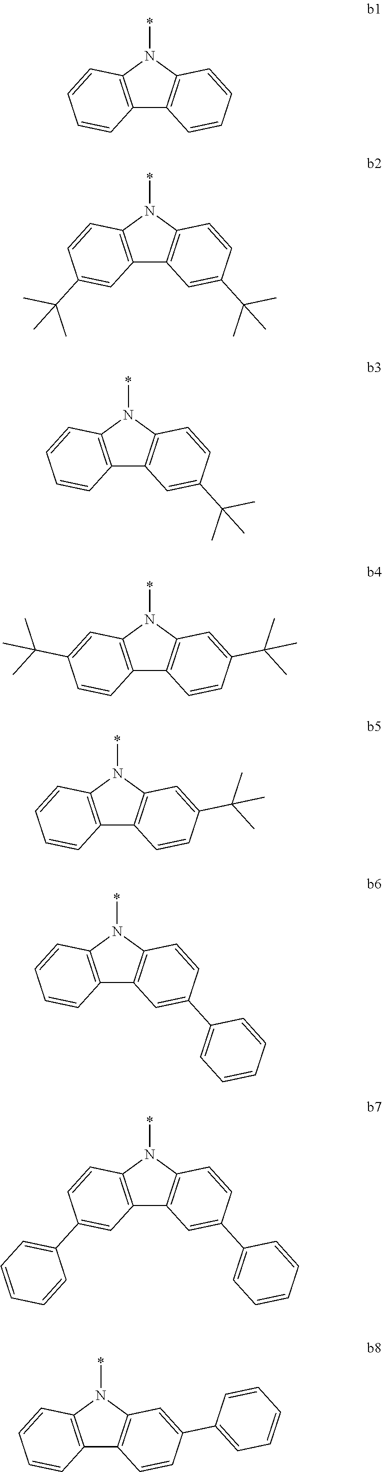

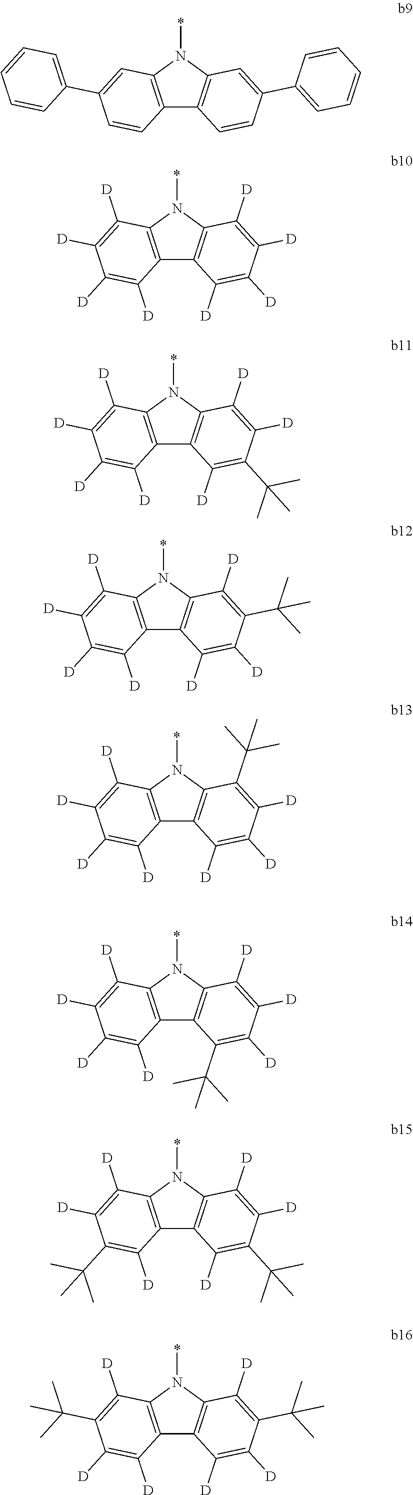

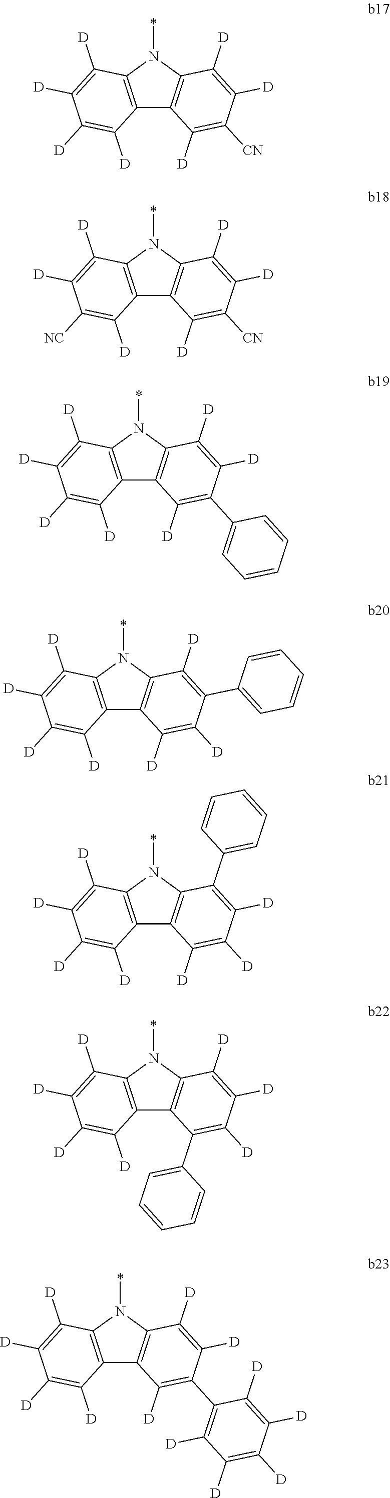

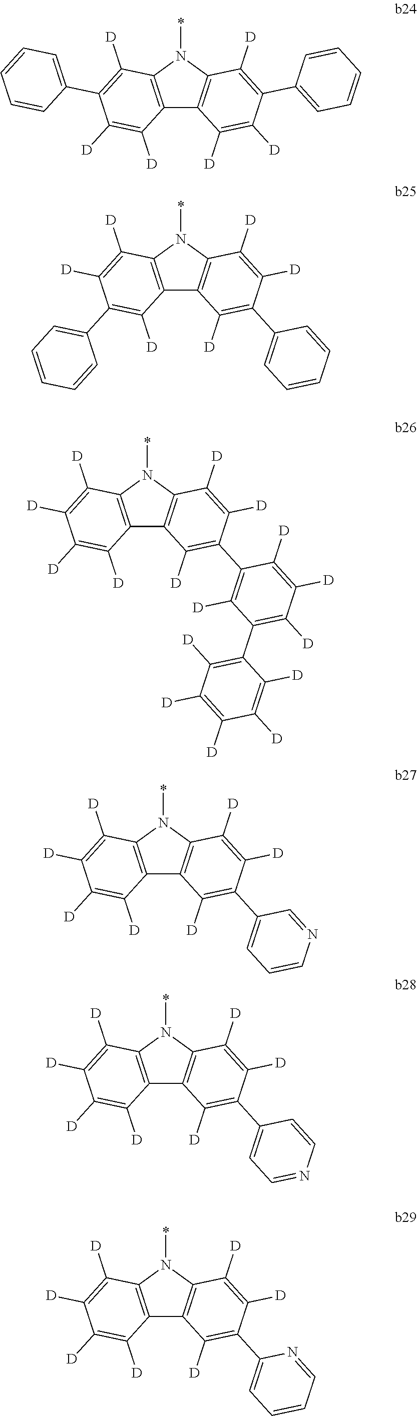

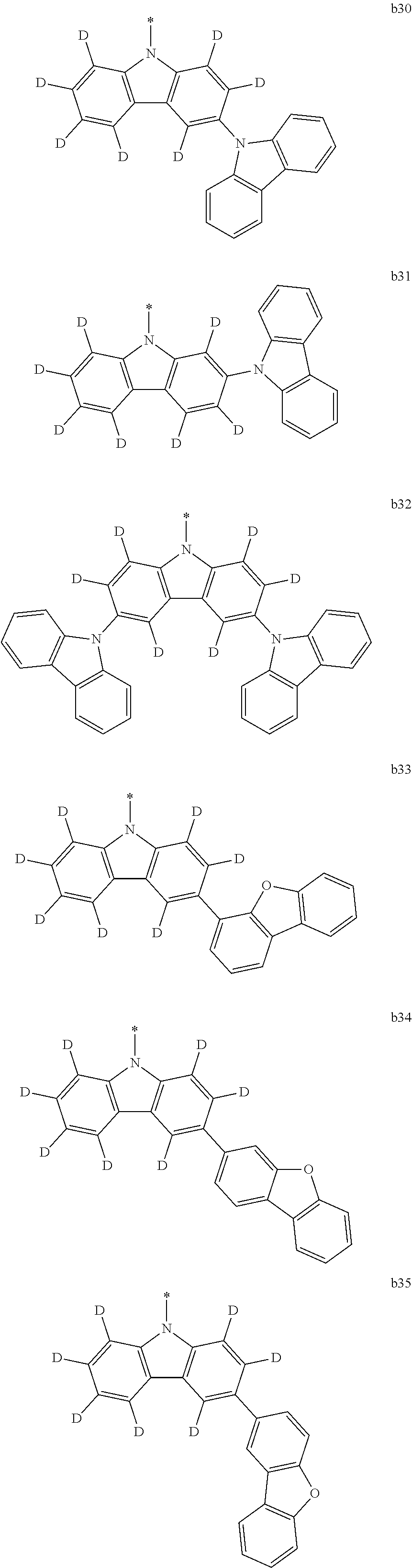

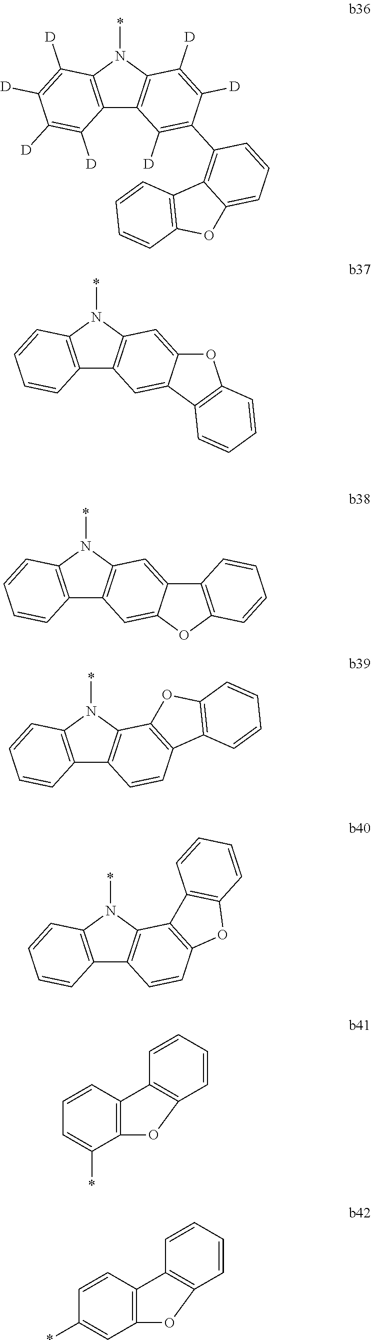

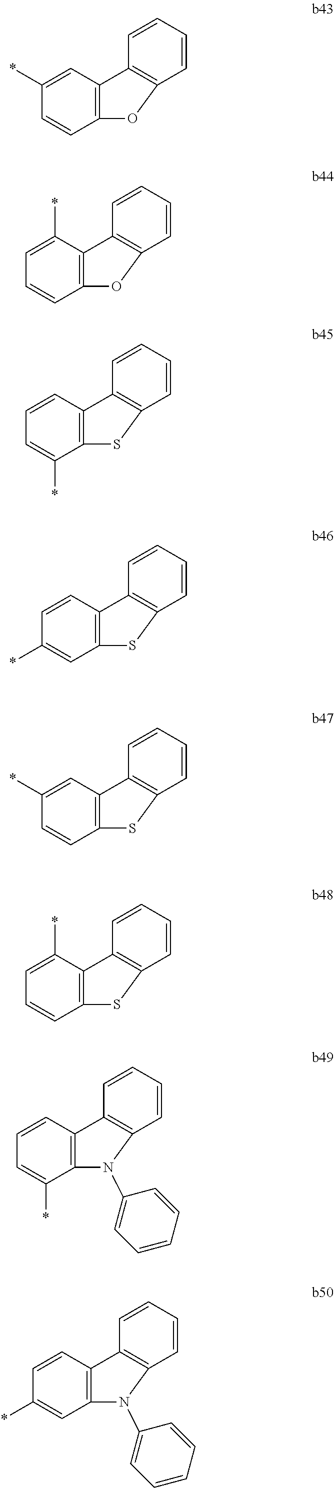

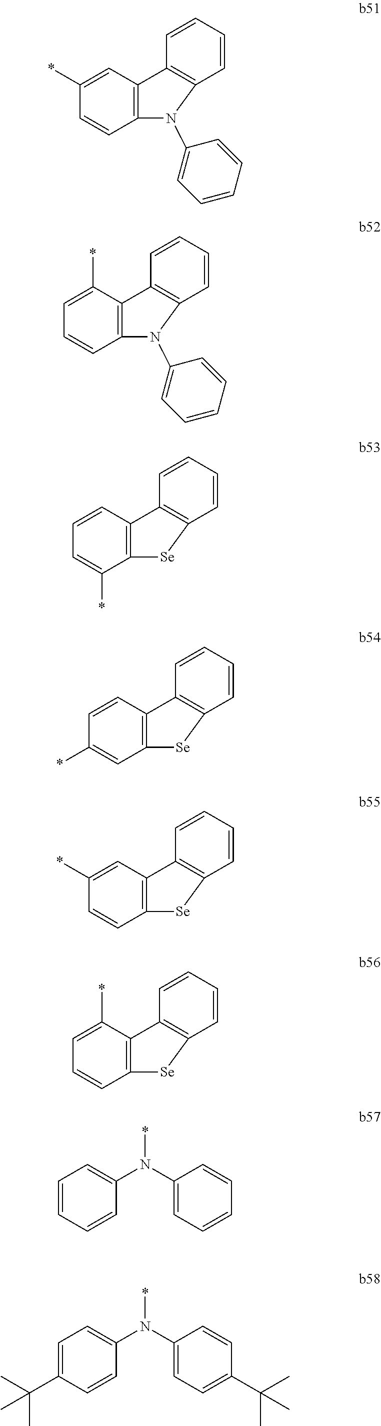

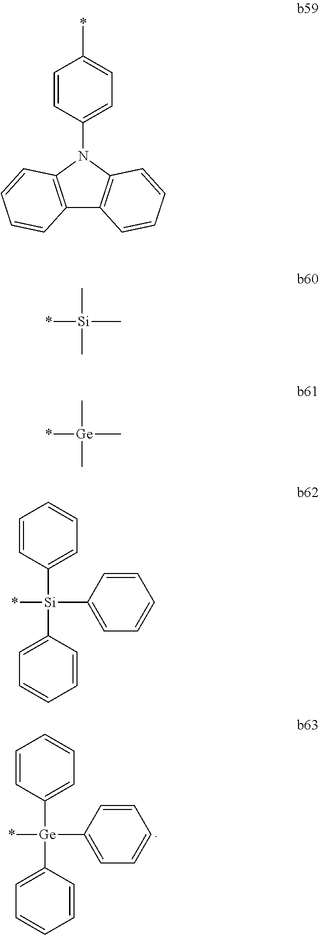

In one or more embodiments, the emission layer may further include at least one of a second compound represented by Formula HT-1, a third compound represented by Formula ET-1, or a fourth compound represented by Formula D-1:

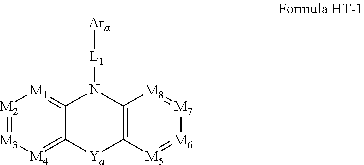

In Formula HT-1, M1 to M8 may each independently be N or CR₅₁, L₁ is a direct linkage, a substituted or unsubstituted arylene group having 6 to 30 ring-forming carbon atoms, or a substituted or unsubstituted heteroarylene group having 2 to 30 ring-forming carbon atoms, Yₐ is a direct linkage, CR₅₂R₅₃, or SiR₅₄R₅₅, Arₐ is a substituted or unsubstituted aryl group having 6 to 30 ring-forming carbon atoms, or a substituted or unsubstituted heteroaryl group having 2 to 30 ring-forming carbon atoms, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or may be bonded to an adjacent group to form a ring.

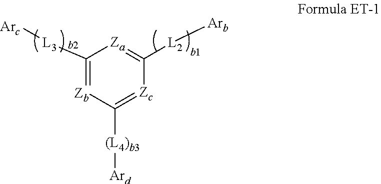

In Formula ET-1, at least one selected from among Zₐ to Z_{c} may be N, the rest (e.g., any remaining selected from among Zₐ to Z_{c}) may be (e.g., may each be any one) CR₅₆, R₅₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, b1 to b3 may each independently be an integer of 0 to 10, Ar_{b} to Ar_{d} may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

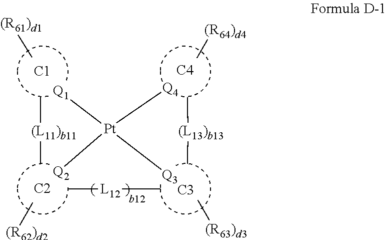

In Formula D-1, Q₁ to Q₄ may each independently be C or N, C₁ to C₄ may each independently be a substituted or unsubstituted hydrocarbon ring having 5 to 30 ring-forming carbon atoms, or a substituted or unsubstituted heterocycle having 2 to 30 ring-forming carbon atoms, L₁₁ to L₁₃ may each independently be a direct linkage,

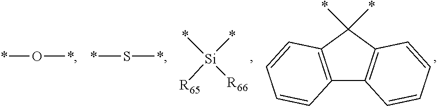

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b11 to b13 may each independently be 0 or 1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and d1 to d4 may each independently be an integer of 0 to 4.

In one or more embodiments of the present disclosure, a display device includes a base layer, a circuit layer arranged on the base layer, and a display element layer which is arranged on the circuit layer and includes a light emitting element, wherein the light emitting element includes a first electrode, a second electrode arranged on the first electrode, and an emission layer which is arranged between the first electrode and the second electrode and includes the first compound represented by Formula 1.

In one or more embodiments, the light emitting element may further include a capping layer arranged on the second electrode, and the capping layer may have a refractive index of about 1.6 or more with respect to light in a range of a wavelength of about 550 nanometer (nm) to about 660 nm.

In one or more embodiments, the display device may further include a light control layer which is arranged on the display element layer and includes a quantum dot, wherein the light emitting element may be to emit a first color light, and the light control layer may include a first light control part including a first quantum dot configured to convert the first color light into a second color light in a longer wavelength region than the first color light (i.e., having a wavelength region longer than a wavelength region of the first color light), a second light control part including a second quantum dot configured to convert the second color light into a third color light in a longer wavelength region than the second color light (i.e., having a wavelength region being longer than a wavelength region of the second color light), and a third light control part configured to transmit the first color light.

In one or more embodiments, the display device may further include a color filter layer arranged on the light control layer, wherein the color filter layer may include a first filter configured to transmit the second color light, a second filter configured to transmit the third color light, and a third filter configured to transmit the first color light.

In one or more embodiments of the present disclosure, a fused polycyclic compound is represented by Formula 1.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure.

In the drawings:

FIG. 1 is a plan view of a display device according to one or more embodiments of the present disclosure;

FIG. 2 is a cross-sectional view of the display device according to one or more embodiments of the present disclosure;

FIG. 3 is a cross-sectional view schematically illustrating a light emitting element according to one or more embodiments of the present disclosure;

FIG. 4 is a cross-sectional view schematically illustrating a light emitting element according to one or more embodiments of the present disclosure;

FIG. 5 is a cross-sectional view schematically illustrating a light emitting element according to one or more embodiments of the present disclosure;

FIG. 6 is a cross-sectional view schematically illustrating a light emitting element according to one or more embodiments of the present disclosure;

FIGS. 7 and 8 are each a cross-sectional view of a display device according to one or more embodiments of the present disclosure;

FIG. 9 is a cross-sectional view illustrating a display device according to one or more embodiments of the present disclosure;

FIG. 10 is a cross-sectional view illustrating a display device according to one or more embodiments of the present disclosure; and

FIG. 11 is a perspective view illustrating a vehicle in which display devices are arranged according to one or more embodiments.

### DETAILED DESCRIPTION

The present disclosure may be modified in one or more suitable manners and have many forms, and thus specific embodiments will be exemplified in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure.

When explaining each of drawings, like reference numbers are utilized for referring to like elements. In the accompanying drawings, the dimensions of each structure are exaggeratingly illustrated for clarity of the present disclosure. It will be understood that, although the terms “first,” “second,” and/or the like, may be utilized herein to describe one or more suitable components, these components should not be limited by these terms. These terms are only utilized to distinguish one component from another. For example, a first component could be termed a second component, and, similarly, a second component could be termed a first component, without departing from the scope of example embodiments of the present disclosure. As utilized herein, the singular forms, “a,” “an,” and “the” are intended to include the plural forms as well, unless the context clearly indicates otherwise.

In the present application, it will be understood that the terms “include,” “includes,” “including,” “comprise,” “comprises”, “comprising,” “has,” “having,” and/or “have” and/or the like specify the presence of features, numbers, steps, operations, component, parts, or combinations thereof disclosed in the specification, but do not exclude the possibility of presence or addition of one or more other features, numbers, steps, operations, component, parts, or combinations thereof.

In the present application, when a layer, a film, a region, or a plate is referred to as being “on” or “in an upper portion of” another layer, film, region, or plate, it may be not only “directly on” the layer, film, region, or plate, but intervening layers, films, regions, or plates may also be present. On the contrary to this, when a layer, a film, a region, or a plate is referred to as being “below”, “in a lower portion of” another layer, film, region, or plate, it can be not only directly under the layer, film, region, or plate, but intervening layers, films, regions, or plates may also be present. In one or more embodiments, it will be understood that when a part is referred to as being “on” another part, it can be arranged above the other part, or arranged under the other part as well.

For example, the terms, such as “lower”, “above”, “upper” and/or the like, are utilized herein for ease of description to describe one element's relation to another element(s) as illustrated in the drawings. The terms are relative concepts and are described based on the directions indicated in the drawings. It will be understood that the terms have a relative concept and are described on the basis of the orientation depicted in the drawings. It will be understood that the spatially relative terms are intended to encompass different orientations of the device in use or operation in addition to the orientation depicted in the drawings. For example, if the device in the drawings is turned over, elements described as “beneath” other elements or features would then be oriented “above” or “over” the other elements or features. Thus, the term “beneath” may encompass both an orientation of above and below. The device may be otherwise oriented (rotated 90 degrees or at other orientations), and the spatially relative descriptors used herein should be interpreted accordingly.

As utilized herein, the terms “use,” “using,” and “used” may be considered synonymous with the terms “utilize,” “utilizing,” and “utilized,” respectively.

As utilized herein, expressions such as “at least one of,” “one of,” “selected from,” and “selected from among,” when preceding a list of elements, modify the entire list of elements and do not modify the individual elements of the list. For example, the expressions “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The term “and/or” includes all combinations of one or more of the associated listed elements.

As utilized herein, the term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Unless otherwise defined, all terms (including chemical, technical and scientific terms) utilized herein have the same meaning as commonly understood by one of ordinary skill in the art to which this present disclosure belongs. It will be further understood that terms, such as those defined in commonly utilized dictionaries, should be interpreted as having a meaning that is consistent with their meaning in the context of the relevant art and will not be interpreted in an idealized or overly formal sense unless expressly so defined herein.

As utilized herein, the phrase “consisting essentially of” means that any additional components will not materially affect the chemical, physical, optical, or electrical properties of the semiconductor film.

As utilized herein, the phrase “on a plane,” or “plan view,” refers to viewing a target portion from the top, and the phrase “on a cross-section” means viewing a cross-section formed by vertically cutting a target portion from the side.

In present disclosure, “not include a or any ‘component’” “exclude a or any ‘component’”, “‘component’-free”, and/or the like refers to that the “component” not being added, selected or utilized as a component in the composition, but the “component” of less than a suitable amount may still be included due to other impurities and/or external factor.

### Definitions

In the specification, the term “substituted or unsubstituted” may refer to substituted or unsubstituted with at least one substituent of (e.g., selected from among) the group including (e.g., consisting of) a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In one or more embodiments, each of the substituents exemplified herein may be substituted or unsubstituted. For example, a biphenyl group may be interpreted as an aryl group or a phenyl group substituted with a phenyl group.

In the specification, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In one or more embodiments, the rings formed by being bonded to each other may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In one or more embodiments, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but the embodiment of the present disclosure is not limited thereto.

In the specification, a cycloalkyl group may refer to a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but the embodiment of the present disclosure is not limited thereto.

In the specification, an alkenyl group refers to a hydrocarbon group including at least one carbon double bond in the middle or terminal of an alkyl group having 2 or more carbon atoms. The alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, and/or the like, but the embodiment of the present disclosure is not limited thereto.

In the specification, an alkynyl group refers to a hydrocarbon group including at least one carbon triple bond in the middle or terminal of an alkyl group having 2 or more carbon atoms. The alkynyl group may be linear or branched. Although the number of carbon atoms is not specifically limited, it is 2 to 30, 2 to 20, or 2 to 10.

Specific examples of the alkynyl group may include an ethynyl group, a propynyl group, and/or the like, but are not limited thereto.

In the specification, the hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the specification, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 60, 6 to 50, 6 to 40, 6 to 30, 6 to 20, or 6 to 15.

Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but the embodiment of the present disclosure is not limited thereto.

In the specification, the fluorenyl group may be substituted, and two substituents may be bonded to each other to form a spiro structure. Examples of the substituted fluorenyl group are as follows. However, the embodiment of the present disclosure is not limited thereto.

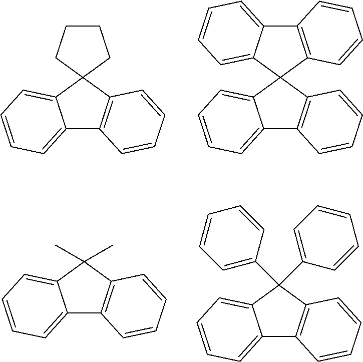

The heterocyclic group herein refers to any functional group or substituent derived from a ring containing at least one of B, O, N, P, Si, or Se as a heteroatom.

The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si or S as a heteroatom. When the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 60, 2 to 50, 2 to 40, 2 to 30, 2 to 20, or 2 to 10.

In the specification, the aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but the embodiment of the present disclosure is not limited thereto.

In the specification, the heteroaryl group may contain at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 60, 2 to 50, 2 to 40, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but the embodiment of the present disclosure is not limited thereto.

In the specification, the description of the aryl group may be applied to an arylene group except that the arylene group is a divalent group. The description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but the embodiment of the present disclosure is not limited thereto.

In the specification, the germanium group includes an alkylgermanium group and an arylgermanium group. Examples of germanium group may include a trimethylgermanium group, triethylgermanium group, a t-butyldimethylgermanium group, a vinyldimethylgermanium group, a propyldimethylgermanium group, a triphenylgermanium group, a tribiphenylgermanium group, a dipenylgermanium group, a phenyl germanium group, and/or the like, but the embodiment of the present disclosure is not limited thereto.

In the specification, the number of ring-forming carbon atoms in the carbonyl group is not specifically limited, but may be 1 to 40, 1 to 30, or 1 to 20. For example, the carbonyl group may have the following structures, but the embodiment of the present disclosure is not limited thereto.

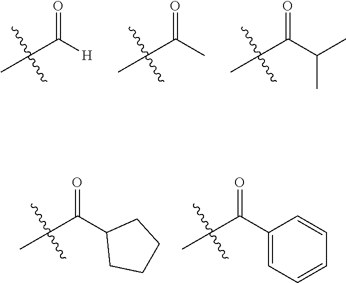

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to that a sulfur atom is bonded to the alkyl group or the aryl group as defined herein. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment of the present disclosure is not limited thereto.

In the specification, an oxy group may refer to that an oxygen atom is bonded to the alkyl group or the aryl group as defined herein. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but the embodiment of the present disclosure is not limited thereto.

The boron group herein may refer to that a boron atom is bonded to the alkyl group or the aryl group as defined herein. The boron group includes an alkyl boron group and an aryl boron group. Examples of the boron group may include a dimethylboron group, a trimethylboron group, a t-butyldimethylboron group, a diphenylboron group, a phenylboron group, and/or the like, but the embodiment of the present disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, and/or the like, but the embodiment of the present disclosure is not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described herein.

In the specification, the aryl group among an aryloxy group, an arylthio group, an arylsulfoxy group, an arylamino group, an arylboron group, an arylsilyl group, an arylamine group is the same as the examples of the aryl group described herein.

In the specification, a direct linkage may refer to a single bond.

In one or more embodiments, in the specification, “ ” and “ ” refer to a position to be connected.

Hereinafter, embodiments of the present disclosure will be described with reference to the accompanying drawings.

### Display Device

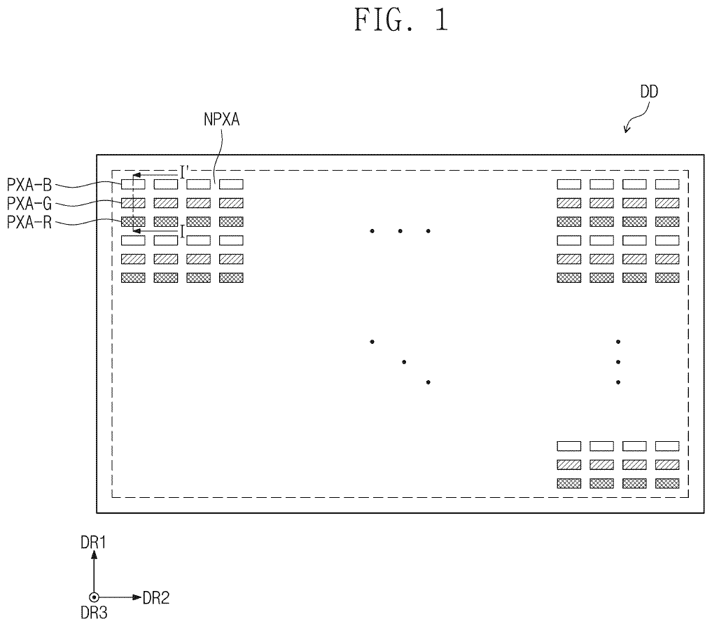

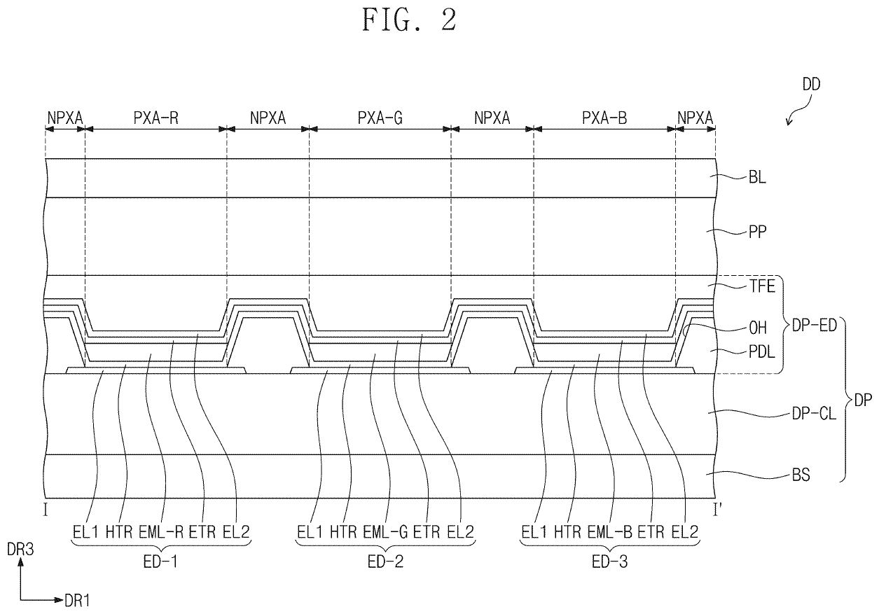

FIG. 1 is a plan view illustrating one or more embodiments of a display device DD. FIG. 2 is a cross-sectional view of the display device DD of the embodiment. FIG. 2 is a cross-sectional view illustrating a part taken along the line I-I′ of FIG. 1.

The display device DD may include a display panel DP and an optical layer PP arranged on the display panel DP. The display panel DP includes light emitting elements ED-1, ED-2, and ED-3. The display device DD may include a plurality of light emitting elements ED-1, ED-2, and ED-3. The optical layer PP may be arranged on the display panel DP to control reflected light in the display panel DP due to external light. The optical layer PP may include, for example, a polarization layer or a color filter layer. In one or more embodiments, unlike the configuration illustrated in the drawing, the optical layer PP may not be provided from the display device DD of one or more embodiments.

A base substrate BL may be arranged on the optical layer PP. The base substrate BL may be a member which provides a base surface on which the optical layer PP arranged. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In one or more embodiments, unlike the configuration illustrated, in one or more embodiments, the base substrate BL may not be provided.

The display device DD according to one or more embodiments may further include a filling layer. The filling layer may be arranged between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining film PDL, the light emitting elements ED-1, ED-2, and ED-3 arranged between portions of the pixel defining film PDL, and an encapsulation layer TFE arranged on the light emitting elements ED-1, ED-2, and ED-3.

The base layer BS may be a member which provides a base surface on which the display device layer DP-ED is provided. The base layer BS may be a glass substrate, a metal substrate, a plastic substrate, and/or the like. However, the embodiment is not limited thereto, and the base layer BS may be an inorganic layer, an organic layer, or a composite material layer.

In one or more embodiments, the circuit layer DP-CL is provided on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-1, ED-2, and ED-3 of the display device layer DP-ED.

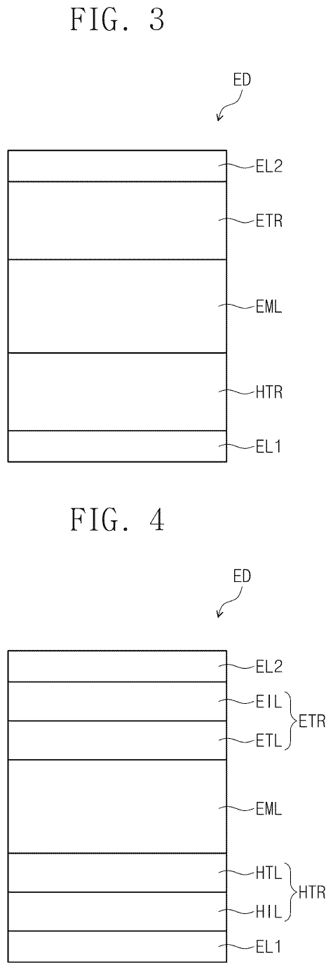

Each of the light emitting elements ED-1, ED-2, and ED-3 may have a structure of each light emitting element ED of embodiments according to FIGS. 3 to 6, as described in more detail elsewhere herein. Each of the light emitting elements ED-1, ED-2, and ED-3 may include a first electrode EL1, a hole transport region HTR, emission layers EML-R, EML-G, and EML-B, an electron transport region ETR, and a second electrode EL2.

FIG. 2 illustrates one or more embodiments in which the emission layers EML-R, EML-G, and EML-B of the light emitting elements ED-1, ED-2, and ED-3 are provided in openings OH defined in the pixel defining film PDL, and the hole transport region HTR, the electron transport region ETR, and the second electrode EL2 are provided as a common layer in the entire light emitting elements ED-1, ED-2, and ED-3. However, the embodiment of the present disclosure is not limited thereto, and unlike the configuration illustrated in FIG. 2, the hole transport region HTR and the electron transport region ETR in one or more embodiments may be provided by being patterned inside the openings OH defined in the pixel defining film PDL. For example, the hole transport region HTR, the emission layers EML-R, EML-G, and EML-B, and the electron transport region ETR of the light emitting elements ED-1, ED-2, and ED-3 in one or more embodiments may be provided by being patterned in an inkjet printing method.

The encapsulation layer TFE may cover the light emitting elements ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The encapsulation layer TFE may be provided on the second electrode EL2 and may be provided filling the opening OH.

Referring to FIGS. 1 and 2, the display device DD may include one or more non-light emitting region(s) NPXA and also include light emitting regions PXA-R, PXA-G, and PXA-B. The light emitting regions PXA-R, PXA-G, and PXA-B may be regions in which light generated by the respective light emitting elements ED-1, ED-2, and ED-3 are emitted. The light emitting regions PXA-R, PXA-G, and PXA-B may be spaced and/or apart from each other on a plane (e.g., in a plan view).

Each of the light emitting regions PXA-R, PXA-G, and PXA-B may be a region divided (i.e., defined) by the pixel defining film PDL. The non-light emitting areas NPXA may be areas between the adjacent light emitting areas PXA-R, PXA-G, and PXA-B, which correspond to the pixel defining film PDL. In one or more embodiments, in the specification, the light emitting regions PXA-R, PXA-G, and PXA-B may respectively correspond to pixels. The pixel defining film PDL may divide the light emitting elements ED-1, ED-2, and ED-3. The emission layers EML-R, EML-G, and EML-B of the light emitting elements ED-1, ED-2, and ED-3 may be provided in openings OH defined in the pixel defining film PDL and separated from each other.

The light emitting regions PXA-R, PXA-G, and PXA-B may be divided into a plurality of groups according to the color of light generated from the light emitting elements ED-1, ED-2, and ED-3. In the display device DD of one or more embodiments illustrated in FIGS. 1 and 2, three light emitting regions PXA-R, PXA-G, and PXA-B, which emit red light, green light, and blue light, respectively, are exemplarily illustrated. For example, the display device DD of one or more embodiments may include the red light emitting region PXA-R, the green light emitting region PXA-G, and the blue light emitting region PXA-B that are separated from each other.

In the display device DD according to one or more embodiments, the plurality of light emitting elements ED-1, ED-2 and ED-3 may be to emit light beams having wavelengths different from each other. For example, in one or more embodiments, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, the embodiment of the present disclosure is not limited thereto, and the first to third light emitting elements ED-1, ED-2, and ED-3 may be to emit light beams in substantially the same wavelength range or at least one light emitting element may be to emit a light beam in a wavelength range different from the others. For example, the first to third light emitting elements ED-1, ED-2, and ED-3 may all emit blue light.

The light emitting regions PXA-R, PXA-G, and PXA-B in the display device DD according to one or more embodiments may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B each may be arranged along the second directional axis DR2. In one or more embodiments, the red light emitting region PXA-R, the green light emitting region PXA-G, and the blue light emitting region PXA-B may be alternately arranged in this order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas when viewed on a plane defined by the first directional axis DR1 and the second directional axis DR2.

In one or more embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality desired or required in the display device DD. For example, the arrangement form of the light emitting regions PXA-R, PXA-G, and PXA-B may be a pentile (PENTILE™) arrangement form or a diamond (Diamond Pixel™) arrangement form, (PENTILE™ and Diamond Pixel™ are registered trademarks owned by Samsung Display Co., Ltd.).

In one or more embodiments, the areas of the light emitting regions PXA-R, PXA-G, and PXA-B may be different from each other. For example, in one or more embodiments, the area of the green light emitting region PXA-G may be smaller than that of the blue light emitting region PXA-B, but the embodiment of the present disclosure is not limited thereto.

Hereinafter, FIG. 3 to FIG. 6 are cross-sectional views schematically showing light emitting elements according to one or more embodiments. The light emitting element ED according to one or more embodiments may include a first electrode EL1, a second electrode EL2 oppositely arranged to the first electrode EL1, and at least one functional layer arranged between the first electrode EL1 and the second electrode EL2. The light emitting element ED of one or more embodiments may include a fused polycyclic compound of one or more embodiments, as described in more detail elsewhere herein, in the at least one functional layer.

The light emitting element ED may include a hole transport region HTR, an emission layer EML, an electron transport region ETR, and/or the like, stacked in order, as the at least one functional layer. Referring to FIG. 3, the light emitting element ED of one or more embodiments may include a first electrode EL1, a hole transport region HTR, an emission layer EML, an electron transport region ETR, and a second electrode EL2, stacked in order.

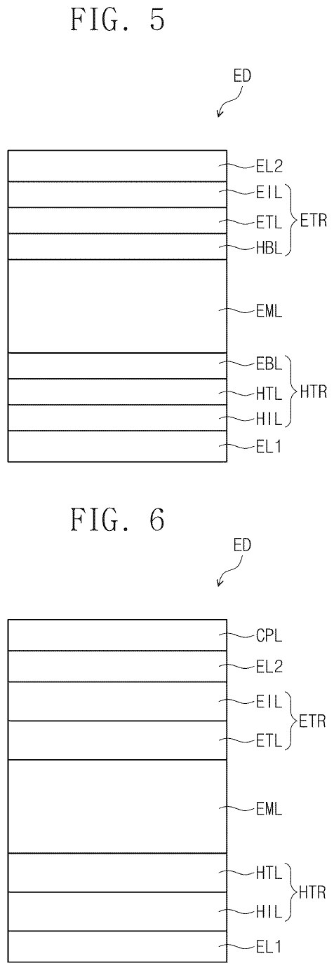

Compared with FIG. 3, FIG. 4 illustrates a cross-sectional view of a light emitting element ED of one or more embodiments, in which a hole transport region HTR includes a hole injection layer HIL and a hole transport layer HTL, and an electron transport region ETR includes an electron injection layer EIL and an electron transport layer ETL. In one or more embodiments, compared with FIG. 3, FIG. 5 illustrates a cross-sectional view of a light emitting element ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting element ED of one or more embodiments including a capping layer CPL arranged on a second electrode EL2.

The light emitting element ED of one or more embodiments may include a fused polycyclic compound of one or more embodiments, which will be explained later, in the at least one functional layer. In the light emitting element ED of one or more embodiments, at least one among the hole transport region HTR, the emission layer EML, and the electron transport region ETR may include the fused polycyclic compound of one or more embodiments. For example, in the light emitting element ED of one or more embodiments, the emission layer EML may include the fused polycyclic compound of one or more embodiments.

The first electrode EL1 has conductivity (e.g., is a conductor). The first electrode EL1 may be formed of a metal material, a metal alloy, or a conductive compound. The first electrode EL1 may be an anode or a cathode. However, the embodiment of the present disclosure is not limited thereto. In one or more embodiments, the first electrode EL1 may be a pixel electrode. The first electrode EL1 may be a transmissive electrode, a transflective electrode, or a reflective electrode.

The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these (e.g., among thereof), a mixture of two or more selected from among these (e.g., among thereof), or an oxide thereof.

When the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound or mixture thereof (e.g., a mixture of Ag and Mg). In one or more embodiments, the first electrode EL1 may have a multilayer structure including a reflective film or a transflective film formed of the herein-described materials, and a transparent conductive film formed of ITO, IZO, ZnO, ITZO, and/or the like, For example, the first electrode EL1 may have a three-layer structure of ITO/Ag/ITO, but the embodiment of the present disclosure is not limited thereto. In one or more embodiments, the embodiment of the present disclosure is not limited thereto, and the first electrode EL1 may include the herein-described metal materials, combinations of at least two metal materials of the herein-described metal materials, oxides of the herein-described metal materials, and/or the like. The thickness of the first electrode EL1 may be from about 700 angstrom (Å) to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer, or an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In one or more embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1:

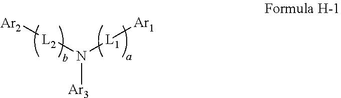

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In one or more embodiments, if (e.g., when) a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In one or more embodiments, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 may be a monoamine compound. In one or more embodiments, the compound represented by Formula H-2 may be a diamine compound in which at least one among Ar₁ to Ar₃ includes the amine group as a substituent. In one or more embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any (e.g., at least) one selected from among the compounds in Compound Group H. However, the compounds listed in Compound Group H are examples, and the compounds represented by Formula H-1 are not limited to those represented by Compound Group H:

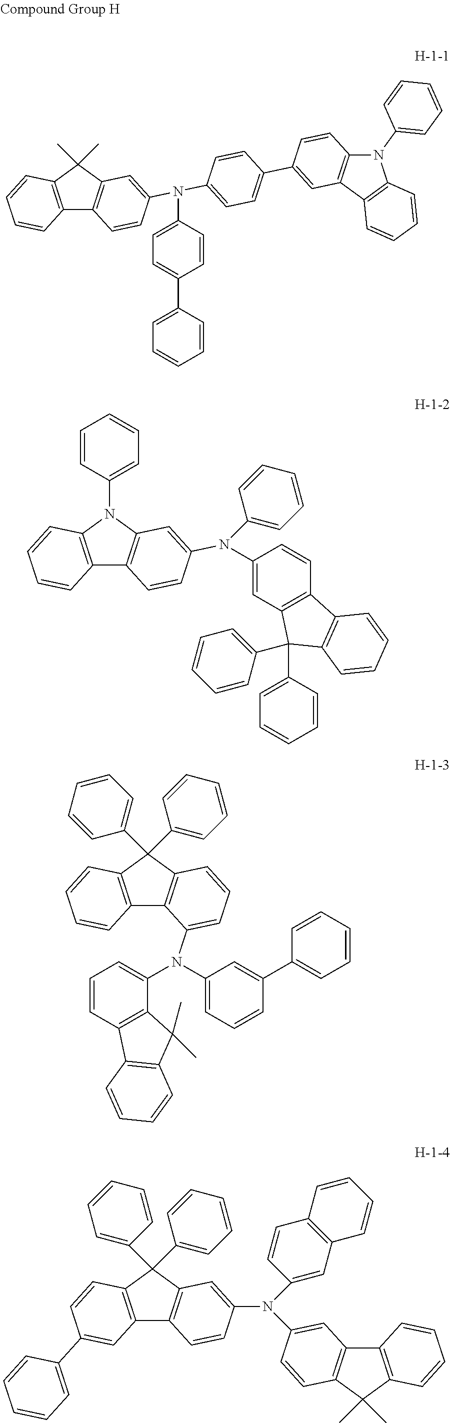 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

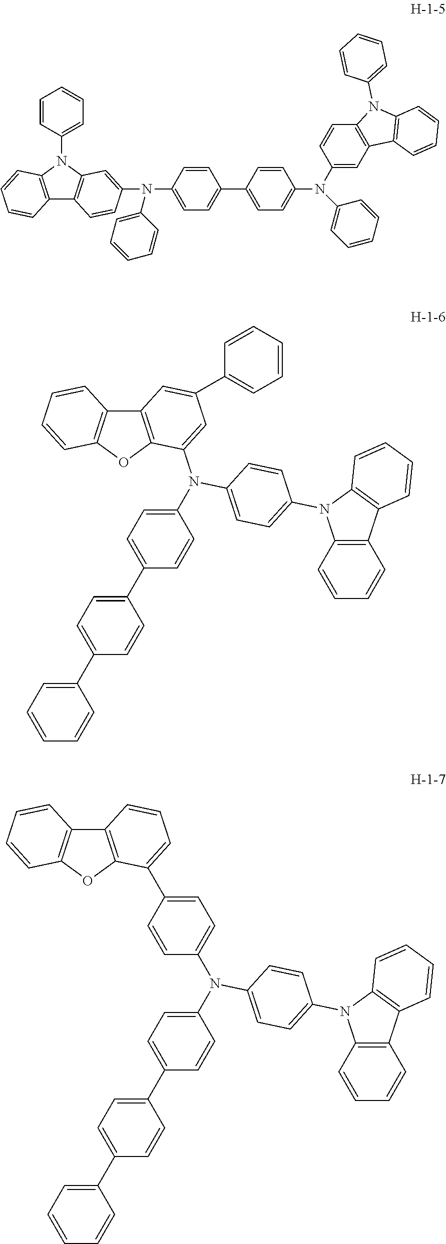 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

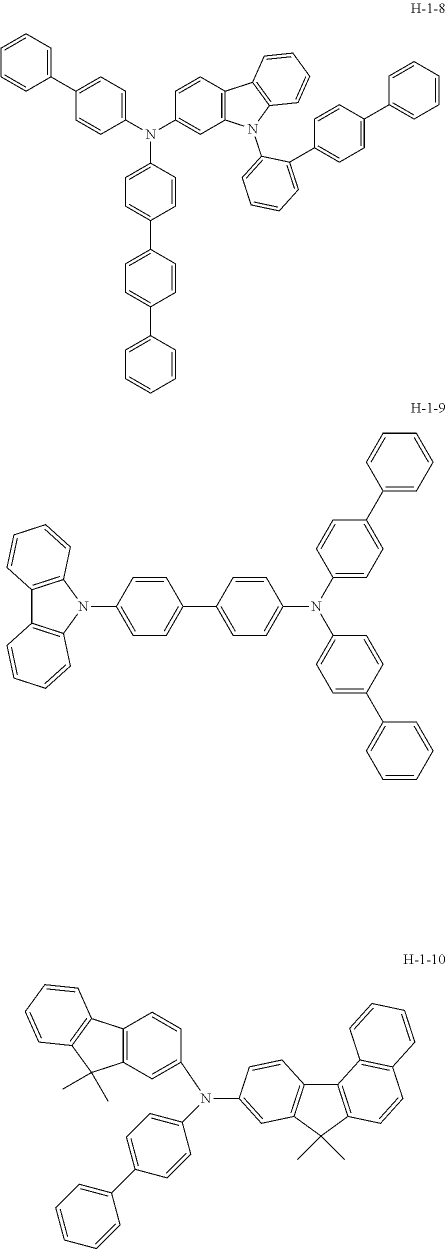 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

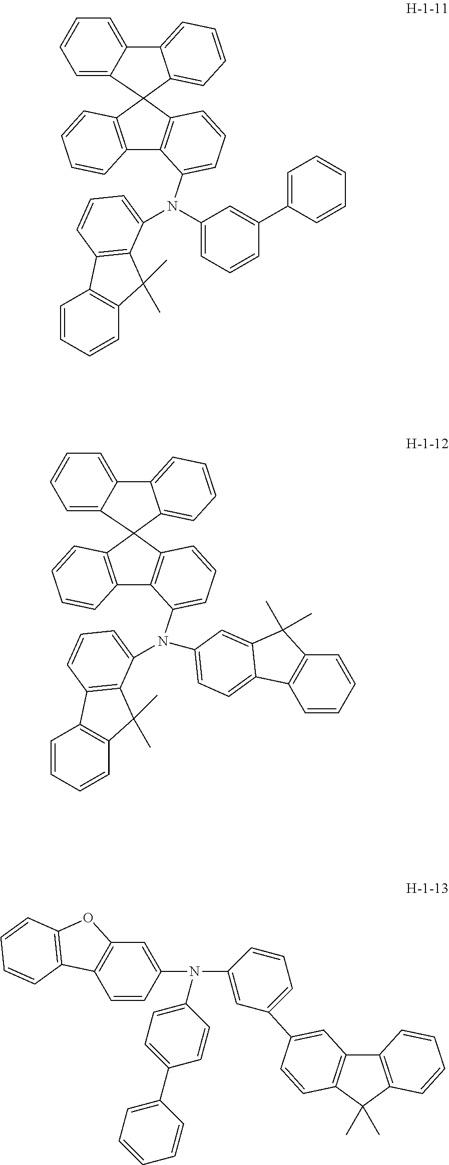 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

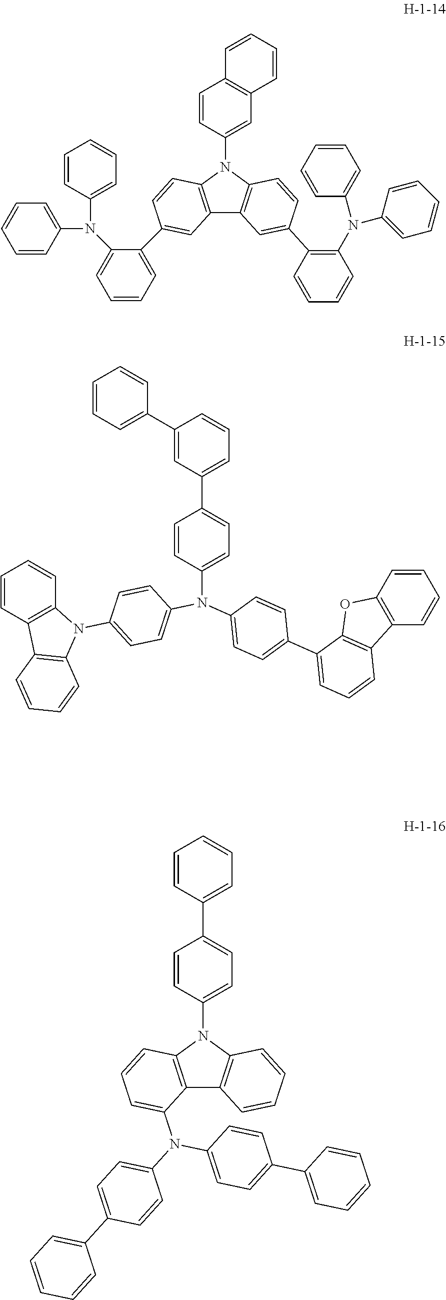 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

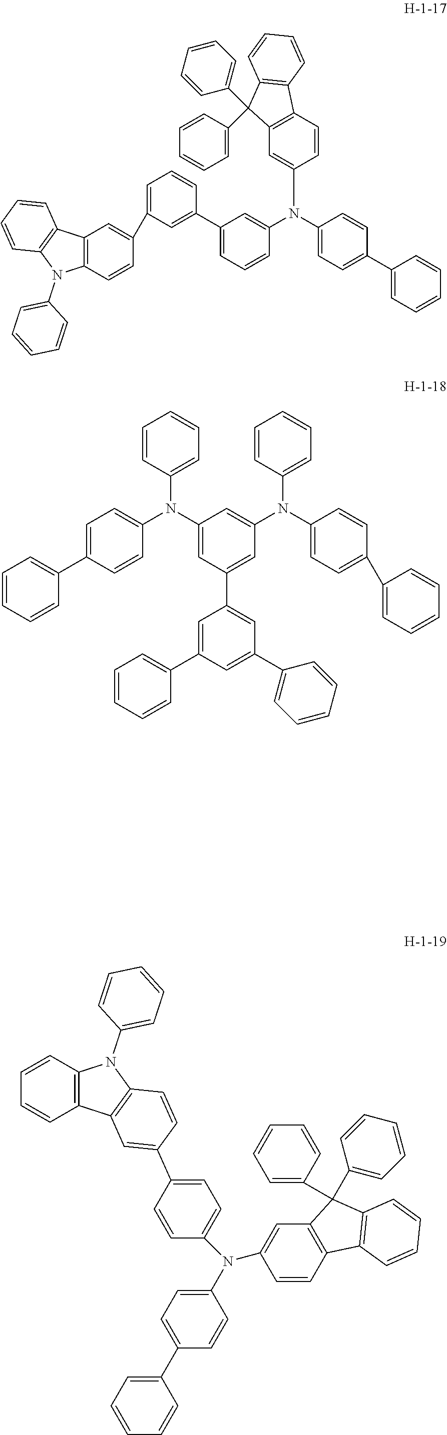 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include at least one selected from among a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methyl phenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), and/or the like.

The hole transport region HTR may include at least one selected from among a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis[4-methylphenyl]benzenamine](TAPC), 4,4′-bis[N,N′-(3-tolyl)amino]-3,3′-dimethyl biphenyl (HMTPD), 1,3-bis(N-carbazolyl) benzene (mCP), and/or the like.

In one or more embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include the herein-described compounds of the hole transport region in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, if (e.g., when) the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the herein-described ranges, satisfactory hole transport properties may be achieved without a substantial increase in driving voltage.

The hole transport region HTR may further include a charge generating material to increase conductivity in addition to the herein-described materials. The charge generating material may be dispersed uniformly (substantially uniformly) or non-uniformly (substantially non-uniformly) in the hole transport region HTR. The charge generating material may be, for example, a p-dopant. The p-dopant may include at least one of a halogenated metal compound, a quinone derivative, a metal oxide, or a cyano group-containing compound, but the embodiment of the present disclosure is not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but the embodiment of the present disclosure is not limited thereto.

As described herein, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be utilized as a material to be included in the buffer layer. The electron blocking layer EBL is a layer that serves to prevent or reduce the electron injection from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of multiple different materials, or a multi-layered structure having a plurality of layers formed of multiple different materials.

The light emitting element ED of one or more embodiments may include a fused polycyclic compound represented by Formula 1 in at least one functional layer arranged between the first electrode EL1 and the second electrode EL2. The emission layer EML in the light emitting element ED according to one or more embodiments may include a fused polycyclic compound of one or more embodiments. In one or more embodiments, the emission layer EML may include the fused polycyclic compound of one or more embodiments as a dopant. The fused polycyclic compound of one or more embodiments may be a dopant material of the emission layer EML. In one or more embodiments, in the specification, the fused polycyclic compound of one or more embodiments may be referred to as a first compound.

### Fused Polycyclic Compound

The fused polycyclic compound of one or more embodiments may include a fused polycyclic heterocycle in which five rings are fused and which contains a first boron atom, a first nitrogen atom, and a second nitrogen atom, and may have a structure in which two aromatic hydrocarbon rings are linked to the fused polycyclic heterocycle. A second boron atom, a first heteroatom, and a second heteroatom may be arranged as a linking group between the fused polycyclic heterocycle and the two aromatic hydrocarbon rings. The two aromatic hydrocarbon rings may be linked to the fused polycyclic heterocycle via the second boron atom, the first heteroatom, and the second heteroatom to form an additional fused ring.

In one or more embodiments, in the fused polycyclic heterocycle included in the fused polycyclic compound, three substituted or unsubstituted benzene rings are linked via the first boron atom, the first nitrogen atom, and the second nitrogen atom, thereby forming five rings. More specifically, in the three benzene rings included in the fused polycyclic heterocycle, the three benzene rings may be linked around the first boron atom, a first benzene ring and a second benzene ring among the three benzene rings may be linked via the first nitrogen atom, and the remaining third benzene ring may be linked to the second benzene ring via the second nitrogen atom. The first boron atom and the first and second nitrogen atoms may all be linked to the second benzene ring.

In one or more embodiments, the two aromatic hydrocarbon rings included in the fused polycyclic compound may be linked to the fused polycyclic heterocycle via a second boron atom, the first heteroatom, and the second heteroatom to form an additional fused ring. More specifically, the fused polycyclic compound of one or more embodiments may have a structure in which a fourth benzene ring and a fifth benzene ring, which are two aromatic hydrocarbon rings, are linked to the fused polycyclic heterocycle, and the second boron atom, the first heteroatom, and the second heteroatom may be arranged as a linking group between the fused polycyclic heterocycle and the fourth and fifth benzene rings. The fourth and fifth benzene rings may be linked to the fused polycyclic heterocycle via the second boron atom, the first heteroatom, and the second heteroatom to form four additional fused rings.

The fourth benzene ring and the fifth benzene ring may be linked to the third benzene ring among the three benzene rings included in the fused polycyclic heterocycle. More specifically, the second boron atom, the first heteroatom, and the second heteroatom may be linked to the third benzene ring, the fourth benzene ring and the third benzene ring may be linked via the second boron atom and the first heteroatom, and the fifth benzene ring and the third benzene ring may be linked via the second boron atom and the second heteroatom. The second boron atom may be linked to a carbon atom, which corresponds to the para position with respect to the second nitrogen atom, among the carbon atoms constituting the third benzene ring.

The first heteroatom may be linked to a carbon atom, which corresponds to the para position with respect to the first boron atom, among the carbon atoms constituting the third benzene ring. The second heteroatom may be linked to a carbon atom, which corresponds to the ortho position with respect to the first boron atom, among the carbon atoms constituting the third benzene ring. In one or more embodiments, in the present specification, the third benzene ring, to which the fourth benzene ring and the fifth benzene ring are linked, may be referred to as a “fused benzene ring.”

In one or more embodiments, the first heteroatom may be a nitrogen (N) atom, an oxygen (O) atom, a sulfur (S) atom, a selenium (Se) atom, or a tellurium (Te) atom. The second heteroatom may be an oxygen (O) atom, a sulfur (S) atom, or a selenium (Se) atom. From the viewpoint of ease of synthesis and chemical stability, the second heteroatom may not include (e.g., may exclude) a nitrogen atom. Because the second heteroatom linked to the ortho-position carbon with respect to the first boron atom does not include a nitrogen atom, the ease of synthesis and chemical stability may be improved.

The fused polycyclic compound of one or more embodiments may include the first substituent linked to the fused polycyclic heterocycle. The first substituent may be linked to at least one of the first nitrogen atom or the second nitrogen atom constituting the fused polycyclic heterocycle in the fused polycyclic compound of one or more embodiments. The first substituent may include a benzene moiety, and may include a first sub-substituent and a second sub-substituent which are substituted at a specific position carbon of the benzene moiety. For example, the first substituent may include a benzene moiety linked to the nitrogen atom of the fused polycyclic heterocycle, and a structure in which the first sub-substituent and the second sub-substituent are linked to two ortho positions with respect to the nitrogen atom. Each of the first sub-substituent and the second sub-substituent may be a substituted or unsubstituted aryl group having 6 to 30 ring-forming carbon atoms. For example, each of the first sub-substituent and the second sub-substituent may be a substituted or unsubstituted phenyl group.

The fused polycyclic compound of one or more embodiments may be represented by Formula 1:

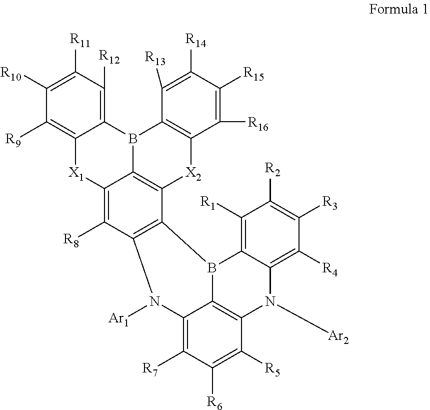

The fused polycyclic compound represented by Formula 1 of one or more embodiments may include a fused polycyclic heterocycle in which five rings are fused with having a first boron atom, a first nitrogen atom, and a second nitrogen atom at the center, and may have a structure in which two aromatic hydrocarbon rings are linked to the fused polycyclic heterocycle. A second boron atom, a first heteroatom, and a second heteroatom may be arranged as a linking group between the fused polycyclic heterocycle and the two aromatic hydrocarbon rings. The two aromatic hydrocarbon rings may be linked to the fused polycyclic heterocycle via the second boron atom, the first heteroatom, and the second heteroatom to form an additional fused ring. In one or more embodiments, in the present specification, in Formula 1, the benzene ring which is substituted with substituents represented by R₁ to R₄ may correspond to the aforementioned first benzene ring, the benzene ring which is substituted with substituents represented by R₅ to R₇ may correspond to the aforementioned second benzene ring, and the benzene ring which is substituted with a substituent represented by R₈ may correspond to the aforementioned third benzene ring.

In Formula 1, X₁ may be NR₁₇, O, S, Se, or Te.

In Formula 1, X₂ may be O, S, or Se.

In Formula 1, X₁ and X₂ may be the same as or different from each other. For example, X₁ may be S, and X₂ may be O. In one or more embodiments, X₁ may be NR₁₇ and X₂ may be O. In one or more embodiments, X₁ may be Se and X₂ may be O. In one or more embodiments, X₁ may be Te, and X₂ may be O. In one or more embodiments, both (e.g., simultaneously) X₁ and X₂ may be O.

In Formula 1, R₁ to R₇ may each independently be a hydrogen atom, a deuterium atom, a halogen atom, a cyano group, a nitro group, a substituted or unsubstituted silyl group, a substituted or unsubstituted germanium group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₁ to R₇ may each independently be a hydrogen atom, a deuterium atom, a fluorine group, a cyano group, a substituted or unsubstituted t-butyl group, a substituted or unsubstituted triphenylsilyl group, a substituted or unsubstituted phenyl group, a substituted or unsubstituted biphenyl group, a substituted or unsubstituted terphenyl group, a substituted or unsubstituted quaterphenyl group, a substituted or unsubstituted quinquephenyl group, a substituted or unsubstituted carbazole group, a substituted or unsubstituted benzofurocarbazole group, or a substituted or unsubstituted dibenzofuran group.

In Formula 1, R₈ to R₁₆ may each independently be a hydrogen atom, a deuterium atom, a halogen atom, a cyano group, a nitro group, a substituted or unsubstituted silyl group, a substituted or unsubstituted germanium group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₈ to R₁₆ may each independently be a hydrogen atom, a deuterium atom, a substituted or unsubstituted t-butyl group, a substituted or unsubstituted trimethylsilyl group, a substituted or unsubstituted trimethylgermanium group, a substituted or unsubstituted diphenylamine group, a substituted or unsubstituted a phenyl group, a substituted or unsubstituted biphenyl group, a substituted or unsubstituted terphenyl group, or a substituted or unsubstituted carbazole group. In one or more embodiments, each of R₈ to R₁₆ may be bonded to an adjacent group to form a ring. For example, if (e.g., when) X₁ is NR₁₇ and R₁₇ is a substituted or unsubstituted phenyl group, R₉ may be bonded to R₁₇ to form a fused ring containing a 5-membered or 6-membered heterocycle. In one or more embodiments, adjacent two among R₈ to R₁₆ may be bonded to each other to form a ring.

In Formula 1, R₁₇ may be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In one or more embodiments, R₁₇ may be bonded to an adjacent group to form a ring. For example, R₁₇ may be a substituted or unsubstituted phenyl group, a substituted or unsubstituted biphenyl group, or a substituted or unsubstituted terphenyl group.

In Formula 1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, Ar₁ and Ar₂ may each independently be a substituted or unsubstituted biphenyl group, a substituted or unsubstituted terphenyl group, a substituted or unsubstituted carbazole group, a substituted or unsubstituted dibenzofuran group, or a substituted or unsubstituted dibenzothiophene group.

In Formula 1, at least one of Ar₁ or Ar₂ may be represented by Formula S. In the present specification, the substituent represented by Formula S may correspond to the aforementioned first substituent.

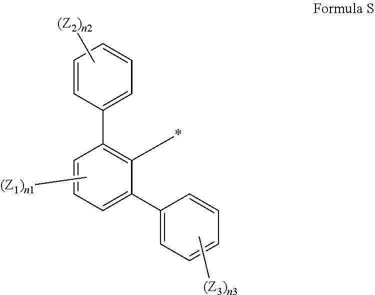

In Formula 1, Z₁ to Z₃ may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In one or more embodiments, Z₁ to Z₃ each may be bonded to an adjacent group to form a ring. For example, Z₁ to Z₃ may each independently be a hydrogen atom, a substituted or unsubstituted t-butyl group, or a substituted or unsubstituted phenyl group.

In Formula S, n1 may be an integer of 0 to 3. When n1 is 0, the fused polycyclic compound of one or more embodiments may not be substituted with Z₁. In Formula 1, the case where n1 is 3 and Z₁'s are all hydrogen atoms may be the same as the case where n1 is 0 in Formula 1. When n1 is an integer of 2 or greater, a plurality of Z₁'s may all be the same, or at least one among the plurality of Z₁'s may be different from the others.

In Formula S, n2 and n3 may each independently be an integer of 0 to 5. When each of n2 and n3 is 0, the fused polycyclic compound of one or more embodiments may not be substituted with each of Z₂ and Z₃. In Formula 1, the case where each of n2 and n3 is 5 and Z₂'s and Z₃'s are each hydrogen atoms may be the same as the case where each of n2 and n3 is 0 in Formula 1. When each of n2 and n3 is an integer of 2 or greater, a plurality of Z₂'s and Z₃'s may each be the same or at least one among the plurality of Z₂'s and Z₃'s may be different from the others.

In Formula S, [symbol] may be a position linked to Formula 1.

The fused polycyclic compound represented by Formula 1 of one or more embodiments may have a structure in which two hydrocarbon rings are fused to the fused polycyclic heterocycle at specific positions via the boron atom and two heteroatoms, thereby achieving high efficiency and long service life.

The fused polycyclic compound of one or more embodiments may include a fused polycyclic heterocycle in which five rings are fused with having a first boron atom, a first nitrogen atom, and a second nitrogen atom at the center, and may have a structure in which two aromatic hydrocarbon rings are linked to the fused polycyclic heterocycle. In one or more embodiments, the fused polycyclic compound of one or more embodiments may include an additional fused ring formed by linking the two aromatic hydrocarbon rings to the fused polycyclic heterocycle via the second boron atom, the first heteroatom, and the second heteroatom. The second boron atom, the first heteroatom, and the second heteroatom which link the two aromatic hydrocarbon rings with the fused polycyclic heterocycle are linked to a specific position of the fused polycyclic heterocycle, and thus the luminous efficiency and service life characteristics may be improved.

One of the important factors that exhibit a relatively low lifetime in a device utilizing thermally activated delayed fluorescence is a relatively low reverse inter-system crossing (RISC) rate in a thermally activated delayed fluorescence (TADF)-based emitter. Because the spin-orbit coupling constant between the lowest excited singlet energy level (S1 level) and the lowest excited triplet energy level (T1 level) is basically close to 0 according to the El-sayed rule, it is difficult to generate a direct transition between the lowest excited singlet energy level (S1 level) and the lowest excited triplet energy level (T1 level), and thus, a complex inter-system crossing mechanism via a higher excited triplet energy level (Tn level, where n is 2 or greater) is utilized. In this case, exciton quenching, such as the collision of the accumulated triplet exciton, occurs, and thus the efficiency and service life of the organic light emitting element may be deteriorated. Accordingly, when the reverse inter-system crossing rate is improved and thus the triplet exciton with high energy accumulated in the emitter may be transited at a high rate, both (e.g., simultaneously) luminous efficiency and service life may be improved.

The fused polycyclic compound according to one or more embodiments of the present present disclosure has a structure in which two hydrocarbon rings are fused to the fused polycyclic heterocycle at specific positions via the boron atom and two heteroatoms, thereby increasing the spin-orbit coupling constant and thus achieving high efficiency and long service life. More specifically, one of the two heteroatoms linking the two aromatic hydrocarbon rings and the fused polycyclic heterocycle is arranged to be positioned at the ortho position with respect to the first boron atom of the fused polycyclic heterocycle, thereby inducing the distortion aspect of the light emitting core and mixing the local excited state (LE state) and the charge transfer state (CT state). This may cause a change in orbital distribution between the lowest excited singlet energy level (S1 level) and the lowest excited triplet energy level (T1 level), so that the inhibition aspect by the El-sayed rule is offset, and thus the spin-orbit coupling constant between the lowest excited singlet energy level (S1 level) and the lowest excited triplet energy level (T1 level) may be increased. Because the transition probability between the triplet state and the singlet state and the delayed fluorescence lifetime (tau, T) depend on the intensity of the spin-orbit interaction, the fused polycyclic compound of one or more embodiments in which the spin-orbit coupling constant is improved may have an improved reverse inter-system crossing rate and a shortened delayed fluorescence lifetime. In one or more embodiments, because the fused polycyclic compound of one or more embodiments has a structure in which a conjugated structure is expanded through an aromatic hydrocarbon ring, a multiple resonance aspect may be improved and the luminous efficiency may be further improved. Accordingly, the luminous efficiency and element service life of the light emitting element including the fused polycyclic compound of one or more embodiments as an emitter may be greatly improved.

Furthermore, the fused polycyclic compound of one or more embodiments may effectively maintain a trigonal planar structure of the boron atom through a steric hindrance aspect by the first substituent. The boron atom may have electron deficiency characteristics by a vacant p-orbital, thereby form a bond with other nucleophiles, and thus be changed into a tetrahedral structure, which may cause deterioration of the device. According to the present disclosure, the fused polycyclic compound of one or more embodiments has the first substituent introduced at the fused ring core, thereby may effectively protect the vacant p-orbital of the boron atom, and thus may prevent or reduce the deterioration phenomenon due to the structural change.

In one or more embodiments, the fused polycyclic compound of one or more embodiments may have an increase in the luminous efficiency because the intermolecular interaction may be suppressed or reduced through the steric hindrance effects by the first substituent, thereby controlling the formation of aggregation, excimer, or exciplex. Because the fused polycyclic compound represented by Formula of one or more embodiments has a bulky structure, a distance between molecules may be increased to reduce Dexter energy transfer, thereby suppressing or reducing an increase in concentration of triplet excitons in the fused polycyclic compound. A high concentration of triplet excitons remains in an excited state for a long period of time, and thus may induce compound decomposition, leading to the generation of hot excitons having a high energy through triplet-triplet annihilation (TTA), thereby resulting in the destruction of the associated (e.g., surrounding) compound structure. In one or more embodiments, because the TTA is a bimolecular reaction, which exhausts triplet excitons utilized for light emission at a high speed, a non-radiative transition may cause a decrease in luminous efficiency. The fused polycyclic compound of one or more embodiments has an increase in the distance between molecules due to the first substituent to thereby suppress or reduce the Dexter energy transfer, and thus may suppress or reduce the deterioration of service life due to the increase of triplet concentration. Therefore, when (e.g., when) the fused polycyclic compound of one or more embodiments is applied to the emission layer EML of the light emitting element ED, the luminous efficiency may be increased and the element service life may also be improved.

In one or more embodiments, in Formula 1, at least one among R₁ to R₇ may be a substituted or unsubstituted alkyl group having 1 to 10 carbon atoms, or may be represented by any (e.g., at least) one selected from among Formula A-1 to Formula A-4:

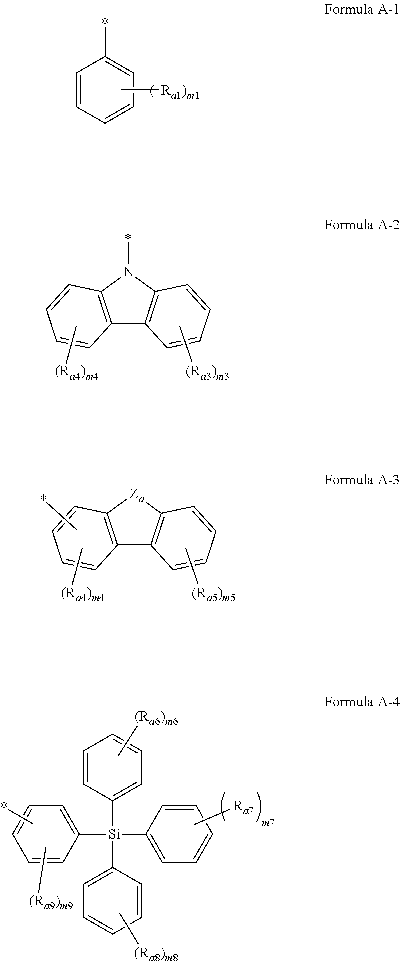

In Formula A-3, Zₐ may be NRₐ₁₀, O, S, or Se. For example, Zₐ may be O.

In Formula A-1 to Formula A-4, Rₐ₁ to Rₐ₁₀ may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₐ₁ to Rₐ₉ may each independently be a hydrogen atom, a deuterium atom, a cyano group, a substituted or unsubstituted phenoxy group, a substituted or unsubstituted diphenylamine group, a substituted or unsubstituted triphenylsilyl group, a substituted or unsubstituted methyl group, a substituted or unsubstituted t-butyl group, a substituted or unsubstituted phenyl group, a substituted or unsubstituted biphenyl group, a substituted or unsubstituted carbazole group, a substituted or unsubstituted dibenzofuran group, or a substituted or unsubstituted pyridine group. Rₐ₁₀ may be a substituted or unsubstituted phenyl group. In one or more embodiments, each of Rₐ₁ to Rₐ₁₀ may be bonded to an adjacent group to form a ring. For example, Rₐ₂ may be provided in plural, and the plurality of Rₐ₂'s may be bonded to each other to form an additional fused ring. In one or more embodiments, Rₐ₃ may be provided in plural, and the plurality of Rₐ₃'s may be bonded to each other to form an additional fused ring.

In Formula A-1 to Formula A-4, m1 and m6 to m8 may each independently be an integer of 0 to 5, m2, m3, m5, and m9 may each independently be an integer of each independently 0 to 4, and m4 is an integer of 0 to 3.

When each of m1, and m6 to m8 is 0, the fused polycyclic compound of one or more embodiments may exclude (e.g., not be substituted with) each of Rₐ₁, and Rₐ₆ to Rₐ₈. The case where each of m1, and m6 to m8 is 5, and Rₐ₁'s and Rₐ₆'s to Rₐ₈'s each are hydrogen atoms may be the same as the case where each of m1, and m6 to m8 is 0. When each of m1 and m6 to m8 is an integer of 2 or greater, a plurality of Rₐ₁'s and Rₐ₆'s to Rₐ₈'s may each be the same or at least one among the plurality of Rₐ₁'s, and Rₐ₆'s to Rₐ₈'s may be different from the others.

When each of m2, m3, m5, and m9 is 0, the fused polycyclic compound of one or more embodiments may not be substituted with each of Rₐ₂, Rₐ₃, Rₐ₅, and Rₐ₈. The case where each of m2, m3, m5, and m9 is 4 and Rₐ₂'s, Rₐ₁'s, Rₐ₅'s and Rₐ₉'s each are hydrogen atoms may be the same as the case where each of m2, m3, m5, and m9 is 0. When each of m2, m3, m5, and m9 is an integer of 2 or more, a plurality of Rₐ₂'s, Rₐ₁'s, Rₐ₅'s and Rₐ₉'s each may be the same or at least one among the plurality of Rₐ₂'s, Rₐ₁'s, Rₐ₅'s and Rₐ₉'s may be different from the others.

When m4 is 0, the fused polycyclic compound of one or more embodiments may exclude (e.g., not be substituted with) Rₐ₄. The case where m4 is 3 and Rₐ₄'s are all hydrogen atoms may be the same as the case where m4 is 0. When m4 is an integer of 2 or more, a plurality of Rₐ₄'s may all be the same, or at least one among the plurality of Rₐ₄'s may be different from the others.

In one or more embodiments, at least one selected from among R₁ to R₁₆ may be at least one (e.g., any one) selected from among Substituent Group 1:

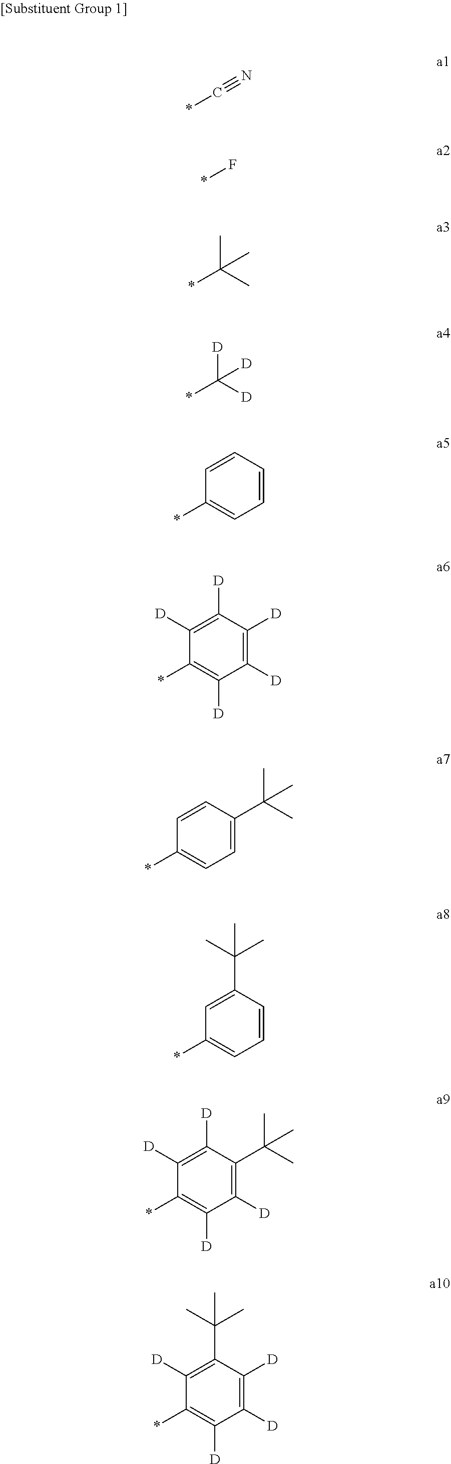

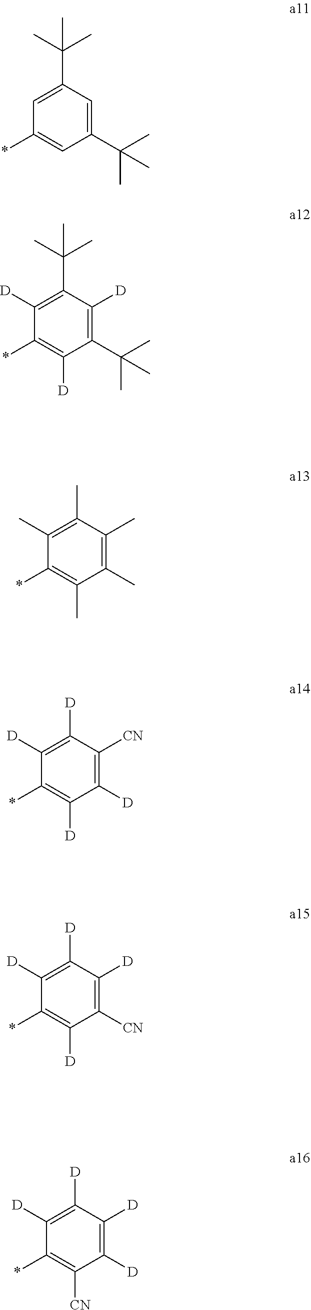 [SMILES: *c1cc(C(C)(C)C)cc(C(C)(C)C)c1 ; *c1c([2H])c(C(C)(C)C)c([2H])c(C(C)(C)C)c1[2H] ; *c1c(C)c(C)c(C)c(C)c1C ; *c1c([2H])c([2H])c(C#N)c([2H])c1[2H] ; *c1c([2H])c([2H])c([2H])c(C#N)c1[2H] ; *c1c([2H])c([2H])c([2H])c([2H])c1C#N]

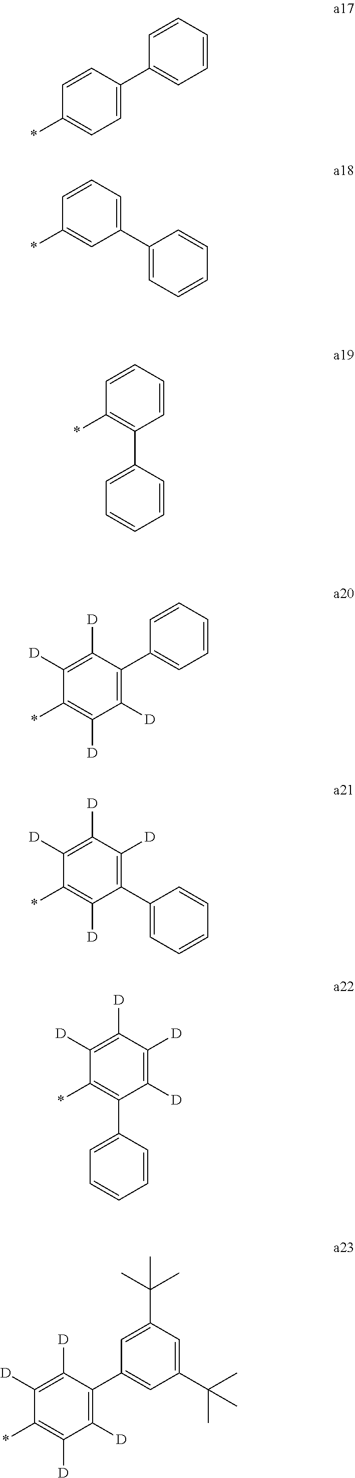

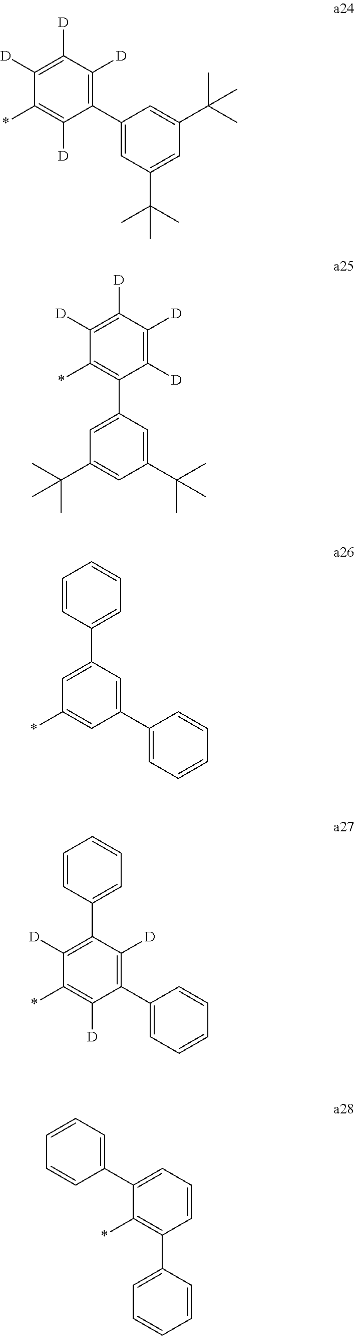

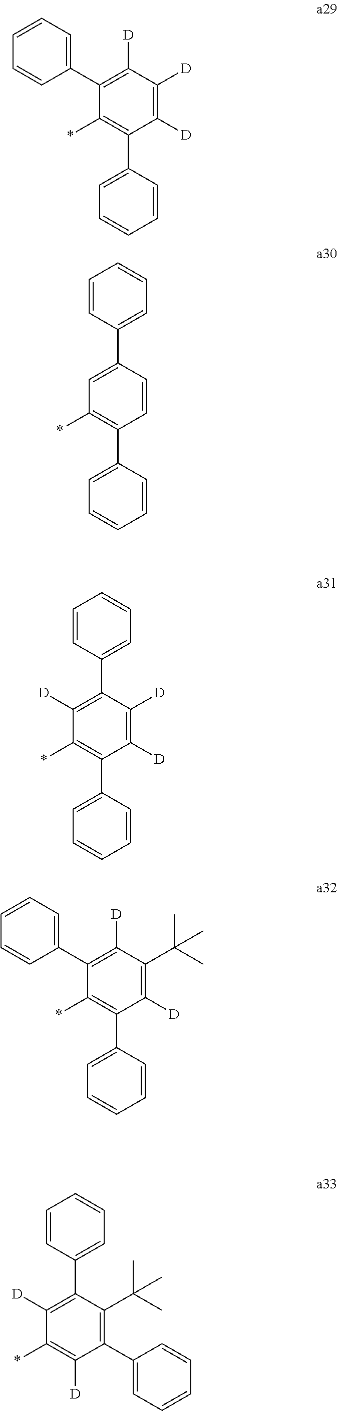

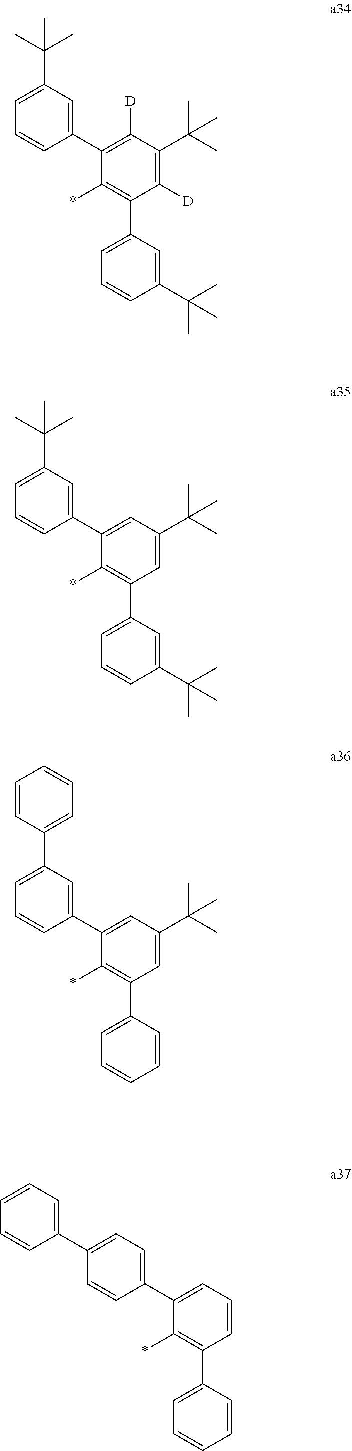 [SMILES: *c1c(-c2cccc(C(C)(C)C)c2)c([2H])c(C(C)(C)C)c([2H])c1-c1cccc(C(C)(C)C)c1 ; *c1c(-c2cccc(C(C)(C)C)c2)cc(C(C)(C)C)cc1-c1cccc(C(C)(C)C)c1 ; *c1c(-c2ccccc2)cc(C(C)(C)C)cc1-c1cccc(-c2ccccc2)c1 ; *c1c(-c2ccccc2)cccc1-c1ccc(-c2ccccc2)cc1]

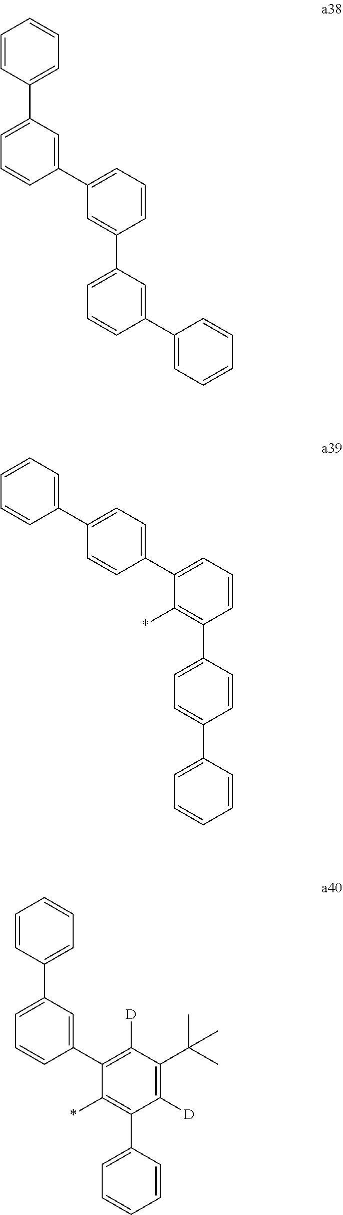

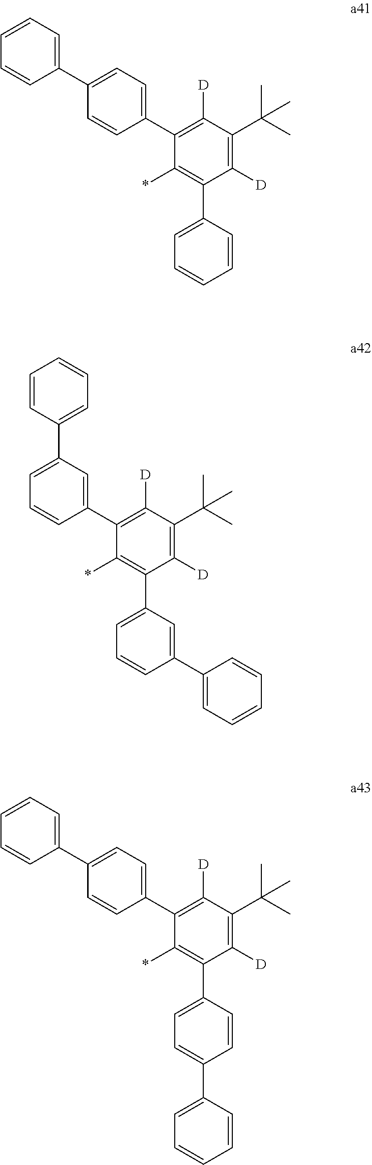 [SMILES: *c1c(-c2ccccc2)c([2H])c(C(C)(C)C)c([2H])c1-c1ccc(-c2ccccc2)cc1 ; *c1c(-c2cccc(-c3ccccc3)c2)c([2H])c(C(C)(C)C)c([2H])c1-c1cccc(-c2ccccc2)c1 ; *c1c(-c2ccc(-c3ccccc3)cc2)c([2H])c(C(C)(C)C)c([2H])c1-c1ccc(-c2ccccc2)cc1]

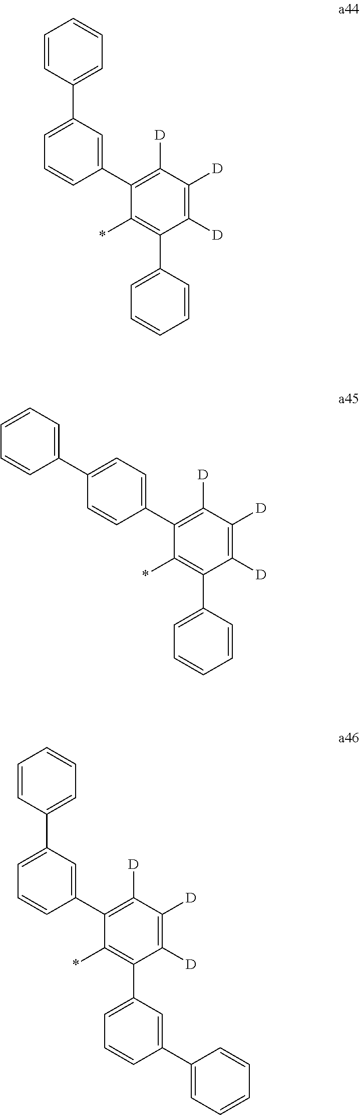 [SMILES: *c1c(-c2ccccc2)c([2H])c([2H])c([2H])c1-c1cccc(-c2ccccc2)c1 ; *c1c(-c2ccccc2)c([2H])c([2H])c([2H])c1-c1ccc(-c2ccccc2)cc1 ; *c1c(-c2cccc(-c3ccccc3)c2)c([2H])c([2H])c([2H])c1-c1cccc(-c2ccccc2)c1]

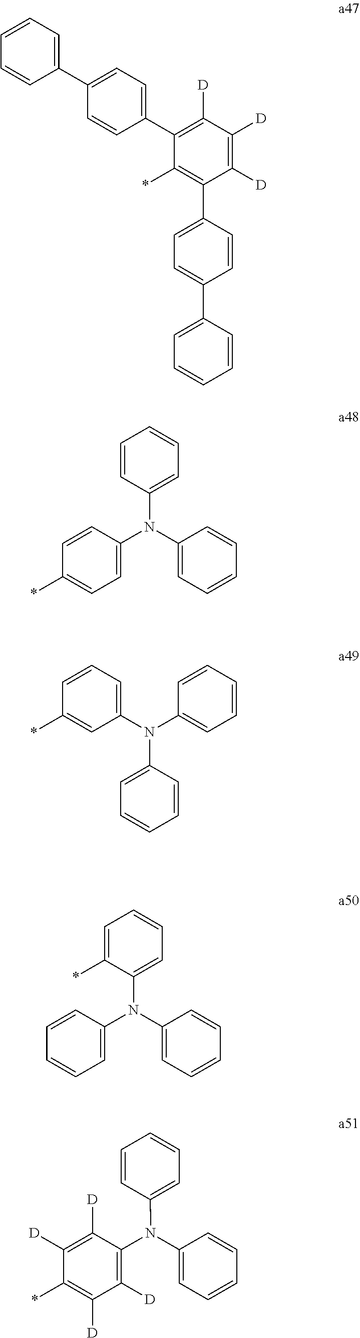 [SMILES: *c1c(-c2ccc(-c3ccccc3)cc2)c([2H])c([2H])c([2H])c1-c1ccc(-c2ccccc2)cc1 ; *c1ccc(N(c2ccccc2)c2ccccc2)cc1 ; *c1cccc(N(c2ccccc2)c2ccccc2)c1 ; *c1ccccc1N(c1ccccc1)c1ccccc1 ; *c1c([2H])c([2H])c(N(c2ccccc2)c2ccccc2)c([2H])c1[2H]]

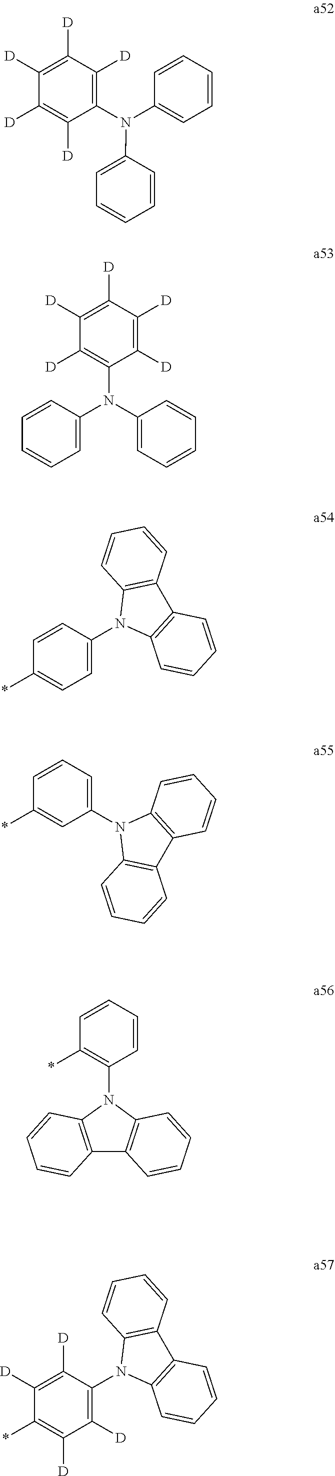 [SMILES: [2H]c1c([2H])c([2H])c(N(c2ccccc2)c2ccccc2)c([2H])c1[2H] ; [2H]c1c([2H])c([2H])c(N(c2ccccc2)c2ccccc2)c([2H])c1[2H] ; *c1ccc(-n2c3ccccc3c3ccccc32)cc1 ; *c1cccc(-n2c3ccccc3c3ccccc32)c1 ; *c1ccccc1-n1c2ccccc2c2ccccc21 ; *c1c([2H])c([2H])c(-n2c3ccccc3c3ccccc32)c([2H])c1[2H]]

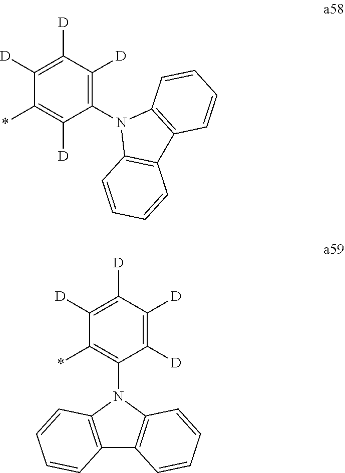 [SMILES: *c1c([2H])c([2H])c([2H])c(-n2c3ccccc3c3ccccc32)c1[2H] ; *c1c([2H])c([2H])c([2H])c([2H])c1-n1c2ccccc2c2ccccc21]

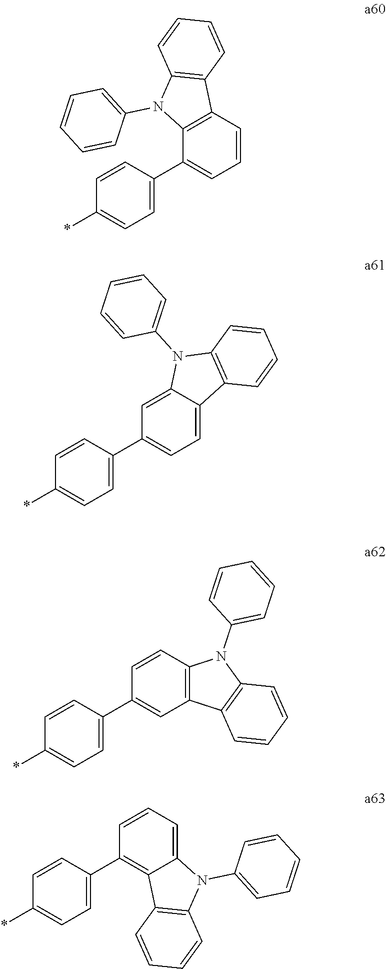 [SMILES: *c1ccc(-c2cccc3c4ccccc4n(-c4ccccc4)c23)cc1 ; *c1ccc(-c2ccc3c4ccccc4n(-c4ccccc4)c3c2)cc1 ; *c1ccc(-c2ccc3c(c2)c2ccccc2n3-c2ccccc2)cc1 ; *c1ccc(-c2cccc3c2c2ccccc2n3-c2ccccc2)cc1]

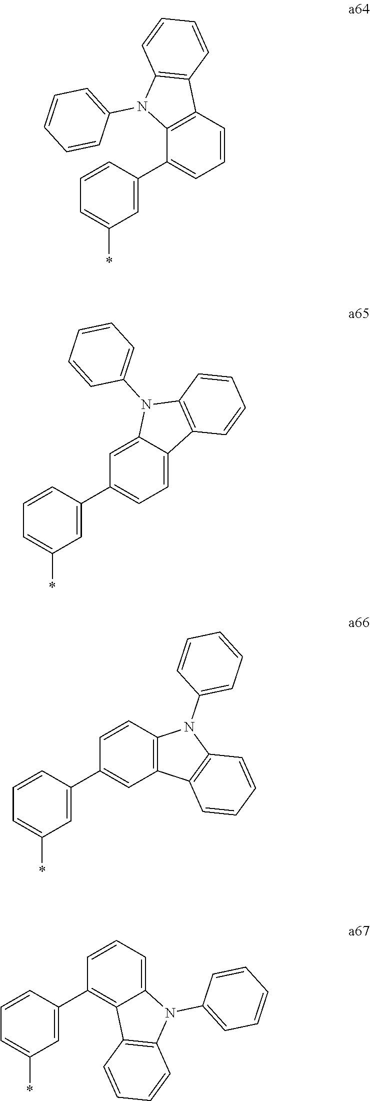 [SMILES: *c1cccc(-c2cccc3c4ccccc4n(-c4ccccc4)c23)c1 ; *c1cccc(-c2ccc3c4ccccc4n(-c4ccccc4)c3c2)c1 ; *c1cccc(-c2ccc3c(c2)c2ccccc2n3-c2ccccc2)c1 ; *c1cccc(-c2cccc3c2c2ccccc2n3-c2ccccc2)c1]

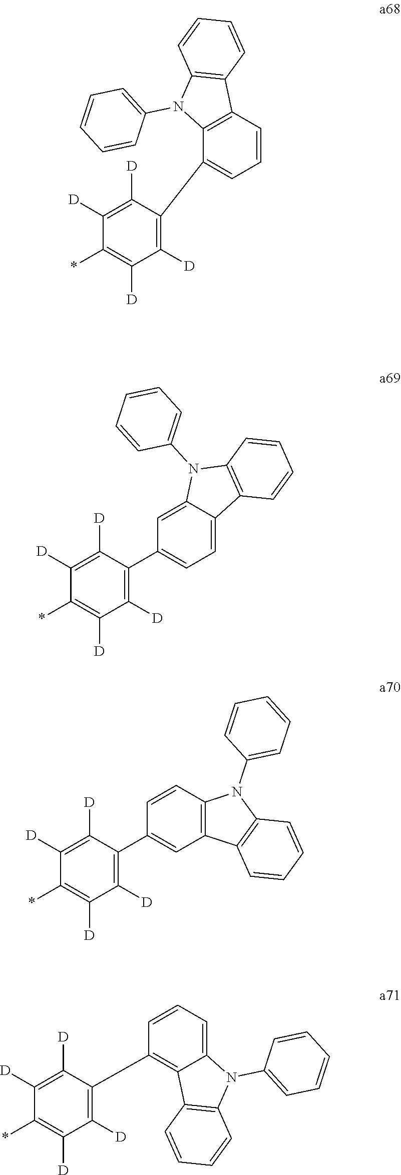 [SMILES: *c1c([2H])c([2H])c(-c2cccc3c4ccccc4n(-c4ccccc4)c23)c([2H])c1[2H] ; *c1c([2H])c([2H])c(-c2ccc3c4ccccc4n(-c4ccccc4)c3c2)c([2H])c1[2H] ; *c1c([2H])c([2H])c(-c2ccc3c(c2)c2ccccc2n3-c2ccccc2)c([2H])c1[2H] ; *c1c([2H])c([2H])c(-c2cccc3c2c2ccccc2n3-c2ccccc2)c([2H])c1[2H]]

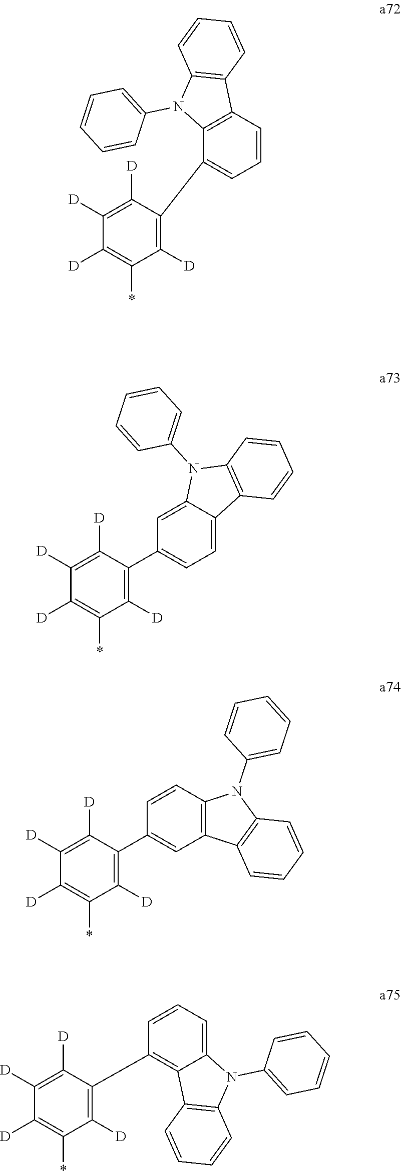 [SMILES: *c1c([2H])c([2H])c([2H])c(-c2cccc3c4ccccc4n(-c4ccccc4)c23)c1[2H] ; *c1c([2H])c([2H])c([2H])c(-c2ccc3c4ccccc4n(-c4ccccc4)c3c2)c1[2H] ; *c1c([2H])c([2H])c([2H])c(-c2ccc3c(c2)c2ccccc2n3-c2ccccc2)c1[2H] ; *c1c([2H])c([2H])c([2H])c(-c2cccc3c2c2ccccc2n3-c2ccccc2)c1[2H]]

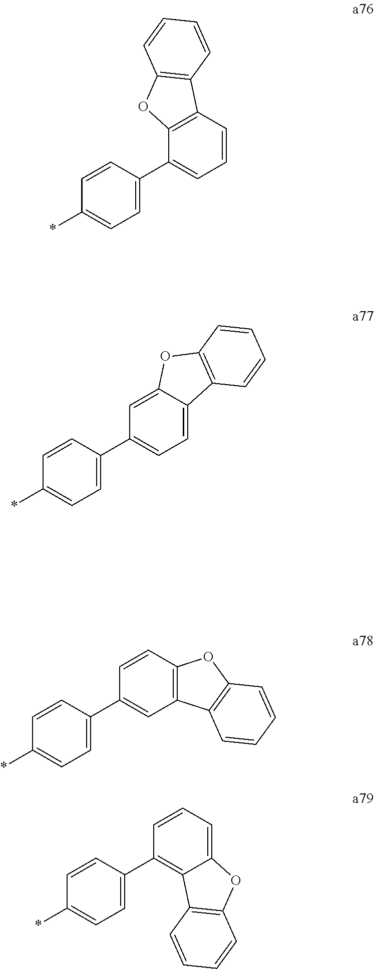 [SMILES: *c1ccc(-c2cccc3c2oc2ccccc23)cc1 ; *c1ccc(-c2ccc3c(c2)oc2ccccc23)cc1 ; *c1ccc(-c2ccc3oc4ccccc4c3c2)cc1 ; *c1ccc(-c2cccc3oc4ccccc4c23)cc1]

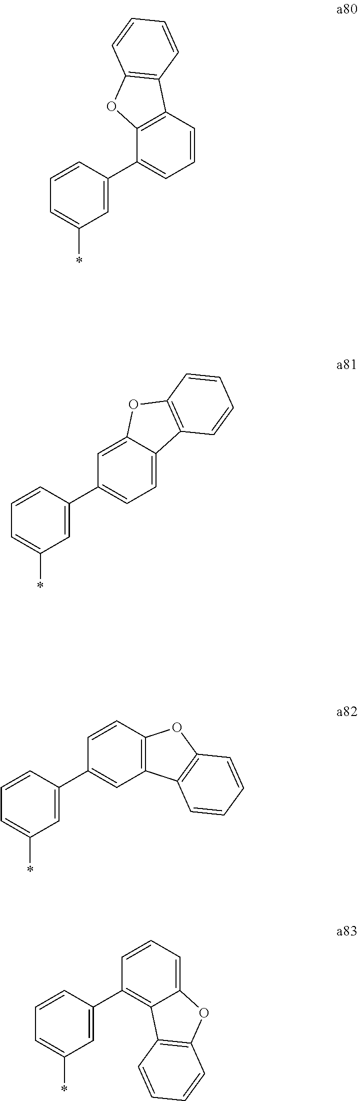 [SMILES: *c1cccc(-c2cccc3c2oc2ccccc23)c1 ; *c1cccc(-c2ccc3c(c2)oc2ccccc23)c1 ; *c1cccc(-c2ccc3oc4ccccc4c3c2)c1 ; *c1cccc(-c2cccc3oc4ccccc4c23)c1]

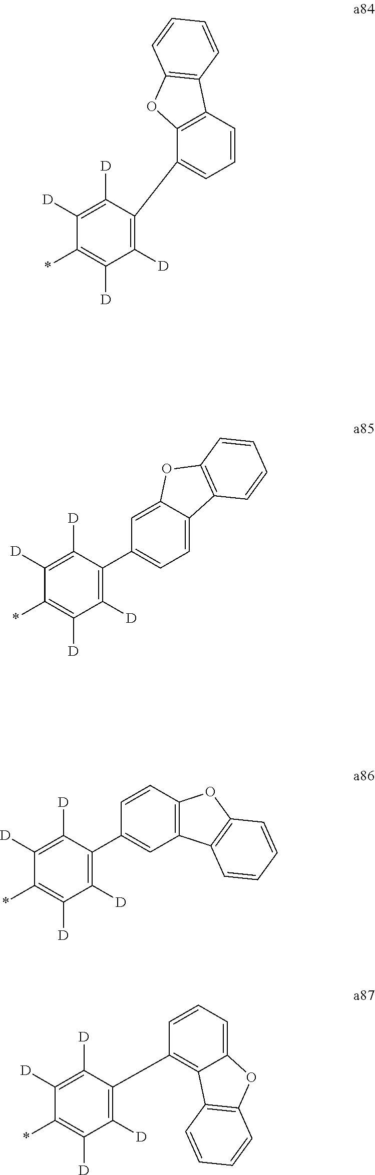 [SMILES: *c1c([2H])c([2H])c(-c2cccc3c2oc2ccccc23)c([2H])c1[2H] ; *c1c([2H])c([2H])c(-c2ccc3c(c2)oc2ccccc23)c([2H])c1[2H] ; *c1c([2H])c([2H])c(-c2ccc3oc4ccccc4c3c2)c([2H])c1[2H] ; *c1c([2H])c([2H])c(-c2cccc3oc4ccccc4c23)c([2H])c1[2H]]

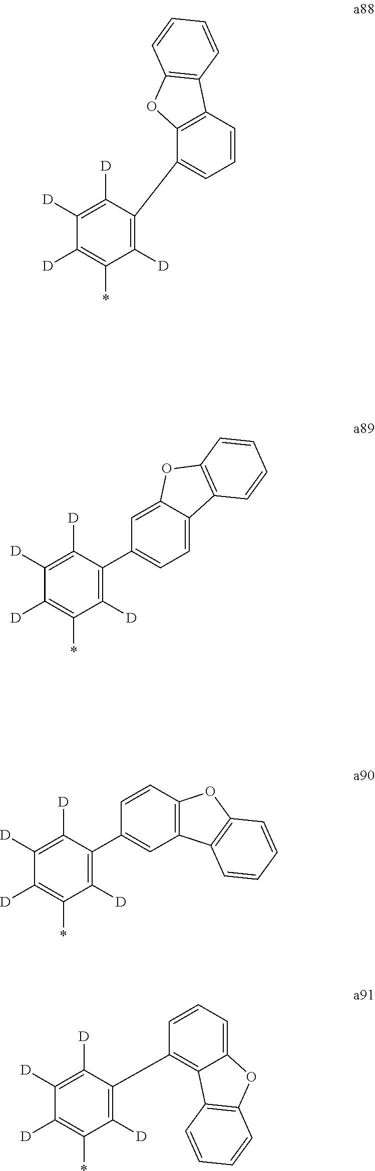 [SMILES: *c1c([2H])c([2H])c([2H])c(-c2cccc3c2oc2ccccc23)c1[2H] ; *c1c([2H])c([2H])c([2H])c(-c2ccc3c(c2)oc2ccccc23)c1[2H] ; *c1c([2H])c([2H])c([2H])c(-c2ccc3oc4ccccc4c3c2)c1[2H] ; *c1c([2H])c([2H])c([2H])c(-c2cccc3oc4ccccc4c23)c1[2H]]

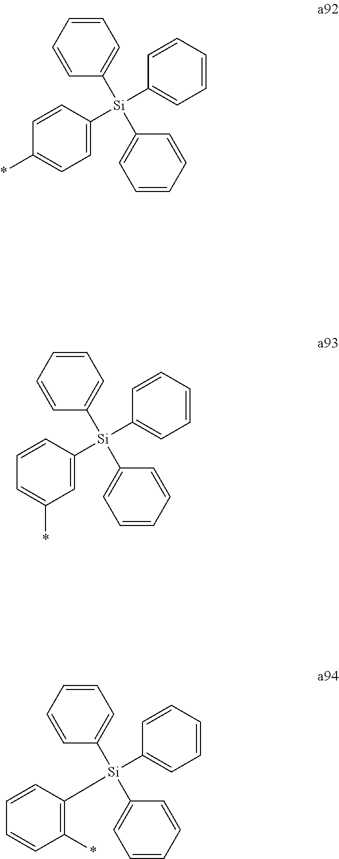 [SMILES: *c1ccc([Si](c2ccccc2)(c2ccccc2)c2ccccc2)cc1 ; *c1cccc([Si](c2ccccc2)(c2ccccc2)c2ccccc2)c1 ; *c1ccccc1[Si](c1ccccc1)(c1ccccc1)c1ccccc1]

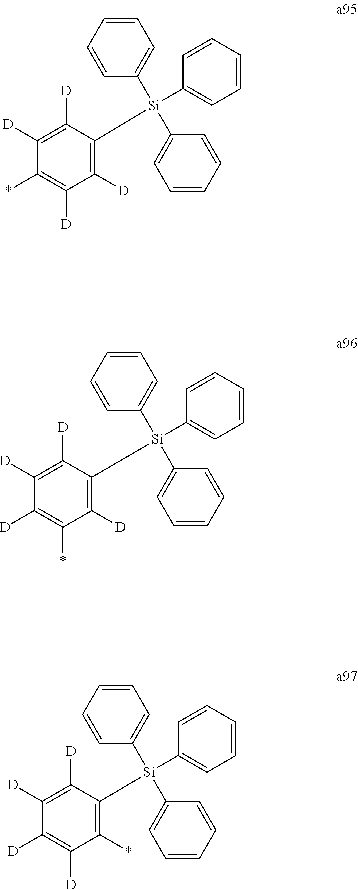 [SMILES: *c1c([2H])c([2H])c([Si](c2ccccc2)(c2ccccc2)c2ccccc2)c([2H])c1[2H] ; *c1c([2H])c([2H])c([2H])c([Si](c2ccccc2)(c2ccccc2)c2ccccc2)c1[2H] ; *c1c([2H])c([2H])c([2H])c([2H])c1[Si](c1ccccc1)(c1ccccc1)c1ccccc1]

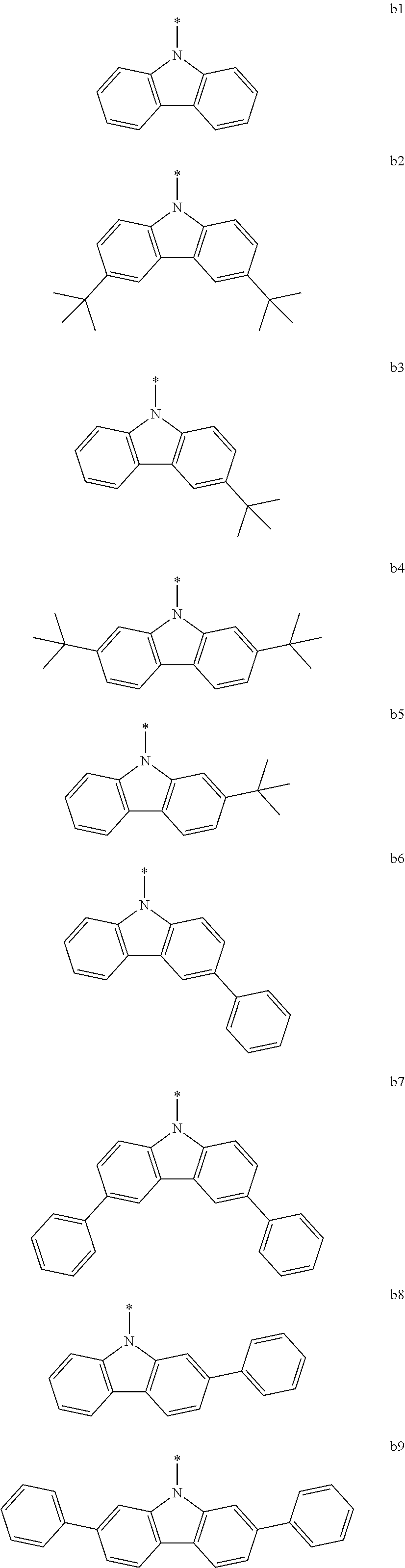

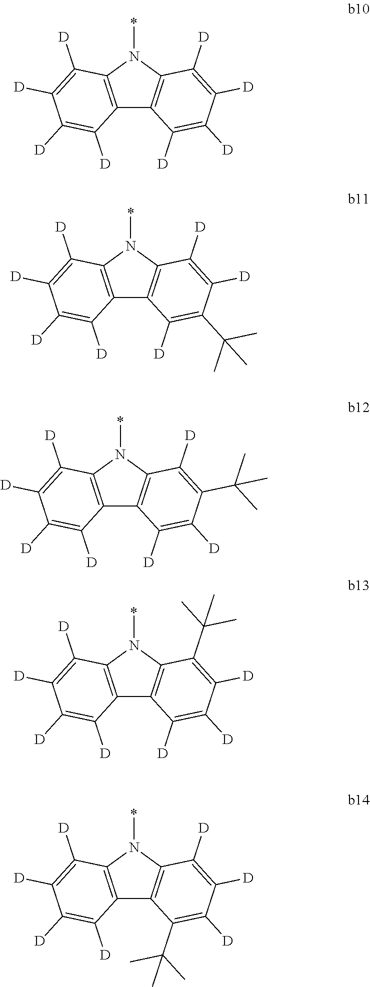

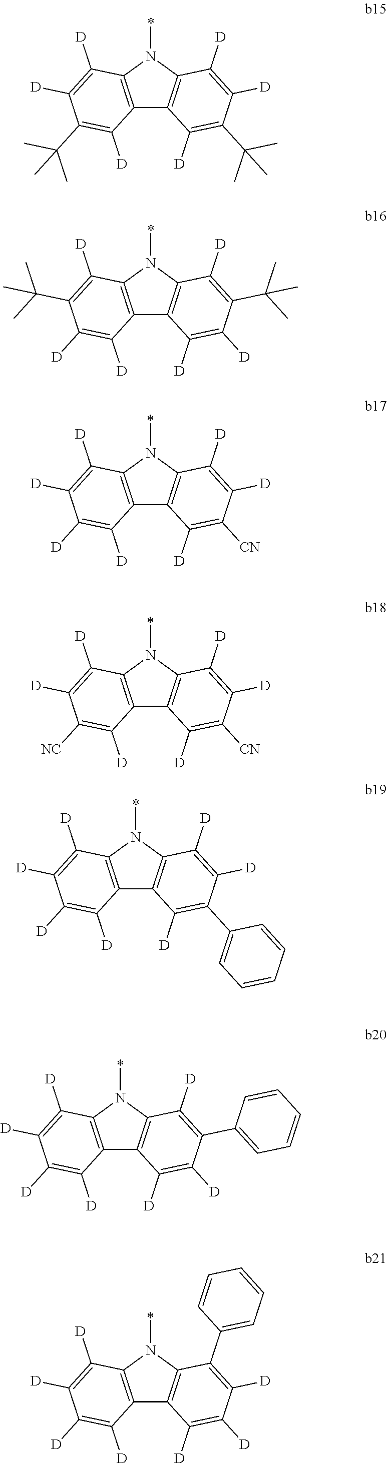

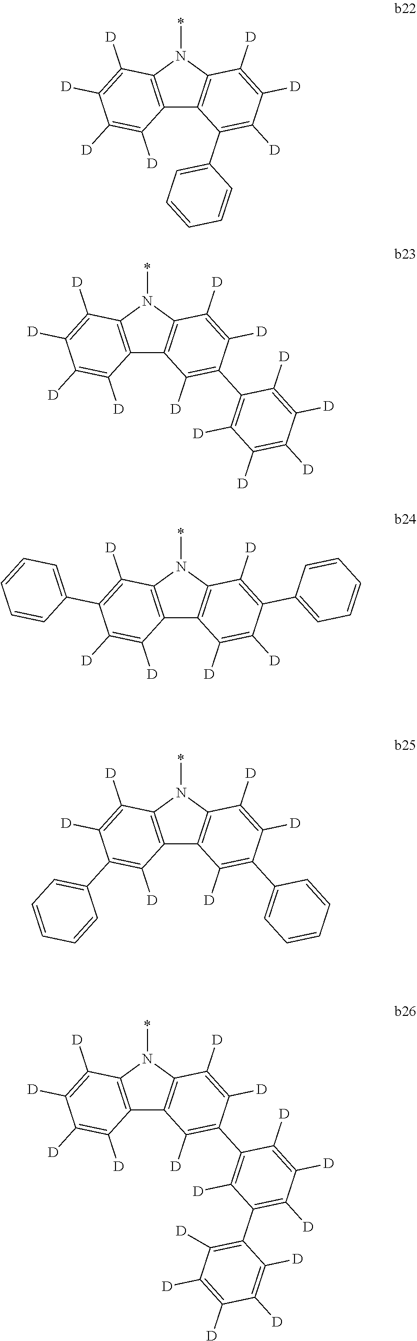 [SMILES: *n1c2c([2H])c([2H])c([2H])c([2H])c2c2c(-c3ccccc3)c([2H])c([2H])c([2H])c21 ; *n1c2c([2H])c([2H])c([2H])c([2H])c2c2c([2H])c(-c3c([2H])c([2H])c([2H])c([2H])c3[2H])c([2H])c([2H])c21 ; *n1c2c([2H])c(-c3ccccc3)c([2H])c([2H])c2c2c([2H])c([2H])c(-c3ccccc3)c([2H])c21 ; *n1c2c([2H])c([2H])c(-c3ccccc3)c([2H])c2c2c([2H])c(-c3ccccc3)c([2H])c([2H])c21 ; *n1c2c([2H])c([2H])c([2H])c([2H])c2c2c([2H])c(-c3c([2H])c([2H])c([2H])c(-c4c([2H])c([2H])c([2H])c([2H])c4[2H])c3[2H])c([2H])c([2H])c21]

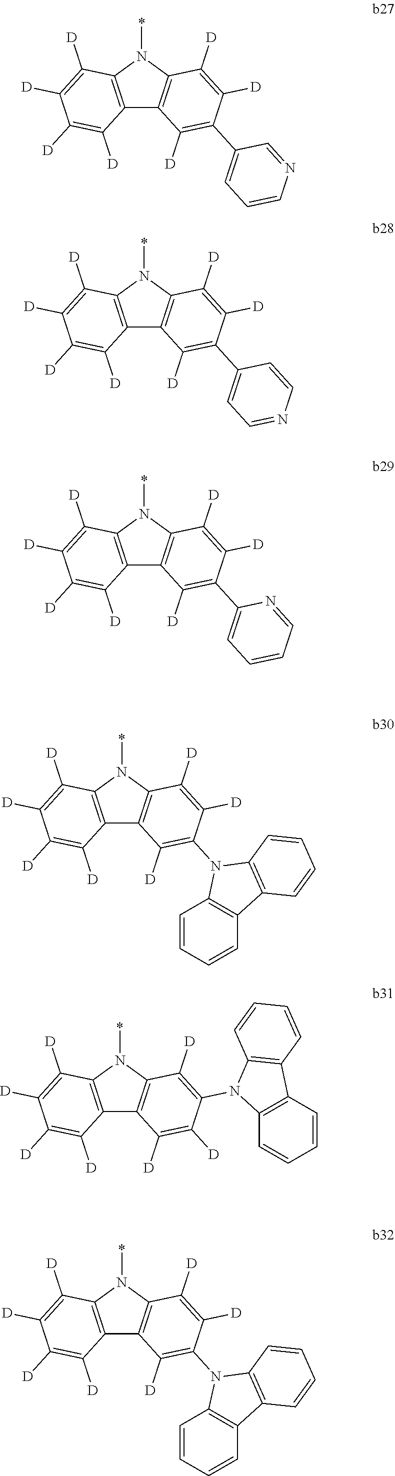 [SMILES: *n1c2c([2H])c([2H])c([2H])c([2H])c2c2c([2H])c(-c3cccnc3)c([2H])c([2H])c21 ; *n1c2c([2H])c([2H])c([2H])c([2H])c2c2c([2H])c(-c3ccncc3)c([2H])c([2H])c21 ; *n1c2c([2H])c([2H])c([2H])c([2H])c2c2c([2H])c(-c3ccccn3)c([2H])c([2H])c21 ; *n1c2c([2H])c([2H])c([2H])c([2H])c2c2c([2H])c(-n3c4ccccc4c4ccccc43)c([2H])c([2H])c21 ; *n1c2c([2H])c([2H])c([2H])c([2H])c2c2c([2H])c([2H])c(-n3c4ccccc4c4ccccc43)c([2H])c21 ; *n1c2c([2H])c([2H])c([2H])c([2H])c2c2c([2H])c(-n3c4ccccc4c4ccccc43)c([2H])c([2H])c21]

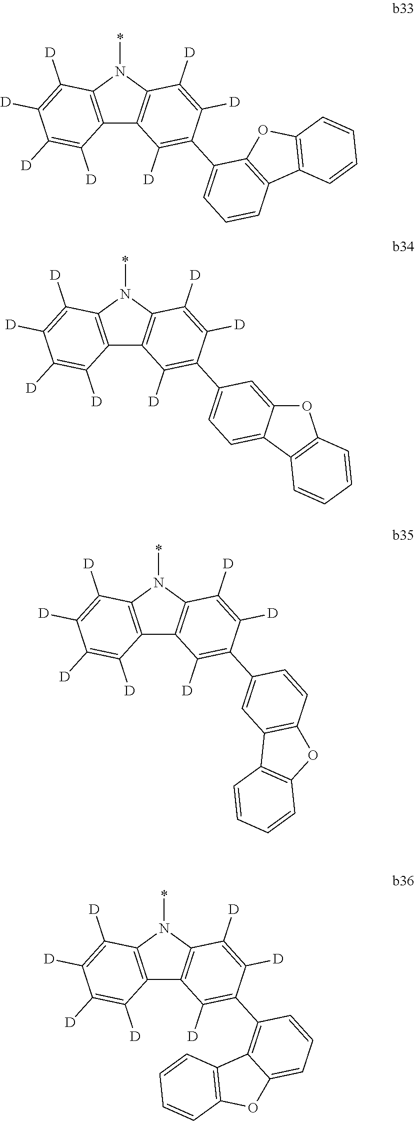 [SMILES: *n1c2c([2H])c([2H])c([2H])c([2H])c2c2c([2H])c(-c3cccc4c3oc3ccccc34)c([2H])c([2H])c21 ; *n1c2c([2H])c([2H])c([2H])c([2H])c2c2c([2H])c(-c3ccc4c(c3)oc3ccccc34)c([2H])c([2H])c21 ; *n1c2c([2H])c([2H])c([2H])c([2H])c2c2c([2H])c(-c3ccc4oc5ccccc5c4c3)c([2H])c([2H])c21 ; *n1c2c([2H])c([2H])c([2H])c([2H])c2c2c([2H])c(-c3cccc4oc5ccccc5c34)c([2H])c([2H])c21]

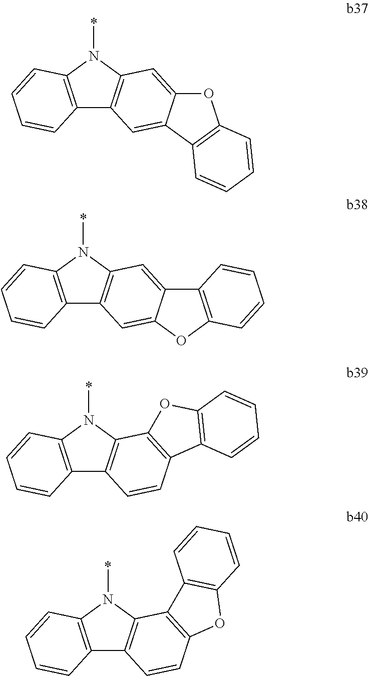 [SMILES: *n1c2ccccc2c2cc3c(cc21)oc1ccccc13 ; *n1c2ccccc2c2cc3oc4ccccc4c3cc21 ; *n1c2ccccc2c2ccc3c4ccccc4oc3c21 ; *n1c2ccccc2c2ccc3oc4ccccc4c3c21]

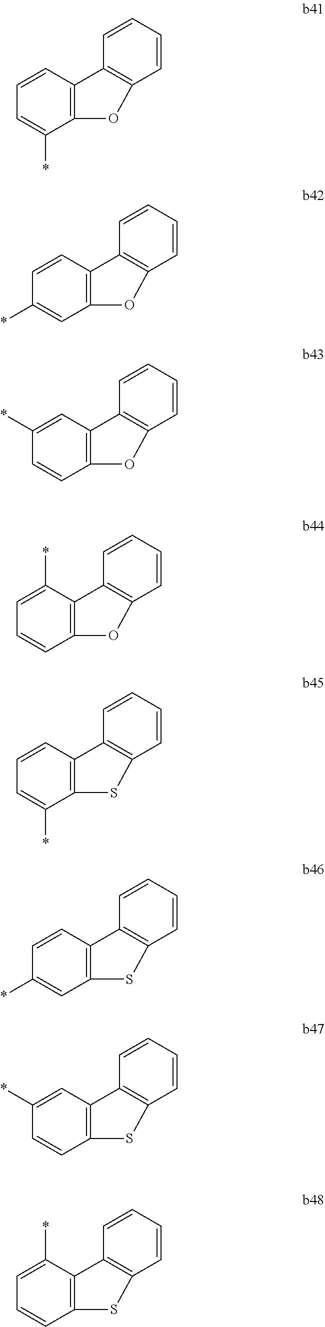

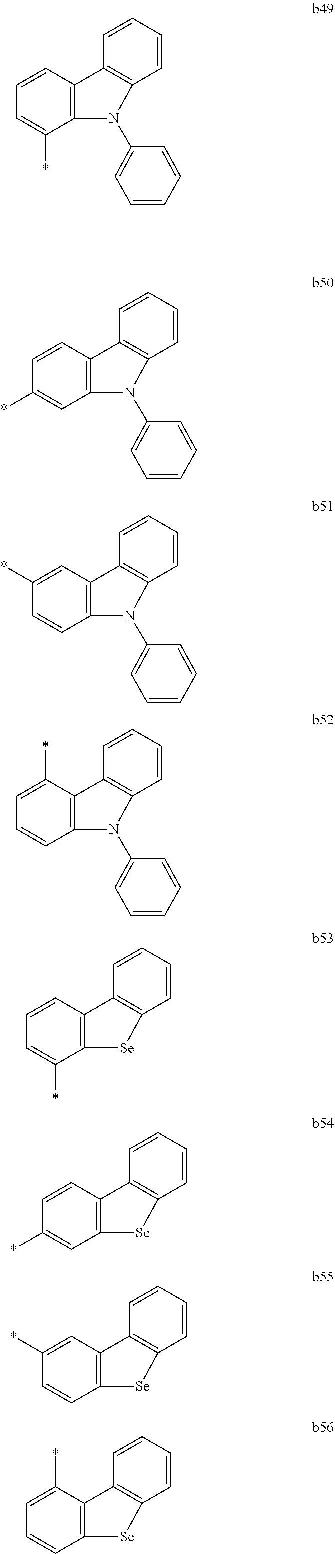

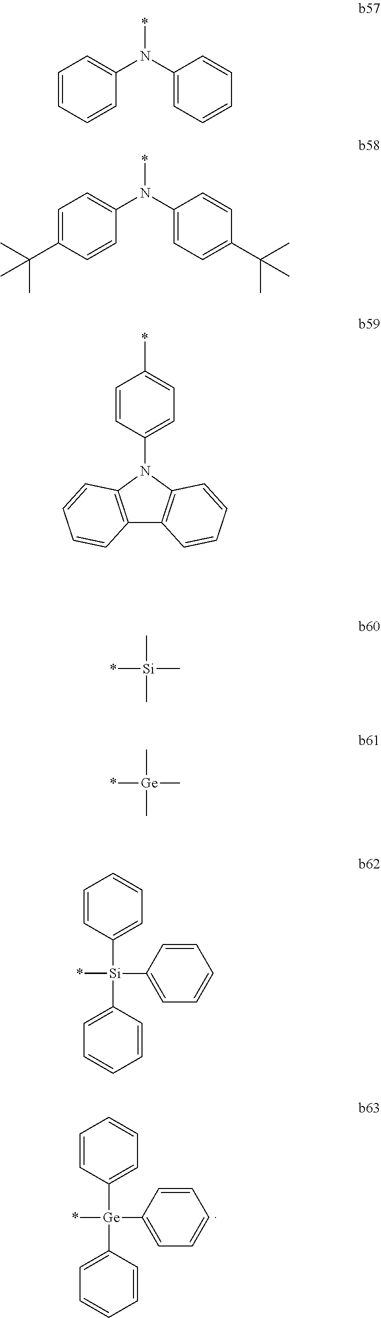

In one or more embodiments, in Formula 1, at least one of Ar₁ or Ar₂ may be represented by Formula S, and the other (e.g., any remaining Ar₁ or Ar₂) may be represented by any (e.g., at least) one selected from among Formula B-1 to Formula B-3:

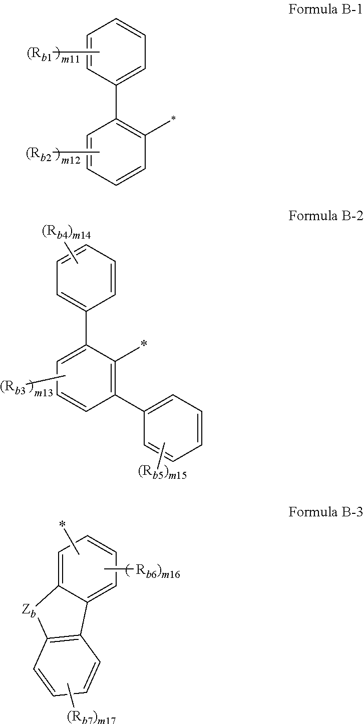

In Formula B-3, Z_{b} may be NR_{b8}, O, S, or Se.

In Formula B-1 to Formula B-3, R_{b1} to R_{b7} may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In one or more embodiments, each of R_{b1} to R_{b7} may be bonded to an adjacent group to form a ring.

In Formula B-3, R_{b8} may be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In one or more embodiments, R_{b8} may be a substituted or unsubstituted aryl group having 6 to 30 ring-forming carbon atoms.

In Formula B-1 to Formula B-3, m11, m14, and m15 may each independently be an integer of 0 to 5, m12 and m17 may each independently be an integer of 0 to 4, and m13 and m16 may each independently be an integer of 0 to 3.

When each of m11, m14, and m15 is 0, the fused polycyclic compound of one or more embodiments may exclude (e.g., not be substituted with) each of R_{b1}, R_{b4}, and R_{b5}. The case where each of m11, m14, and m15 is 5 and R_{b1}'s, R_{b4}'s, and R_{b5}'s are each hydrogen atoms may be the same as the case where each of m11, m14, and m15 is 0. When each of m11, m14, and m15 is an integer of 2 or more, a plurality of R_{b1}'s, R_{b4}'s, and R_{b5}'s each may be the same or at least one among the plurality of R_{b1}'s, R_{b4}'s, and R_{b5}'s may be different from the others.

When each of m12 and m17 is 0, the fused polycyclic compound of one or more embodiments may exclude (e.g., not be substituted with) each of R_{b2} and R_{b7}. The case where each of m12 and m17 is 4 and R_{b2}'s and R_{b7}'s are each hydrogen atoms may be the same as the case where each of m12 and m17 is 0. When each of m12 and m17 is an integer of 2 or greater, a plurality of R_{b2}'s and R_{b7}'s may each be the same or at least one among the plurality of R_{b2}'s and R_{b7}'s may be different from the others.

When each of m13 and m16 is 0, the fused polycyclic compound of one or more embodiments may not be substituted with each of R_{b3} and R_{b6}. The case where each of m13 and m16 is 3 and R_{b3}'s and R_{b6}'s are each hydrogen atoms may be the same as the case where each of m13 and m16 is 0. When each of m13 and m16 is an integer of 2 or greater, a plurality of R_{b3}'s and R_{b6}'s may each be the same or at least one among the plurality of R_{b3}'s and R_{b6}'s may be different from the others.

In Formula B-1 to Formula B-3, [symbol] may be a position linked to Formula 1.

In one or more embodiments, the fused polycyclic compound represented by Formula 1 may be represented by Formula 2-1 or Formula 2-2:

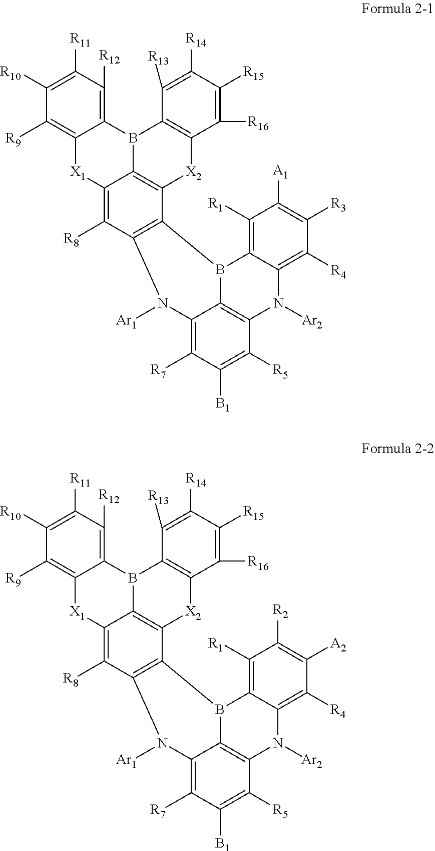

In Formula 2-1 and Formula 2-2, A₁ and A₂ may each independently be represented by any (e.g., at least) one selected from among Formula A-1 to Formula A-4. In one or more embodiments, A₁ and A₂ may each independently be selected from among Substituent Group 1 as described herein.

In Formula 2-1 and Formula 2-2, B₁ may be a substituted or unsubstituted alkyl group are the 1 to 10 carbon atoms. For example, B₁ may be a substituted or unsubstituted t-butyl group.

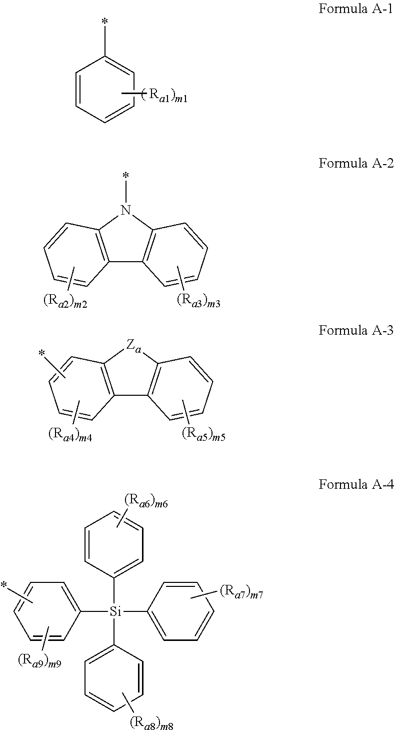

In Formula A-3, Zₐ may be NRₐ₁₀, O, S, or Se. For example, Zₐ may be O.

In Formula A-1 to Formula A-4, Rₐ₁ to Rₐ₁₀ may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₐ₁ to Rₐ₉ may each independently be a hydrogen atom, a deuterium atom, a cyano group, a substituted or unsubstituted phenoxy group, a substituted or unsubstituted diphenylamine group, a substituted or unsubstituted triphenylsilyl group, a substituted or unsubstituted methyl group, a substituted or unsubstituted t-butyl group, a substituted or unsubstituted phenyl group, a substituted or unsubstituted biphenyl group, a substituted or unsubstituted carbazole group, a substituted or unsubstituted dibenzofuran group, or a substituted or unsubstituted pyridine group. Rₐ₁₀ may be a substituted or unsubstituted phenyl group. In one or more embodiments, each of Rₐ₁ to Rₐ₁₀ may be bonded to an adjacent group to form a ring. For example, Rₐ₂ may be provided in plural, and the plurality of Rₐ₂'s may be bonded to each other to form an additional fused ring. In one or more embodiments, Rₐ₃ may be provided in plural, and the plurality of Rₐ₃'s may be bonded to each other to form an additional fused ring.

In Formula A-1 to Formula A-4, m1 and m6 to m8 may each independently be an integer of 0 to 5, m2, m3, m5, and m9 may each independently be an integer of each independently 0 to 4, and m4 is an integer of 0 to 3.

When each of m1, and m6 to m8 is 0, the fused polycyclic compound of one or more embodiments may not be substituted with each of Rₐ₁, and Rₐ₆ to Rₐ₈. The case where each of m1, and m6 to m8 is 5, and Rₐ₁'s and Rₐ₆'s to Rₐ₈'s each are hydrogen atoms may be the same as the case where each of m1, and m6 to m8 is 0. When each of m1 and m6 to m8 is an integer of 2 or greater, a plurality of Rₐ₁'s and Rₐ₆'s to Rₐ₈'s may each be the same or at least one among the plurality of Rₐ₁'s, and Rₐ₆'s to Rₐ₈'s may be different from the others.

When each of m2, m3, m5, and m9 is 0, the fused polycyclic compound of one or more embodiments may not be substituted with each of Rₐ₂, Rₐ₃, Rₐ₅, and Rₐ₈. The case where each of m2, m3, m5, and m9 is 4 and Rₐ₂'s, Rₐ₁'s, Rₐ₅'s and Rₐ₉'s each are hydrogen atoms may be the same as the case where each of m2, m3, m5, and m9 is 0. When each of m2, m3, m5, and m9 is an integer of 2 or more, a plurality of Rₐ₂'s, Rₐ₁'s, Rₐ₅'s and Rₐ₉'s each may be the same or at least one among the plurality of Rₐ₂'s, Rₐ₁'s, Rₐ₅'s and Rₐ₉'s may be different from the others.

When m4 is 0, the fused polycyclic compound of one or more embodiments may not be substituted with Rₐ₄. The case where m4 is 3 and Rₐ₄'s are all hydrogen atoms may be the same as the case where m4 is 0. When m4 is an integer of 2 or more, a plurality of Rₐ₄'s may all be the same, or at least one among the plurality of Rₐ₄'s may be different from the others.

In Formula 2-1 to Formula 2-2, the descriptions in Formula 1 may be applied to X₁, X₂, Ar₁, Ar₂, R₁ to R₅, and R₇ to R₁₆.

In one or more embodiments, the fused polycyclic compound represented by Formula 1 may be represented by any (e.g., at least) one selected from among Formula 3-1 to Formula 3-3:

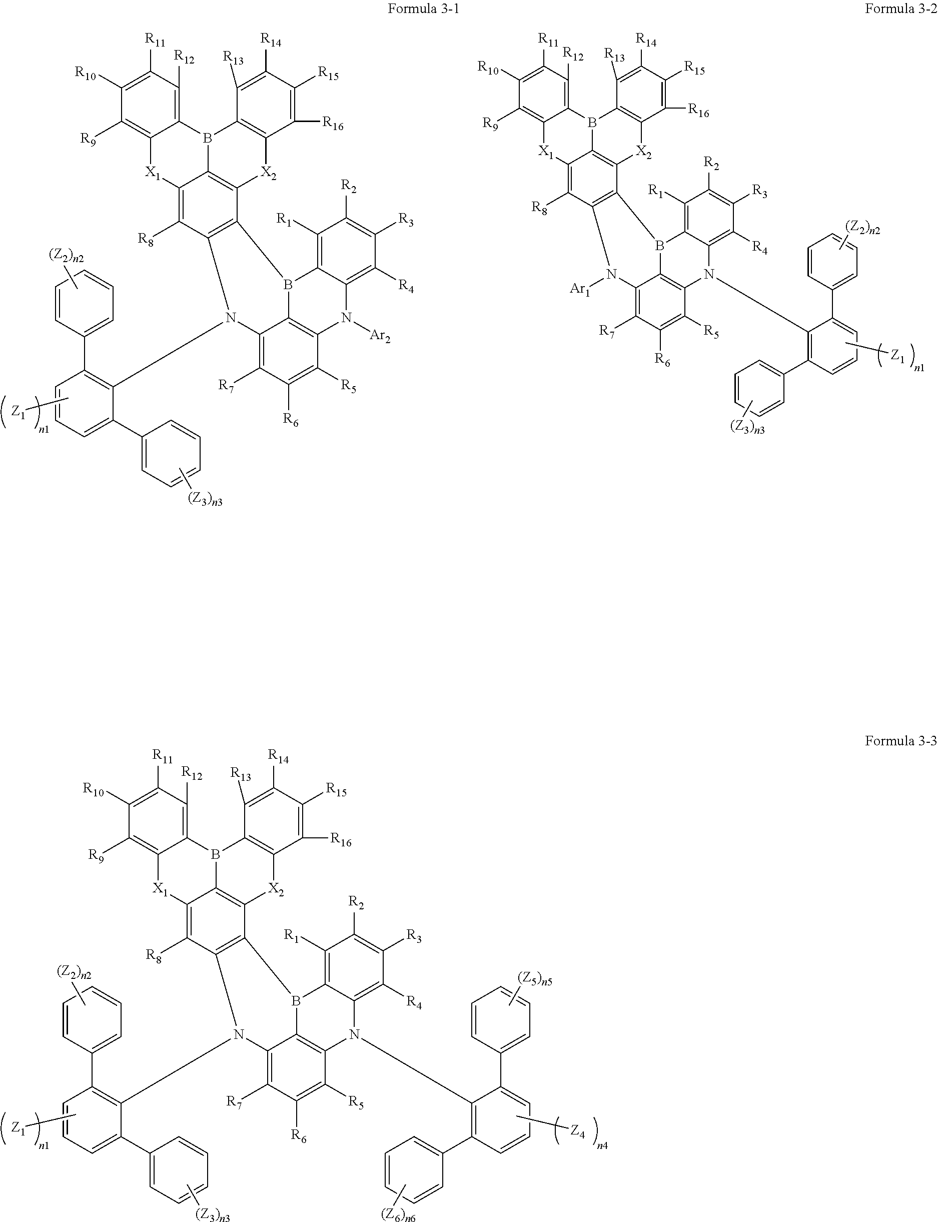

In Formula 3-3, Z₄ to Z₆ may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In one or more embodiments, Z₄ to Z₆ each may be bonded to an adjacent group to form a ring. For example, Z₄ to Z₆ may each independently be a hydrogen atom or a substituted or unsubstituted t-butyl group.

In Formula 3-3, n4 may be an integer of 0 to 3. When n4 is 0, the fused polycyclic compound of one or more embodiments may not be substituted with Z₄. The case where n4 is 3 and Z₄'s are all hydrogen atoms may be the same as the case where n4 is 0. When n4 is an integer of 2 or greater, a plurality of Z₄'s may all be the same, or at least one among the plurality of Z₄'s may be different from the others.

In Formula 3-3, n5 and n6 may each independently be an integer of 0 to 5. When each of n5 and n6 is 0, the fused polycyclic compound of one or more embodiments may not be substituted with each of Z₅ and Z₆. The case where each of n5 and n6 is 5 and Z₅'s and Z₆'s are each hydrogen atoms may be the same as the case where each of n5 and n6 is 0. When each of n5 and n6 is an integer of 2 or greater, a plurality of Z₅'s and Z₆'s may each be the same or at least one among the plurality of Z₅'s and Z₆'s may be different from the others.

In Formula 3-1 to Formula 3-3, the descriptions in Formula 1 and Formula S may be applied to X₁, X₂, Ar₁, Ar₂, R₁ to R₁₆, Z₁ to Z₃, and n1 to n3.

In one or more embodiments, the first compound represented by Formula 1 may be represented by any (e.g., at least) one selected from among Formula 4-1 to Formula 4-5:

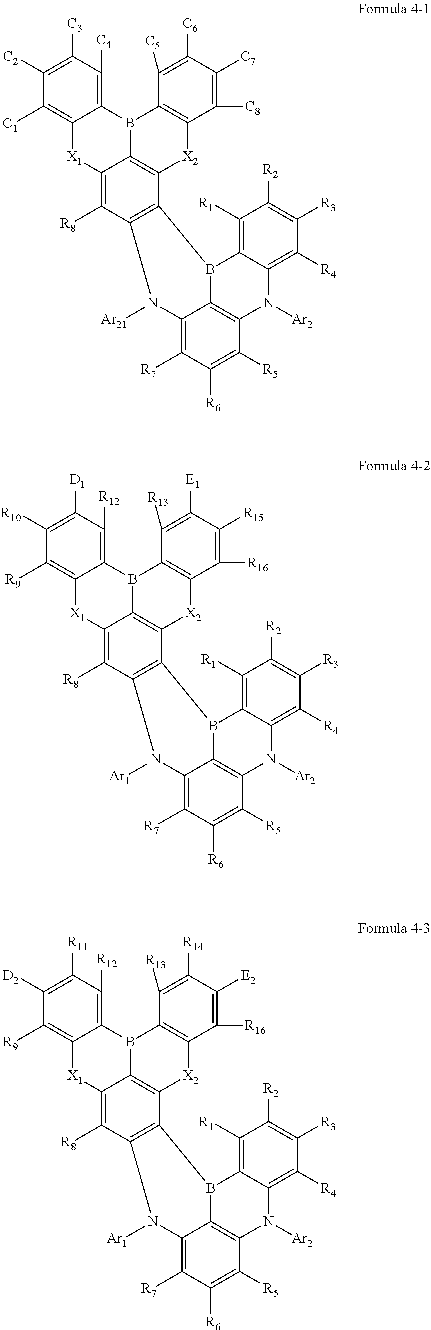

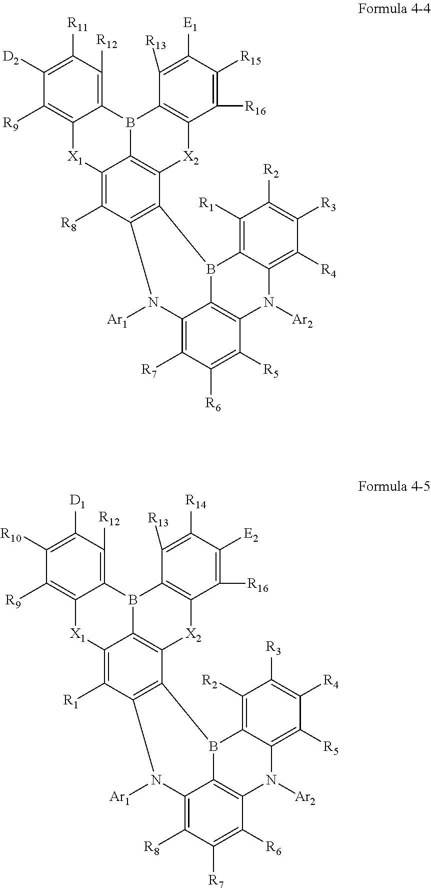

In Formula 4-1, C₁ to C₈ may each independently be a hydrogen atom or a deuterium atom.

In Formula 4-1 to Formula 4-5, D₁, D₂, E₁, and E₂ may each independently be a substituted or unsubstituted alkyl group having 1 to 10 carbon atoms, or may be represented by any (e.g., at least) one selected from among Formula C-1 to Formula C-5. In one or more embodiments, D₁, D₂, E₁, and E₂ may each independently be of (e.g., selected from among) Substituent Group 1 as described herein.

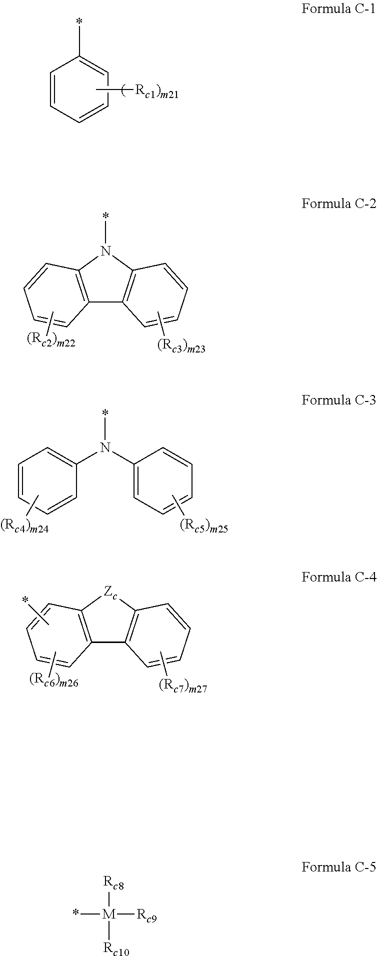

In Formula C-4, Z_{c} may be NR_{c11}, O, S, or Se.

In Formula C-5, M may be Si or Ge.

In Formula C-1 to Formula C-4, R_{c1} to R_{c7} may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In one or more embodiments, each of R_{c1} to R_{c7} may be bonded to an adjacent group to form a ring. R_{c1} to R_{c7} may each independently be a hydrogen atom, a deuterium atom, a cyano group, or a substituted or unsubstituted phenyl group.

In Formula C-4 and Formula C-5, R_{c8} to R_{c11} may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In one or more embodiments, R_{c8} to R_{c10} may each independently be a substituted or unsubstituted alkyl group having 1 to 20 carbon atoms, or a substituted or unsubstituted aryl group having 6 to 30 ring-forming carbon atoms. In one or more embodiments, R_{c11} may be a substituted or unsubstituted aryl group having 6 to 30 ring-forming carbon atoms, or a substituted or unsubstituted heteroaryl group having 2 to 30 ring-forming carbon atoms. For example, R_{c8} to R_{c10} may each independently be a substituted or unsubstituted methyl group, or a substituted or unsubstituted phenyl group, and R_{c11} may be a substituted or unsubstituted phenyl group.

In Formula C-1 to Formula C-4, m21, m24, and m25 may each independently be an integer of 0 to 5, m22, m23, and m27 may each independently be an integer of 0 to 4, and m26 is an integer 0 to 3.

When each of m21, m24, and m25 is 0, the fused polycyclic compound of one or more embodiments may not be substituted with each of R_{c1}, R_{c4}, and R_{c5}. The case where each of m21, m24, and m25 is 5 and R_{c1}'s, R_{c4}'s, and R_{c5}'s are each hydrogen atoms may be the same as the case where each of m21, m24, and m25 is 0. When each of m21, m24, and m25 is an integer of 2 or more, a plurality of R_{c1}'s, R_{c4}'s, and R_{c5}'s each may be the same or at least one among the plurality of R_{c1}'s, R_{c4}'s, and R_{c5}'S may be different from the others.

When each of m22, m23, and m27 is 0, the fused polycyclic compound of one or more embodiments may not be substituted with each of R_{c2}, R_{c3}, and R_{c7}. The case where each of m22, m23, and m27 is 4 and R_{c2}'s, R_{c3}'S, and R_{c7}'s are each hydrogen atoms may be the same as the case where each of m22, m23, and m27 is 0.

When each of m22, m23, and m27 is an integer of 2 or more, a plurality of R_{c2}'s, R_{c3}'S, and R_{c7}'s each may be the same or at least one among the plurality of R_{c2}'s, R_{c8}'s, and R_{c7}'S may be different from the others.

When m26 is 0, the fused polycyclic compound of one or more embodiments may not be substituted with R_{c6}. The case where m26 is 3 and R_{c6}'s are all hydrogen atoms may be the same as the case where m26 is 0. When m26 is an integer of 2 or more, a plurality of R_{c6}'s may all be the same, or at least one among the plurality of R_{c6}'S may be different from the others.

In Formula 4-1 to Formula 4-5, the same as described in Formula 1 may be applied to X₁, X₂, Ar₁, Ar₂, and R₁ to R₁₆.

In one or more embodiments, the fused polycyclic compound represented by Formula 1 may be represented by any (e.g., at least) one selected from among Formula 5-1 to Formula 5-3:

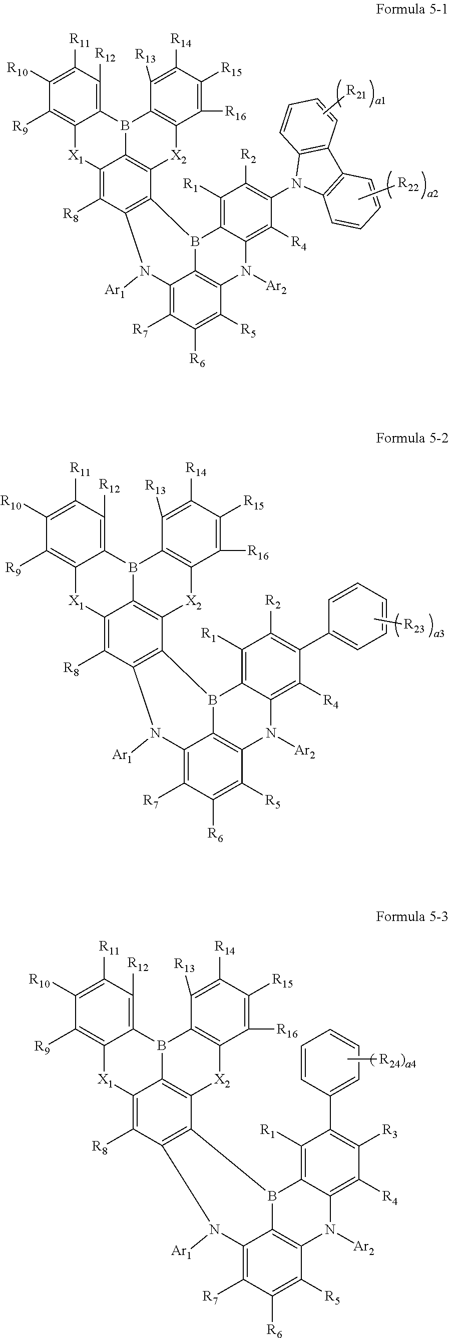

In Formula 5-1 to Formula 5-3, R₂₁ to R₂₄ may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₂₁ to R₂₄ may each independently be a hydrogen atom, a deuterium atom, a cyano group, a substituted or unsubstituted phenoxy group, a substituted or unsubstituted diphenylamine group, a substituted or unsubstituted triphenylsilyl group, a substituted or unsubstituted methyl group, a substituted or unsubstituted t-butyl group, a substituted or unsubstituted phenyl group, a substituted or unsubstituted biphenyl group, a substituted or unsubstituted carbazole group, a substituted or unsubstituted dibenzofuran group, or a substituted or unsubstituted pyridine group. In one or more embodiments, each of R₂₁ to R₂₄ may be bonded to an adjacent group to form a ring. For example, R₂₁ may be provided in plural, and the plurality of R₂₁'s may be bonded to each other to form an additional fused ring. In one or more embodiments, R₂₂ may be provided in plural, and the plurality of R₂₂'s may be bonded to each other to form an additional fused ring.

In Formula 5-1, a1 and a2 may each independently be an integer of 0 to 4. When each of a1 and a2 is 0, the fused polycyclic compound of one or more embodiments may not be substituted with each of R₂₁ and R₂₂. The case where each of a1 and a2 is 4 and R₂₁'s and R₂₂'s are each hydrogen atoms may be the same as the case where each of a1 and a2 is 0. When each of a1 and a2 is an integer of 2 or more, a plurality of R₂₁'s and R₂₂'s may each be the same or at least one among the plurality of R₂₁'s and R₂₂'s may be different from the others.

In Formula 5-2 and Formula 5-3, a3 and a4 may each independently be an integer of 0 to 5. When each of a3 and a4 is 0, the fused polycyclic compound of one or more embodiments may not be substituted with each of R₂₃ and R₂₄. The case where each of a3 and a4 is 5 and R₂₃'s and R₂₄'s are each hydrogen atoms may be the same as the case where each of a3 and a4 is 0. When each of a3 and a4 is an integer of 2 or more, a plurality of R₂₃'s and R₂₄'s may each be the same or at least one among the plurality of R₂₃'s and R₂₄'s may be different from the others.

In Formula 5-1 to Formula 5-3, the descriptions in Formula 1 may be applied to X₁, X₂, Ar₁, Ar₂, and R₁ to R₁₆.

In one or more embodiments, the fused polycyclic compound represented by Formula 1 may be represented by any (e.g., at least) one selected from among Formula 6-1 to Formula 6-3:

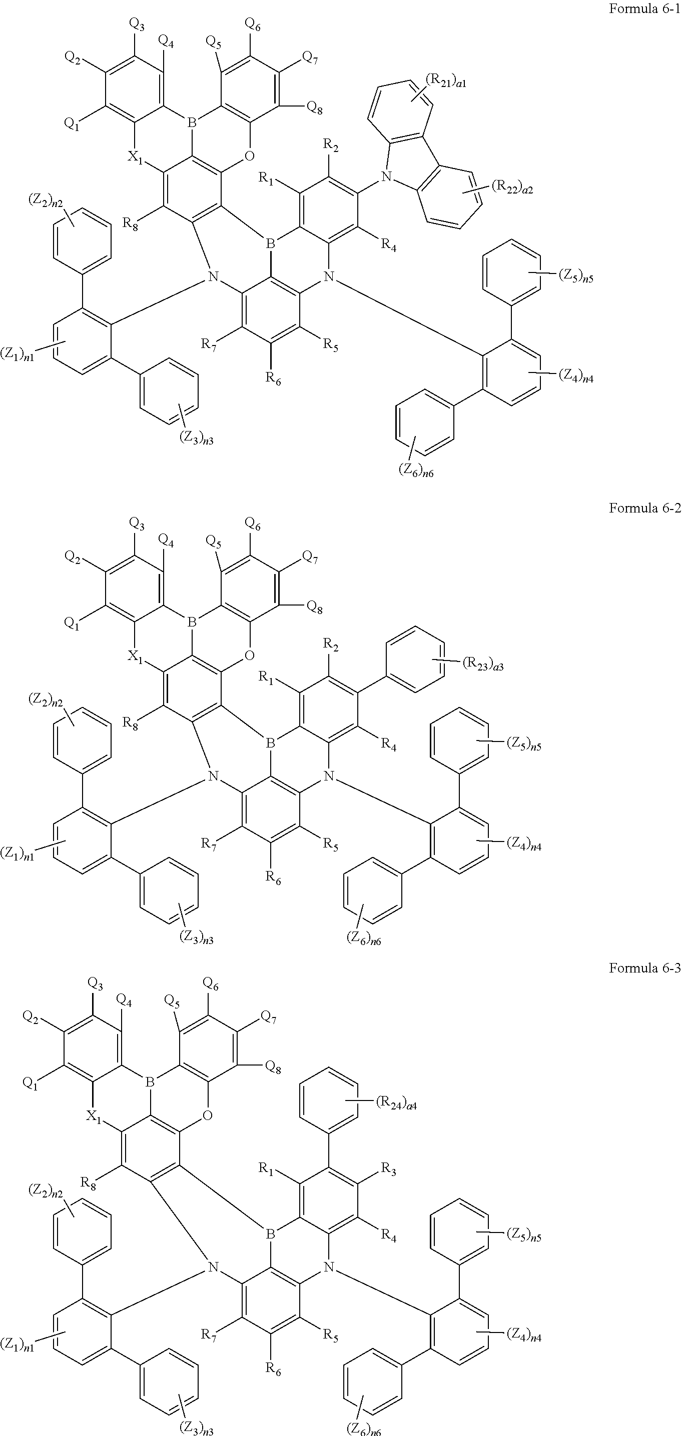

In Formula 6-1 to Formula 6-3, R₂₁ to R₂₄ may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₂₁ to R₂₄ may each independently be a hydrogen atom, a deuterium atom, a cyano group, a substituted or unsubstituted phenoxy group, a substituted or unsubstituted diphenylamine group, a substituted or unsubstituted triphenylsilyl group, a substituted or unsubstituted methyl group, a substituted or unsubstituted t-butyl group, a substituted or unsubstituted phenyl group, a substituted or unsubstituted biphenyl group, a substituted or unsubstituted carbazole group, a substituted or unsubstituted dibenzofuran group, or a substituted or unsubstituted pyridine group. In one or more embodiments, each of R₂₁ to R₂₄ may be bonded to an adjacent group to form a ring. For example, R₂₁ may be provided in plural, and the plurality of R₂₁'s may be bonded to each other to form an additional fused ring. In one or more embodiments, R₂₂ may be provided in plural, and the plurality of R₂₂'s may be bonded to each other to form an additional fused ring.

In Formula 6-1 to Formula 6-3, Z₄ to Z₆ may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In one or more embodiments, Z₄ to Z₆ each may be bonded to an adjacent group to form a ring. For example, Z₄ to Z₆ may each independently be a hydrogen atom, a substituted or unsubstituted t-butyl group, or a substituted or unsubstituted phenyl group.

In Formula 6-1 to Formula 6-3, a1 and a2 may each independently be an integer of 0 to 4, a3, a4, n5, and n6 may each independently be an integer of 0 to 5, and n4 is an integer of 0 to 3.

When each of a1 and a2 is 0, the fused polycyclic compound of one or more embodiments may not be substituted with each of R₂₁ and R₂₂. The case where each of a1 and a2 is 4 and R₂₁'s and R₂₂'s are each hydrogen atoms may be the same as the case where each of a1 and a2 is 0. When each of a1 and a2 is an integer of 2 or more, a plurality of R₂₁'s and R₂₂'s may each be the same or at least one among the plurality of R₂₁'s and R₂₂'s may be different from the others.

When each of a3, a4, n5, and n6 is 0, the fused polycyclic compound of one or more embodiments may not be substituted with each of R₂₃, R₂₄, Z₅, and Z₆. The case where each of a3, a4, n5, and n6 is 5 and R₂₃'s, R₂₄'s, Z₅'s, and Z₆'s are each hydrogen atoms may be the same as the case where each of a3, a4, n5, and n6 is 0. When each of a3, a4, n5, and n6 is an integer of 2 or greater, a plurality of R₂₃'s, R₂₄'s, Z₅'s, and Z₆'s may each be the same or at least one among the plurality of R₂₃'s, R₂₄'s, Z₅'s, and Z₆'s may be different from the others.

In Formula 6-1 to Formula 6-3, at least one selected from among Q₁ to Q₅ may be represented by any (e.g., at least) one selected from among Formula C-1 to Formula C-5, and the rest may each independently be a hydrogen atom or a deuterium atom. In one or more embodiments, at least one among Q₁ to Q₅ may be of (e.g., selected from among) Substituent Group 1 as described herein, and the rest (e.g., any remaining selected from among Q₁ to Q₈) may each independently be a hydrogen atom or a deuterium atom.

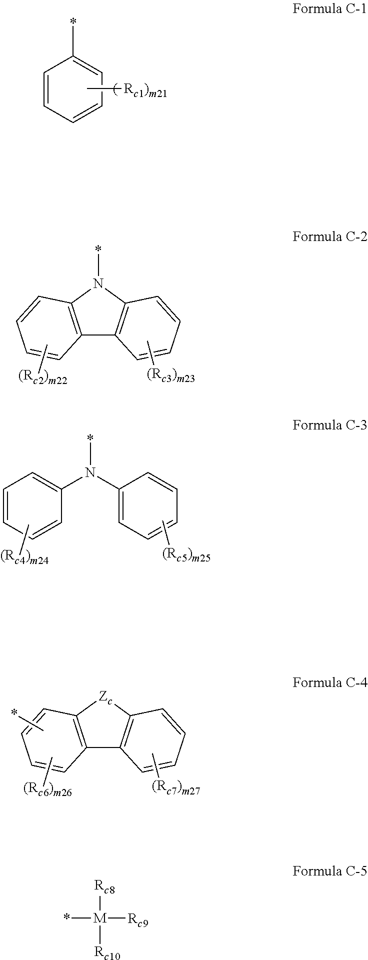

In Formula C-4, Z_{c} may be NR_{c11}, O, S, or Se.

In Formula C-5, M may be Si or Ge.

In Formula C-1 to Formula C-4, R_{c1} to R_{c7} may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In one or more embodiments, each of R_{c1} to R_{c7} may be bonded to an adjacent group to form a ring. R_{c1} to R_{c7} may each independently be a hydrogen atom, a deuterium atom, a cyano group, or a substituted or unsubstituted phenyl group.

In Formula C-4 and Formula C-5, R_{c8} to R_{c11} may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In one or more embodiments, R_{c8} to R_{c10} may each independently be a substituted or unsubstituted alkyl group having 1 to 20 carbon atoms, or a substituted or unsubstituted aryl group having 6 to 30 ring-forming carbon atoms. In one or more embodiments, R_{c11} may be a substituted or unsubstituted aryl group having 6 to 30 ring-forming carbon atoms, or a substituted or unsubstituted heteroaryl group having 2 to 30 ring-forming carbon atoms. For example, R_{c8} to R_{c10} may each independently be a substituted or unsubstituted methyl group, or a substituted or unsubstituted phenyl group, and R_{c11} may be a substituted or unsubstituted phenyl group.

In Formula C-1 to Formula C-4, m21, m24, and m25 may each independently be an integer of 0 to 5, m22, m23, and m27 may each independently be an integer of 0 to 4, and m26 is an integer 0 to 3.

When each of m21, m24, and m25 is 0, the fused polycyclic compound of one or more embodiments may not be substituted with each of R_{c1}, R_{c4}, and R_{c5}. The case where each of m21, m24, and m25 is 5 and R_{c1}'s, R_{c4}'s, and R_{c5}'s are each hydrogen atoms may be the same as the case where each of m21, m24, and m25 is 0. When each of m21, m24, and m25 is an integer of 2 or more, a plurality of R_{c1}'s, R_{c4}'s, and R_{c5}'s each may be the same or at least one among the plurality of R_{c1}'s, R_{c4}'s, and R_{c5}'S may be different from the others.

When each of m22, m23, and m27 is 0, the fused polycyclic compound of one or more embodiments may not be substituted with each of R_{c2}, R_{c3}, and R_{c7}. The case where each of m22, m23, and m27 is 4 and R_{c2}'s, R_{c3}'S, and R_{c7}'s are each hydrogen atoms may be the same as the case where each of m22, m23, and m27 is 0. When each of m22, m23, and m27 is an integer of 2 or more, a plurality of R_{c2}'s, R_{c3}'s, and R_{c7}'s each may be the same or at least one among the plurality of R_{c2}'s, R_{c8}'s, and R_{c7}'s may be different from the others.

When m26 is 0, the fused polycyclic compound of one or more embodiments may not be substituted with R_{c6}. The case where m26 is 3 and R_{c6}'s are all hydrogen atoms may be the same as the case where m26 is 0. When m26 is an integer of 2 or more, a plurality of R_{c6}'s may all be the same, or at least one among the plurality of R_{c6}'S may be different from the others.

In Formula 6-1 to Formula 6-3, the same as described in Formula 1 and Formula S may be applied to X₁, R₁ to R₈, Z₁ to Z₃, and n1 to n3.

In one or more embodiments, the fused polycyclic compound represented by Formula 1 of one or more embodiments may include at least one deuterium atom as a substituent. The fused polycyclic compound represented by Formula 1 of one or more embodiments may include a structure in which at least one hydrogen atom is substituted with a deuterium atom.

The fused polycyclic compound of one or more embodiments may be any (e.g., at least) one selected from among the compounds represented by Compound Group 1. At least one functional layer included in the light emitting element ED of one or more embodiments may include at least one fused polycyclic compound among the compounds represented by Compound Group 1. The light emitting element ED of one or more embodiments may include at least one fused polycyclic compound (e.g., may include one or more fused polycyclic compounds) selected from among the compounds represented by Compound Group 1 in the emission layer EML.

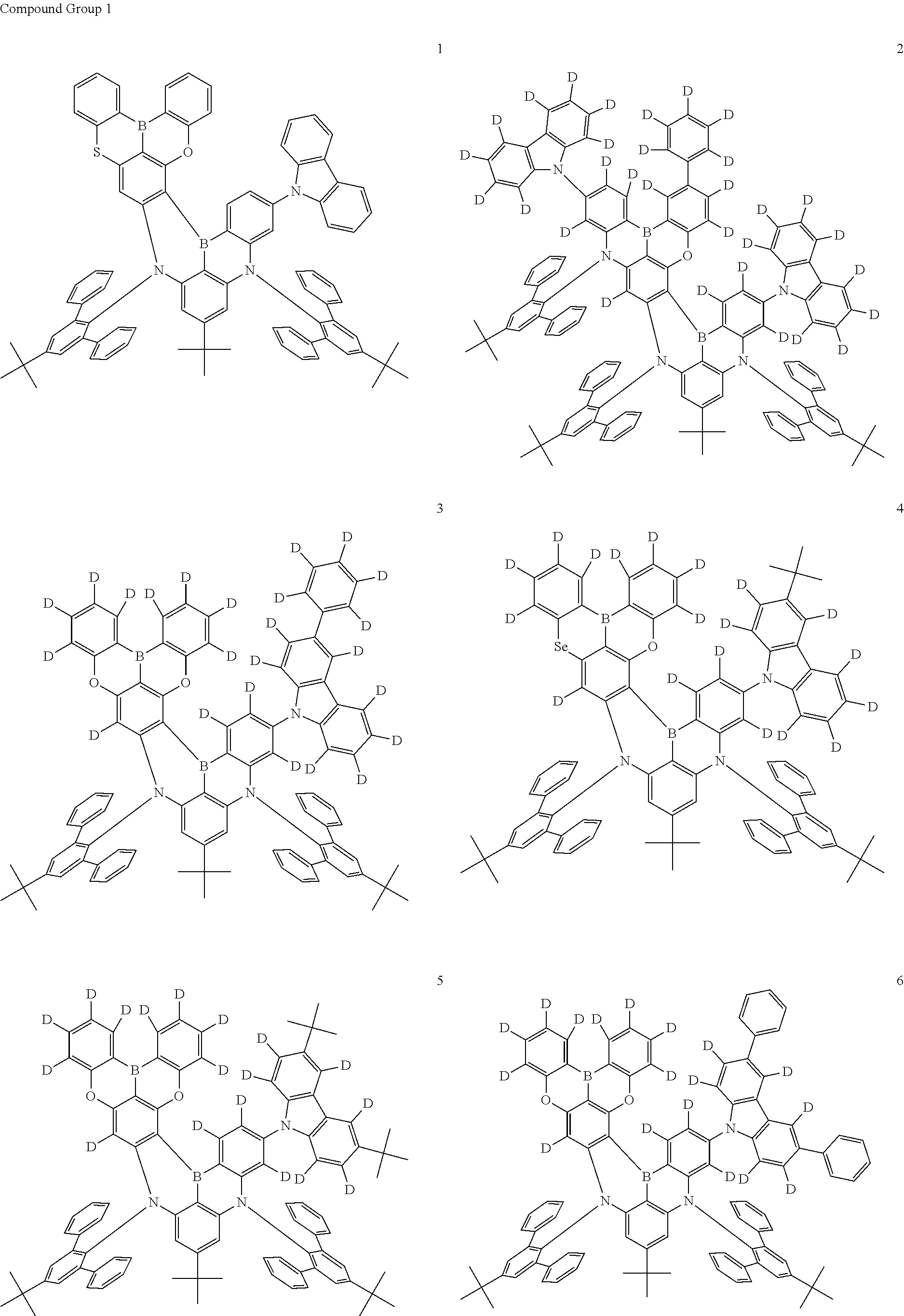

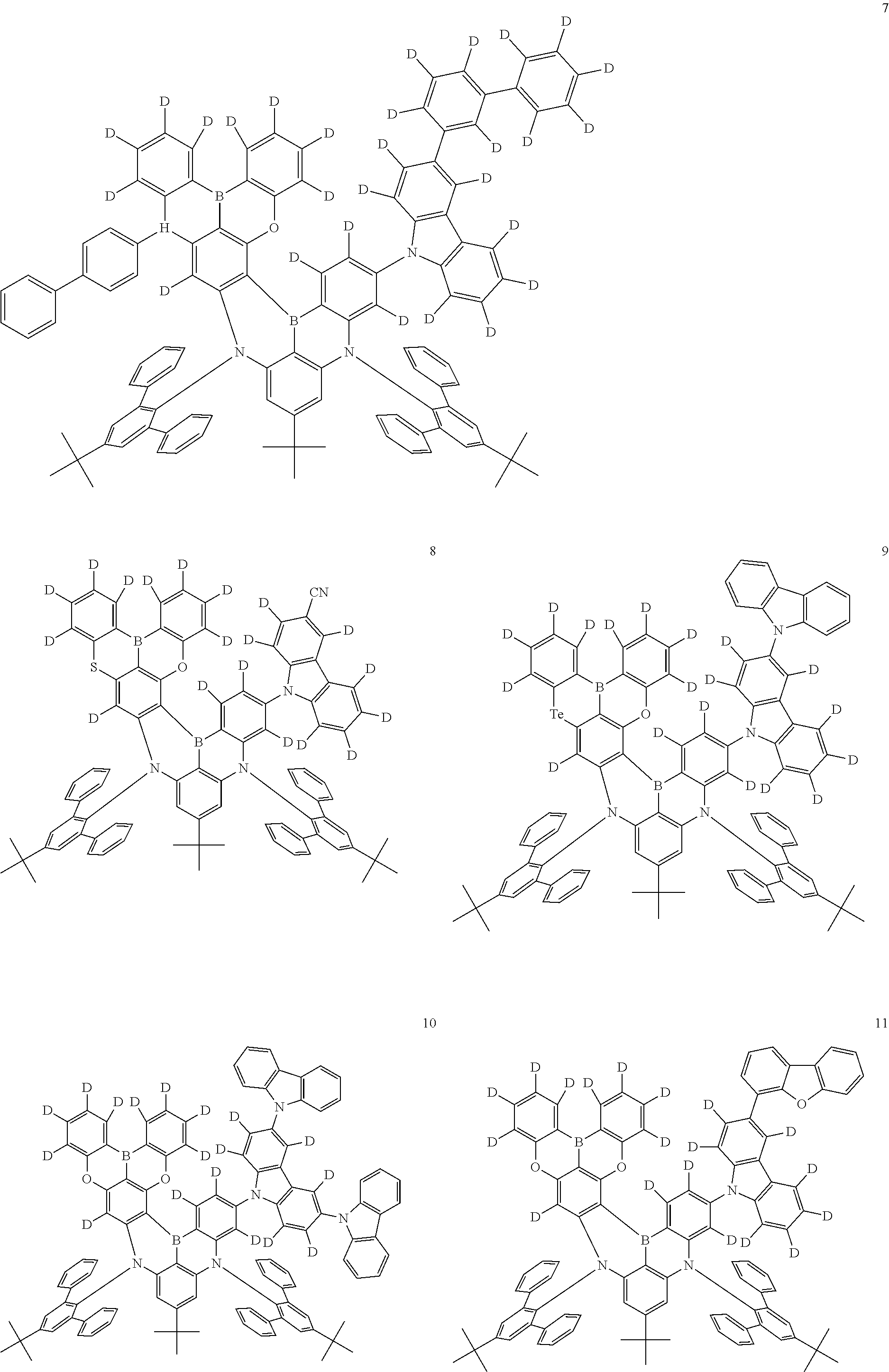

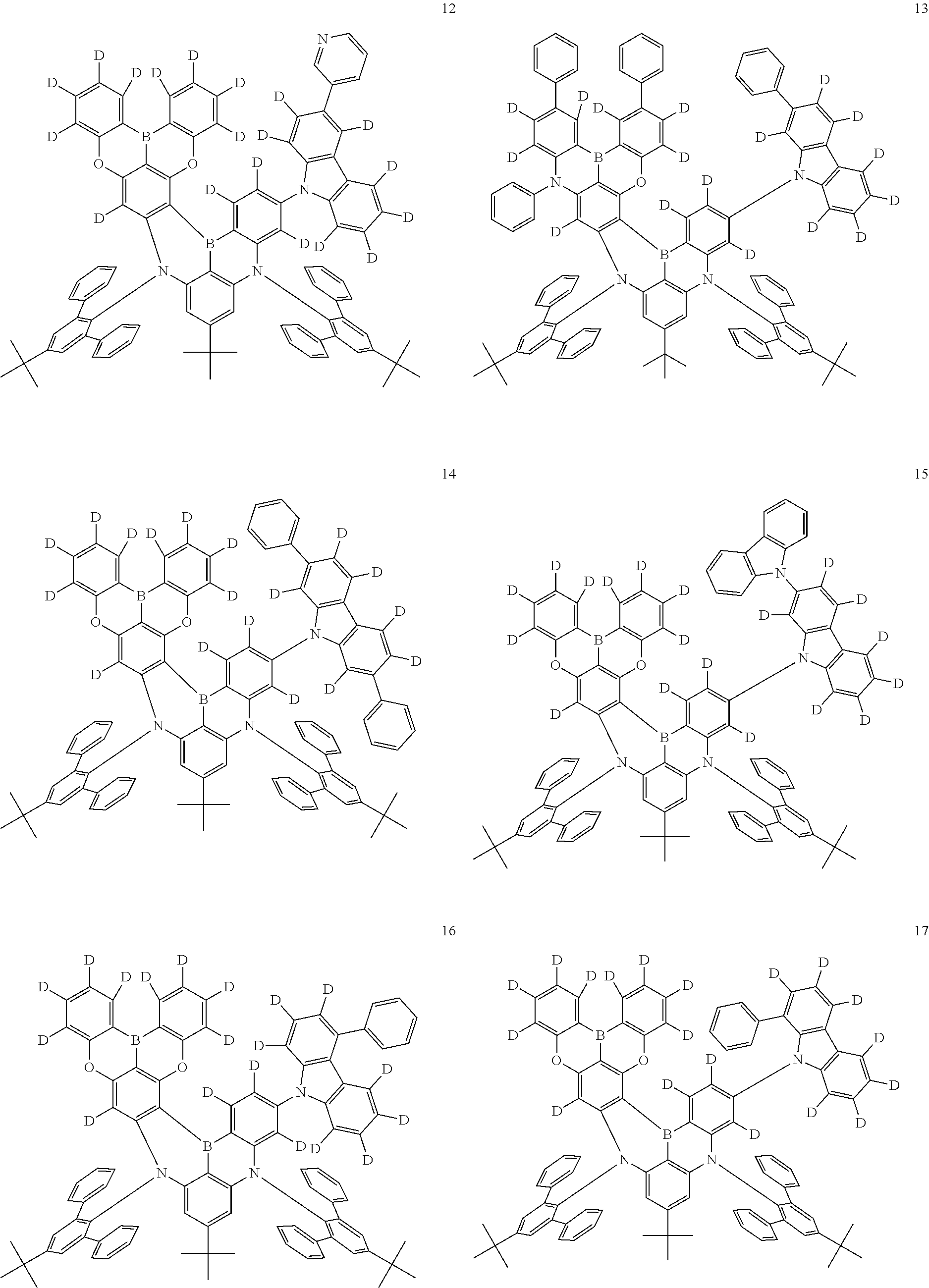

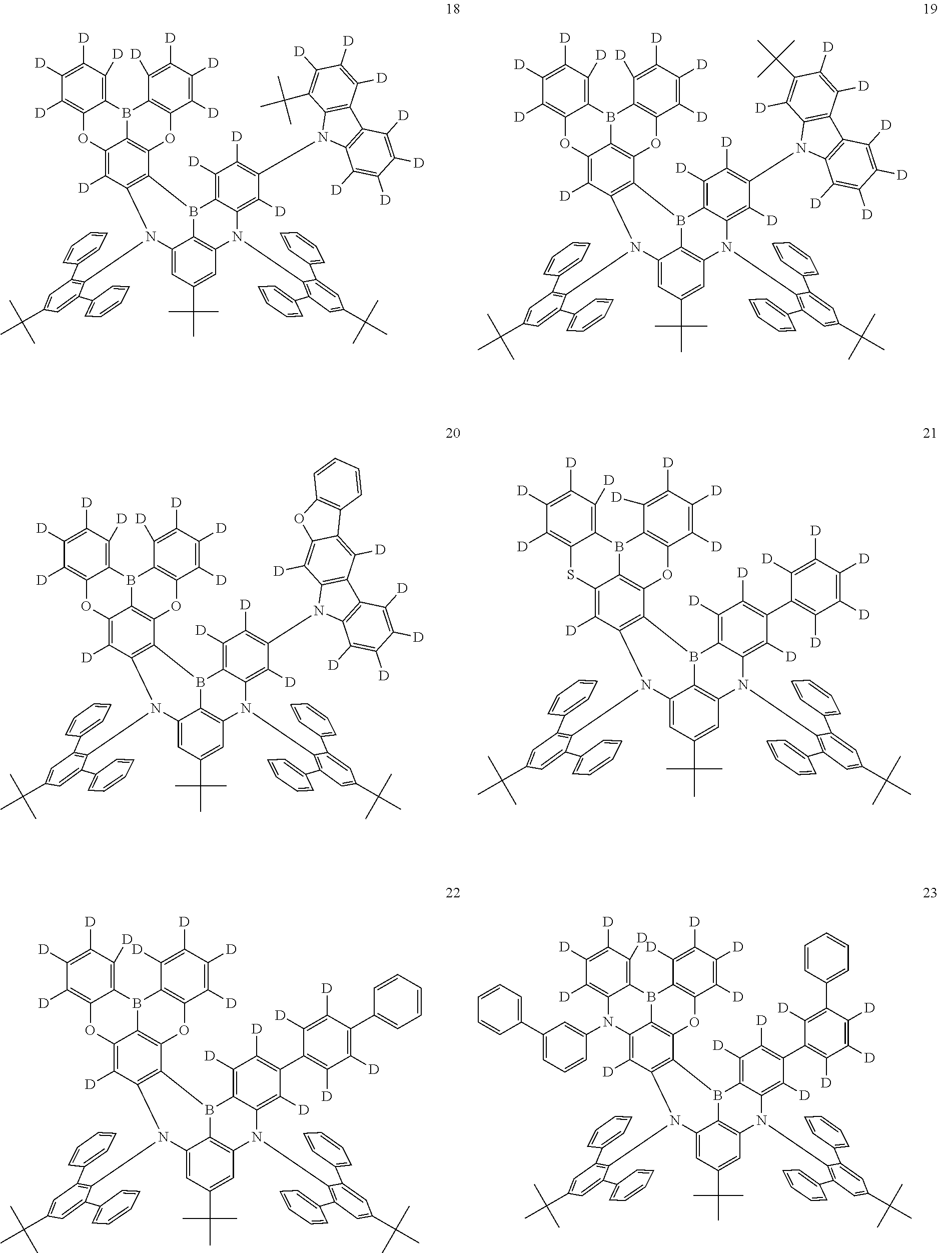

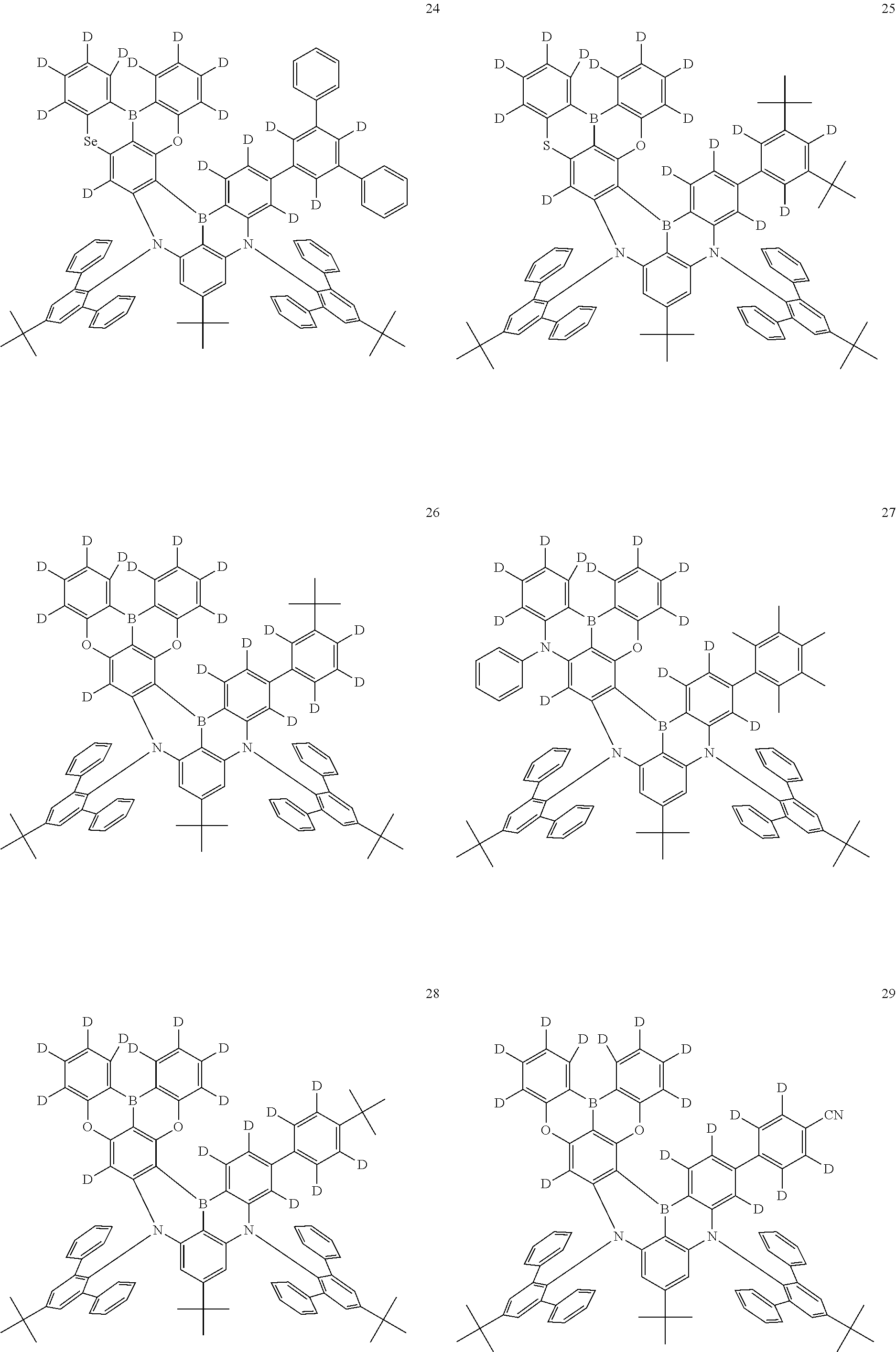

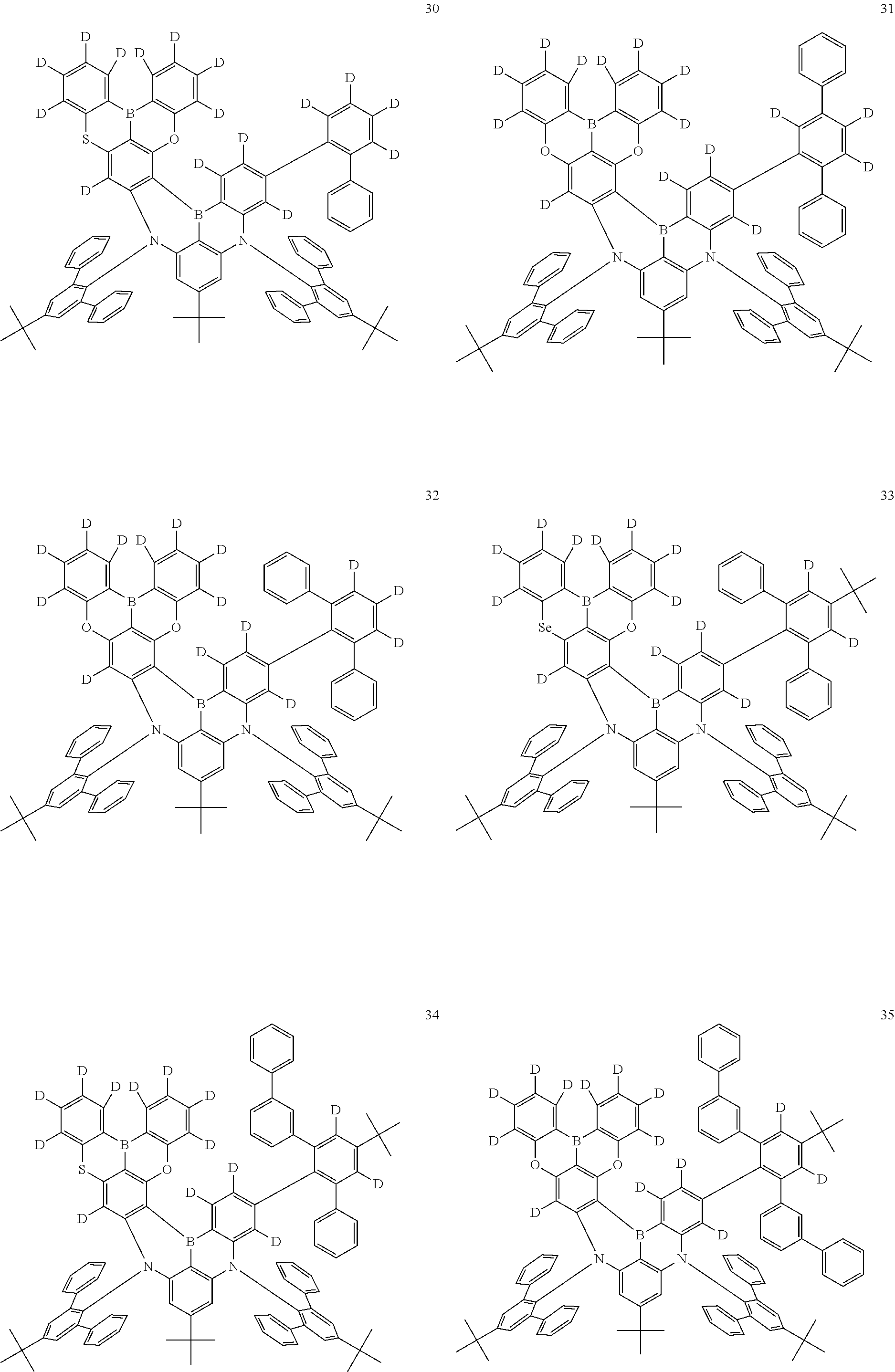

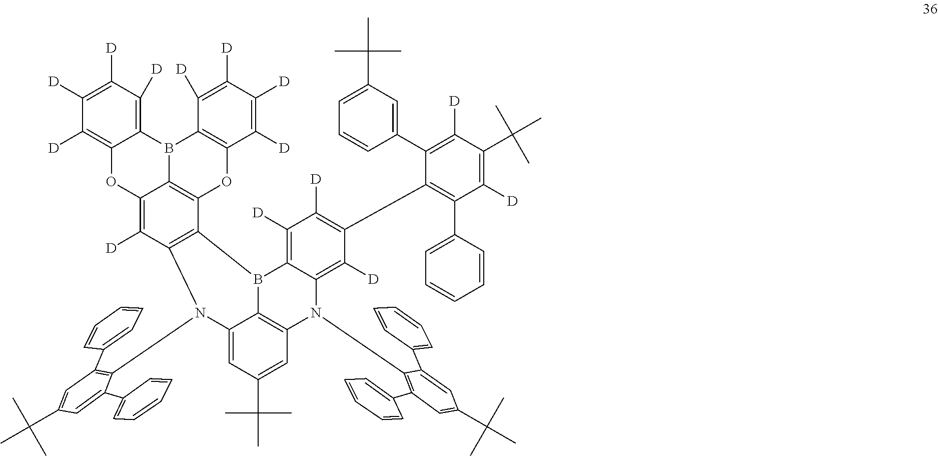 [SMILES: [2H]c1c([2H])c([2H])c2c(c1[2H])Oc1c([2H])c3c(c4c1B2c1c([2H])c([2H])c([2H])c([2H])c1O4)B1c2c(cc(C(C)(C)C)cc2N3c2c(-c3ccccc3)cc(C(C)(C)C)cc2-c2ccccc2)N(c2c(-c3ccccc3)cc(C(C)(C)C)cc2-c2ccccc2)c2c([2H])c(-c3c(-c4ccccc4)c([2H])c(C(C)(C)C)c([2H])c3-c3cccc(C(C)(C)C)c3)c([2H])c([2H])c21]

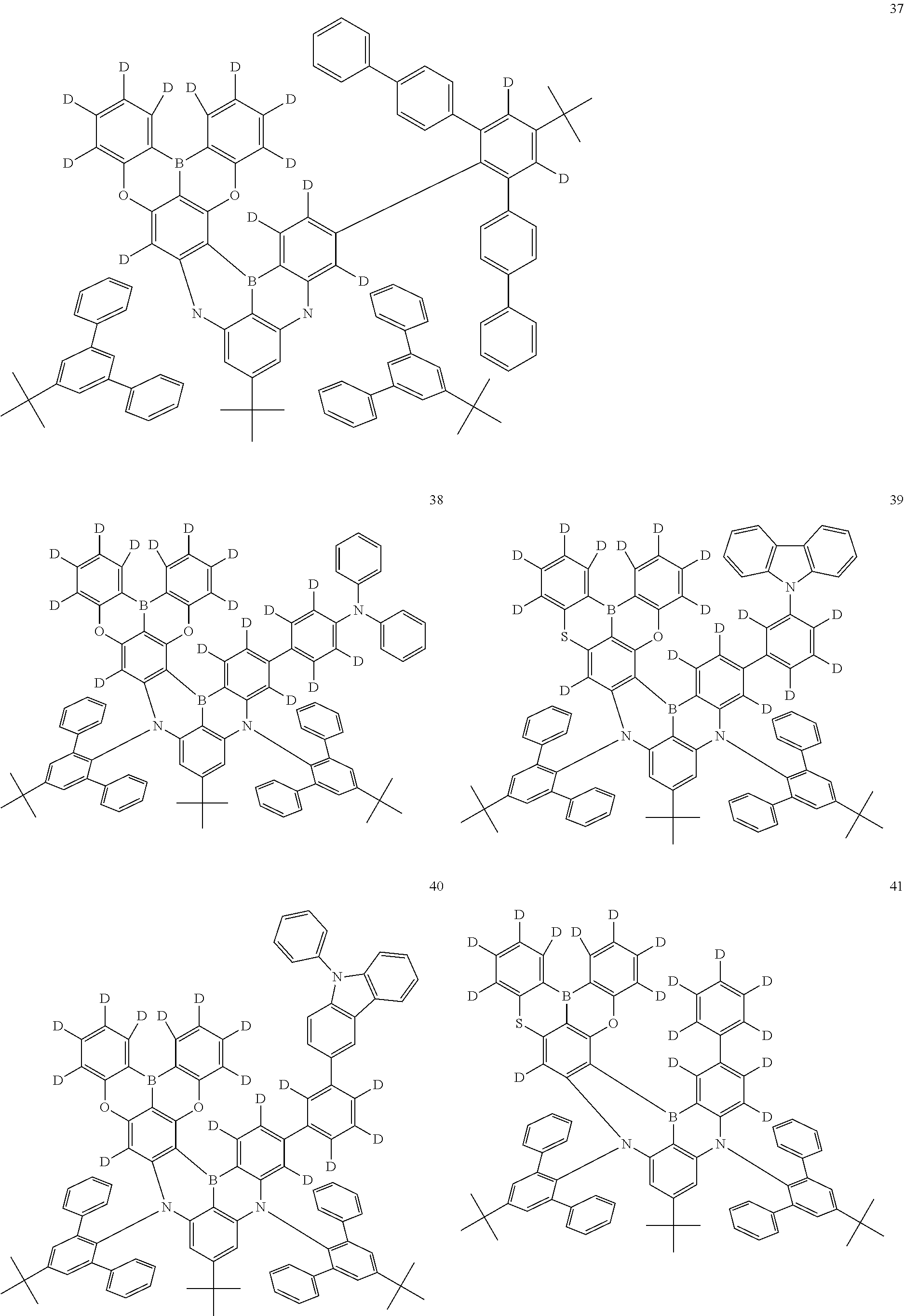

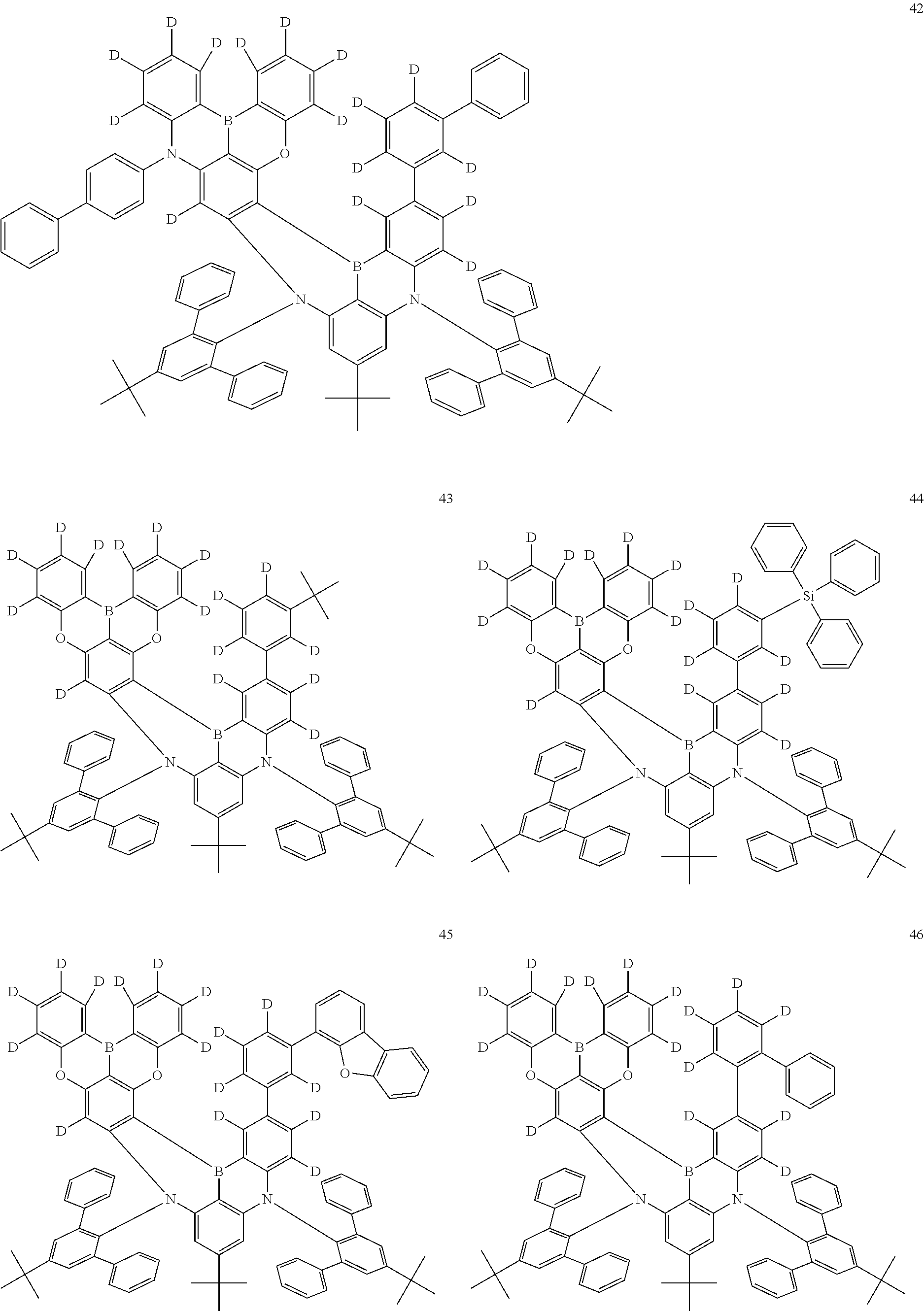

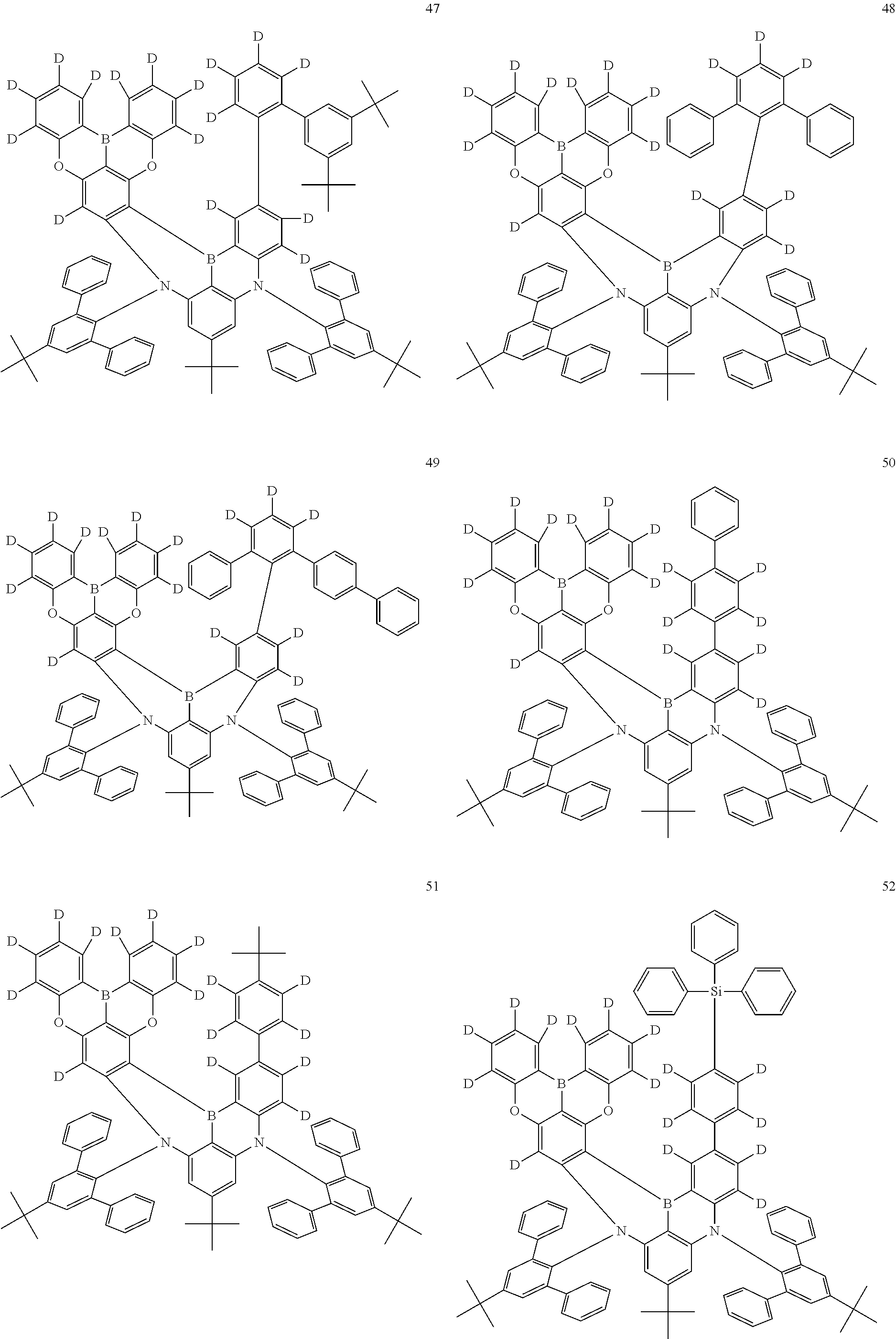

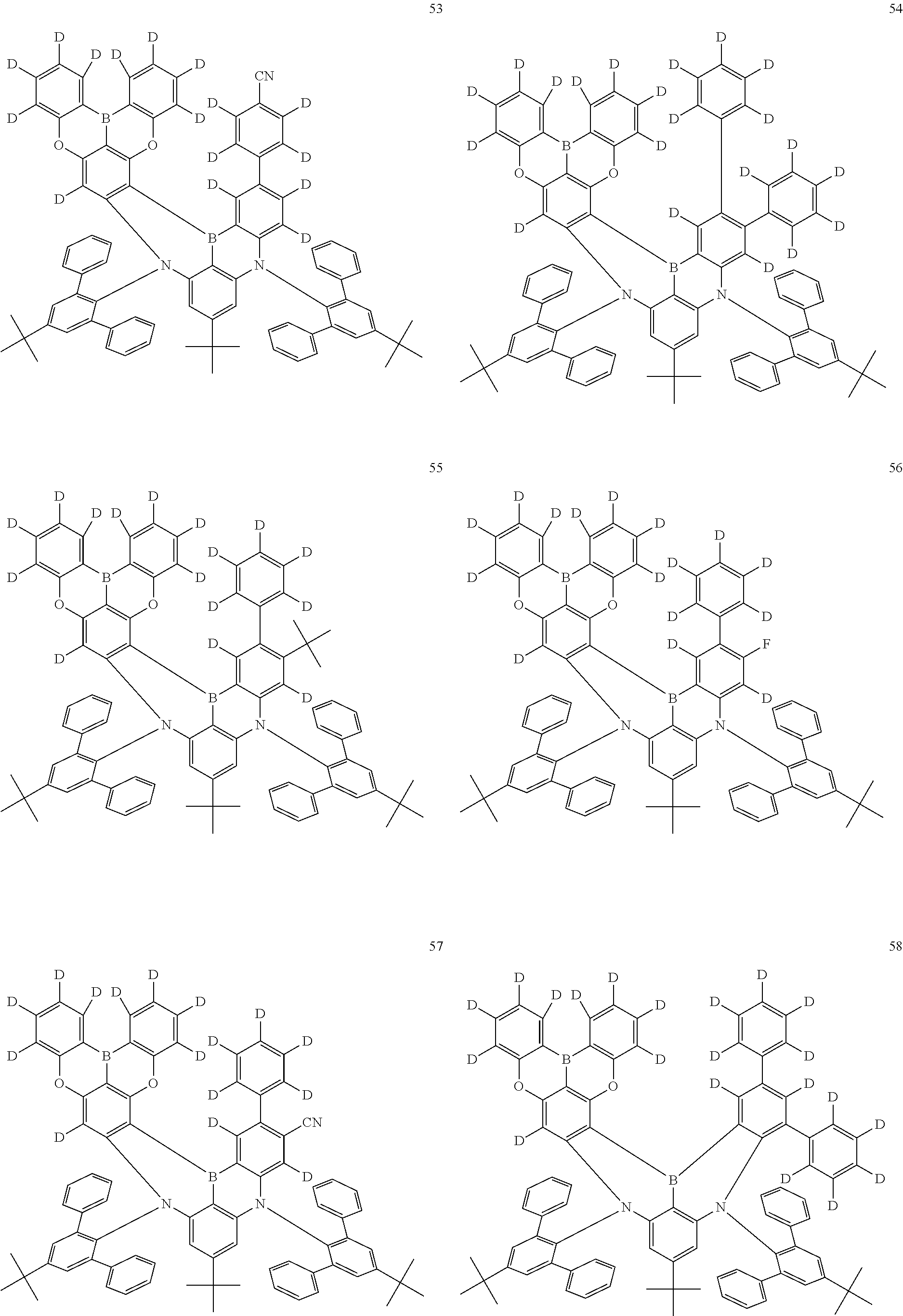

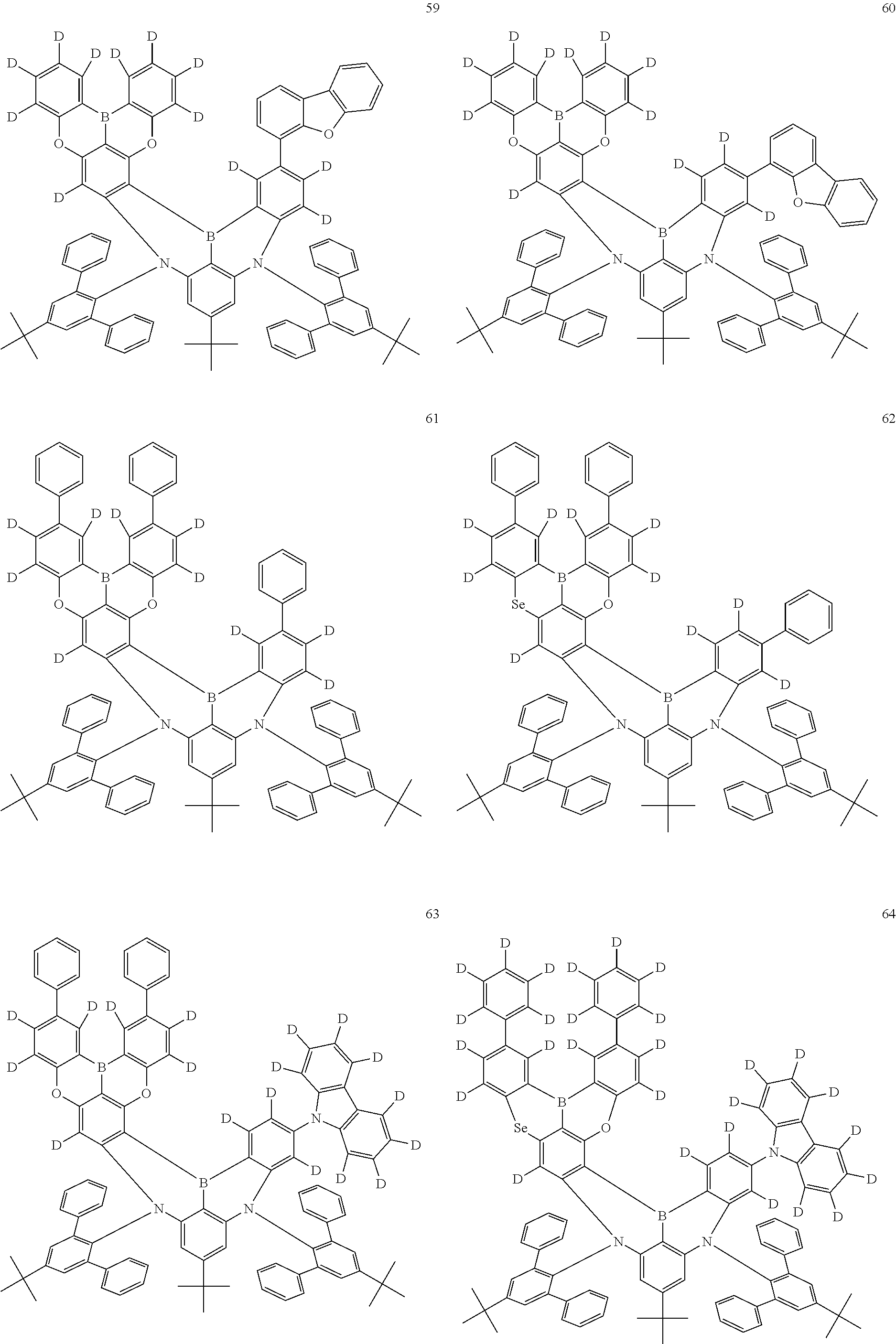

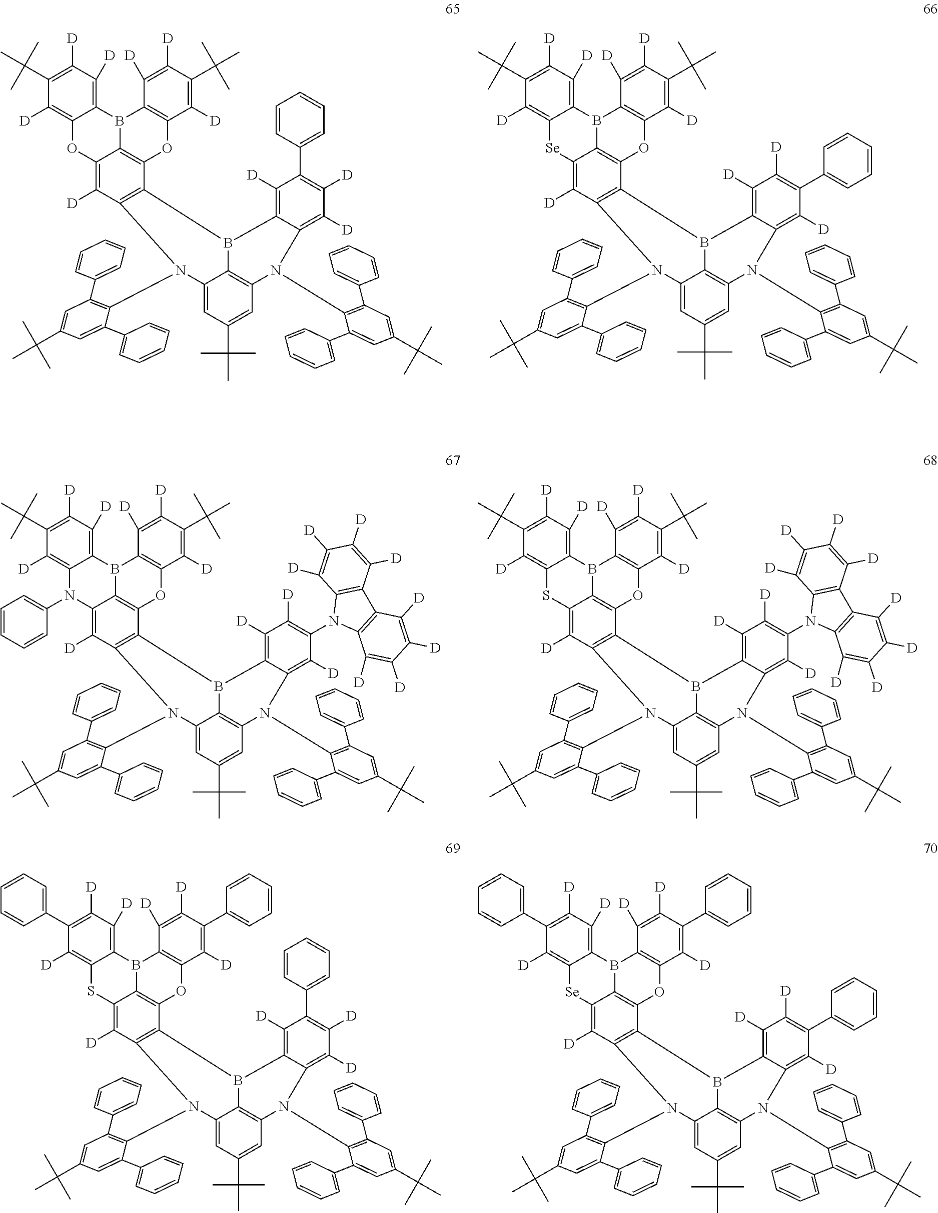

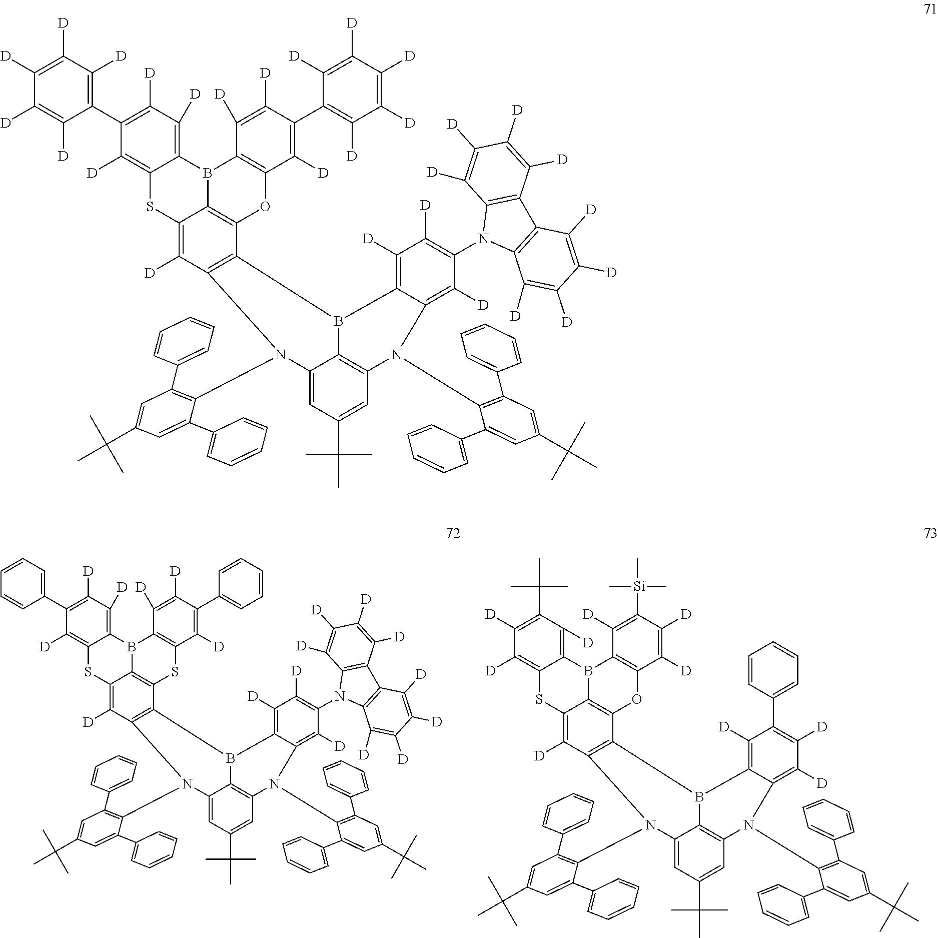

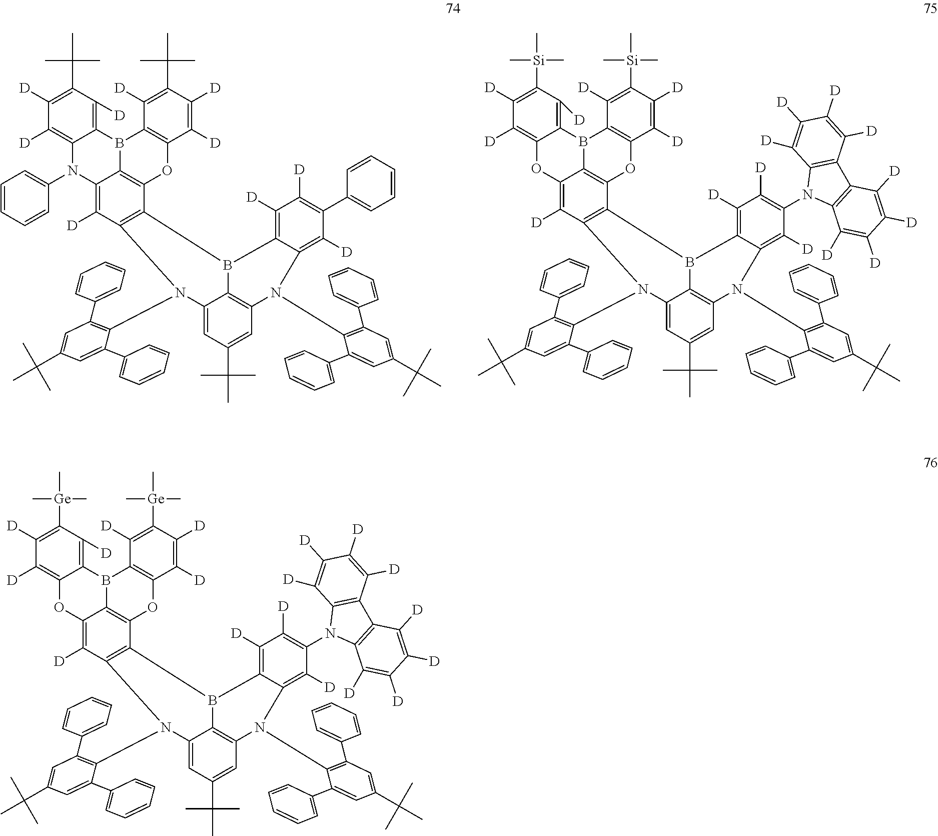

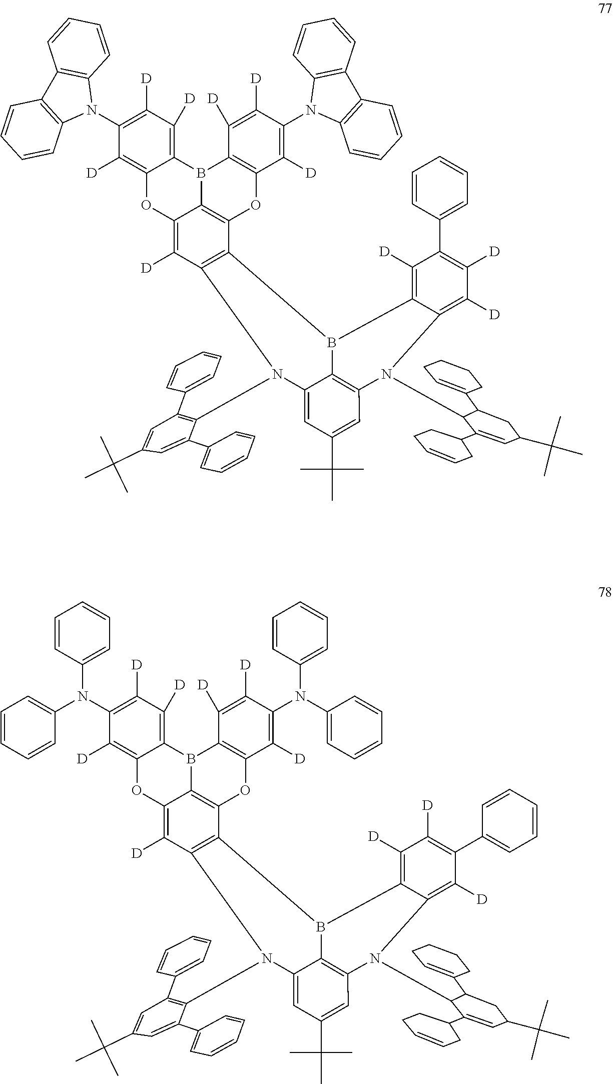

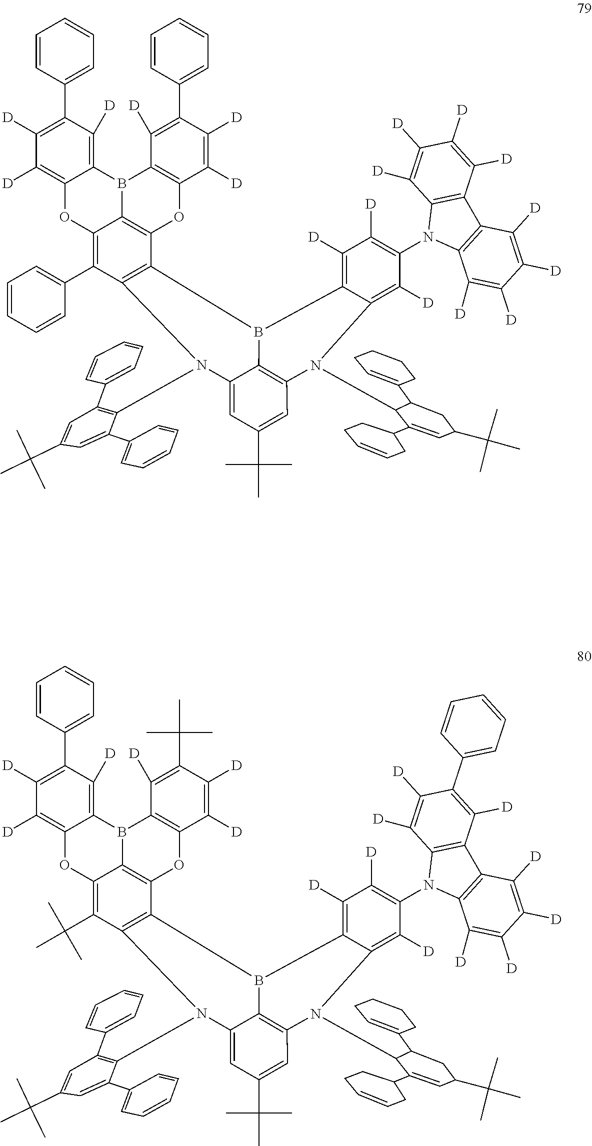

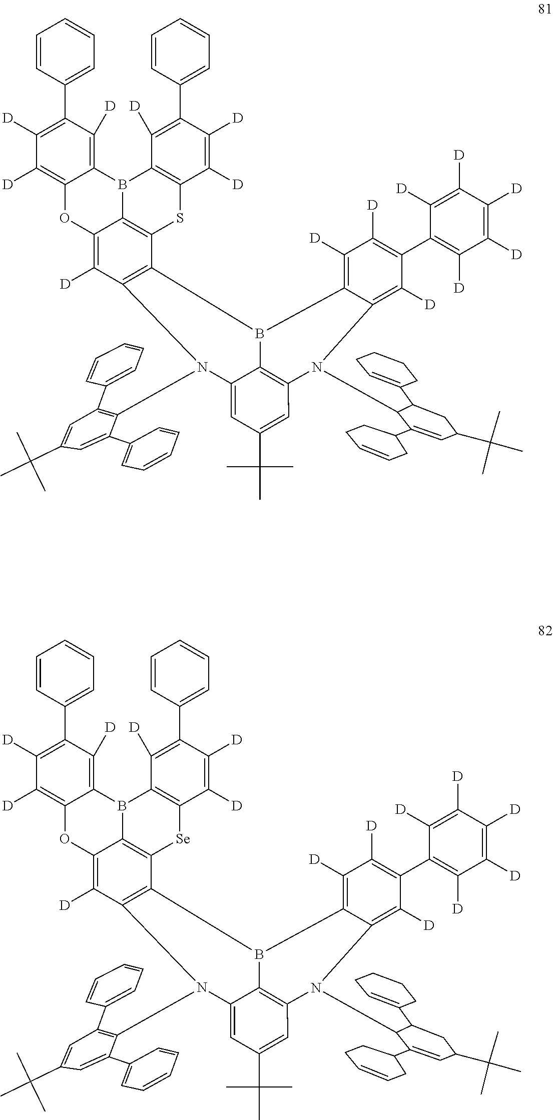

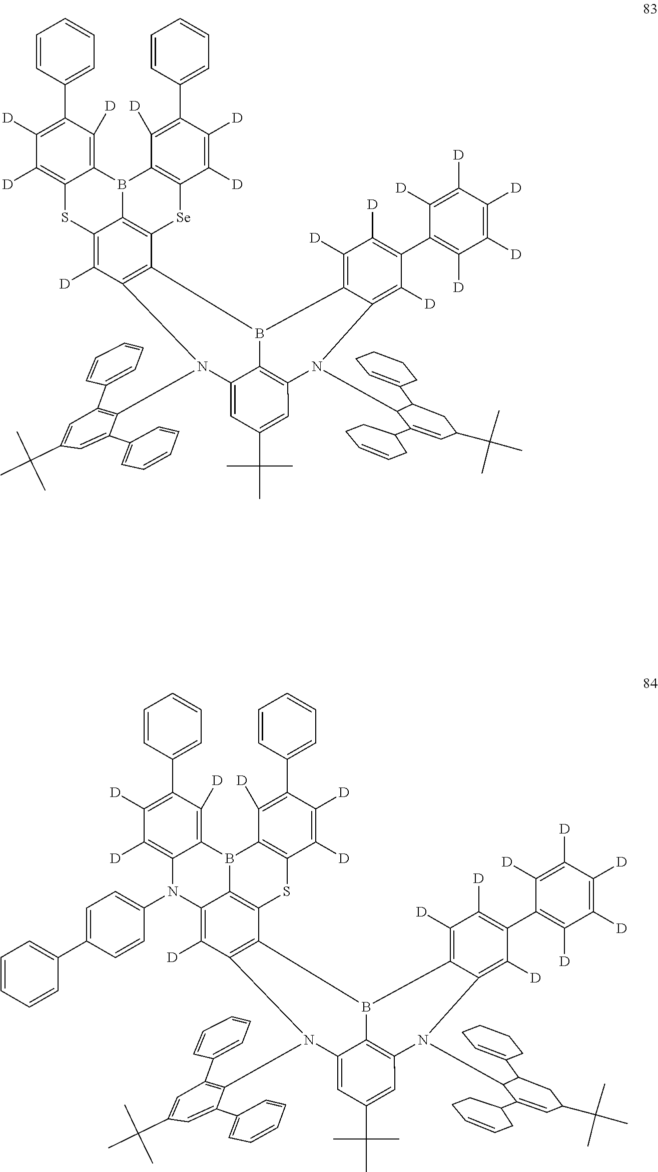

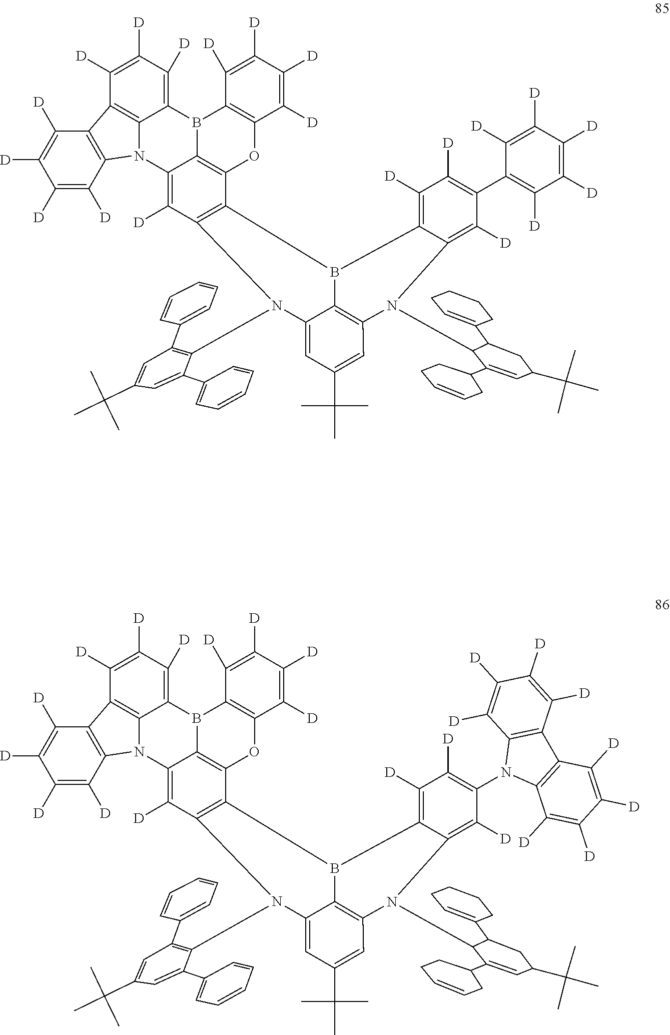

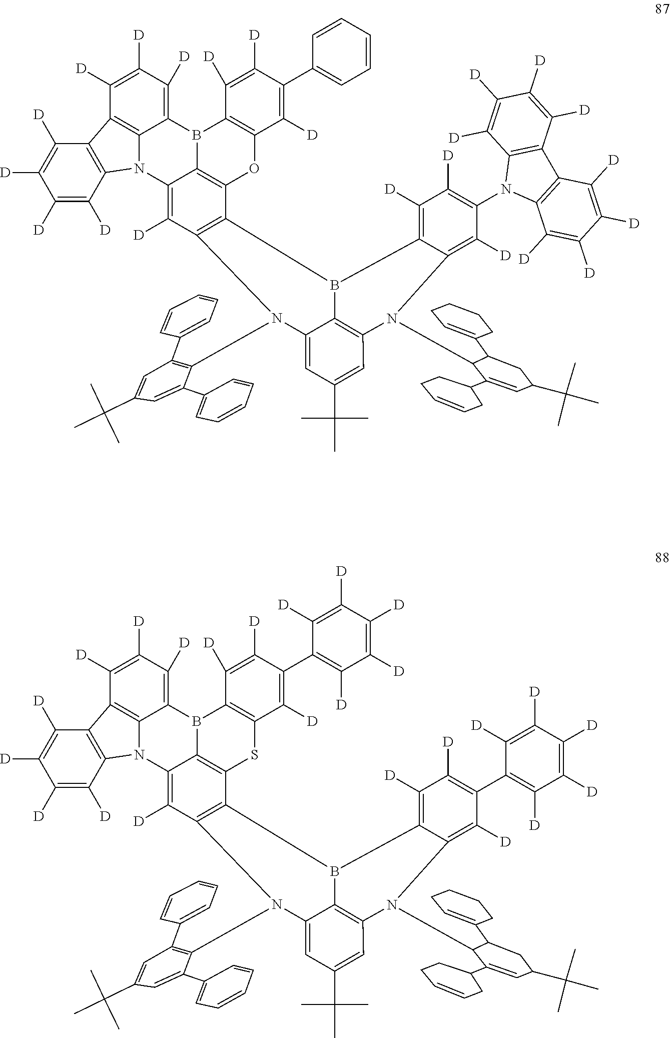

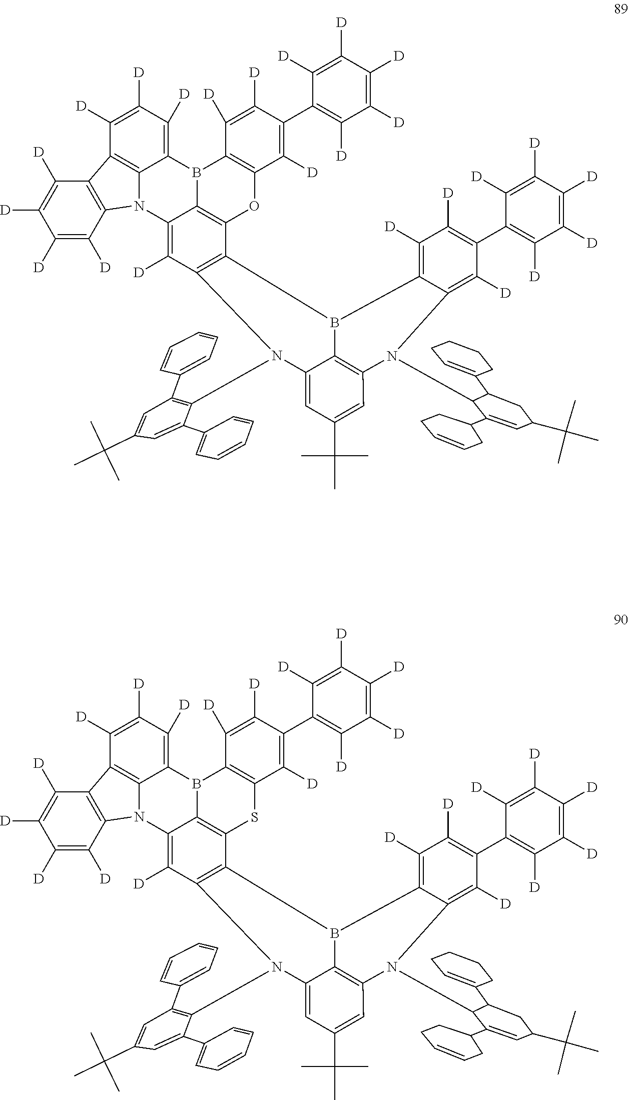

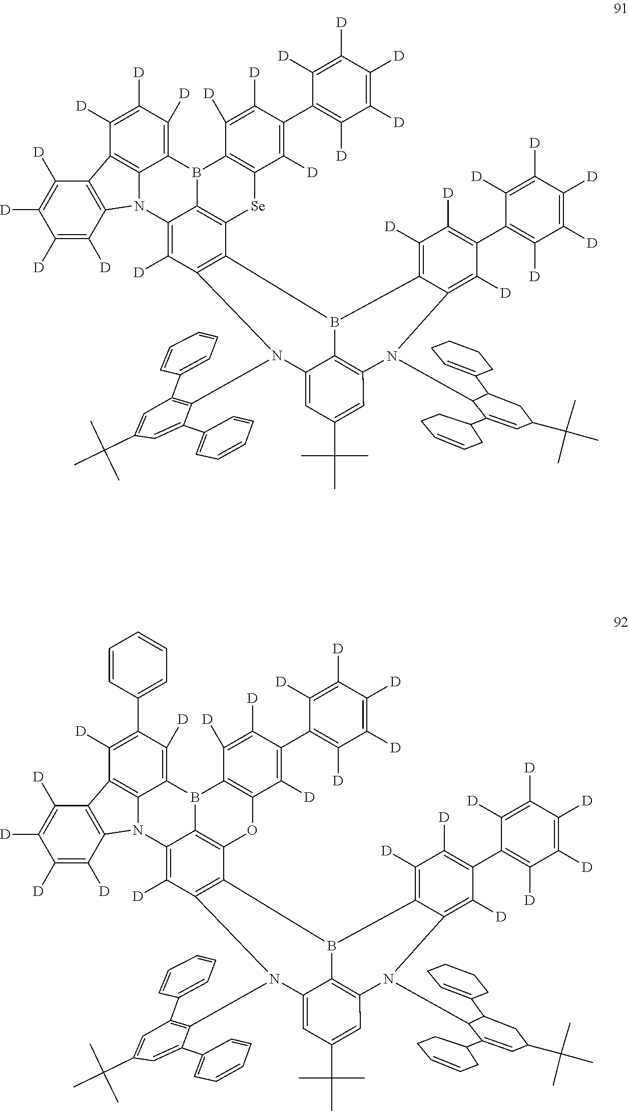

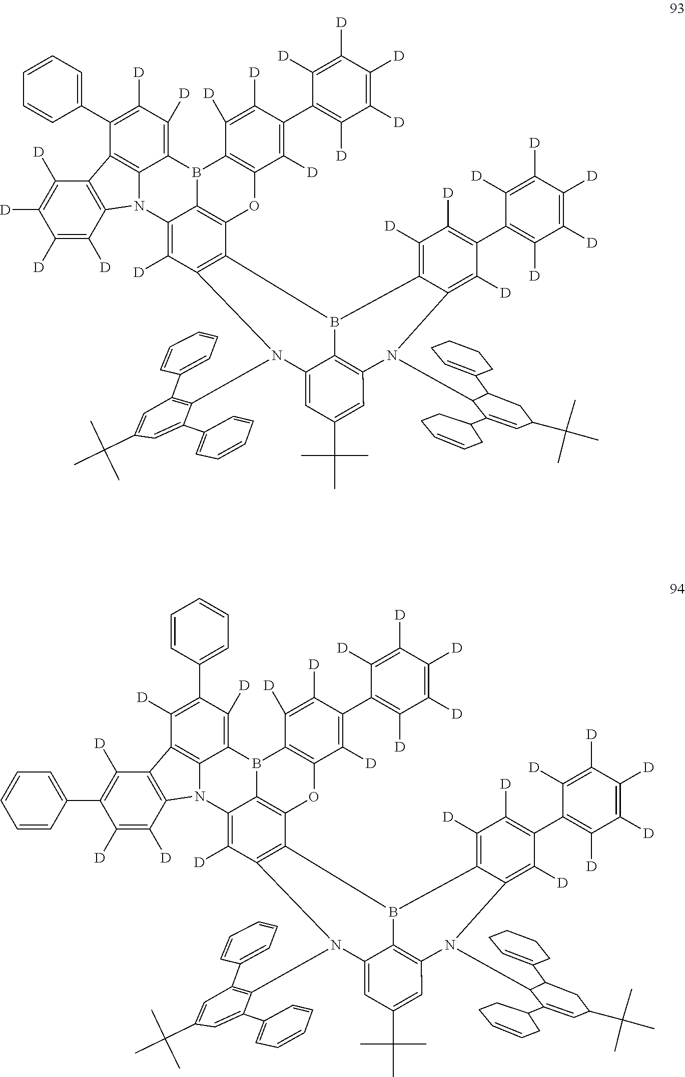

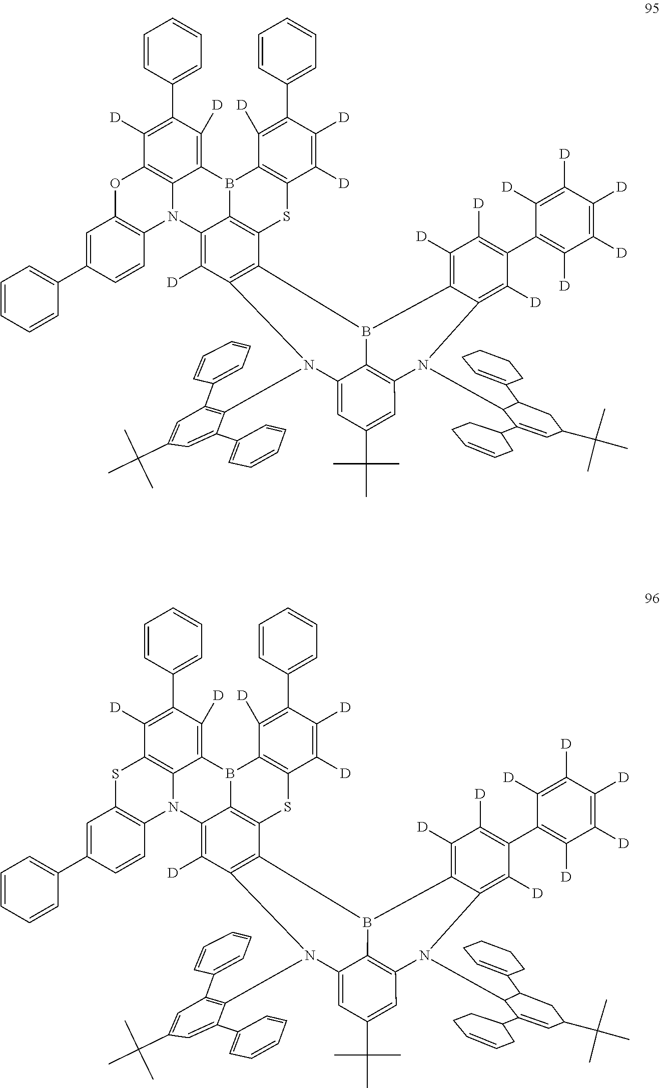

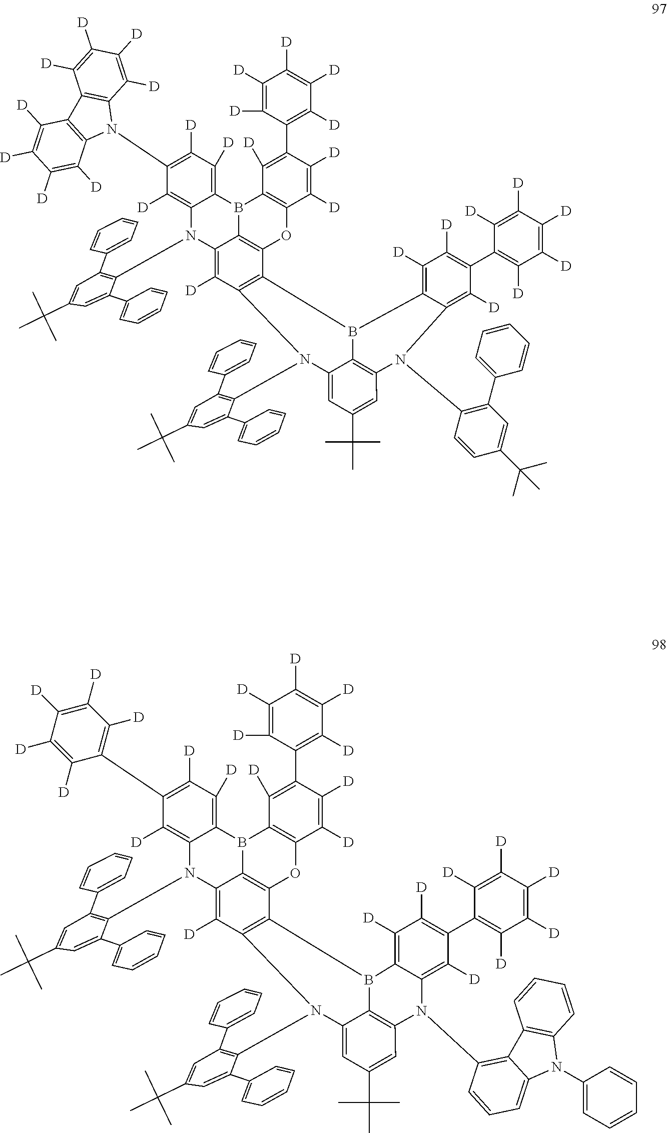

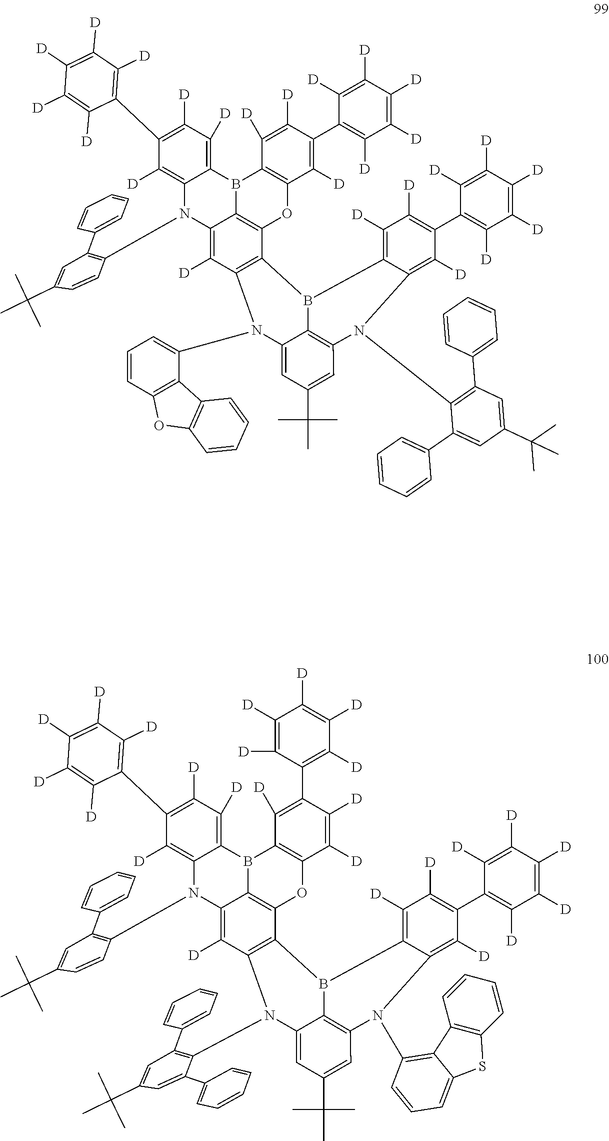

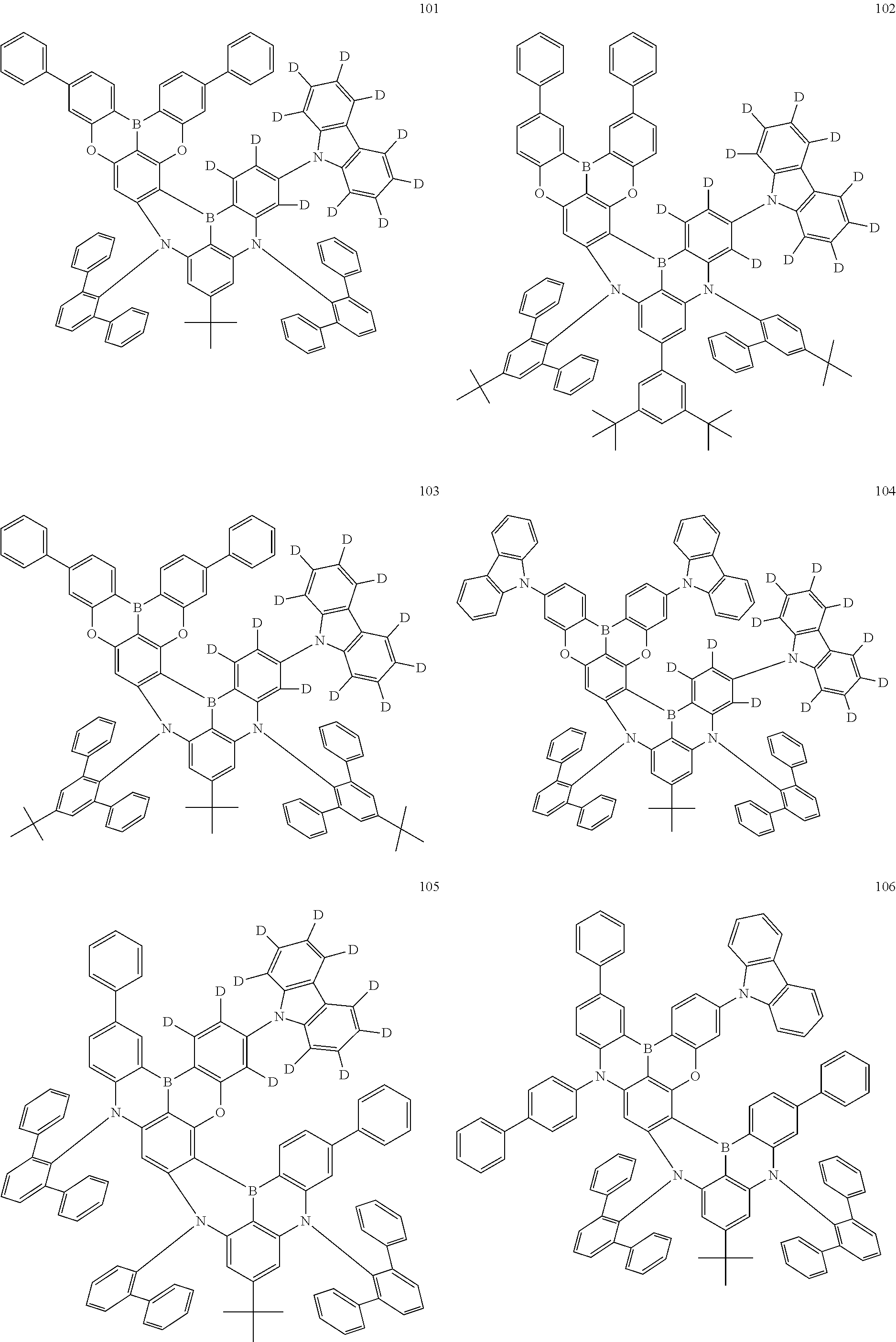

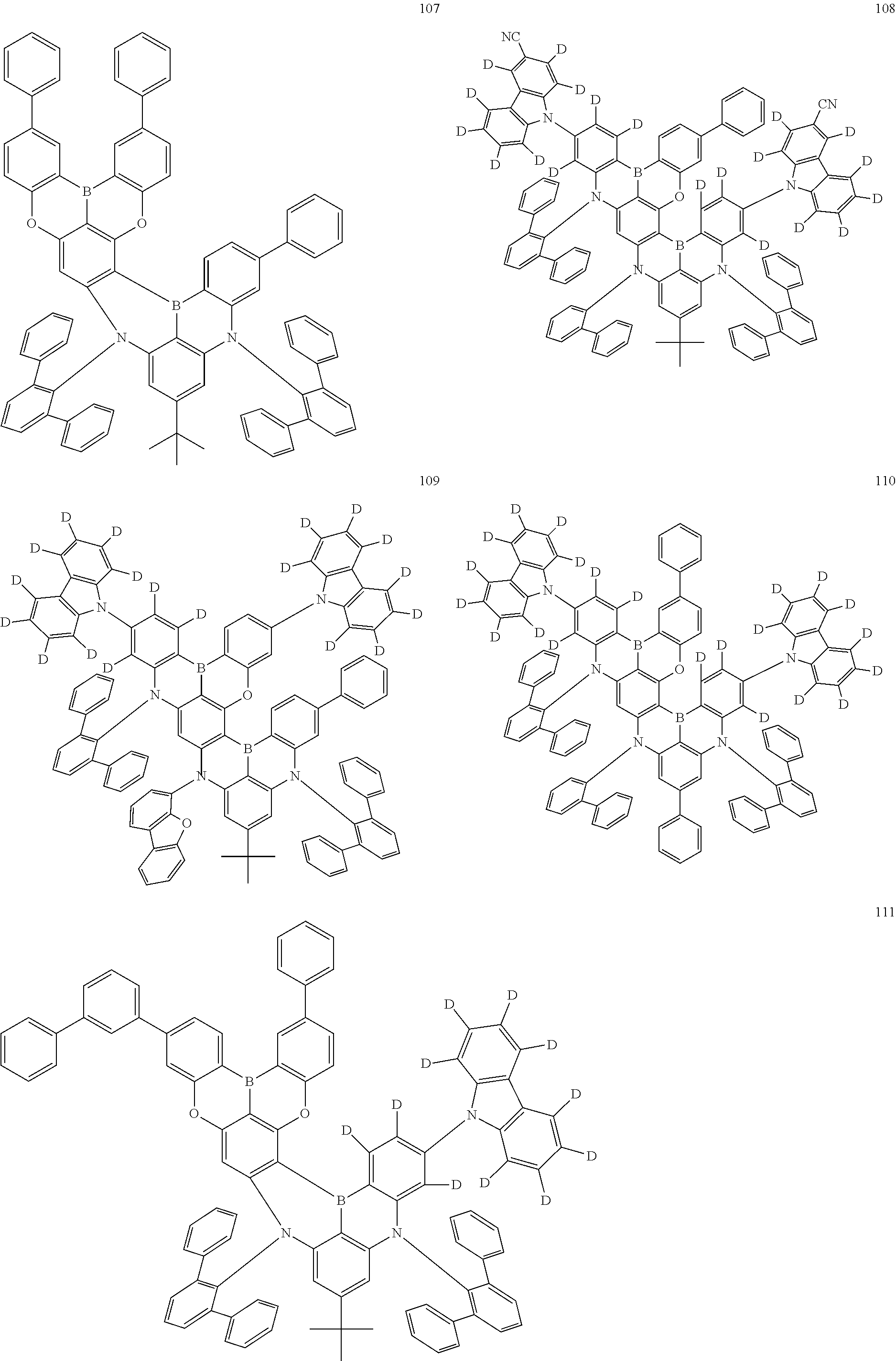

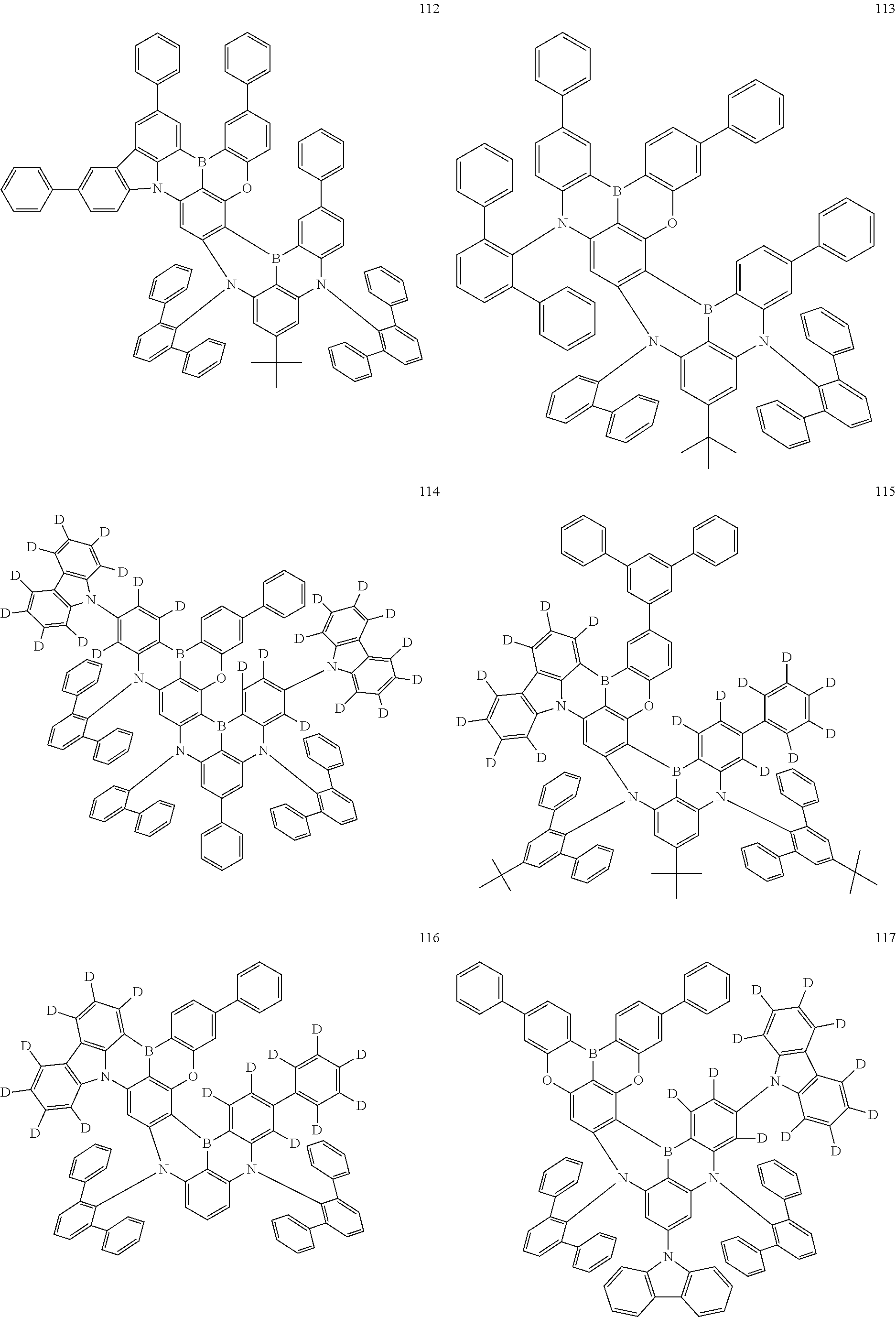

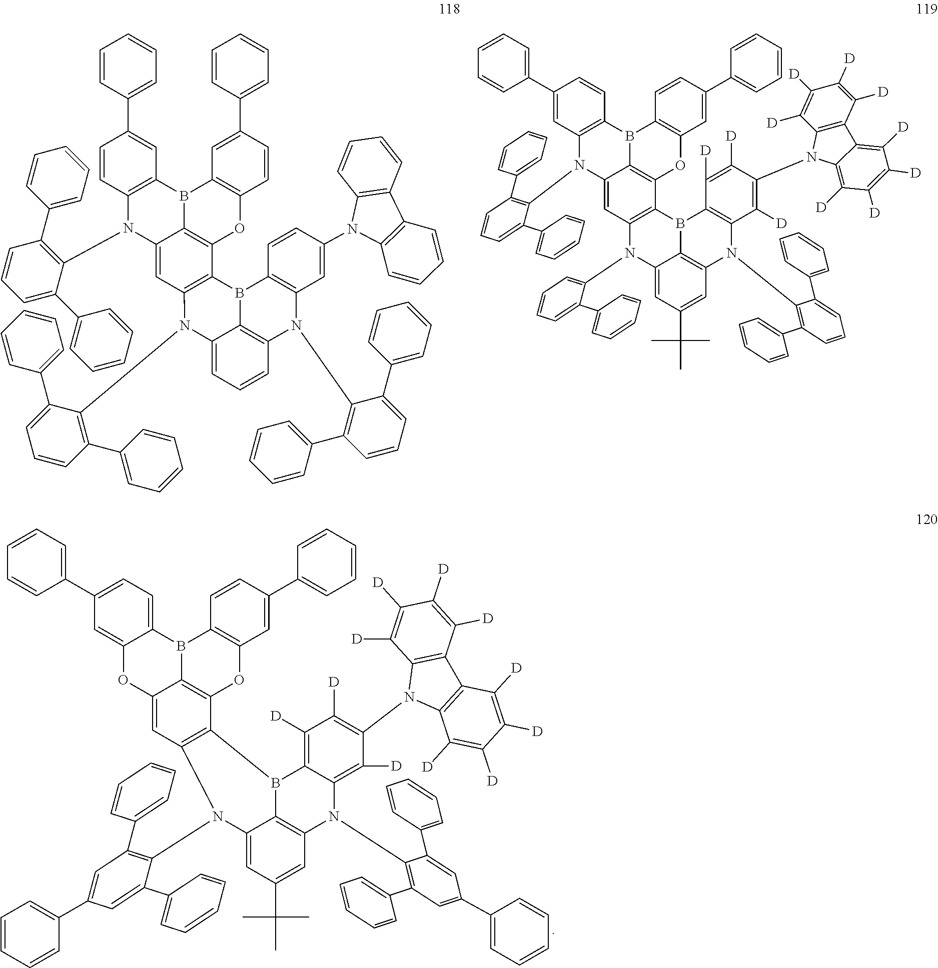

In the embodiment compounds presented in Compound Group 1, “D” refers to a deuterium atom.

The emission spectrum of the fused polycyclic compound represented by Formula 1 of one or more embodiments has a full width of half maximum (FWHM) of about 10 nm to about 50 nm, and about 20 nm to about 40 nm. The emission spectrum of the first dopant represented by Formula 1 of one or more embodiments has the described ranges of FWHM, thereby improving luminous efficiency if (e.g., when) applied to an element. In one or more embodiments, if (e.g., when) the polycyclic compound of one or more embodiments is utilized as a blue light emitting element material for the light emitting element, the element service life may be improved.

In one or more embodiments, the fused polycyclic compound represented by Formula 1 of one or more embodiments may be a thermally activated delayed fluorescence emitting material. Furthermore, the fused polycyclic compound represented by Formula 1 of one or more embodiments may be a thermally activated delayed fluorescence dopant having the difference (ΔE_{ST}) between the lowest triplet exciton energy level (T1 level) and the lowest singlet exciton energy level (S1 level) of about 0.6 eV or less. The fused polycyclic compound represented by Formula 1 of one or more embodiments may be a thermally activated delayed fluorescence dopant having the difference (ΔE_{ST}) between a lowest triplet exciton energy level (T1 level) and a lowest singlet exciton energy level (S1 level) of about 0.2 eV or less. However, the embodiment of the present disclosure is not limited thereto.

In one or more embodiments, the fused polycyclic compound represented by Formula 1 of one or more embodiments may include the first substituent and the second substituent in the compound. By adjusting the substitution numbers and positions of the first substituent and the second substituent, the singlet energy level and the triplet energy level may be appropriately adjusted in the overall compound.

Accordingly, the fused polycyclic compound according to one or more embodiments of the present disclosure may exhibit improved thermally activated delayed fluorescence characteristics.

The fused polycyclic compound represented by Formula 1 of one or more embodiments may be a luminescent material having a luminescence center wavelength in a wavelength region of about 430 nm to about 490 nm. For example, the fused polycyclic compound of one or more embodiments, represented by Formula 1 may be a blue thermally activated delayed fluorescence (TADF) dopant. However, the embodiment of the present disclosure is not limited thereto, if (e.g., when) the fused polycyclic compound of one or more embodiments is utilized as a luminescent material, the first dopant may be utilized as a dopant material that emits light in one or more suitable wavelength regions, such as a red emitting dopant and a green emitting dopant.

The emission layer EML in the light emitting element ED of one or more embodiments may be to emit delayed fluorescence. For example, the emission layer EML may be to emit thermally activated delayed fluorescence (TADF).

In one or more embodiments, the emission layer EML of the light emitting element ED may be to emit blue light. For example, the emission layer EML of the light emitting element ED of one or more embodiments may be to emit blue light in the wavelength range of about 490 nm or less. However, the embodiment of the present disclosure is not limited thereto, and the emission layer EML may be to emit green light or red light.

In one or more embodiments, the fused polycyclic compound of one or more embodiments may be included in the emission layer EML. The fused polycyclic compound of one or more embodiments may be included as a dopant material in the emission layer EML. The fused polycyclic compound of one or more embodiments may be a thermally activated delayed fluorescence material. The fused polycyclic compound of one or more embodiments may be utilized as a thermally activated delayed fluorescence dopant. For example, in the light emitting element ED of one or more embodiments, the emission layer EML may include, as a thermally activated delayed fluorescence dopant, at least one among the fused polycyclic compounds represented by Compound Group 1 as described herein. However, utilization of the fused polycyclic compound of one or more embodiments is not limited thereto.

In one or more embodiments, the emission layer EML may include multiple compounds. The emission layer EML of one or more embodiments may include the fused polycyclic compound represented by Formula 1, i.e., the first compound, and at least one among a second compound represented by Formula HT-1, a third compound represented by Formula ET-1 and a fourth compound represented by Formula D-1.

In one or more embodiments, the emission layer EML may include the first compound represented by Formula 1 and further include at least one among a second compound represented by Formula HT-1 and a third compound represented by Formula ET-1.

In one or more embodiments, the emission layer EML may include a second compound represented by Formula HT-1. In one or more embodiments, the second compound may be utilized as a hole transport host material in an emission layer EML.

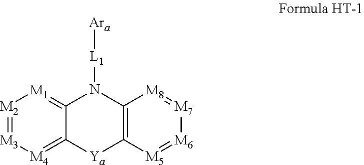

In Formula HT-1, M1 to M₈ may each independently be N or CR₅₁. For example, all M1 to M₈ may be CR₅₁. In one or more embodiments, any (e.g., at least) one selected from among M1 to M₈ may be N, and the remainder (e.g., any remaining selected from among M1 to M₈) may be CR₅₁.

In Formula HT-1, L₁ may be a direct linkage, a substituted or unsubstituted arylene group of 6 to 30 ring-forming carbon atoms, or a substituted or unsubstituted heteroarylene group of 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, and/or the like, but one or more embodiments of the present disclosure is not limited thereto.

In Formula HT-1, Yₐ may be a direct linkage, CR₅₂R₅₃, or SiR₅₄R₅₅. For example, two benzene rings connected with the nitrogen atom of Formula HT-1 may be connected via a direct linkage,

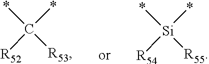

In Formula HT-1, when Yₐ is a direct linkage, the substituent represented by Formula HT-1 may include a carbazole moiety.

In Formula HT-1, Arₐ may be a substituted or unsubstituted aryl group of 6 to 30 ring-forming carbon atoms, or a substituted or unsubstituted heteroaryl group of 2 to 30 ring-forming carbon atoms. For example, Arₐ may be a substituted or unsubstituted carbazole group, a substituted or unsubstituted dibenzofuran group, a substituted or unsubstituted dibenzothiophene group, a substituted or unsubstituted biphenyl group, and/or the like, but one or more embodiments of the present disclosure is not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. In one or more embodiments, each of R₅₁ to R₅₅ may be combined with an adjacent group to form a ring. For example, R₅₁ to R₅₅ may each independently be a hydrogen atom or a deuterium atom. R₅₁ to R₅₅ may each independently be an unsubstituted methyl group or an unsubstituted phenyl group.

In one or more embodiments, the second compound represented by Formula HT-1 may be represented by any (e.g., at least) one selected from among the compounds represented in Compound Group 2. An emission layer EML may include at least one (e.g., one or more) selected from among the compounds represented in Compound Group 2 as a hole transport host material.

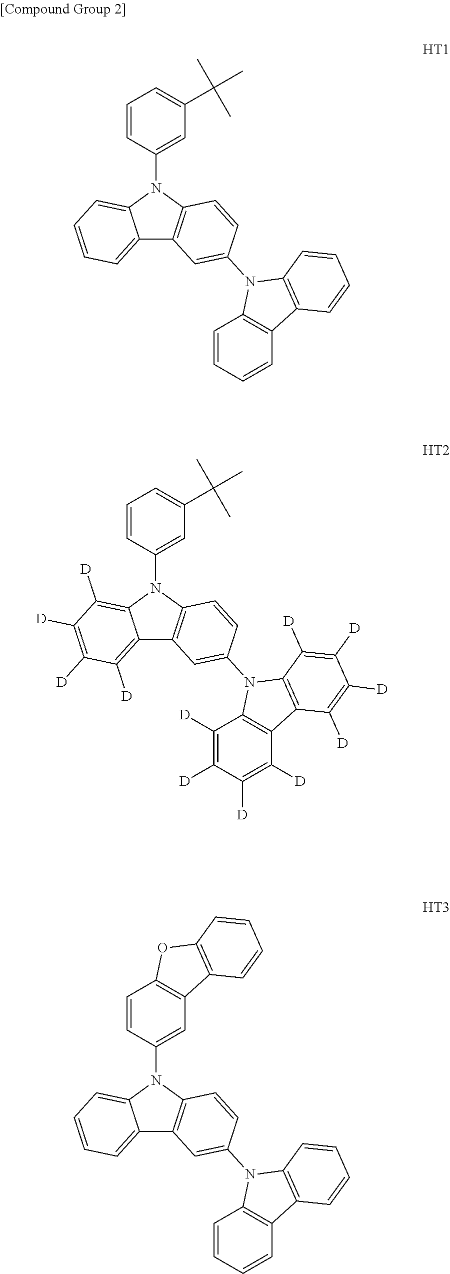 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

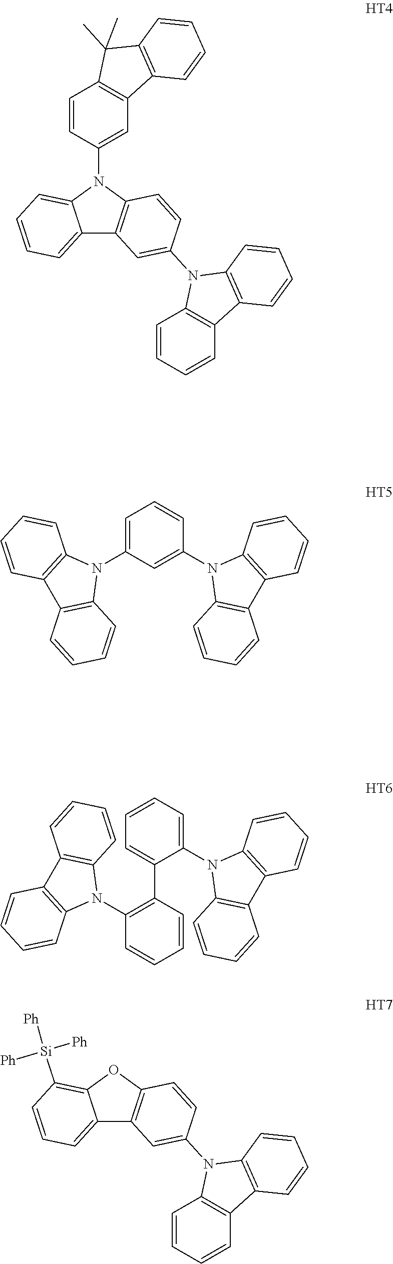 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

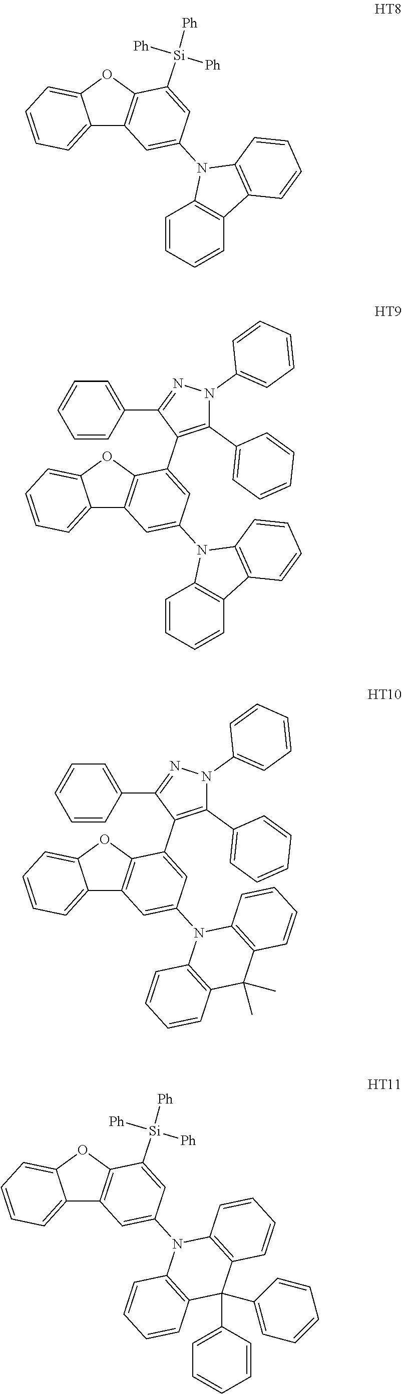 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

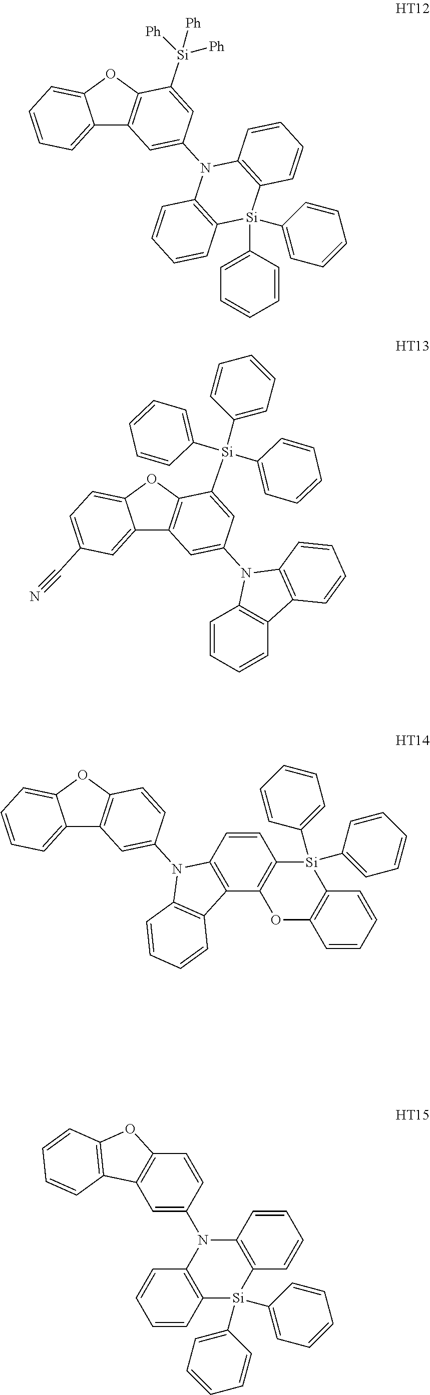

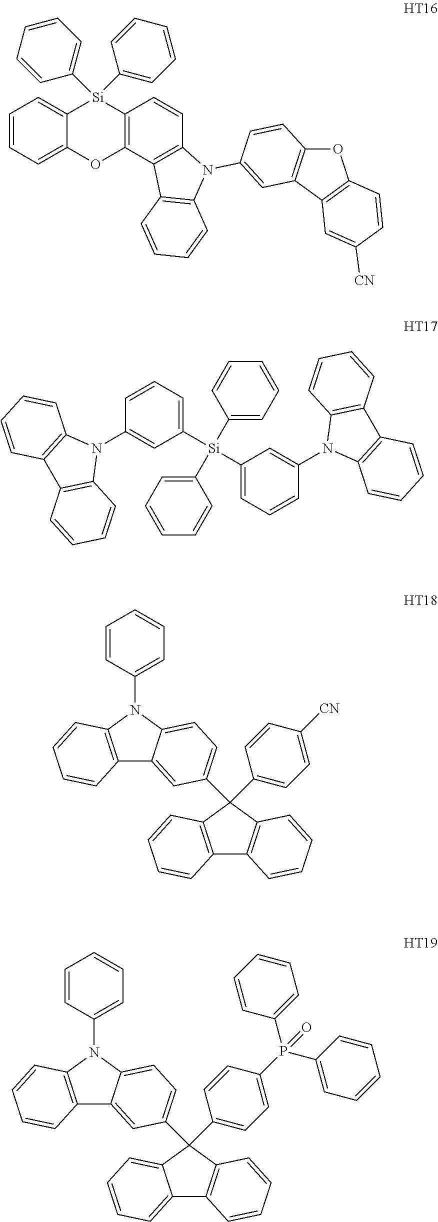 [SMILES: N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1]

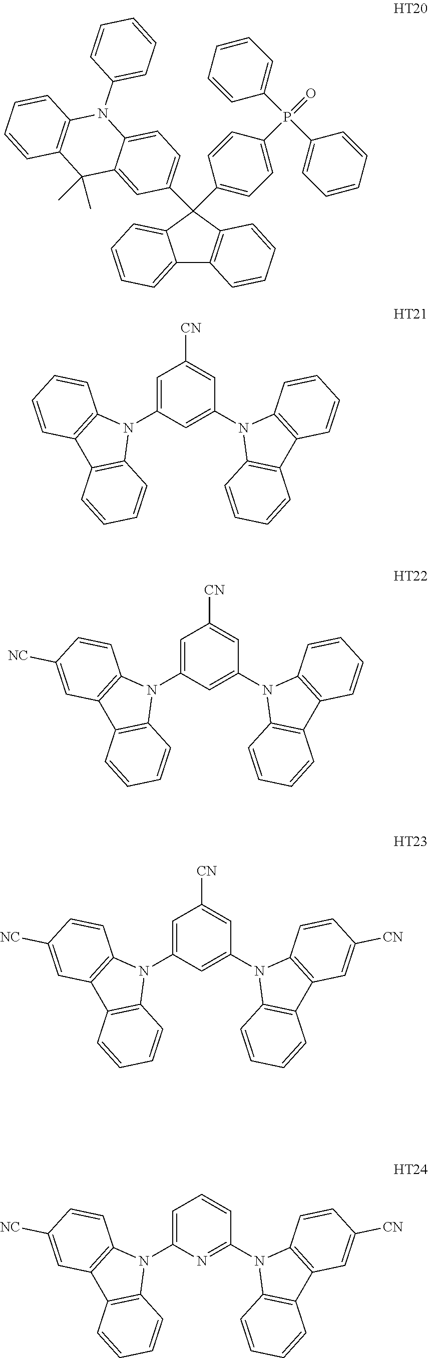 [SMILES: CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

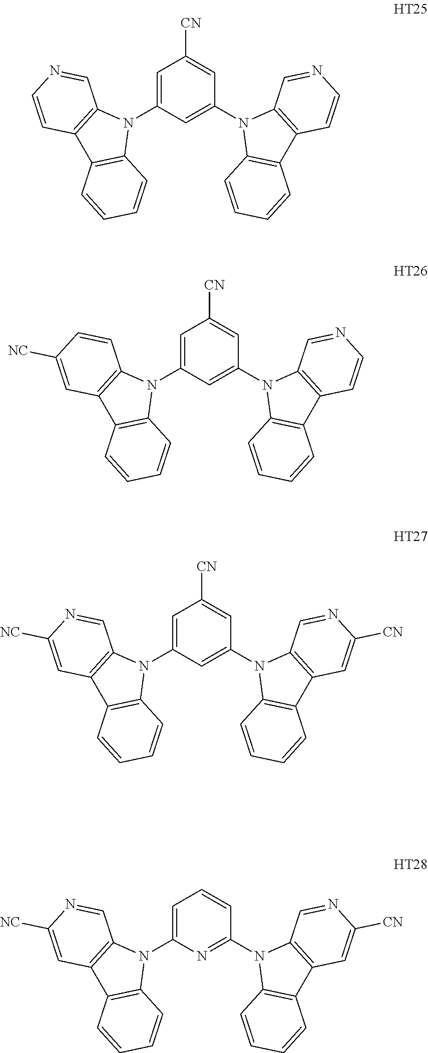 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

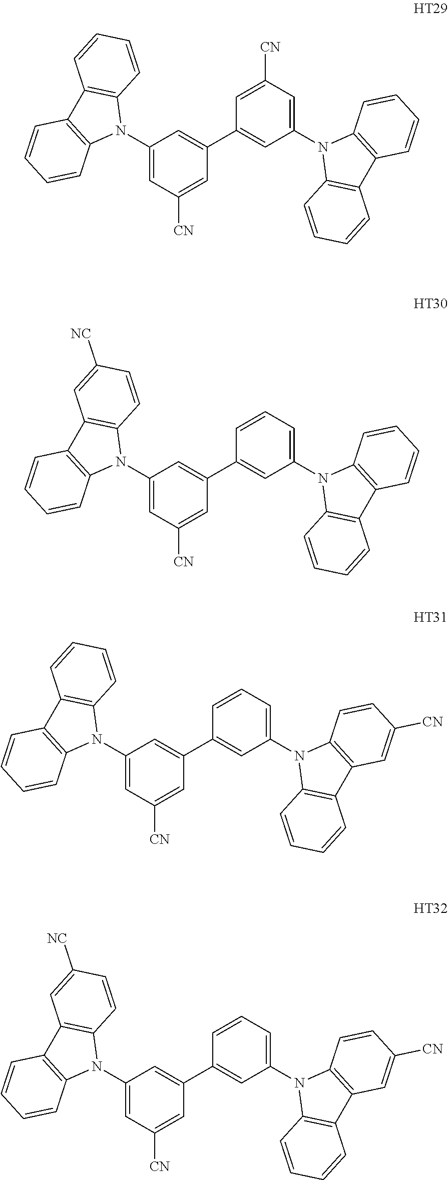 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

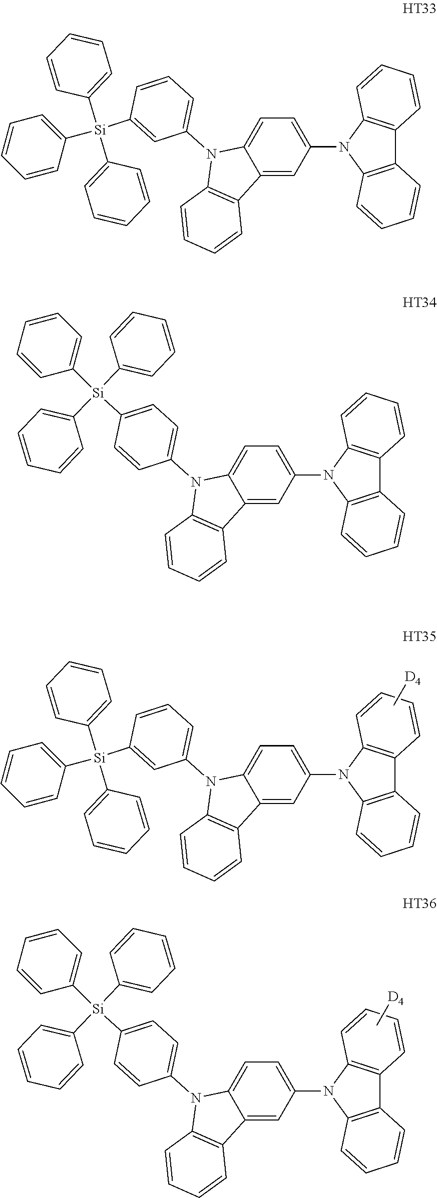

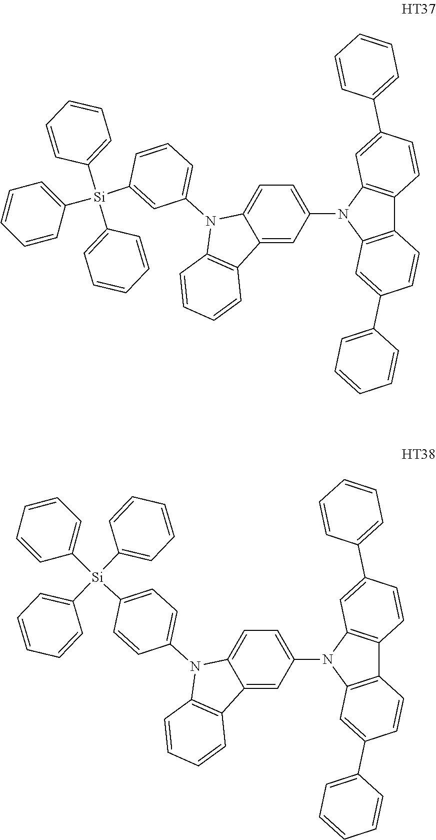 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1]

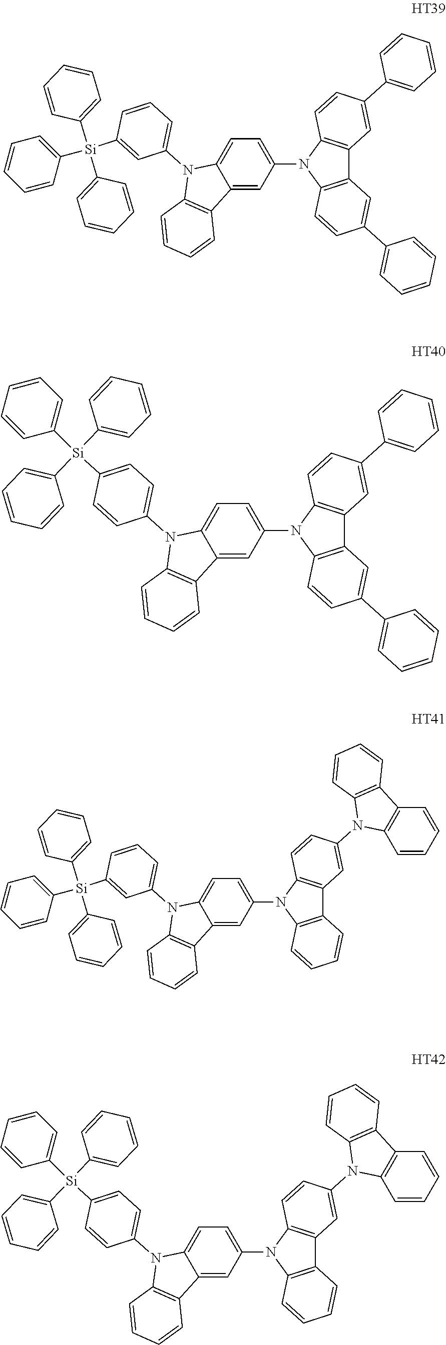 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

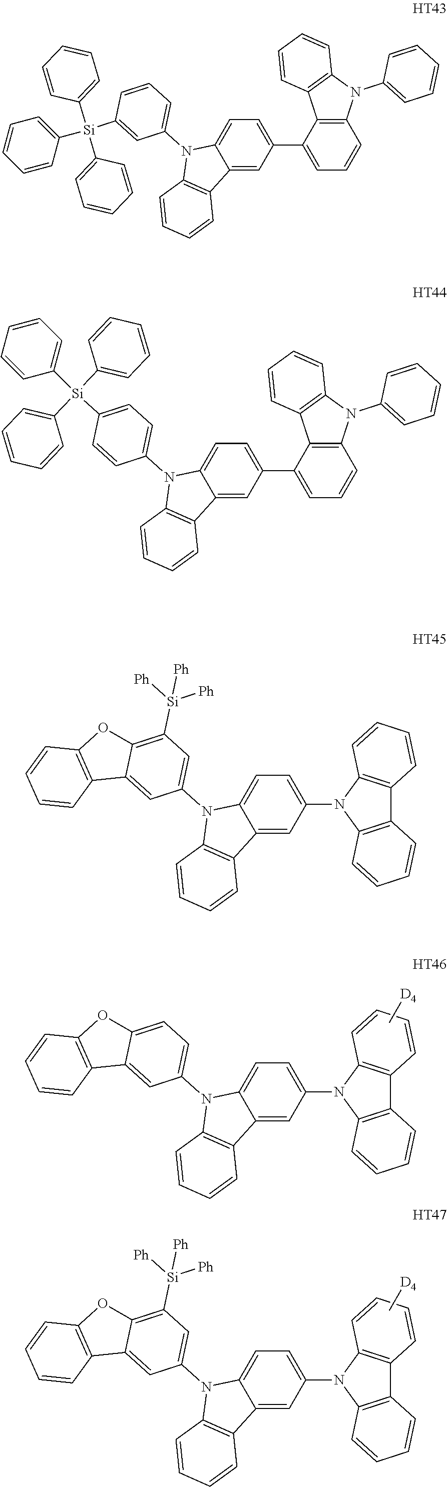

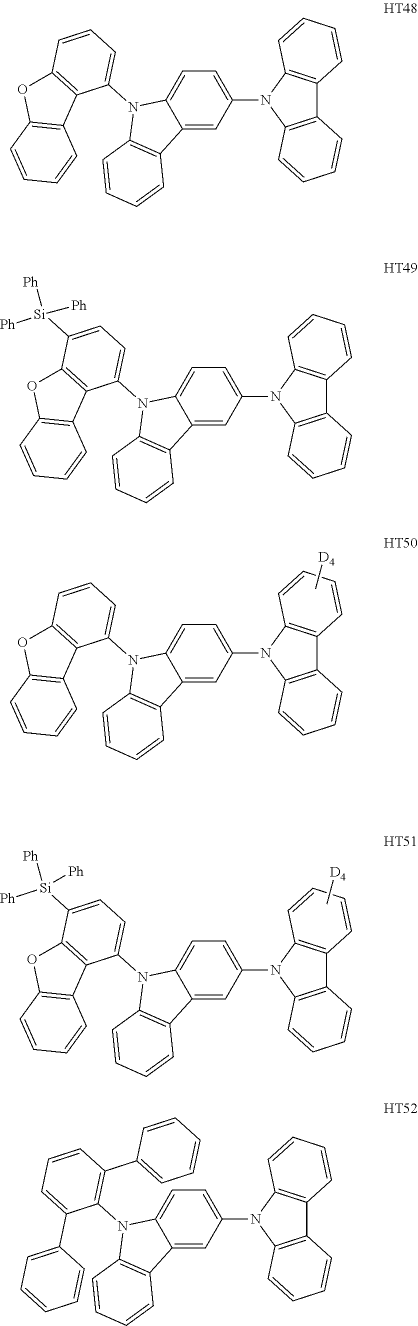

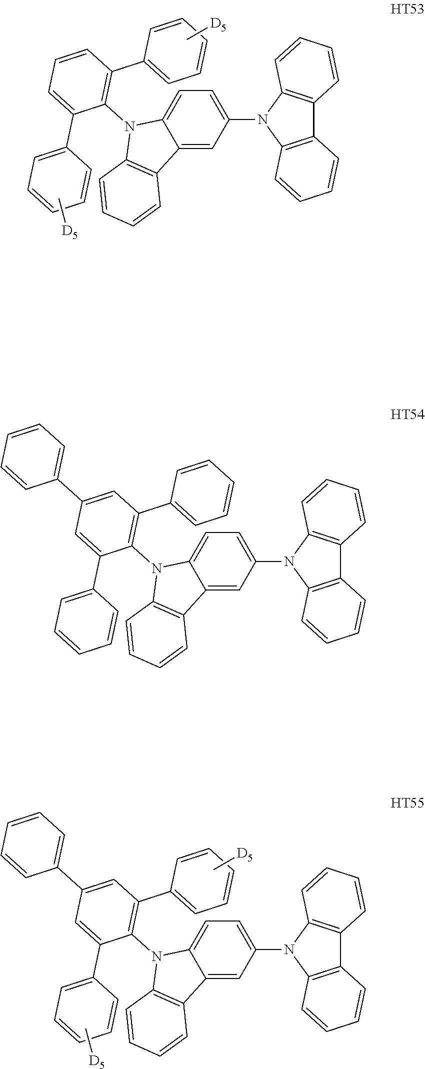

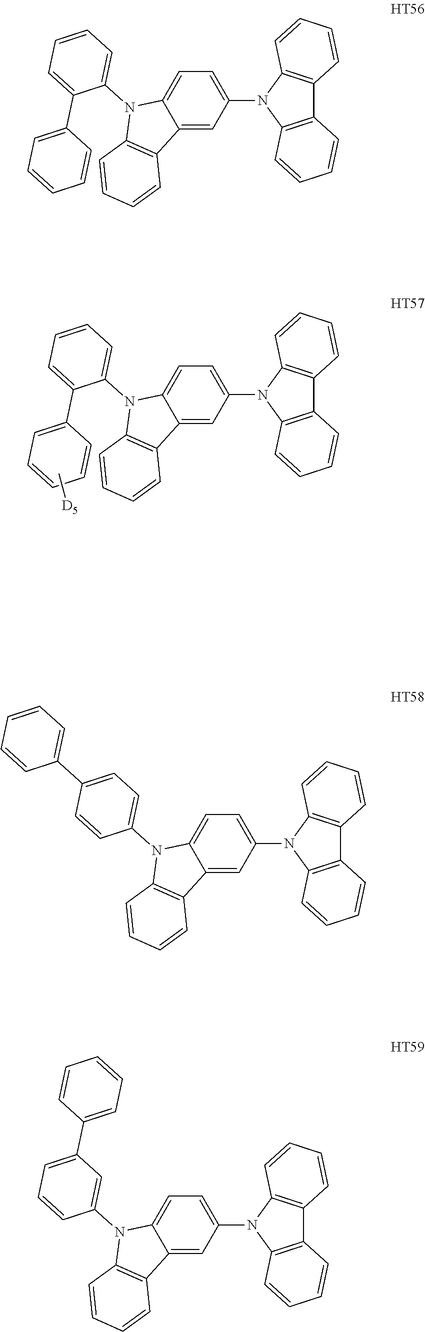

In the compounds suggested in Compound Group 2, “D” refers to a deuterium atom, and “Ph” may refer to a substituted or unsubstituted phenyl group. For example, in the compounds suggested in Compound Group 2, “Ph” may be an unsubstituted phenyl group.

In one or more embodiments, the emission layer EML may include a third compound represented by Formula ET-1. For example, the third compound may be utilized as an electron transport host material in the emission layer EML.

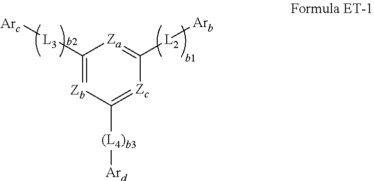

In Formula ET-1, at least one selected from among Xₐ to X_{c} may be N, and the remainder may be CR₅₆. For example, at least one selected from among Xₐ to X_{c} may be N, and the remaining two selected from among Xₐ to X_{c} may may each independently be CR₅₆. In this case, the third compound represented by Formula ET-1 may include a pyridine moiety. In one or more embodiments, at least two selected from among Xₐ to X_{c} may be N, and the remaining one selected from among Xₐ to X_{c} may be CR₅₆. In this case, the third compound represented by Formula ET-1 may include a pyrimidine moiety. In one or more embodiments, Xₐ to X_{c} may be all N. In this case, the third compound represented by Formula ET-1 may include a triazine moiety.

In Formula ET-1, R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1 to b3 may each independently be an integer of 0 to 10.

In Formula ET-1, Ar_{b} to Ar_{d} may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Ar₂ to Ar₄ may be substituted or unsubstituted phenyl groups or substituted or unsubstituted carbazole groups.

In Formula ET-1, L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms.

In one or more embodiments, when each of b1 to b3 is an integer of 2 or more, L₂ to L₄ may each independently be a substituted or unsubstituted arylene group of 6 to 30 ring-forming carbon atoms, or a substituted or unsubstituted heteroarylene group of 2 to 30 ring-forming carbon atoms.

In one or more embodiments, the third compound may be represented by any (e.g., at least) one selected from among the compounds in Compound Group 3.

The light emitting element ED of one or more embodiments may include at least one (e.g., one or more) selected from among the compounds in Compound Group 3.

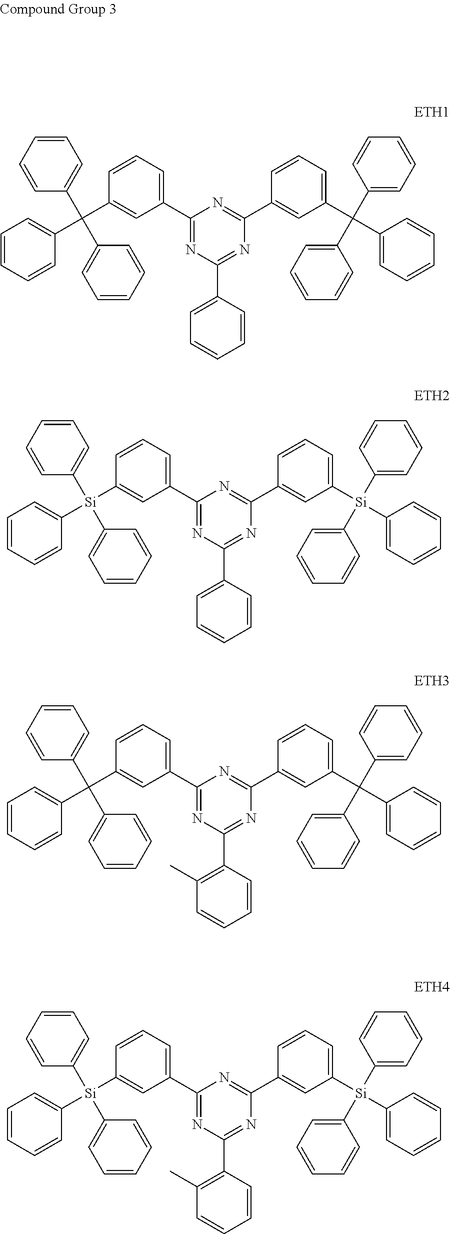 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

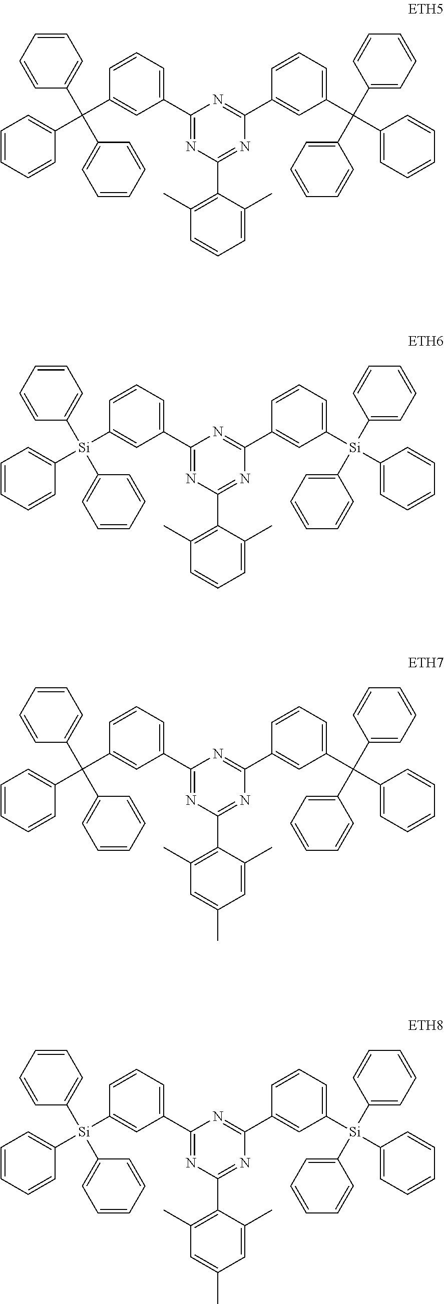 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

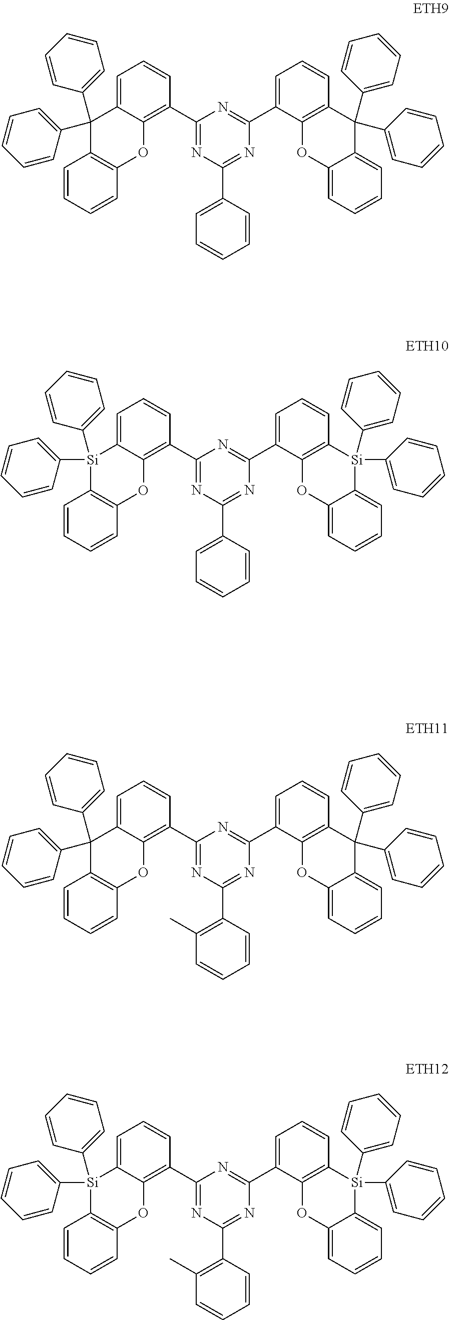 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

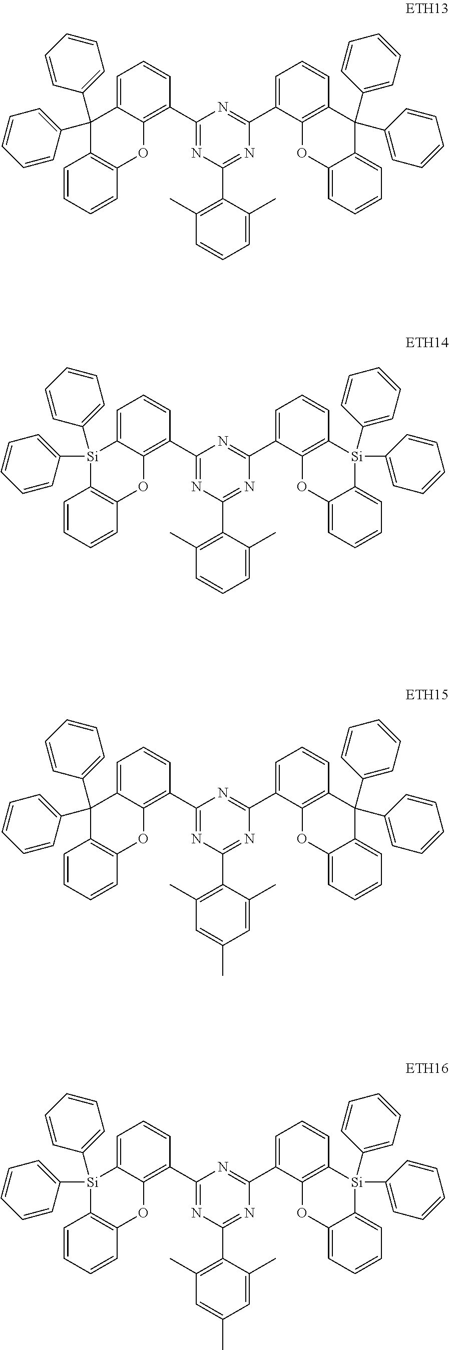 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

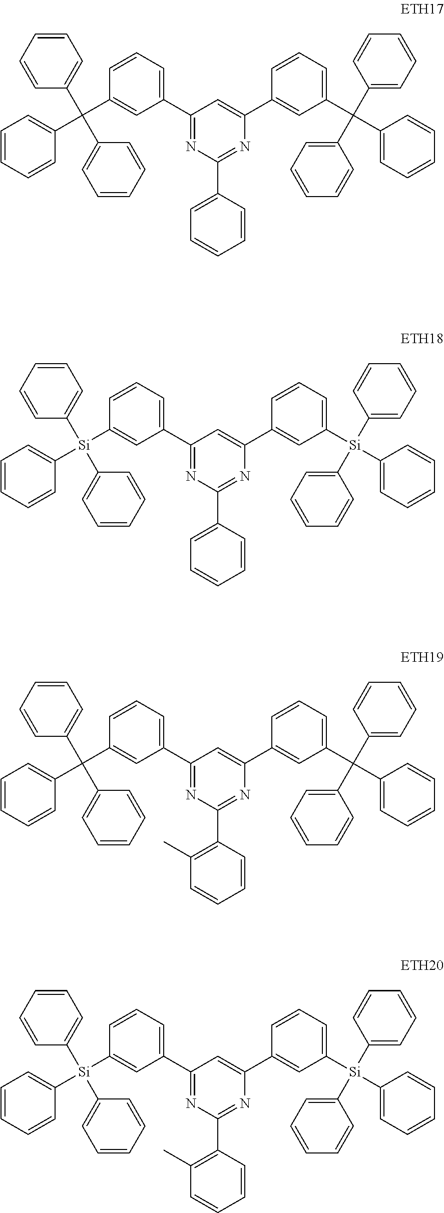 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

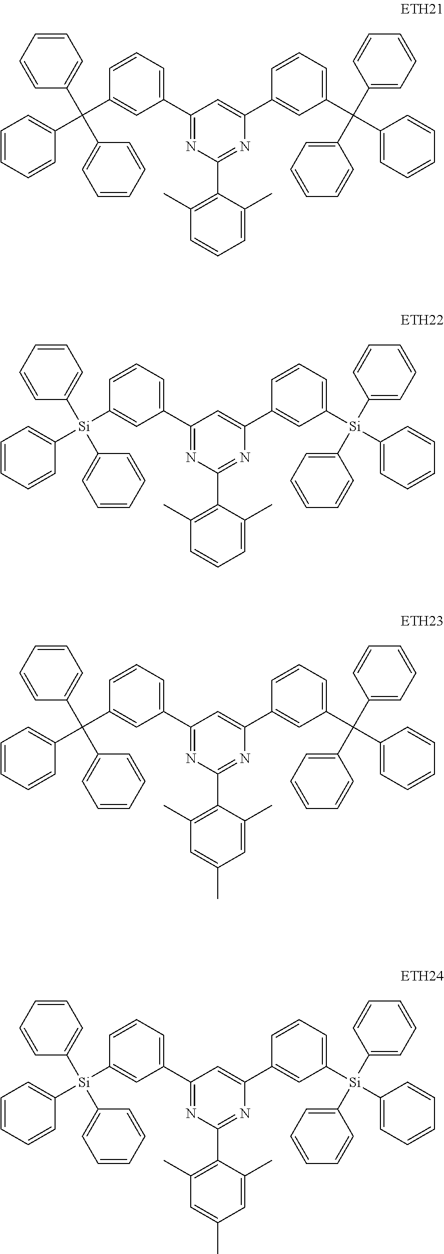 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

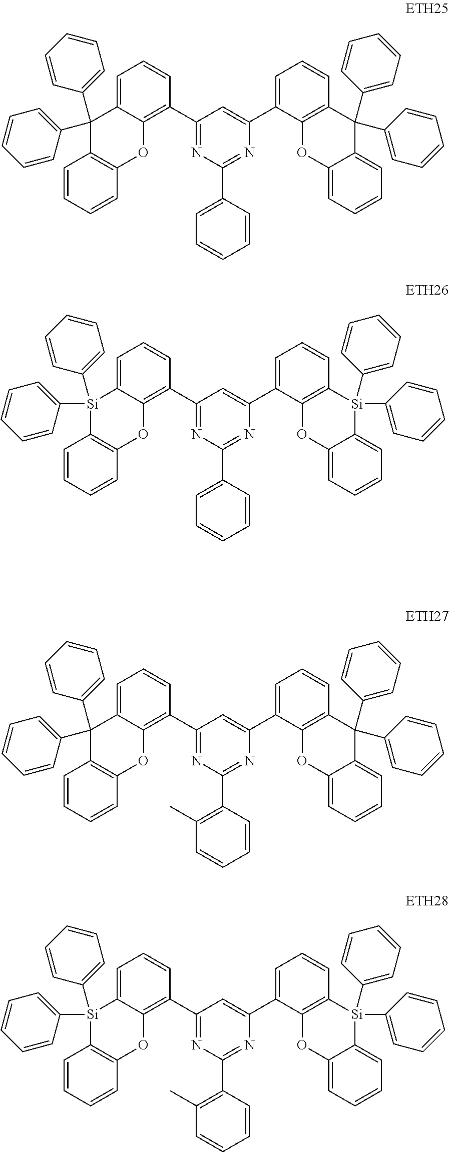 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

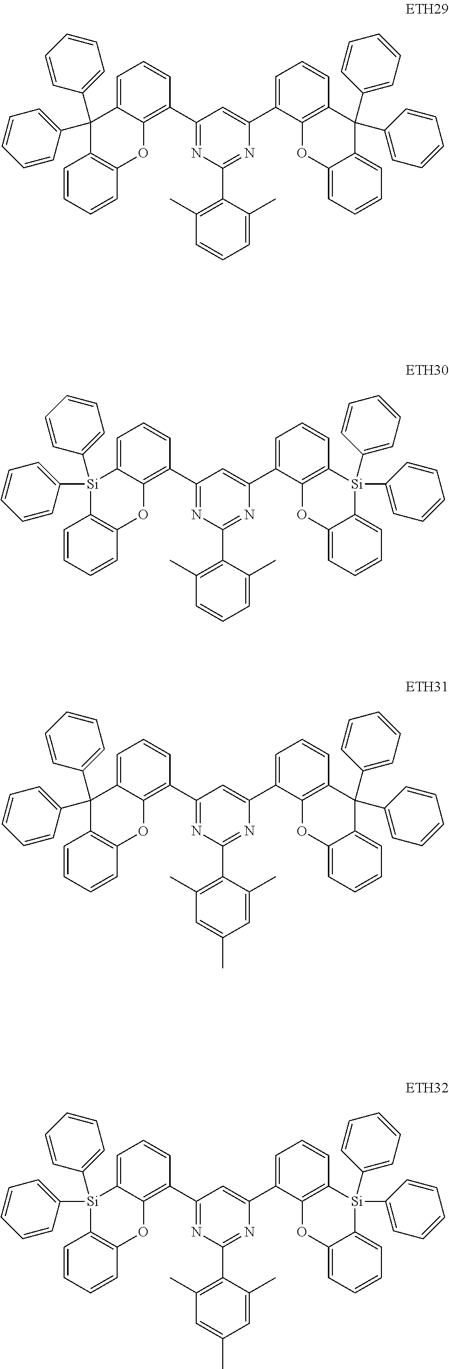 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

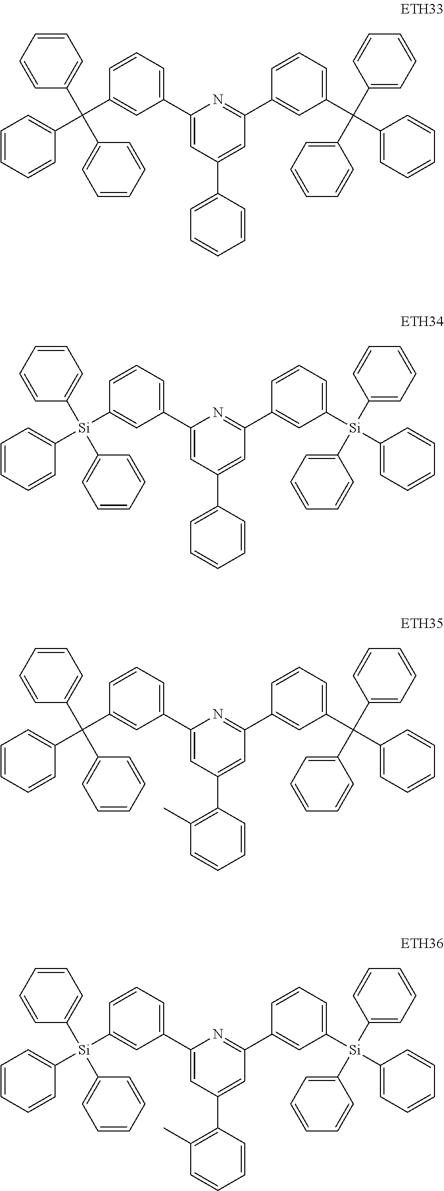 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

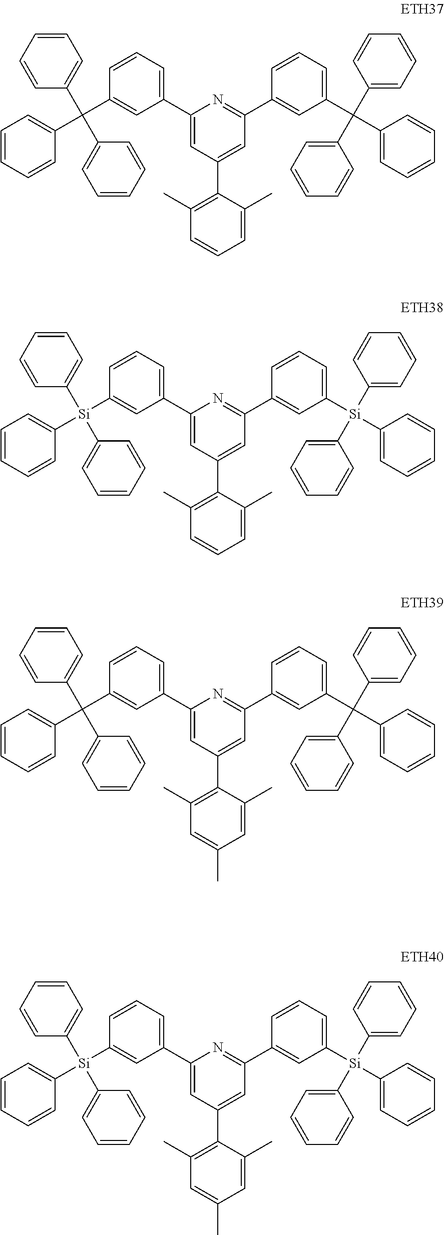 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

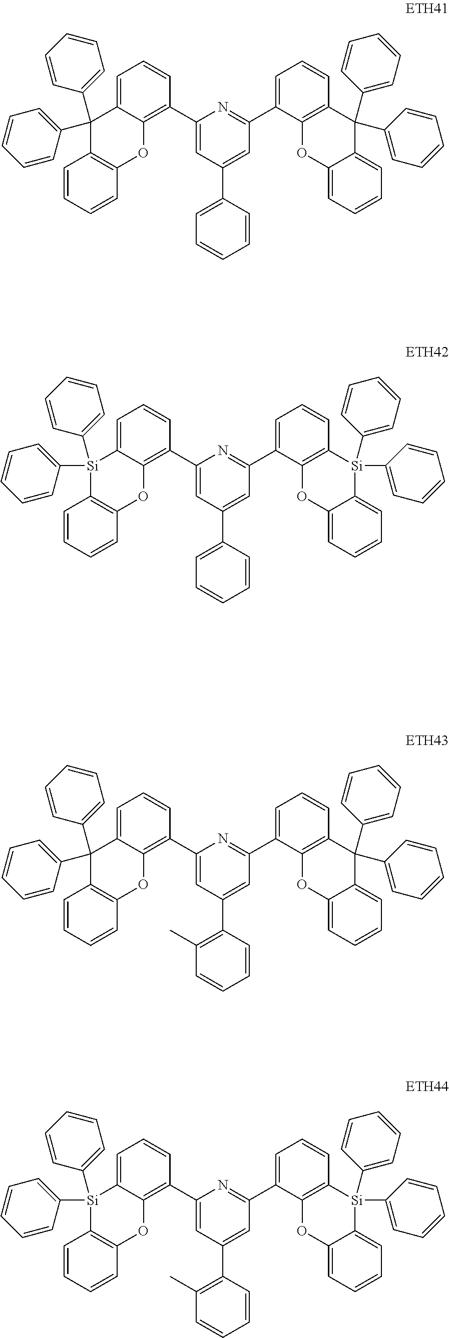 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

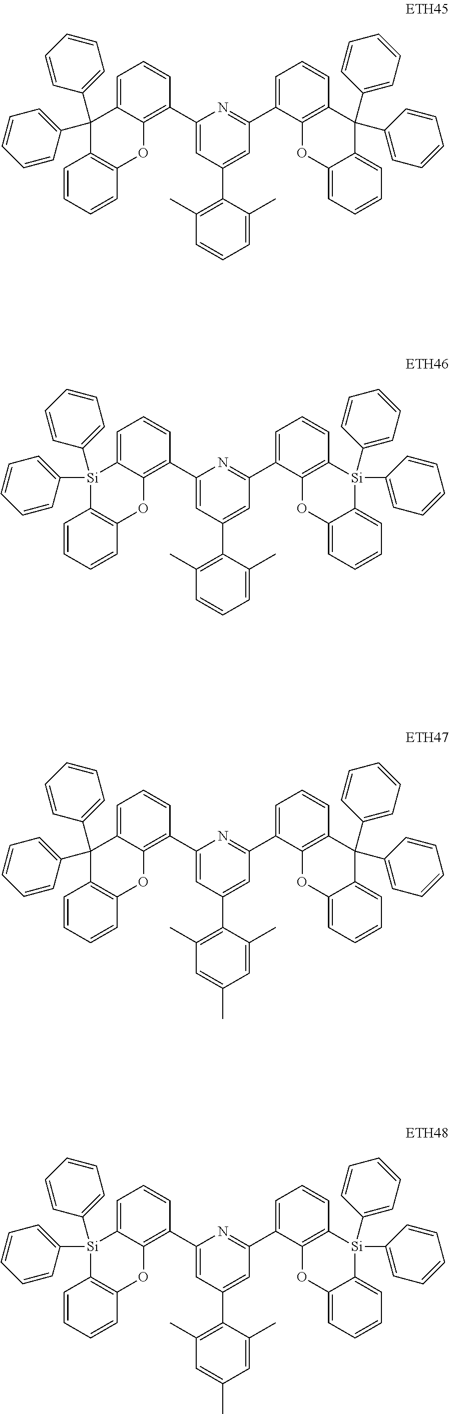 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

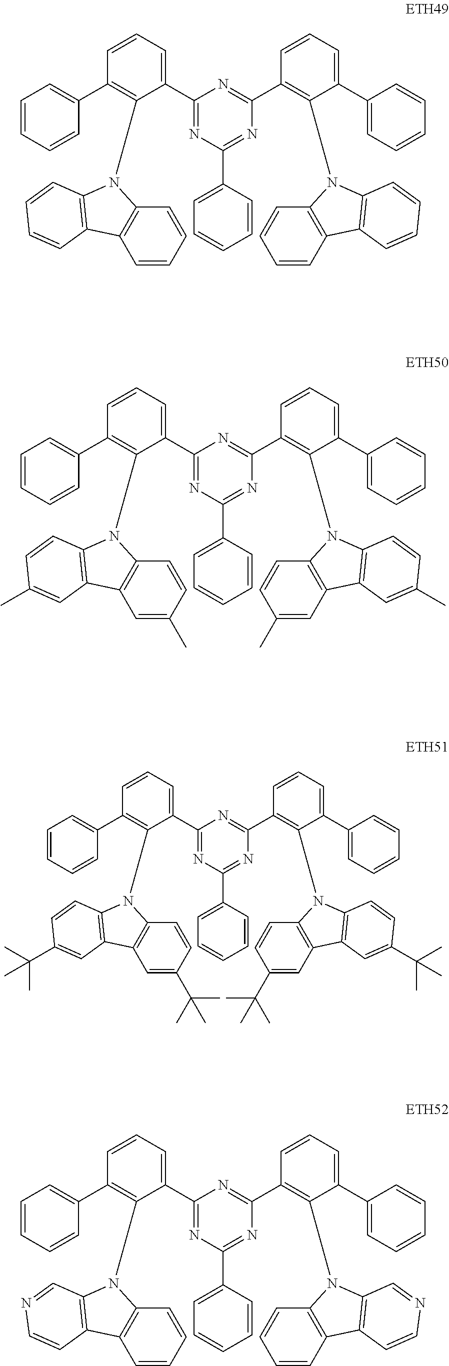

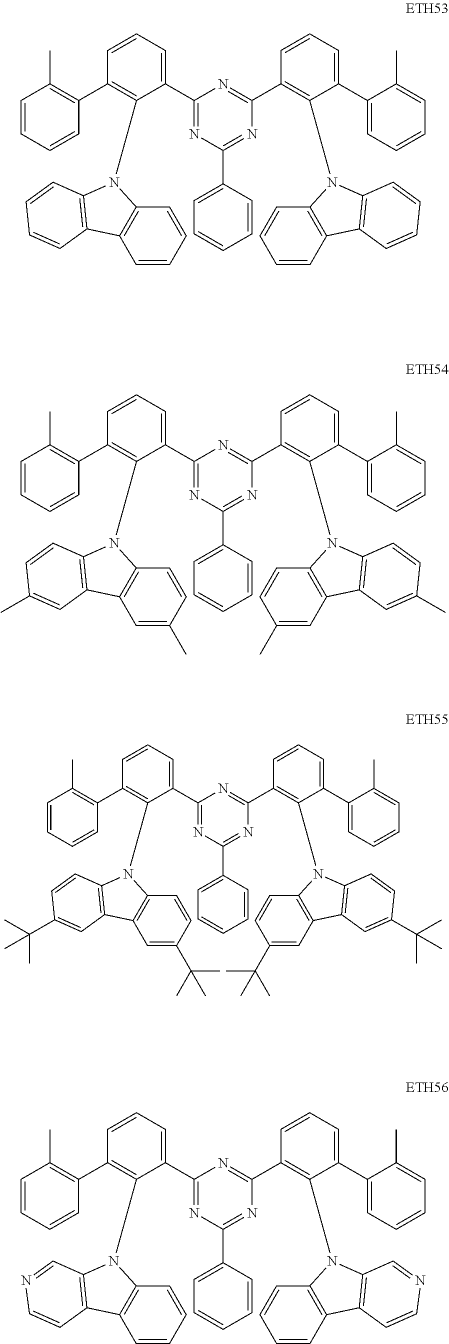

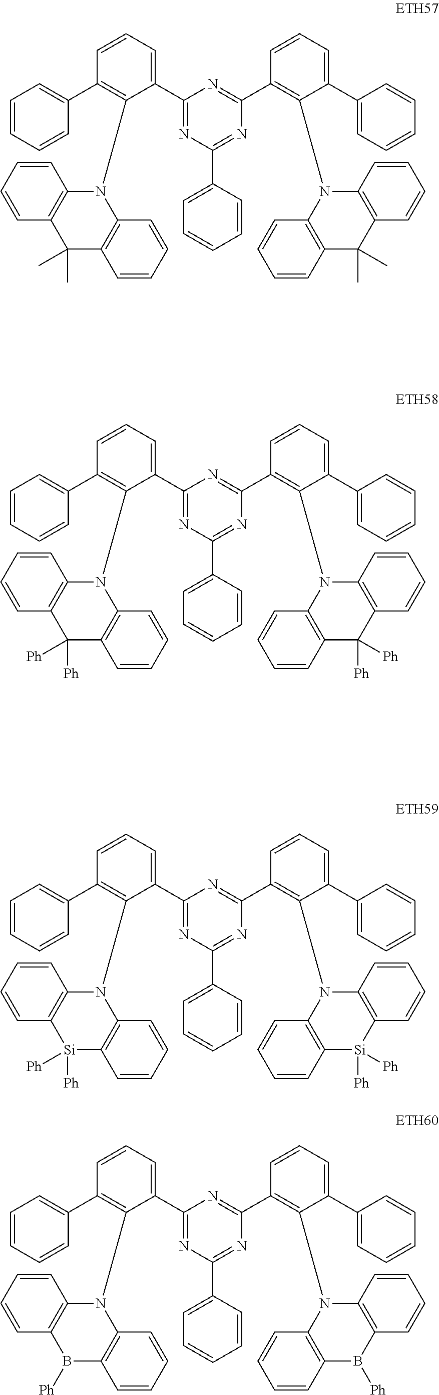

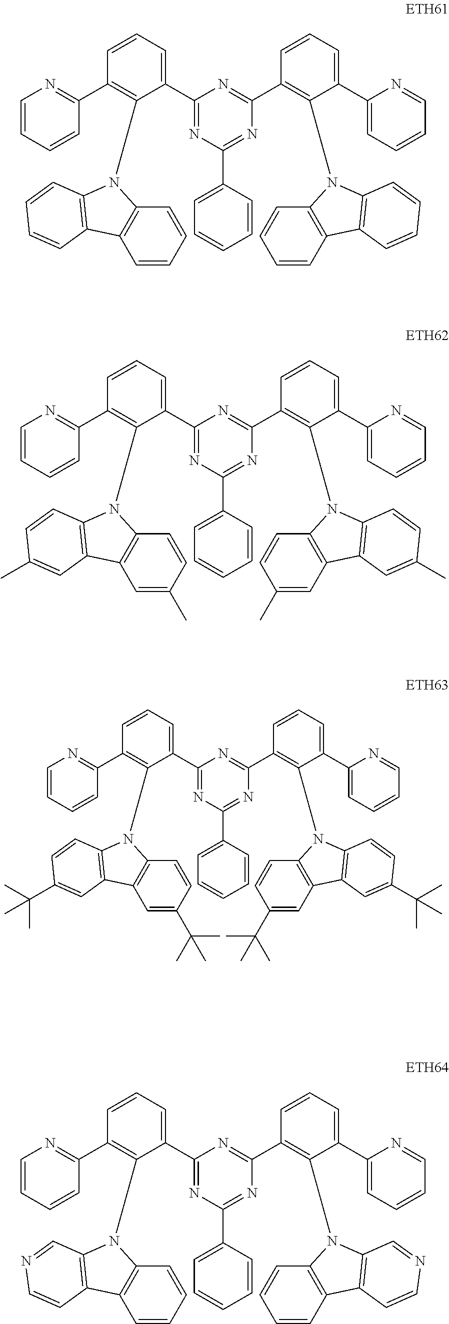

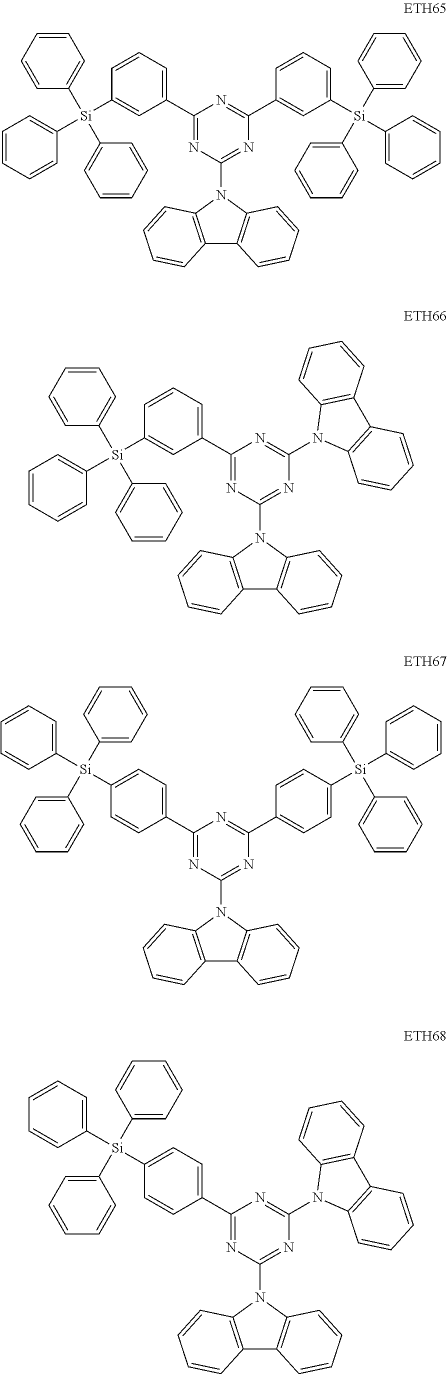 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

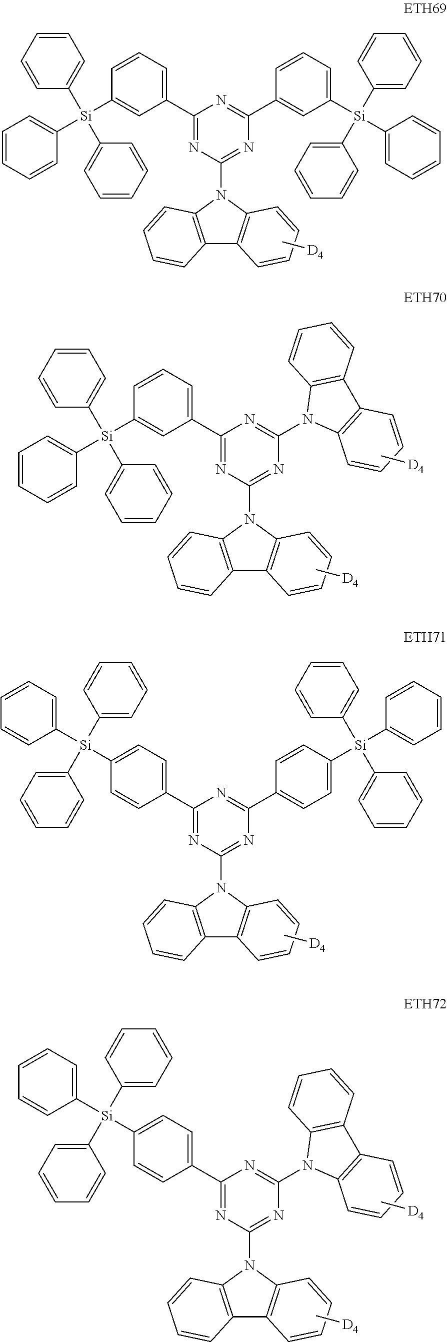

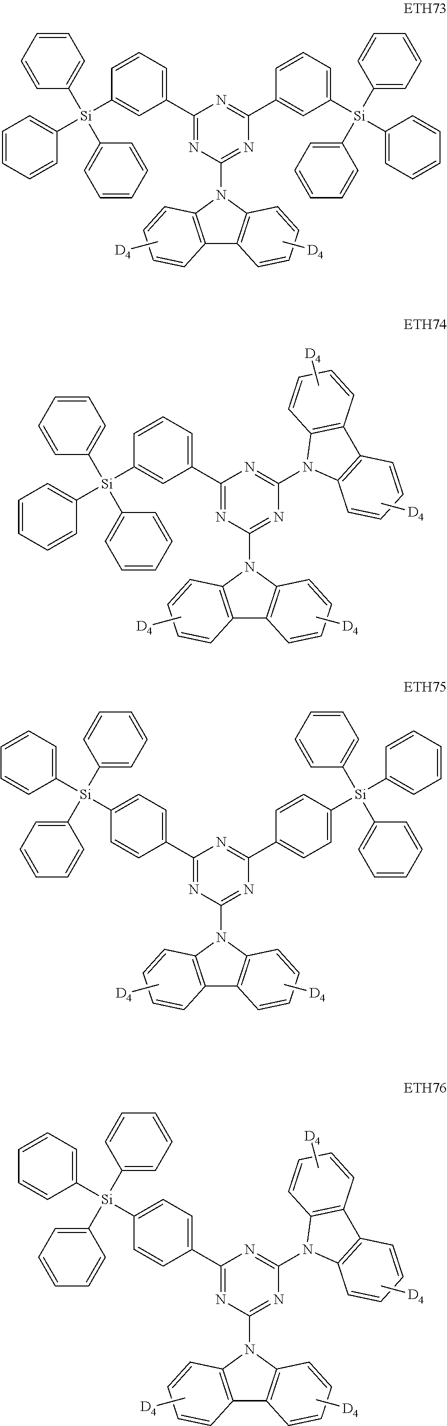

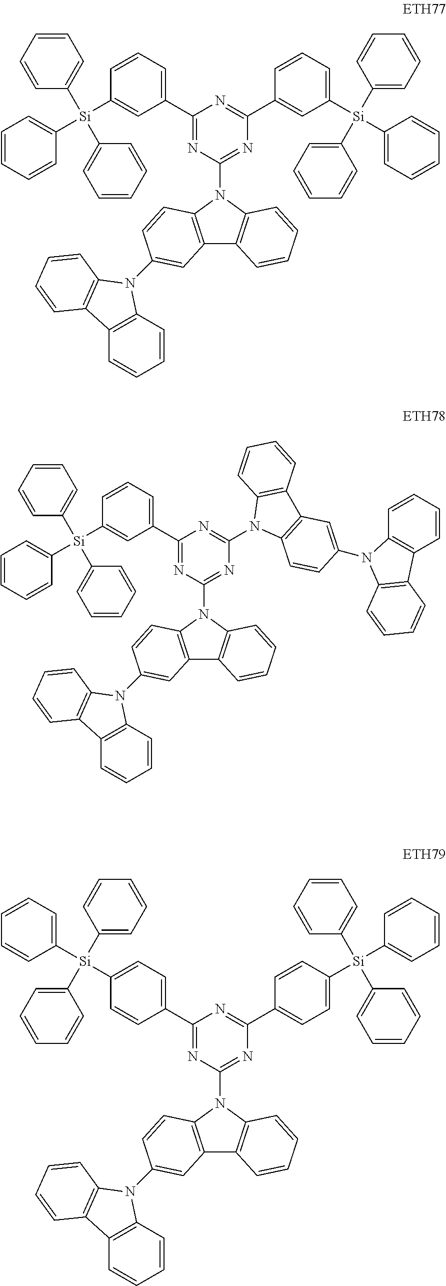 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

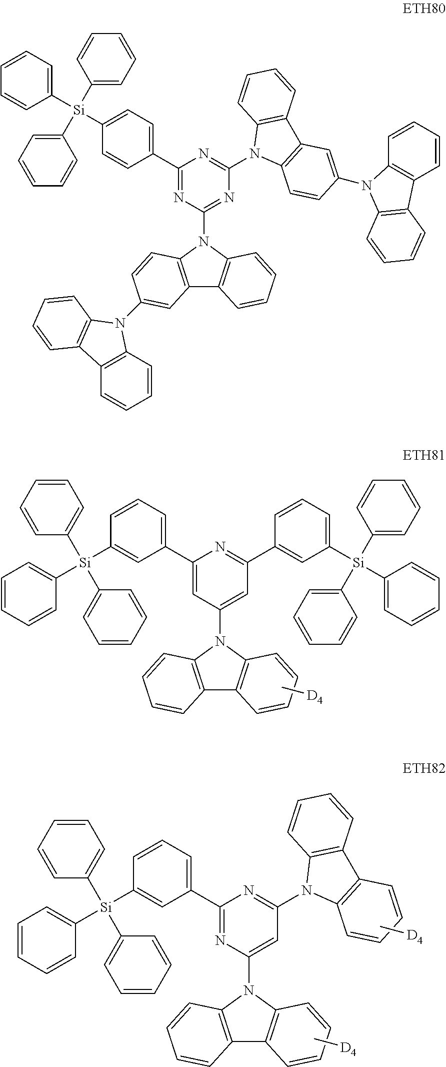

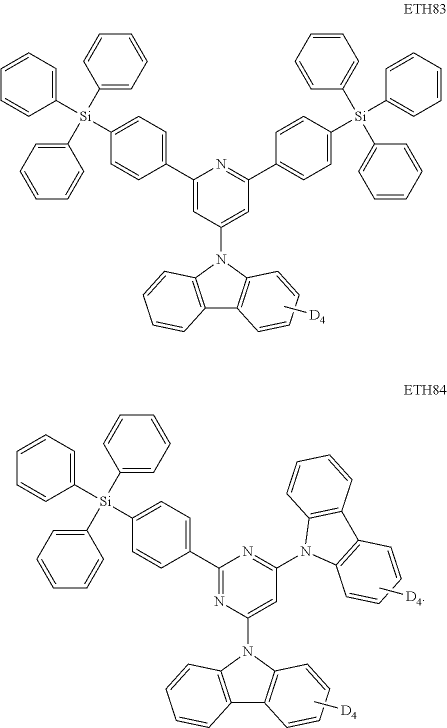

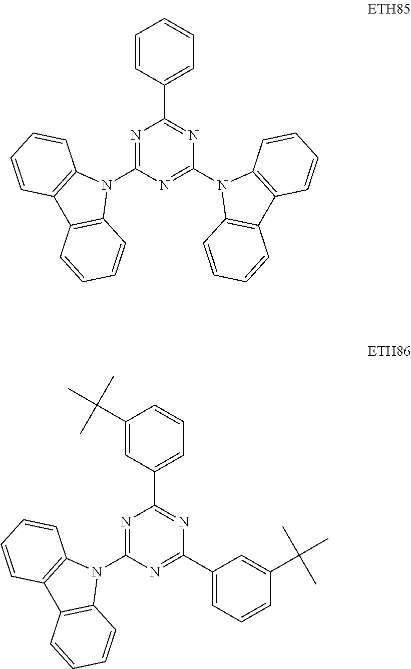 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In the compounds suggested in Compound Group 3, “D” refers to a deuterium atom, and “Ph” refers to an unsubstituted phenyl group.

The emission layer EML may include the second compound and the third compound, and the second compound and the third compound may form exciplex. In the emission layer EML, exciplex may be formed by a hole transport host and an electron transport host. In this case, the triplet energy of the exciplex formed by the hole transport host and the electron transport host may correspond to a difference between the lowest unoccupied molecular orbital (LUMO) energy level of the electron transport host and the highest occupied molecular orbital (HOMO) energy level of the hole transport host.

For example, the absolute value of the triplet energy level (T1) of the exciplex formed by the hole transport host and the electron transport host may be about 2.4 electron volt (eV) to about 3.0 eV. In one or more embodiments, the triplet energy of the exciplex may be a smaller value than the energy gap of each host material. The exciplex may have a triplet energy of about 3.0 eV or less, that is the energy gap between the hole transport host and the electron transport host.

In one or more embodiments, the emission layer EML may include a fourth compound in addition to the first compound to the third compound. The fourth compound may be utilized as a phosphorescence sensitizer of an emission layer EML. Because energy may transfer from the fourth compound to the first compound, light emission may arise.

For example, the emission layer EML may include an organometallic complex including platinum (Pt) as a central metal atom and ligands bonded to the central metal atom, as the fourth compound. In the light emitting element ED of one or more embodiments, the emission layer EML may include a compound represented by Formula D-1 as the fourth compound.

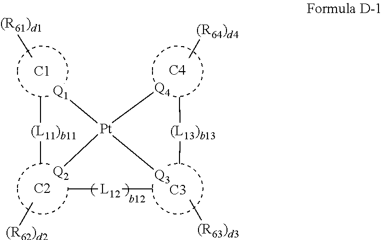

In Formula D-1, Q₁ to Q₄ may each independently be C or N.

In Formula D-1, 01 to Q₄ may each independently be a substituted or unsubstituted hydrocarbon ring of 5 to 30 ring-forming carbon atoms, or a substituted or unsubstituted heterocycle of 2 to 30 ring-forming carbon atoms.

In Formula D-1, L₁ to L₁₃ may each independently be a direct linkage,

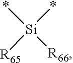

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃, “ ” refers to a part connected with C1 to C4.

In Formula D-1, b11 to b13 may each independently be 0 or 1. When b11 is 0, C1 and C2 may be unconnected. When b12 is 0, C2 and C3 may be unconnected. When b3 is 0, C3 and C4 may be unconnected.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. In one or more embodiments, each of R₆₁ to R₆₆ may be combined with an adjacent group to form a ring. R₆₁ to R₆₆ may each independently be a substituted or unsubstituted methyl group, or a substituted or unsubstituted t-butyl group.

In Formula D-1, d1 to d4 may each independently be an integer of 0 to 4. In Formula D-1, when d1 to d4 are 0, the fourth compound may be unsubstituted with R₆₁ to R₆₄, respectively. A case where d1 to d4 are 4, and R₆₁ to R₆₄ are hydrogen atoms, may be the same as a case where d1 to d4 are 0. When d1 to d4 are integers of 2 or more, each of multiple R₆₁ to R₆₄ may be all the same, or at least one among multiple R₆₁ to R₆₄ may be different.

In Formula D-1, C1 to C4 may each independently be a substituted or unsubstituted hydrocarbon ring or a substituted or unsubstituted heterocycle, represented by any (e.g., at least) one selected from among C-1 to C-4.

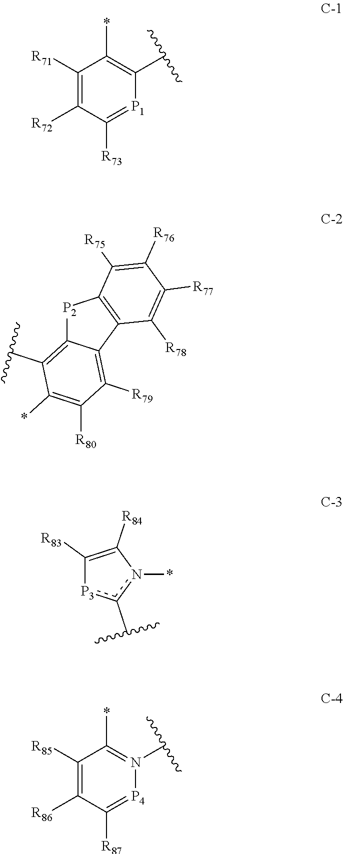

In C-1 to C-4, P₁ may be or CR₇₄, P₂ may be or NR₈₁, P₃ may be or NR₈₂, and P₄ may be or CR₆₈. R₇₁ to R₈₈ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In one or more embodiments, in C-1 to C-4, “ ” is a part connected with a central metal atom of Pt, and “ ” corresponds to a part connected with an adjacent ring group (C1 to C4) or linker (L₁₁ to L₁₃).

The emission layer EML of one or more embodiments may include the first compound that is a fused polycyclic compound, and at least one among the second to fourth compounds. For example, the emission layer EML may include the first compound, the second compound and the third compound. In the emission layer EML, the second compound and the third compound may form exciplex, and in the exciplex, energy transfer to the first compound may arise, and light emission may arise.

In one or more embodiments, the emission layer EML may include the first compound, the second compound, the third compound and the fourth compound. In the emission layer EML, the second compound and the third compound may form exciplex, and in the exciplex, energy transfer to the fourth compound and the first compound may arise, and light emission may arise. In one or more embodiments, the fourth compound may be a sensitizer. In the light emitting element ED of one or more embodiments, the fourth compound included in the emission layer EML may act as a sensitizer and may play the role of transferring energy from a host to the first compound that is a light-emitting dopant. For example, the fourth compound that plays the role of an auxiliary dopant may accelerate energy transfer to the first compound that is a light emitting dopant and increase the light emitting ratio of the first compound.

Accordingly, the emission efficiency of the emission layer EML of one or more embodiments may be improved. In one or more embodiments, when the energy transfer to the first compound increases, excitons formed in the emission layer EML may not be accumulated but rapidly emit light, and the deterioration of a device may be reduced. Accordingly, the lifetime of the light emitting element ED of one or more embodiments may increase.

The light emitting element ED of one or more embodiments includes all of the first compound, the second compound, the third compound and the fourth compound, and the emission layer EML may include the combination of two host materials and two dopant materials. In the light emitting element ED of one or more embodiments, the emission layer EML may include the second compound and the third compound, which are two different hosts, the first compound which emits delayed fluorescence, and the fourth compound including an organometallic complex, concurrently (e.g., simultaneously), and may show excellent or suitable emission efficiency properties.

In one or more embodiments, the fourth compound represented by Formula D-1 may be represented by any one (e.g., at least one) selected from among the compounds represented in Compound Group 4. The emission layer EML may include at least one (e.g., one or more) selected from among the compounds represented in Compound Group 4 as a sensitizer material.

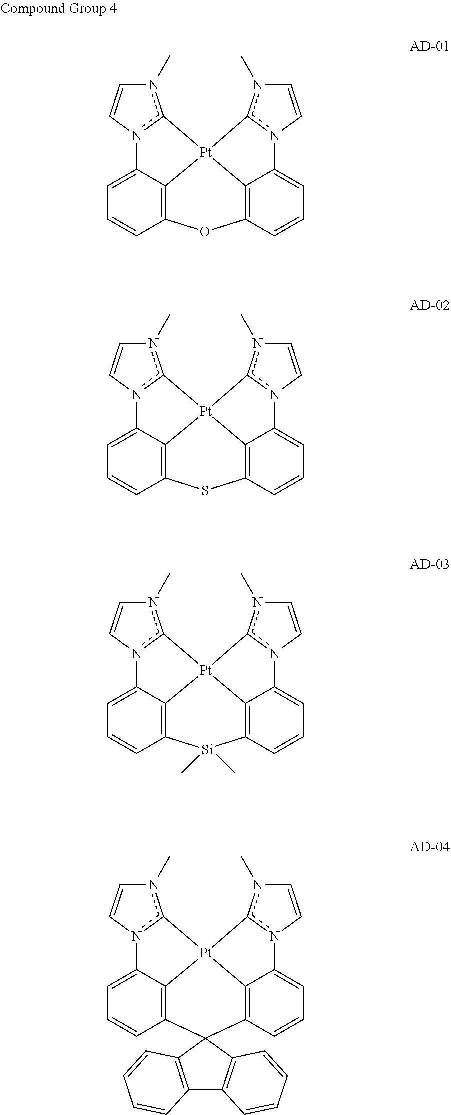

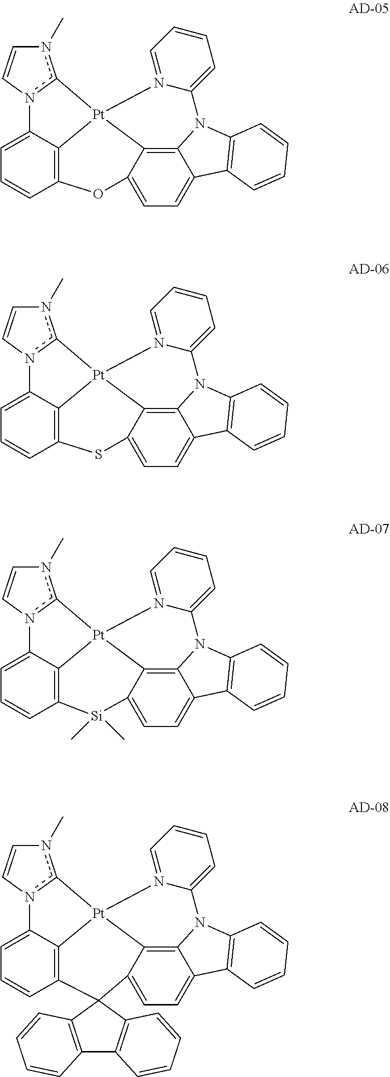

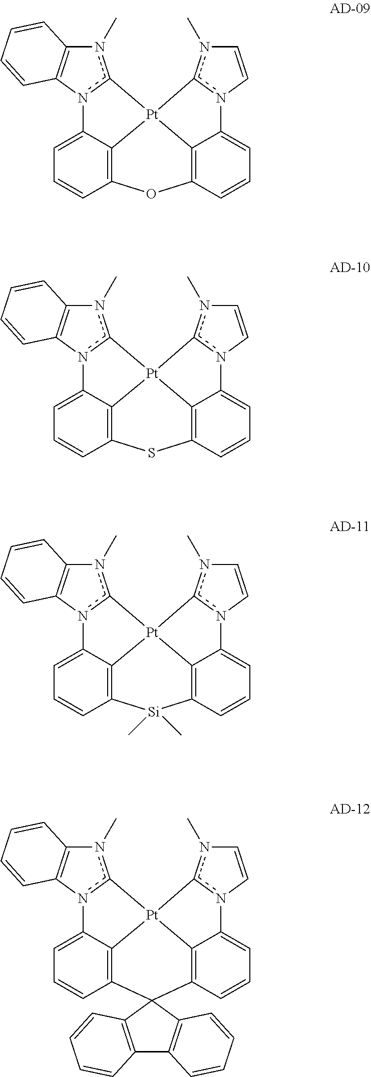

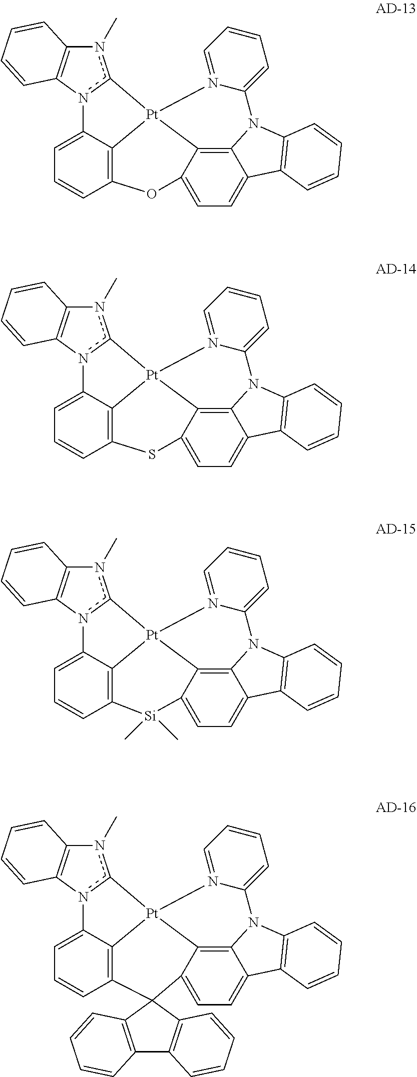

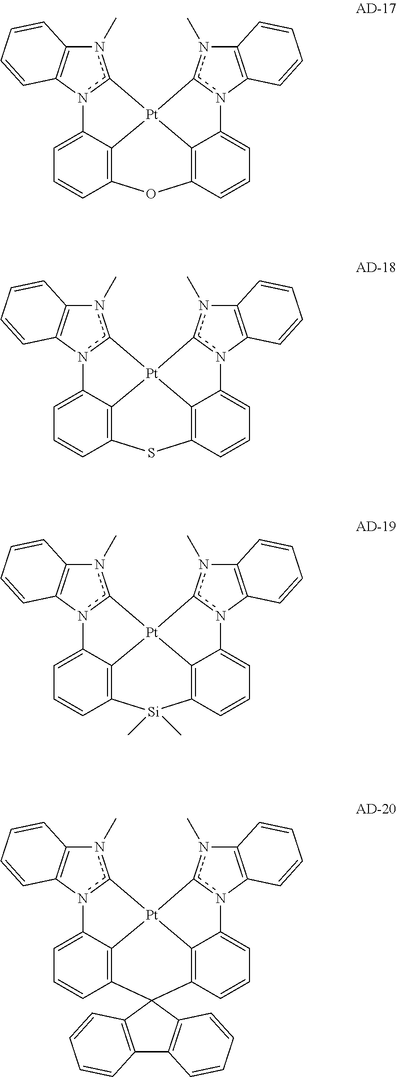

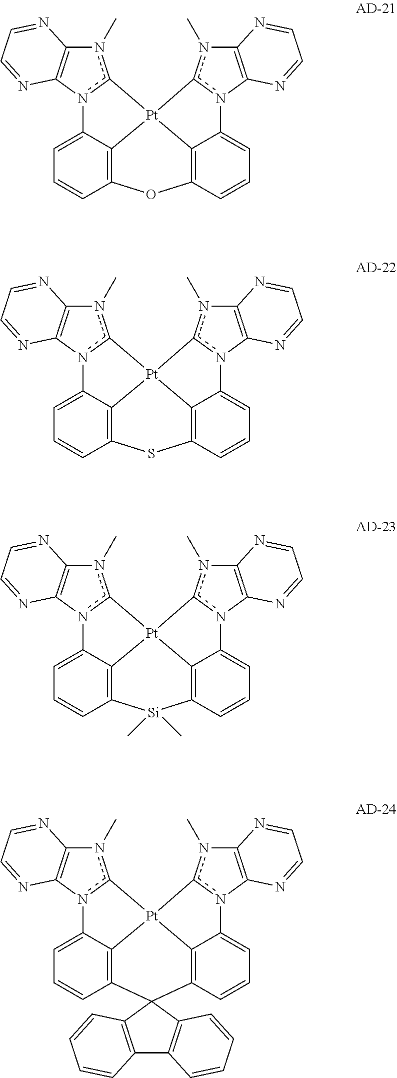

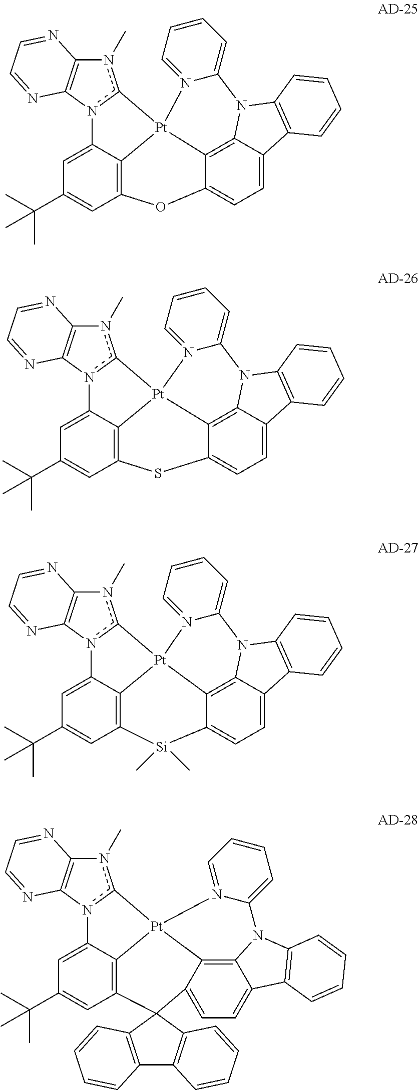

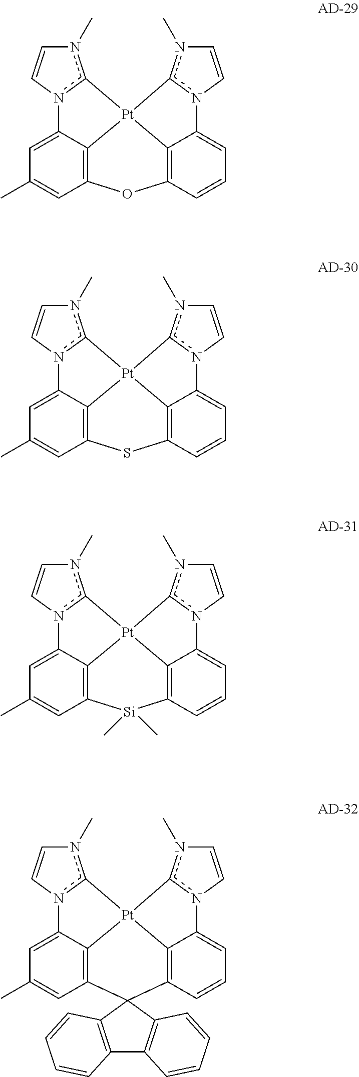

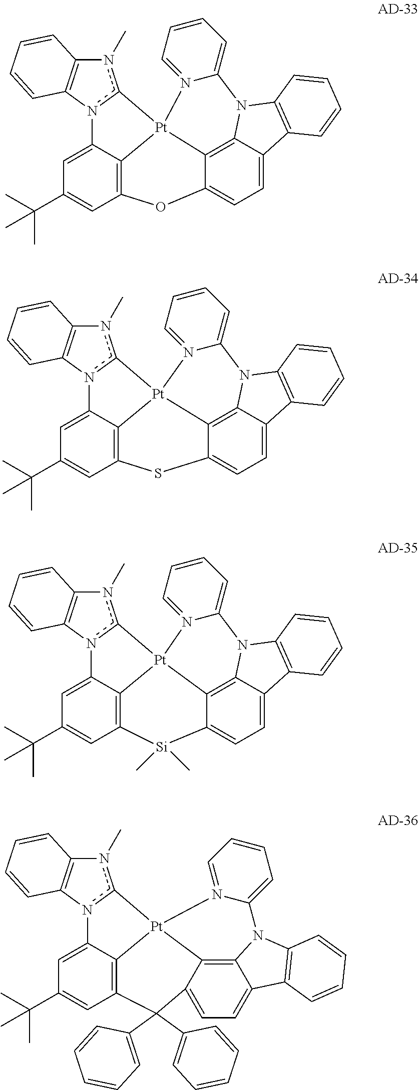

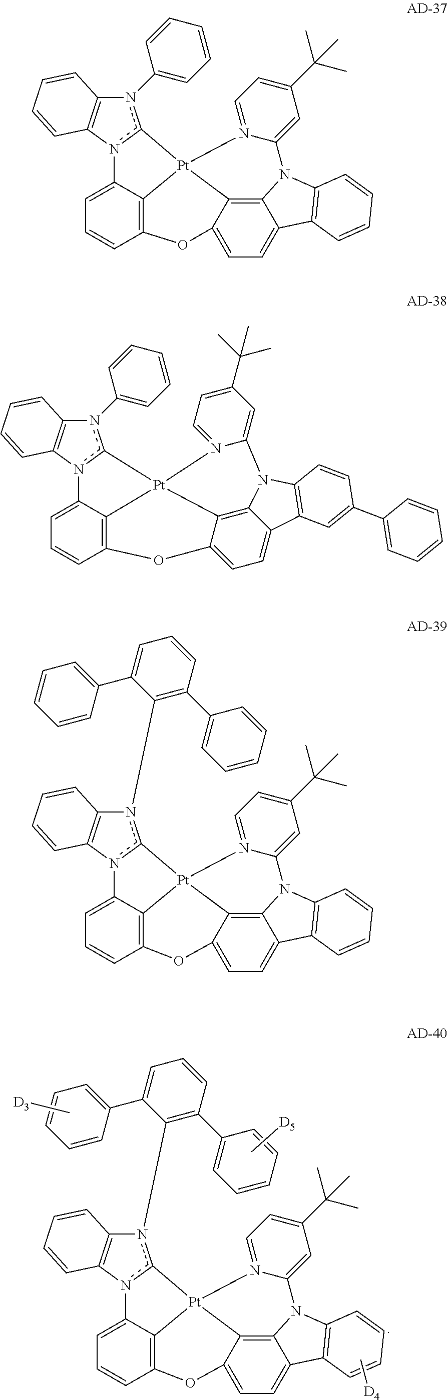

In the compounds suggested in Compound Group 4, “D” refers to a deuterium atom.

In one or more embodiments, the light emitting element ED of one or more embodiments may include multiple emission layers. Multiple emission layers may be stacked in order and provided, and for example, a light emitting element ED including multiple emission layers may be to emit white light. The light emitting element including multiple emission layers may be a light emitting element of a tandem structure. When the light emitting element ED includes multiple emission layers, at least one emission layer EML may include the first compound represented by Formula 1 of one or more embodiments. In one or more embodiments, when the light emitting element ED includes multiple emission layers, at least one emission layer EML may include all of the first compound, the second compound, the third compound, and the fourth compound.

In the light emitting element ED of one or more embodiments, when the emission layer EML includes all of the first compound, the second compound, the third compound, and the fourth compound, the amount of the first compound may be about 0.1 wt % to about 5 wt % based on the total weight of the first compound, the second compound, the third compound, and the fourth compound. However, one or more embodiments of the present disclosure is not limited thereto. When the amount of the first compound satisfies the herein-described ratio, energy transfer from the second compound and the third compound to the first compound may increase, and accordingly, the emission efficiency and device lifetime may increase.

In the emission layer EML, the total amount of the second compound and the third compound may be the remaining amount excluding the amount of the first compound and the fourth compound. For example, the total amount of the second compound and the third compound may be about 65 wt % to about 95 wt % based on the total weight of the first compound, the second compound, the third compound, and the fourth compound.

In the total amount of the second compound and the third compound, the weight ratio of the second compound and the third compound may be about 3:7 to about 7:3.

When the total amount of the second compound and the third compound satisfies the herein-described ratio, charge balance properties in the emission layer EML may be improved, and emission efficiency and device lifetime may be improved. When the total amount of the second compound and the third compound deviates from the herein-described ratio range, charge balance in the emission layer EML may be broken, emission efficiency may be degraded, and the device may be easily deteriorated.

When the emission layer EML includes the fourth compound, the amount of the fourth compound may be about 4 wt % to 30 wt % based on the total weight of the first compound, the second compound, the third compound and the fourth compound in the emission layer EML. However, one or more embodiments of the present disclosure is not limited thereto. When the amount of the fourth compound satisfies the herein-described amount, energy transfer from a host to the first compound that is a light emitting dopant may increase, and emission ratio may be improved. Accordingly, the emission efficiency of the emission layer EML may be improved. When the amount ratio of the first compound, the second compound, the third compound and the fourth compound, included in the emission layer EML satisfies the herein-described amount ratio, excellent or suitable emission efficiency and long lifetime may be achieved.

In the light emitting element ED of one or more embodiments, the emission layer EML may further include anthracene derivatives, pyrene derivatives, fluoranthene derivatives, chrysene derivatives, dihydrobenzanthracene derivatives, or triphenylene derivatives. For example, the emission layer EML may include anthracene derivatives or pyrene derivatives.

In the light emitting element ED of embodiments, shown in FIG. 3 to FIG. 6, the emission layer EML may further include suitable hosts and dopants in addition to the herein-described host and dopant. For example, the emission layer EML may include a compound represented by Formula E-1. The compound represented by Formula E-1 may be utilized as a fluorescence host material.

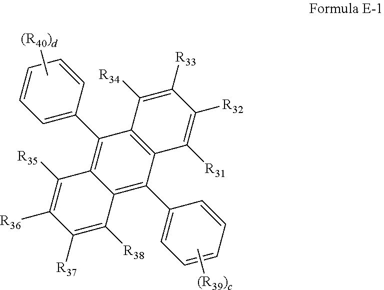

In Formula E-1, R₃₁ to R₄₀ may each independently be a hydrogen atom, a deuterium atom, a halogen atom, a substituted or unsubstituted silyl group, a substituted or unsubstituted thiol group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. In one or more embodiments, R₃₁ to R₄₀ may be combined with an adjacent group to form a saturated hydrocarbon ring, an unsaturated hydrocarbon ring, a saturated heterocycle or an unsaturated heterocycle.

In Formula E-1, “c” and “d” may each independently be an integer of 0 to 5.

Formula E-1 may be represented by any (e.g., at least) one selected from among Compound E1 to Compound E19.

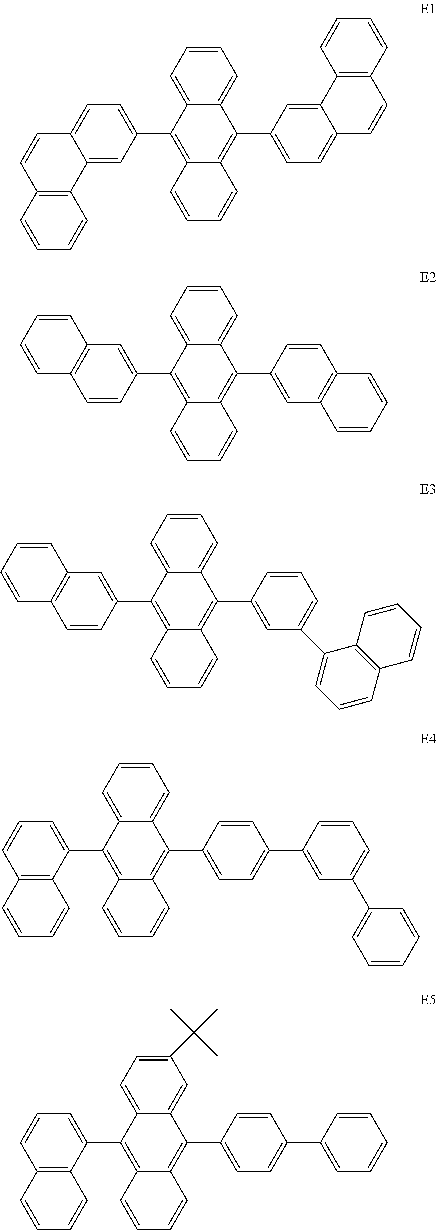

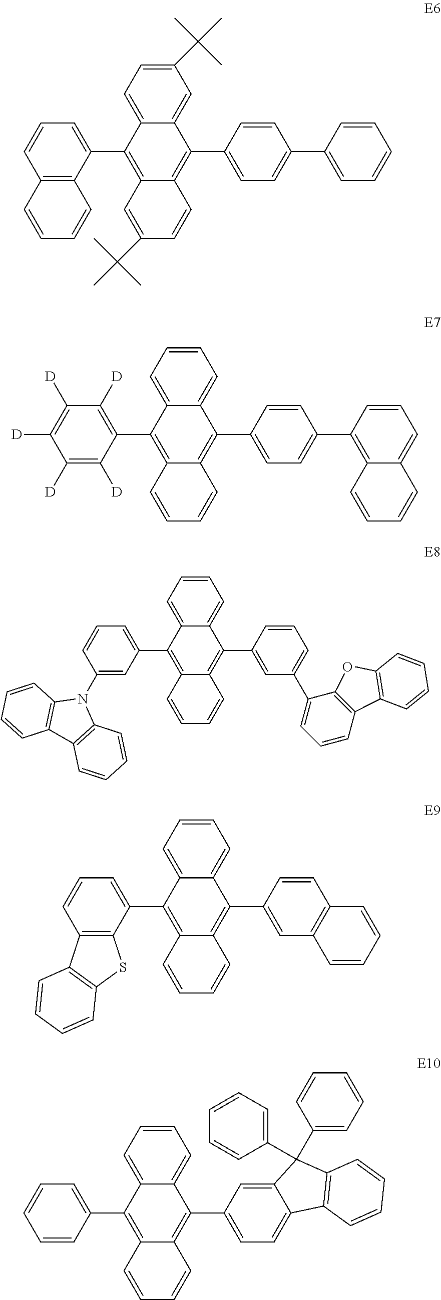

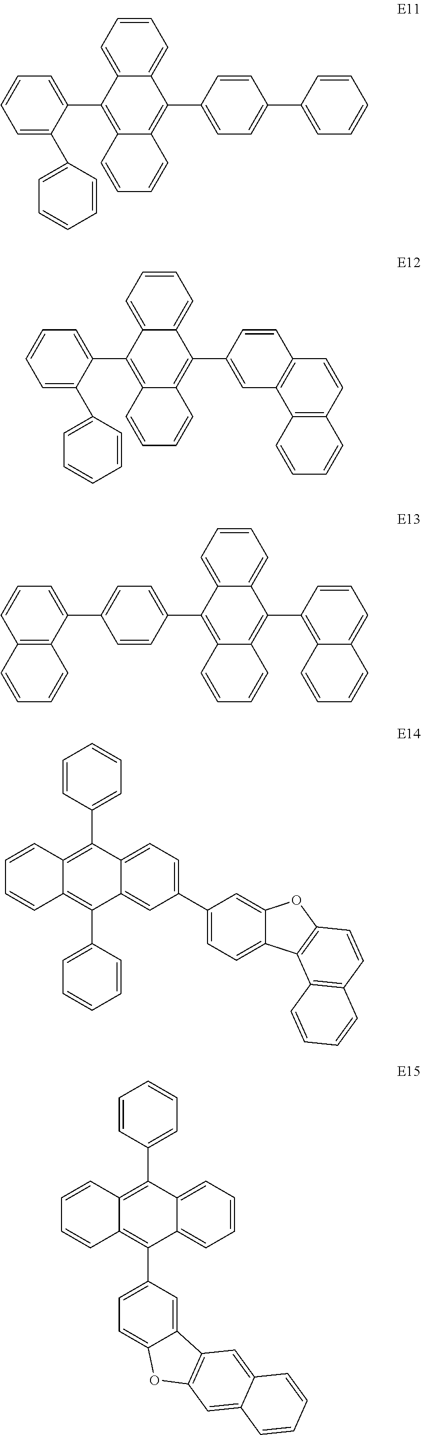

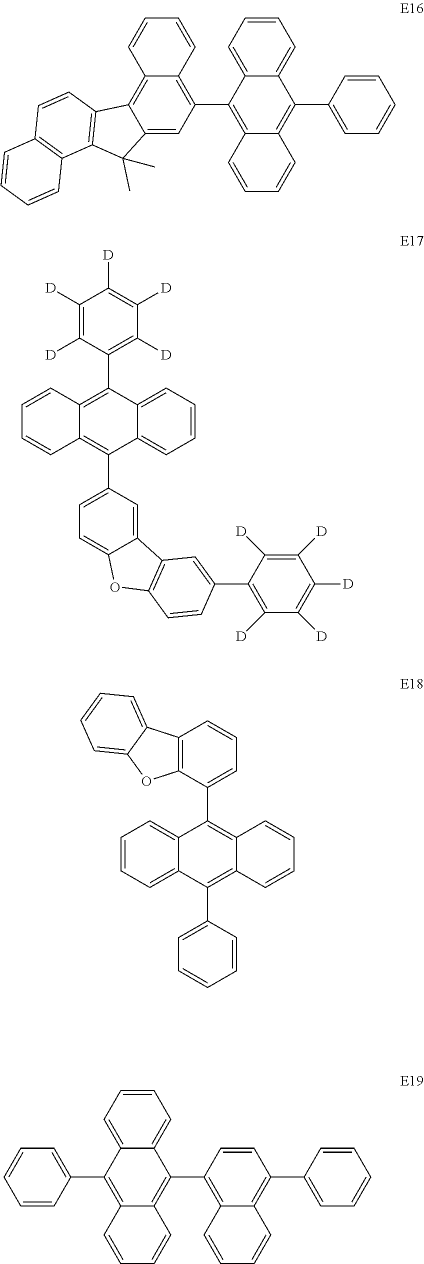

In one or more embodiments, the emission layer EML may include a compound represented by Formula E-2a or Formula E-2b. The compound represented by Formula E-2a or Formula E-2b may be utilized as a phosphorescence host material.

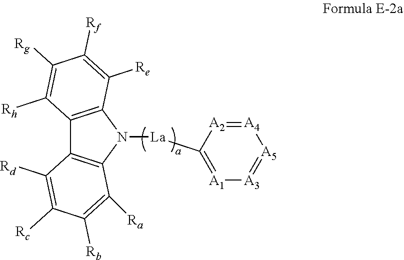

In Formula E-2a, “a” may be an integer of 0 to 10, La may be a direct linkage, a substituted or unsubstituted arylene group of 6 to 30 ring-forming carbon atoms, or a substituted or unsubstituted heteroarylene group of 2 to 30 ring-forming carbon atoms. In one or more embodiments, when “a” is an integer of 2 or more, multiple La may each independently be a substituted or unsubstituted arylene group of 6 to 30 ring-forming carbon atoms, or a substituted or unsubstituted heteroarylene group of 2 to 30 ring-forming carbon atoms.

In one or more embodiments, in Formula E-2a, A₁ to A₅ may each independently be N or CRi. Rₐ to Rᵢ may each independently be a hydrogen atom, a deuterium atom, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Rₐ to R₁ may be combined with an adjacent group to form a hydrocarbon ring or a heterocycle including N, O, S, and/or the like as a ring-forming atom.

In one or more embodiments, in Formula E-2a, two or three of selected from among A₁ to A₅ may be N, and the remainder may be CRᵢ.

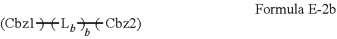

In Formula E-2b, Cbz1 and Cbz2 may each independently be an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” is an integer of 0 to 10, and when “b” is an integer of 2 or more, multiple L_{b} may each independently be a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by any (e.g., at least) one selected from among the compounds in Compound Group E-2. However, the compounds shown in Compound Group E-2 are only illustrations, and the compound represented by Formula E-2a or Formula E-2b is not limited to the compounds represented in Compound Group E-2.

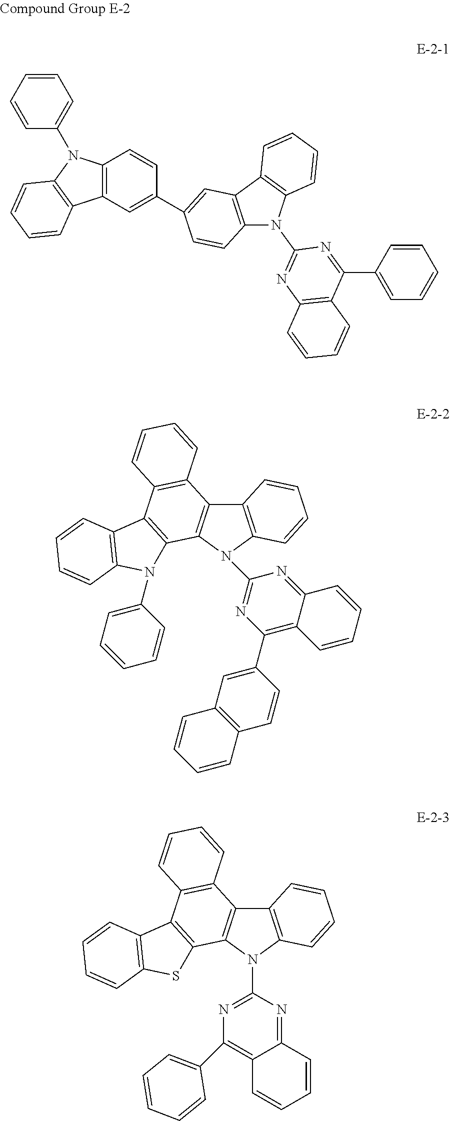 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

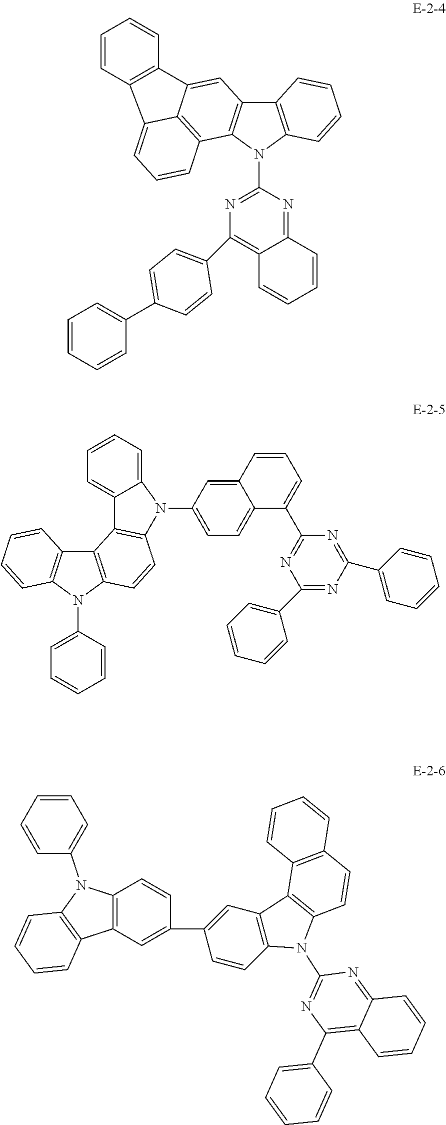 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

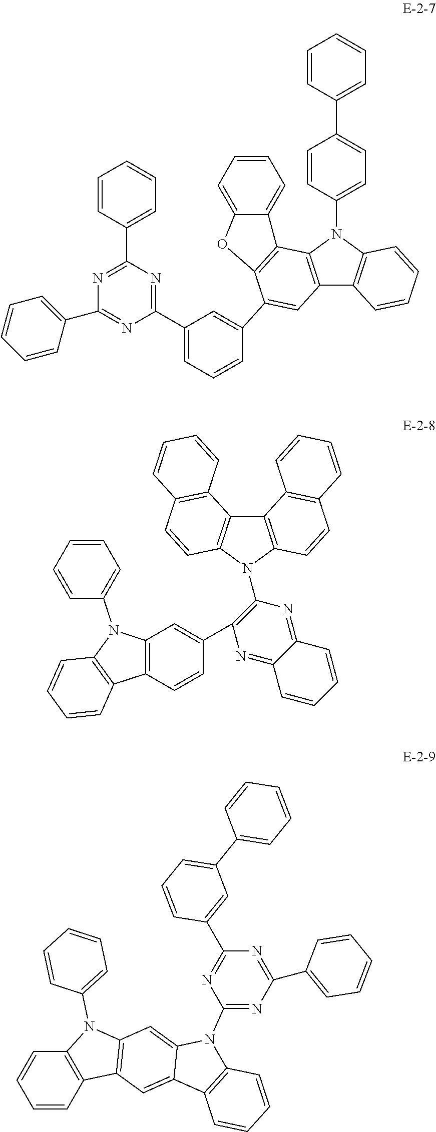 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

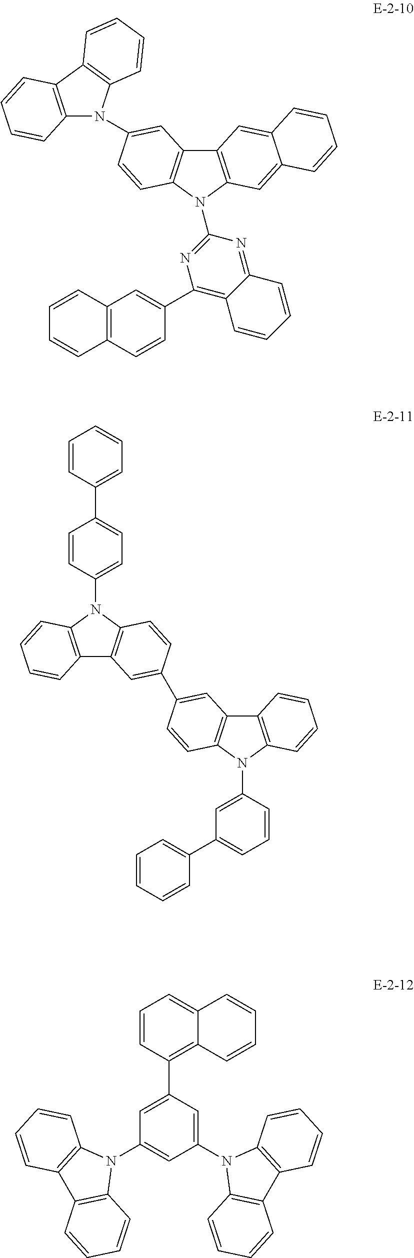 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

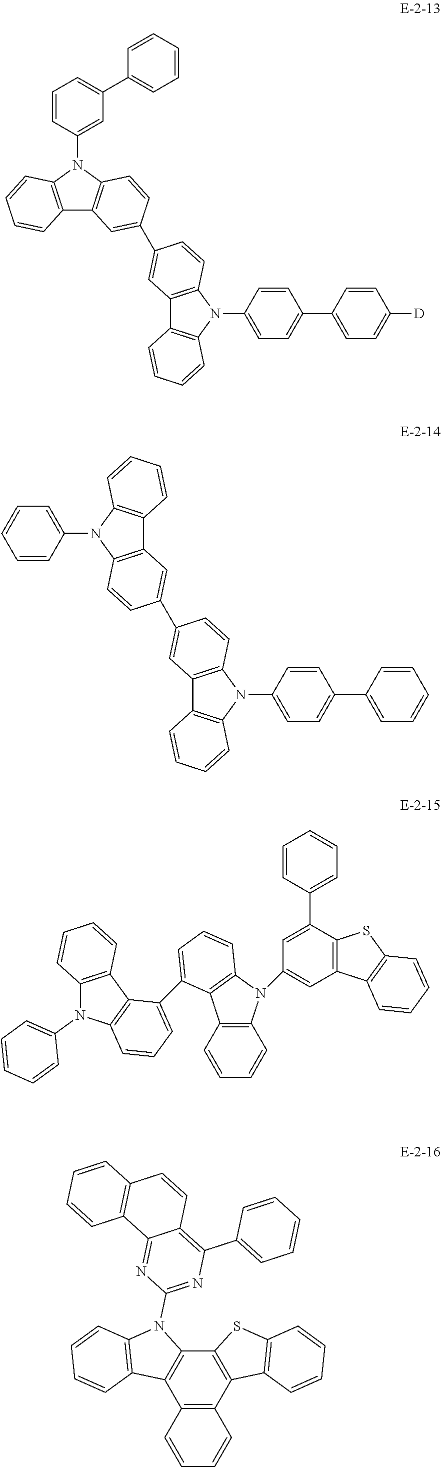 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1]

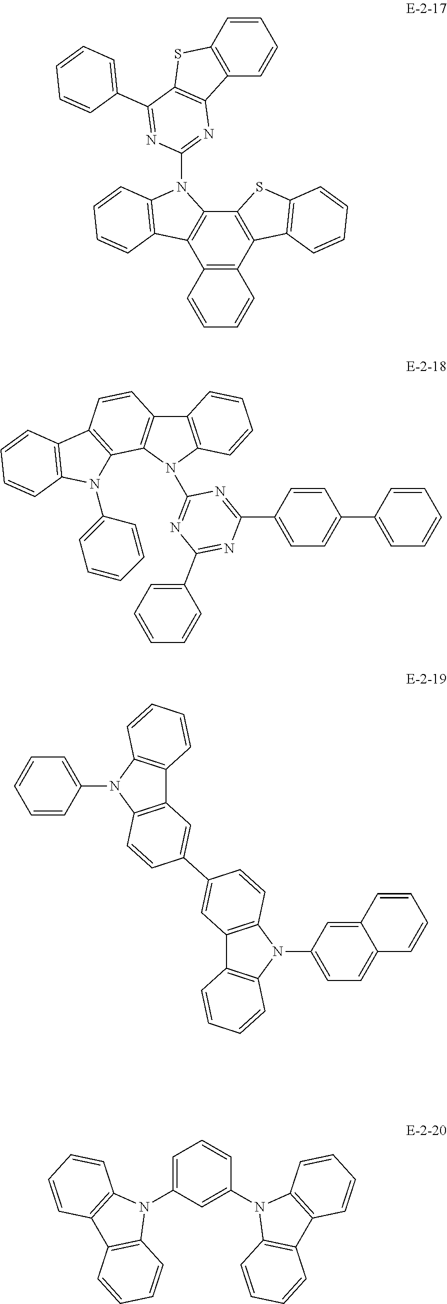 [SMILES: c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1]

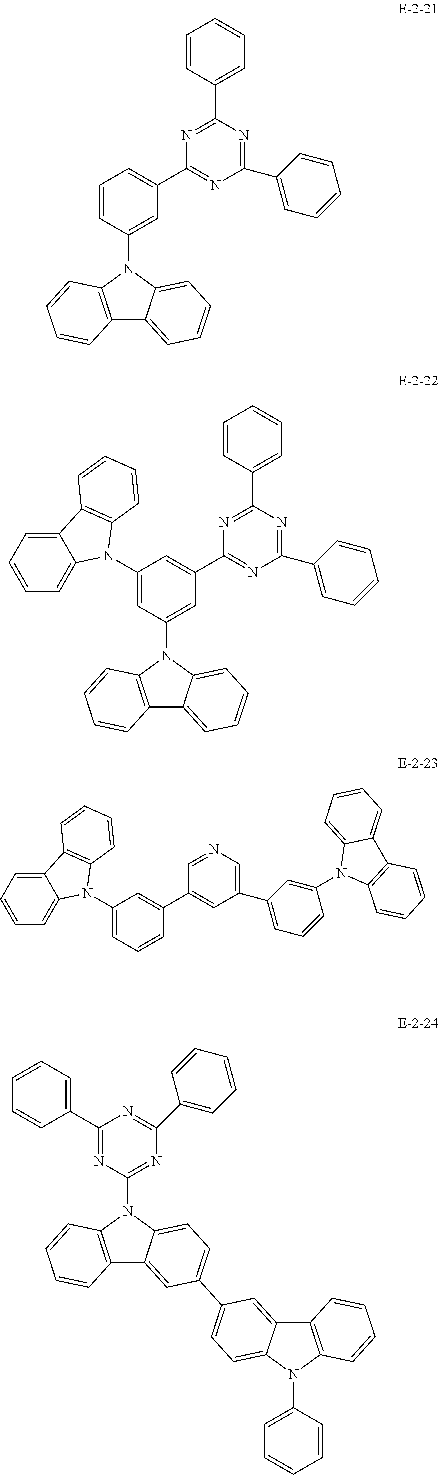 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a common material well-suitable in the art as a host material. For example, the emission layer EML may include as a host material, at least one of bis(4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, one or more embodiments of the present disclosure is not limited thereto. For example, tris(8-hydroxyquinolinato)aluminum (Alq3), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO3), octaphenylcyclotetra siloxane (DPSiO4), and/or the like may be utilized as the host material.

The emission layer EML may include a compound represented by Formula M-a. The compound represented by Formula M-a may be utilized as a phosphorescence dopant material.

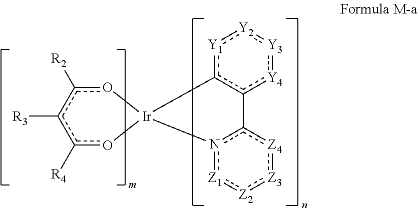

In Formula M-a, Y₁ to Y₄, and Z₁ to Z₄ may each independently be CR₁ or N, and R₁ to R₄ may each independently be a hydrogen atom, a deuterium atom, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula M-a, “m” may be 0 or 1, and “n” may be 2 or 3. In Formula M-a, when “m” is 0, “n” is 3, and when “m” is 1, “n” is 2.

The compound represented by Formula M-a may be utilized as a phosphorescence dopant.

The compound represented by Formula M-a may be represented by any (e.g., at least) one selected from among Compounds M-a1 to M-a25. However, Compounds M-a1 to M-a25 are merely illustrations, and the compound represented by Formula M-a is not limited to the compounds represented by Compounds M-a1 to M-a25.

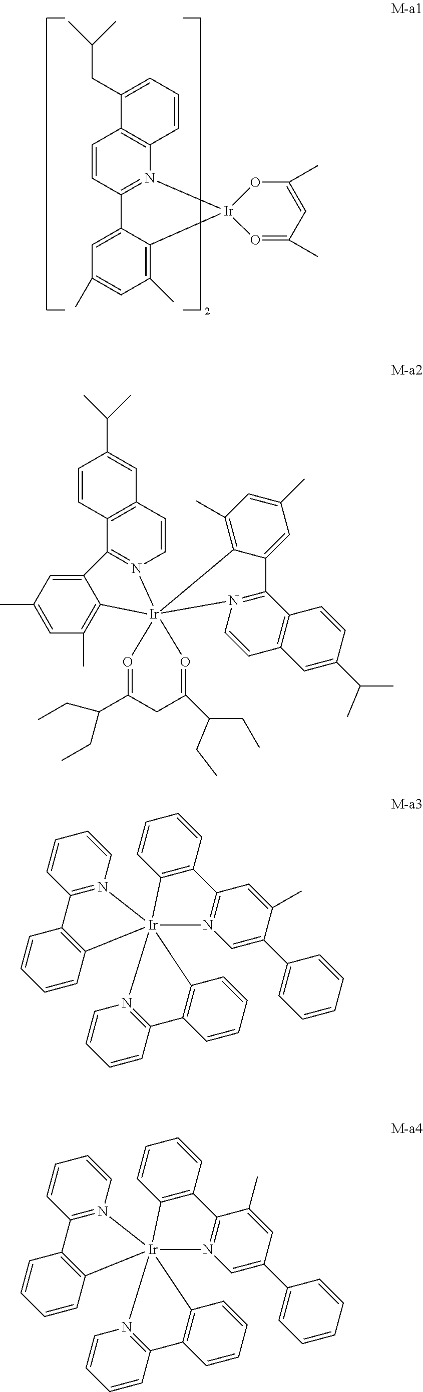

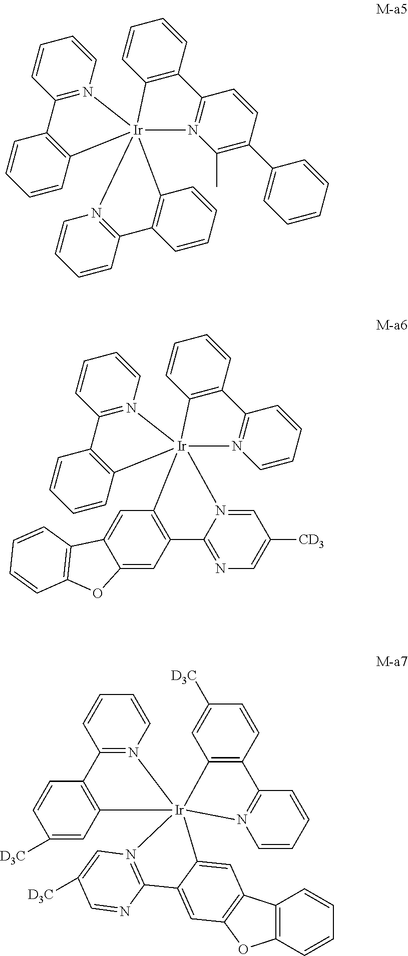

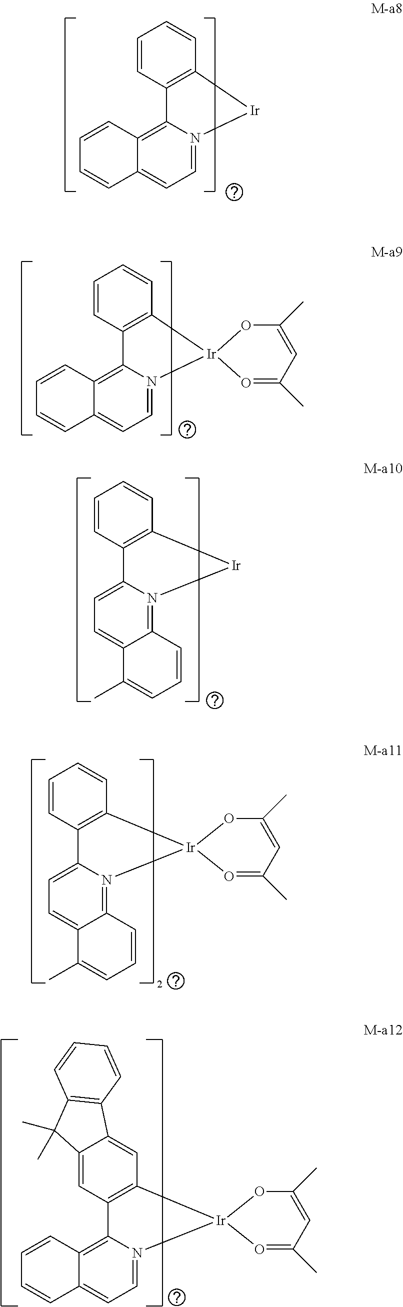

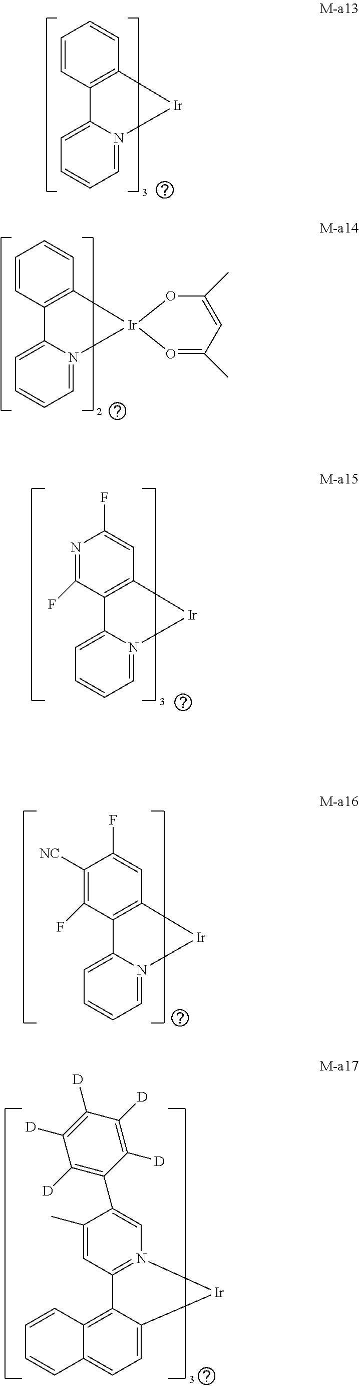

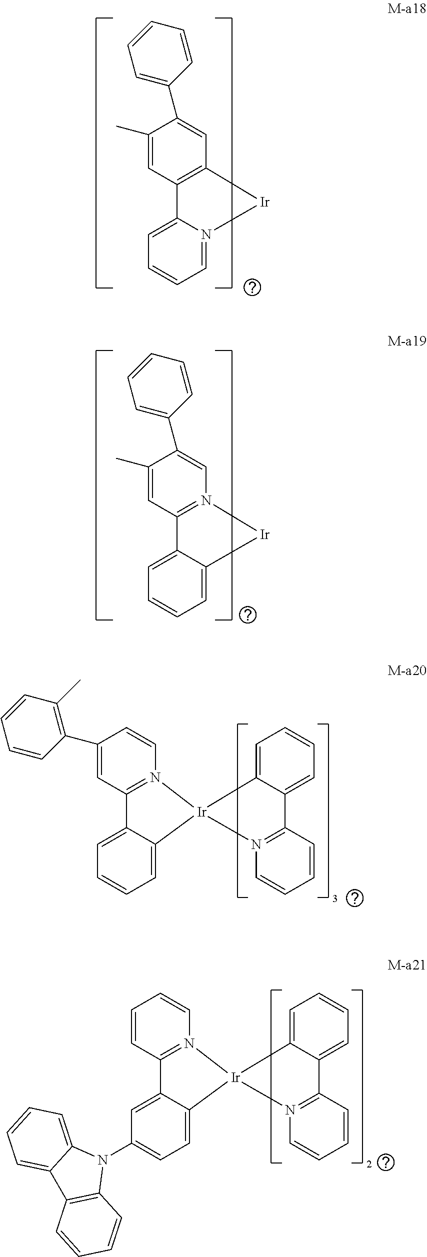

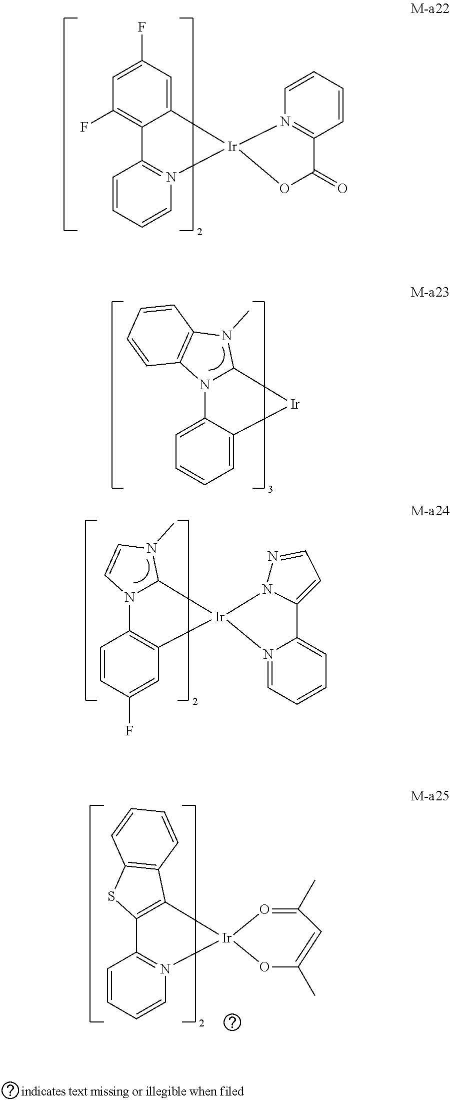

The emission layer EML may further include any (e.g., at least) one selected from among Formula F-a to Formula F-c. The compounds represented by Formula F-a to Formula F-c may be utilized as fluorescence dopant materials.

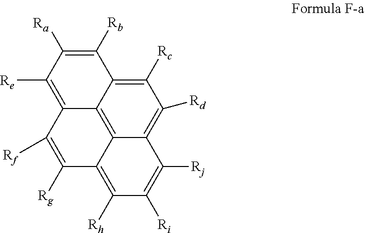

In Formula F-a, two of selected from among Rₐ to Rⱼ may each independently be substituted with. The remainder not substituted with
among Rₐ to Rⱼ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. For example, at least one selected from among Ar₁ and Ar₂ may be a heteroaryl group including O or S as a ring-forming atom.

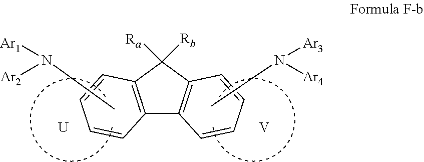

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Ar₁ to Ar₄ may each independently be a substituted or unsubstituted aryl group of 6 to 30 ring-forming carbon atoms, or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms, or a substituted or unsubstituted heterocycle of 2 to 30 ring-forming carbon atoms. At least one selected from among Ar₁ to Ar₄ may be a heteroaryl group including O or S as a ring-forming atom.

In Formula F-b, the number of rings represented by U and V may each independently be 0 or 1. For example, in Formula F-b, when the number of U or V is 1, one ring forms a fused ring at the designated part by U or V, and when the number of U or V is 0, a ring is not present at the designated part by U or V. For example, when the number of U is 0, and the number of V is 1, or when the number of U is 1, and the number of V is 0, a fused ring having the fluorene core of Formula F-b may be a ring compound with four rings. In one or more embodiments, when the number of both (e.g., simultaneously) U and V is 0, the fused ring of Formula F-b may be a ring compound with three rings. In one or more embodiments, when the number of both (e.g., simultaneously) U and V is 1, a fused ring having the fluorene core of Formula F-b may be a ring compound with five rings.

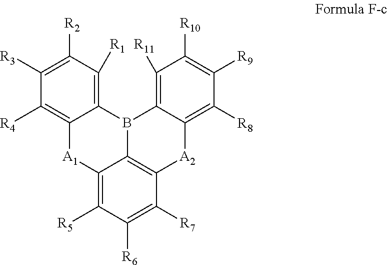

In Formula F-c, A₁ and A₂ may each independently be O, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thiol group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In Formula F-c, A₁ and A₂ may each independently be combined with the substituents of an adjacent ring to form a fused ring. For example, when A₁ and A₂ may each independently be NRₘ, A₁ may be combined with R₄ or R₅ to form a ring. In one or more embodiments, A₂ may be combined with R₇ or R₈ to form a ring.

In one or more embodiments, the emission layer EML may include as a suitable dopant material, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and the derivatives thereof (for example, 2,5,8,11-tetra-t-butylperylene (TBP)), pyrene and the derivatives thereof (for example, 1,1-dipyrene, 1,4-dipyrenylbenzene, and 1,4-bis(N,N-diphenylamino)pyrene), and/or the like.

The emission layer EML may include a suitable phosphorescence dopant material. For example, the phosphorescence dopant may utilize a metal complex including iridium (Ir), platinum (Pt), osmium (Os), gold (Au), titanium (Ti), zirconium (Zr), hafnium (Hf), europium (Eu), terbium (Tb) or thulium (Tm). For example, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), or platinum octaethyl porphyrin (PtOEP) may be utilized as the phosphorescence dopant. However, one or more embodiments of the present disclosure is not limited thereto.

The emission layer may include a quantum dot.

In the description, the quantum dot refers to the crystal of a semiconductor compound. The quantum dot may be to emit light in one or more suitable emission wavelengths according to the size of the crystal. The quantum dot may be to emit light in one or more suitable emission wavelengths by controlling the element ratio in the quantum dot compound.

The diameter of the quantum dot may be, for example, about 1 nanometer (nm) to about 10 nm.

The quantum dot may be synthesized by a chemical bath deposition, a metal organic chemical vapor deposition, a molecular beam epitaxy or a similar process therewith.

The chemical bath deposition is a method of mixing an organic solvent and a precursor material and then, growing a quantum dot particle crystal. During growing the crystal, the organic solvent may naturally play the role of a dispersant which is coordinated on the surface of the quantum dot crystal and may control the growth of the crystal. Accordingly, the chemical bath deposition is more advantageous if (e.g., when) compared to a vapor deposition method including a metal organic chemical vapor deposition (MOCVD) and molecular beam epitaxy (MBE), and the growth of the quantum dot particle may be controlled or selected through a low-cost process.

The emission layer EML may include a quantum dot material. The core of the quantum dot may be selected from among a II-VI group compound, a III-VI group compound, a I-III-VI group compound, a III-V group compound, a III-II-V group compound, a IV-VI group compound, a IV group element, a IV group compound, and combinations thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a (e.g., any suitable) mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof. In one or more embodiments, the Group II-VI compound may further include a Group I metal and/or a Group IV element. The Group I-II-VI compound may be selected from CuSnS or CuZnS, and the Group II-IV-VI compound may be selected from ZnSnS and the like. The Group I-II-IV-VI compound may be selected from quaternary compound(s) selected from the group consisting of Cu₂ZnSnS₂, Cu₂ZnSnS₄, Cu₂ZnSnSe₄, Ag₂ZnSnS₂, and a mixture thereof.

The III-VI group compound may include a binary compound such as In₂S₃, and In₂Se₃, a ternary compound such as InGaS₃, and InGaSe₃, or a (e.g., any suitable) combination thereof.

The I-III-VI group compound may be of (e.g., selected from among) a ternary compound of (e.g., selected from among) the group including (e.g., consisting of) AgInS, AgInS₂, CuInS, CuInS₂, AgGaS₂, CuGaS₂, CuGaO₂, AgGaO₂, AgAlO₂ and mixtures thereof, or a quaternary compound such as AgInGaS₂, and/or CuInGaS₂.

The III-V group compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from the group consisting of GaAINP, GaAINAs, GaAINSb, GaAlPAs, GaAlPSb, GaInNP, GaInNAs, GaInNSb, GaInPAs, GaInPSb, InAINP, InAINAs, InAINSb, InAlPAs, InAlPSb, and mixtures thereof. In one or more embodiments, the III-V group compound may further include a II group metal. For example, InZnP, and/or the like may be selected as a III-II-V group compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof.

The Group II-IV-V compound may be selected from a ternary compound selected from the group consisting of ZnSnP, ZnSnP₂, ZnSnAs₂, ZnGeP₂, ZnGeAs₂, CdSnP₂, CdGeP₂ and a mixture thereof.

The Group IV element may be selected from the group consisting of Si, Ge, and a mixture thereof. The Group IV compound may be a binary compound selected from the group consisting of SiC, SiGe, and a mixture thereof.

Each element included in the multi-element compound such as the binary compound, ternary compound, and quaternary compound may be present in particles at a substantially uniform concentration or a non-substantially uniform concentration. For example, the preceding formulae indicate the types (kinds) of elements included in a compound, and element ratios in the compound may be different. For example, AgInGaS₂ may indicate AgInₓGa₁₋ₓS₂ (x is a real number between 0 and 1).

In this case, the binary compound, the ternary compound or the quaternary compound may be present at substantially uniform concentration in a particle or may be present at a partially different concentration distribution state in the same particle. In one or more embodiments, a core/shell structure in which one quantum dot wraps another quantum dot may be possible. The interface of the core and the shell may have a concentration gradient in which the concentration of an element present in the shell is decreased toward the center.

In some embodiments, the quantum dot may have the herein-described core-shell structure including a core including a nanocrystal and a shell wrapping the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal or non-metal oxide, a semiconductor compound, or combinations thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO, or a ternary compound such as MgAl₂O₄, CoFe₂O₄, NiFe₂O₄ and CoMn₂O₄, but one or more embodiments of the present disclosure is not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but one or more embodiments of the present disclosure is not limited thereto.

The quantum dot may have a full width of half maximum (FWHM) of emission wavelength spectrum of about 45 nm or less, about 40 nm or less, or about 30 nm or less. Within the described ranges, color purity or color reproducibility may be improved. In one or more embodiments, light emitted via such quantum dot may be emitted in all directions, and light view angle properties may be improved.

In one or more embodiments, the shape of the quantum dot may be generally utilized shapes in the art, without specific limitation. More particularly, the shape of spherical, pyramidal, multi-arm, or cubic nanoparticle, nanotube, nanowire, nanofiber, nanoplate particle, and/or the like may be utilized.

As the size of the quantum dot or the ratio of elements in the quantum dot compound is regulated, the energy band gap may be accordingly controlled or selected to obtain light of one or more suitable wavelengths from the quantum dot emission layer. Therefore, by utilizing the quantum dots as described herein (utilizing quantum dots of different sizes or having different element ratios in the quantum dot compound), a light emitting element emitting light of one or more suitable wavelengths may be obtained. For example, the size of the quantum dots or the ratio of elements in the quantum dot compound may be regulated to emit red, green, and/or blue light. In one or more embodiments, the quantum dots may be configured to emit white light by combining light of one or more suitable colors.

In the light emitting element ED of embodiments, as shown in FIG. 3 to FIG. 6, the electron transport region ETR is provided on the emission layer EML. The electron transport region ETR may include at least one of an electron blocking layer HBL, an electron transport layer ETL or an electron injection layer EIL. However, one or more embodiments of the present disclosure is not limited thereto.

The electron transport region ETR may have a single layer formed utilizing a single material, a single layer formed utilizing multiple different materials, or a multilayer structure having multiple layers formed utilizing multiple different materials.

For example, the electron transport region ETR may have a single layer structure of an electron injection layer EIL or an electron transport layer ETL, or a single layer structure formed utilizing an electron injection material and an electron transport material. Further, the electron transport region ETR may have a single layer structure formed utilizing multiple different materials, or a structure stacked from the emission layer EML of electron transport layer ETL/electron injection layer EIL, or hole blocking layer HBL/electron transport layer ETL/electron injection layer EIL, without limitation. The thickness of the electron transport region ETR may be, for example, from about 1,000 angstrom (Å) to about 1,500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-2.

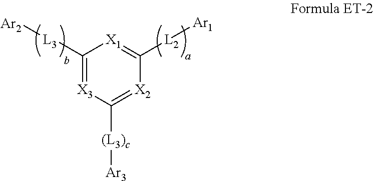

In Formula ET-2, at least one selected from among X₁ to X₃ may be N, and the remainder (e.g., any remaining selected from among X₁ to X₃) may be CRₐ. Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, “a” to “c” may each independently be an integer of 0 to 10. In Formula ET-2, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. In one or more embodiments, when “a” to “c” are integers of 2 or more, L₁ to L₃ may each independently be a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, one or more embodiments of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq2), 9,10-di(naphthalene-2-yl)anthracene (ADN), 1,3-bis[3,5-di(pyridin-3-yl)phenyl]benzene (BmPyPhB), CNNPTRZ(4′-(4-(4-(4,6-diphenyl-1,3,5-triazin-2-yl)phenyl)naphthalen-1-yl)-[1,1′-biphenyl]-4-carbonitrile) and mixtures thereof, without limitation.

In one or more embodiments, electron transport region ETR may include any (e.g., at least) one selected from among the compounds in Compound Group 3.

The electron transport region ETR may include at least one selected from among Compounds ET1 to ET36.

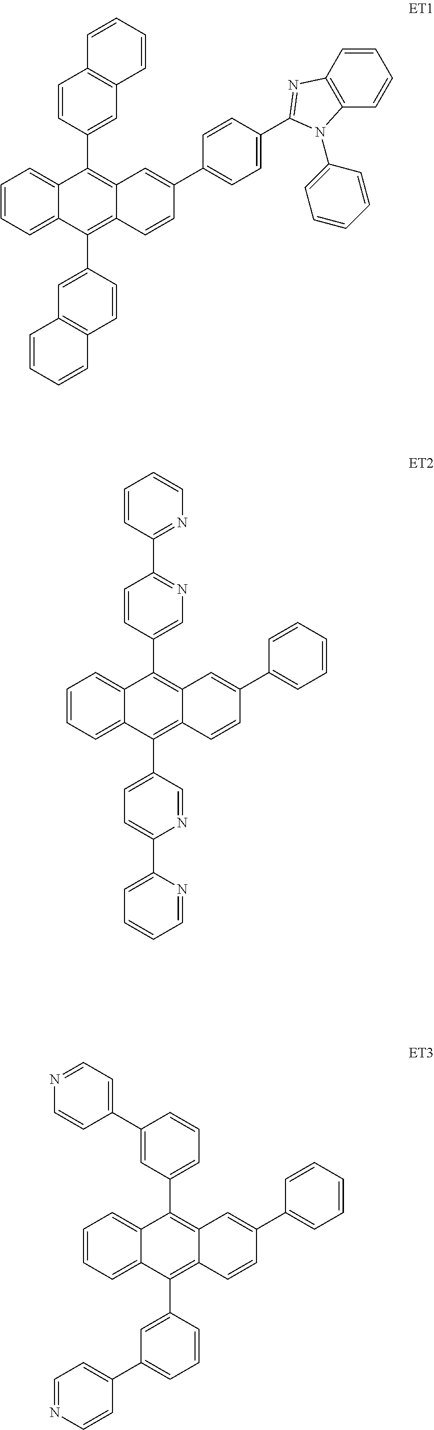 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

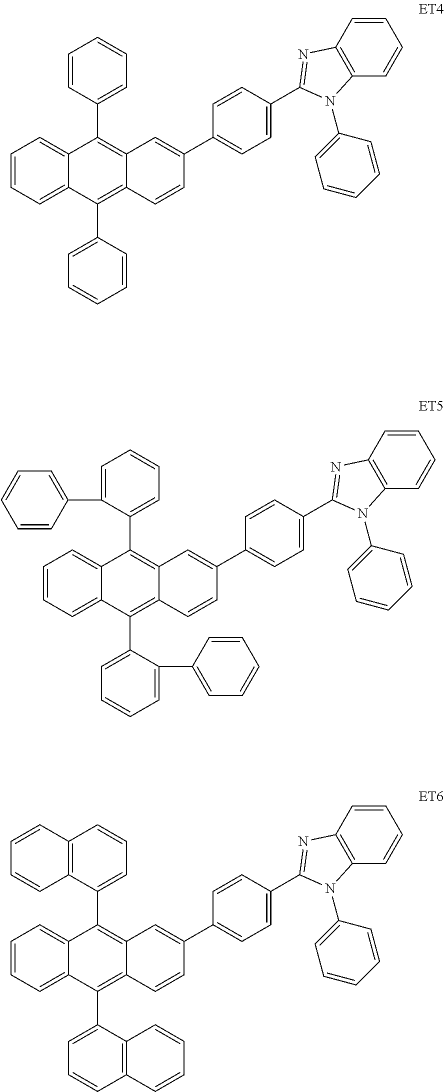 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

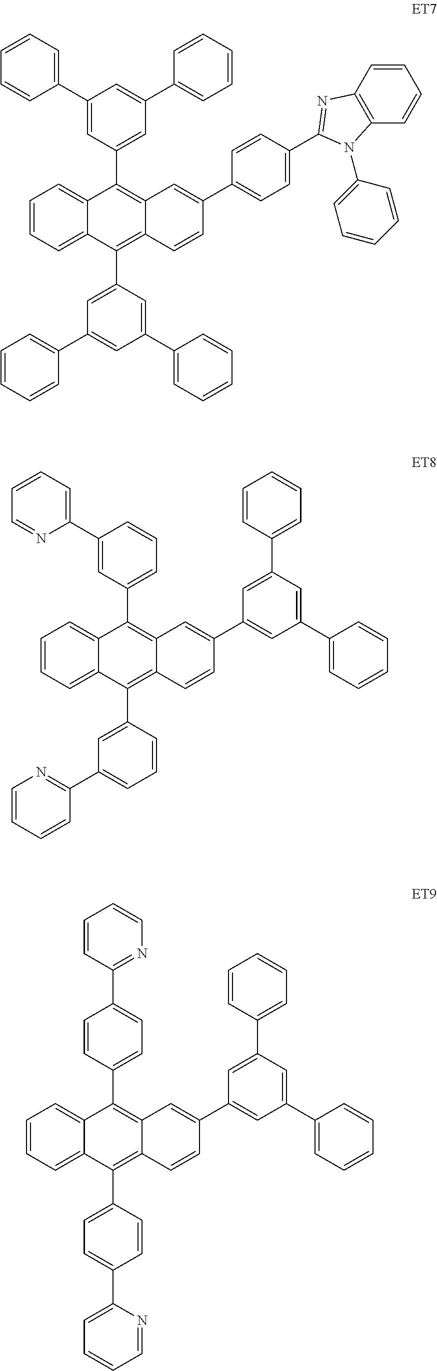 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

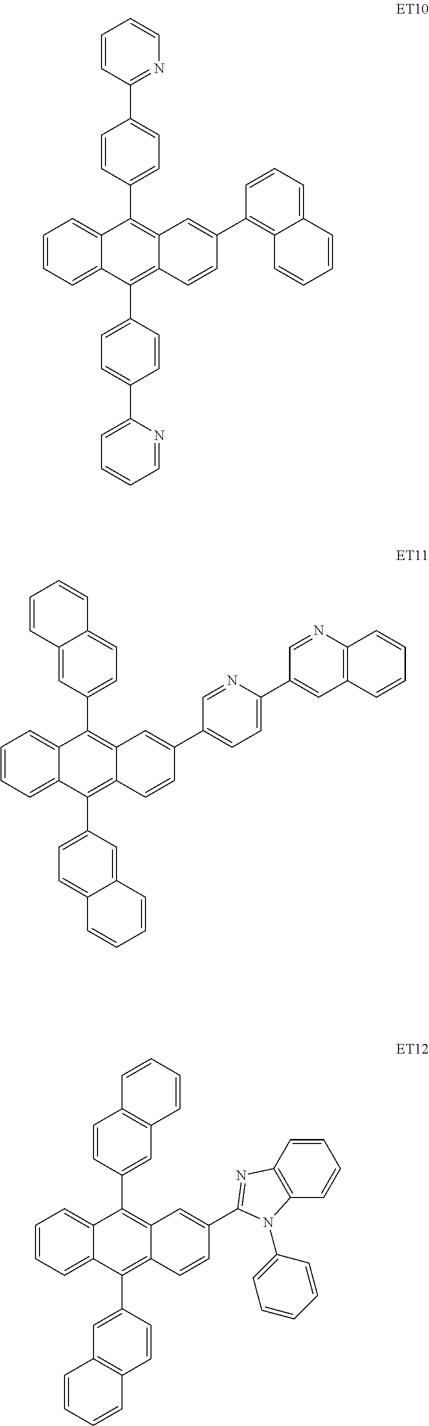 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

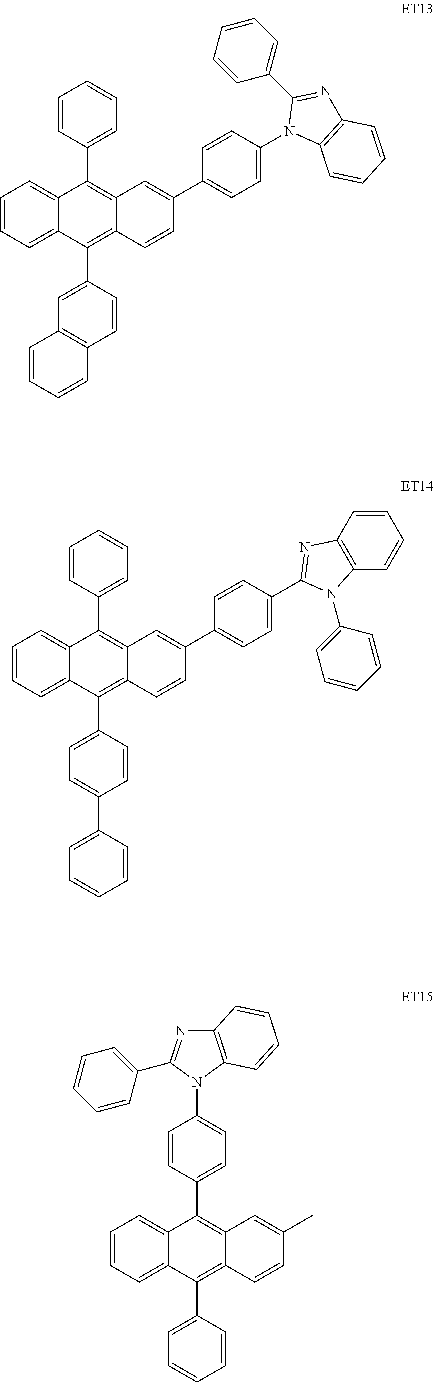 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5ccc(-c6nc7ccccc7n6-c6ccccc6)cc5)ccc34)cc2)cc1 ; Cc1ccc2c(-c3ccccc3)c3ccccc3c(-c3ccc(-n4c(-c5ccccc5)nc5ccccc54)cc3)c2c1]

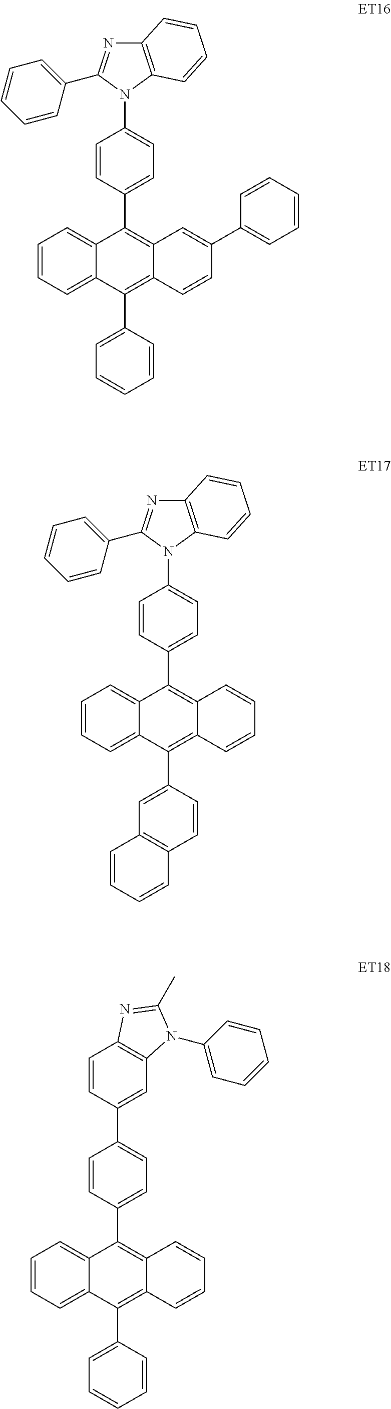 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

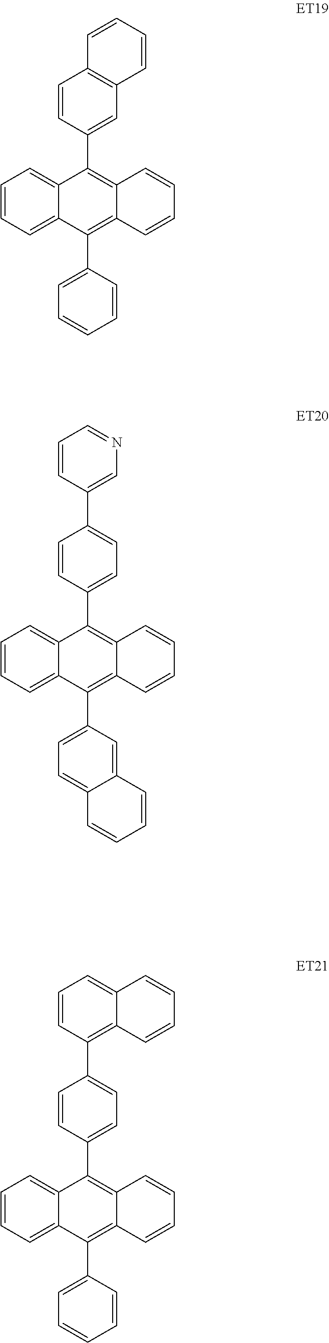

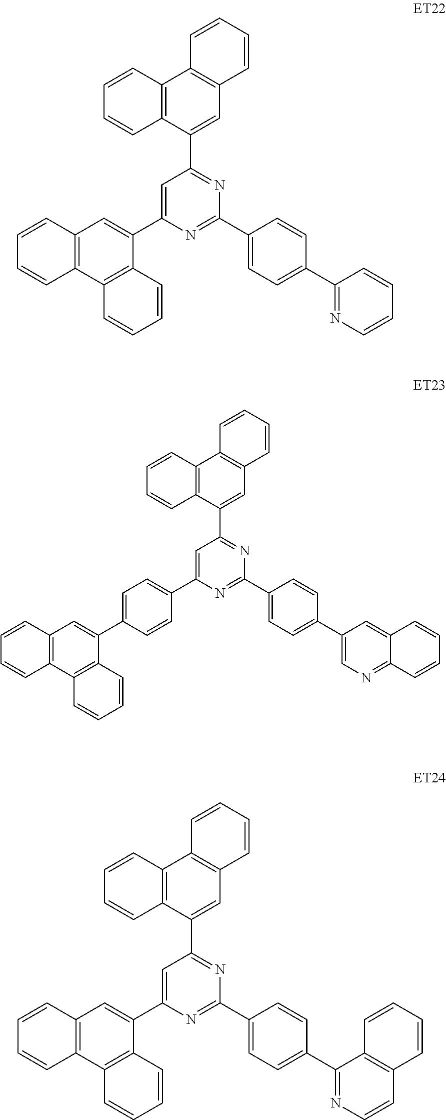 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

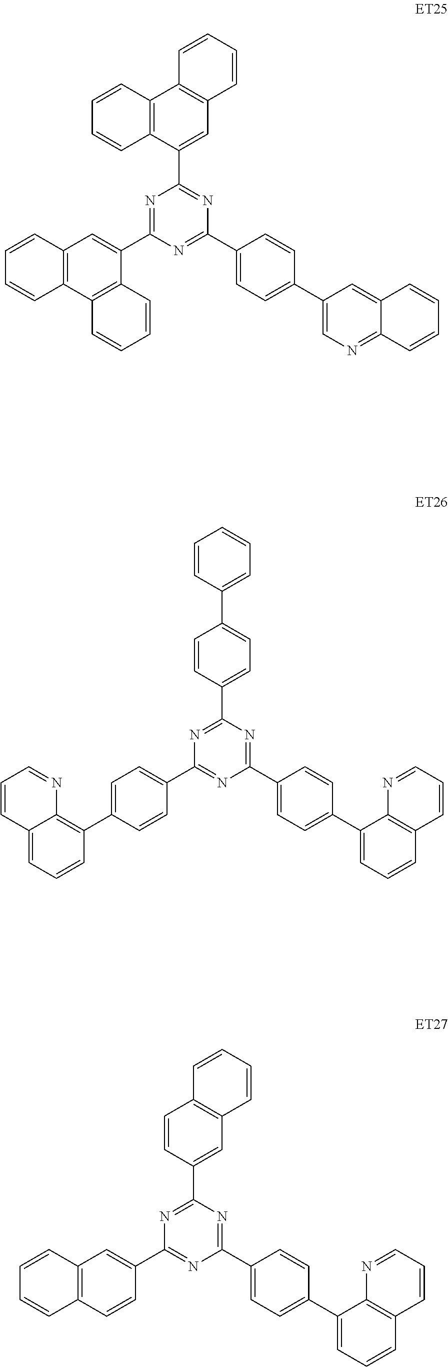 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

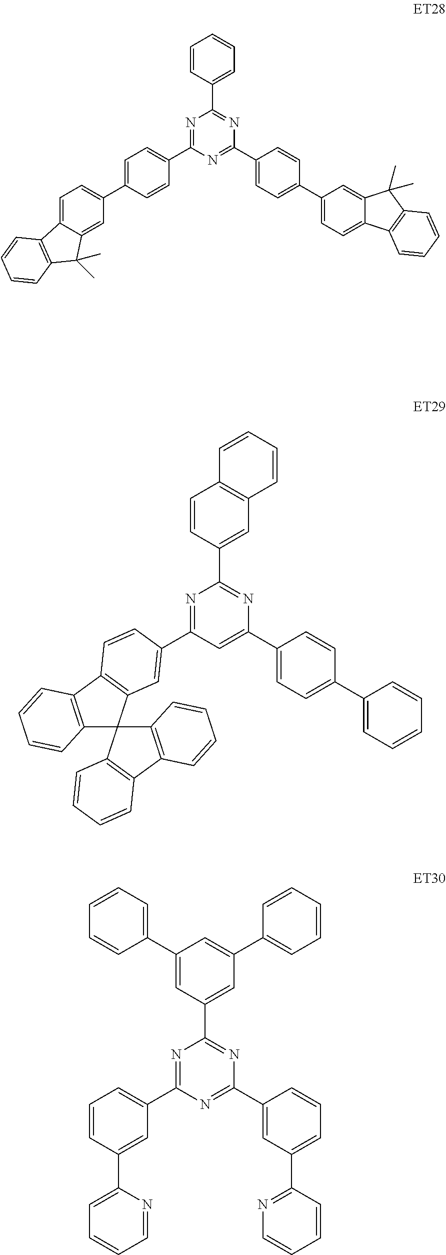 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

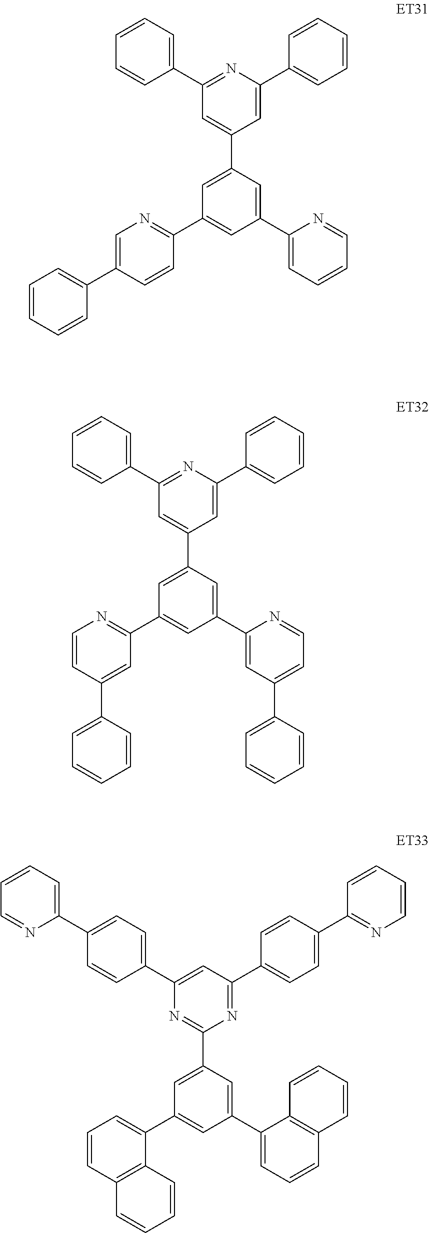 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

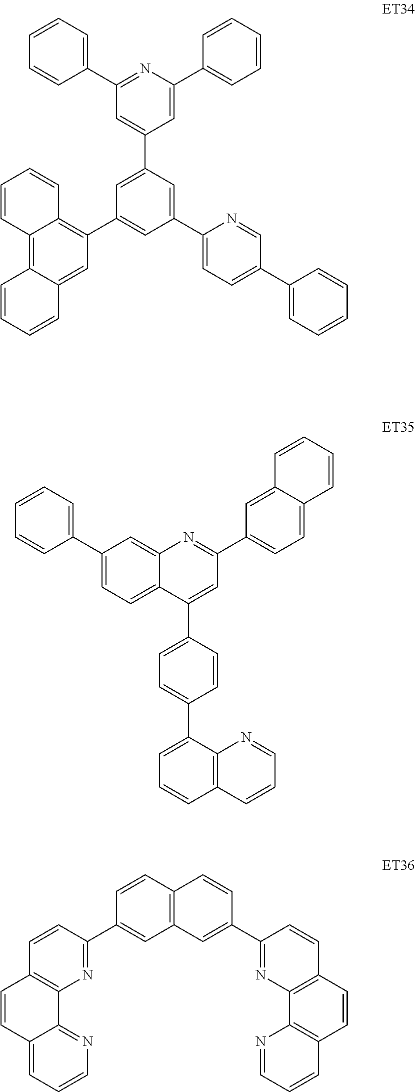 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In one or more embodiments, the electron transport region ETR may include a metal halide such as LiF, NaCl, CsF, RbCl, RbI, CuI and KI, a lanthanide metal such as Yb, or a co-depositing material of the metal halide and the lanthanide metal. For example, the electron transport region ETR may include KI:Yb, RbI:Yb, LiF:Yb, and/or the like, as the co-depositing material. In one or more embodiments, the electron transport region ETR may utilize a metal oxide such as Li₂O and BaO, or 8-hydroxy-lithium quinolate (Liq). However, one or more embodiments of the present disclosure is not limited thereto. The electron transport region ETR also may be formed utilizing a mixture material of an electron transport material and an insulating organo metal salt. The organo metal salt may be a material having an energy band gap of about 4 eV or more. For example, the organo metal salt may include, for example, metal acetates, metal benzoates, metal acetoacetates, metal acetylacetonates, or metal stearates.

The electron transport region ETR may include at least one selected from among 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen) in addition to the aforementioned materials. However, one or more embodiments of the present disclosure is not limited thereto.

The electron transport region ETR may include the compounds of the electron transport region in at least one selected from among an electron injection layer EIL, an electron transport layer ETL, and a hole blocking layer HBL.

When the electron transport region ETR includes the electron transport layer ETL, the thickness of the electron transport layer ETL may be from about 100 Å to about 1,000 Å, for example, from about 150 Å to about 500 Å. When the thickness of the electron transport layer ETL satisfies the herein-described ranges, satisfactory electron transport properties may be obtained without substantial increase of a driving voltage. When the electron transport region ETR includes the electron injection layer EIL, the thickness of the electron injection layer EIL may be from about 1 Å to about 100 Å, or from about 3 Å to about 90 Å. When the thickness of the electron injection layer EIL satisfies the herein described ranges, satisfactory electron injection properties may be obtained without inducing substantial increase of a driving voltage.

The second electrode EL2 is provided on the electron transport region ETR. The second electrode EL2 may be a common electrode. The second electrode EL2 may be a cathode or an anode, but one or more embodiments of the present disclosure is not limited thereto. For example, when the first electrode EL1 is an anode, the second cathode EL2 may be a cathode, and when the first electrode EL1 is a cathode, the second electrode EL2 may be an anode.

The second electrode EL2 may be a transmissive electrode, a transflective electrode or a reflective electrode. When the second electrode EL2 is the transmissive electrode, the second electrode EL2 may include a transparent metal oxide, for example, ITO, IZO, ZnO, ITZO, and/or the like.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, compounds including thereof, or mixtures thereof (for example, AgMg, AgYb, or MgYb). In one or more embodiments, the second electrode EL2 may have a multilayered structure including a reflective layer or a transflective layer formed utilizing the herein-described materials and a transparent conductive layer formed utilizing ITO, IZO, ZnO, ITZO, and/or the like. For example, the second electrode EL2 may include the aforementioned metal materials, combinations of two or more metal materials selected from among the aforementioned metal materials, or oxides of the aforementioned metal materials.

In one or more embodiments, the second electrode EL2 may be connected with an auxiliary electrode. When the second electrode EL2 is connected with the auxiliary electrode, the resistance of the second electrode EL2 may decrease.

In one or more embodiments, on the second electrode EL2 in the light emitting element ED of one or more embodiments, a capping layer CPL may be further arranged. The capping layer CPL may include a multilayer or a single layer.

In one or more embodiments, the capping layer CPL may be an organic layer or an inorganic layer. For example, when the capping layer CPL includes an inorganic material, the inorganic material may include an alkali metal compound such as LiF, an alkaline earth metal compound such as MgF₂, SiON, SiNₓ, SiO_{y}, and/or the like

For example, when the capping layer CPL includes an organic material, the organic material may include 2,2′-dimethyl-N,N′-di-[(1-naphthyl)-N,N′-diphenyl]-1,1′-biphenyl-4,4′-diamine (α-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), and/or the like, or includes an epoxy resin, or acrylate such as methacrylate. In one or more embodiments, a capping layer CPL may include at least one among Compounds P₁ to P₅, but one or more embodiments of the present disclosure is not limited thereto.

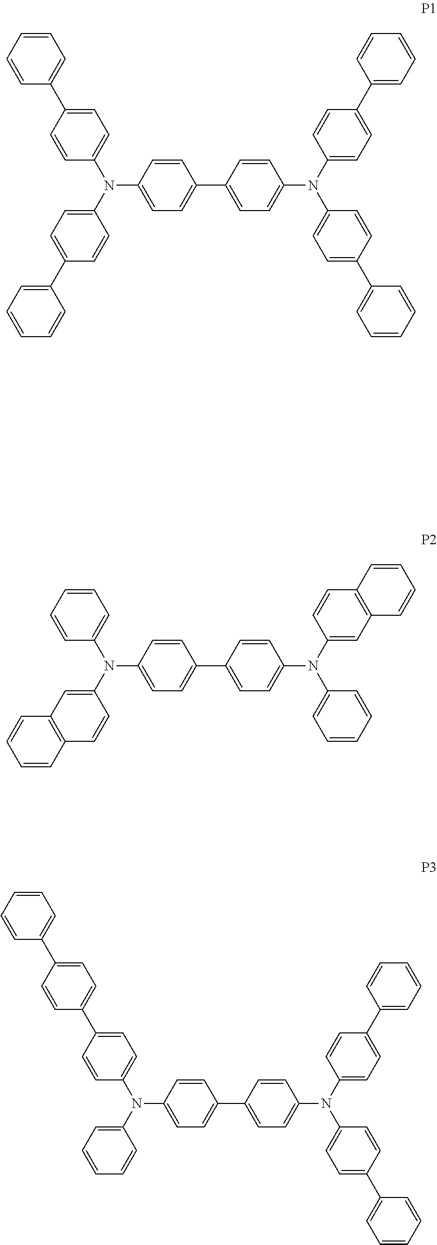 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

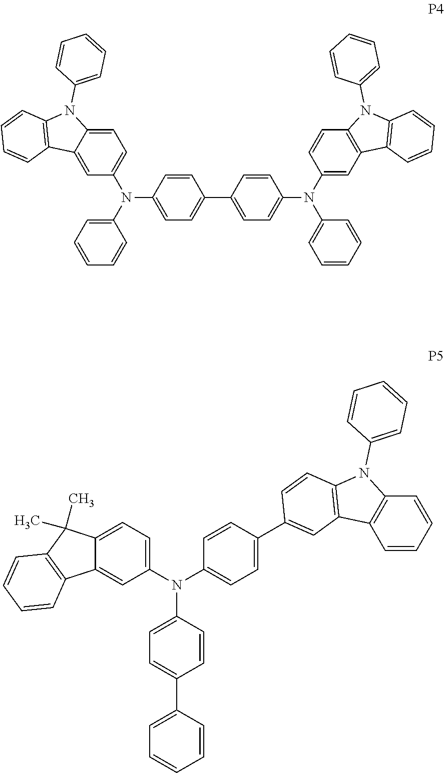 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the refractive index of the capping layer CPL may be about 1.6 or more. For example, the refractive index of the capping layer CPL with respect to light in a wavelength range of about 550 nm to about 660 nm may be about 1.6 or more.

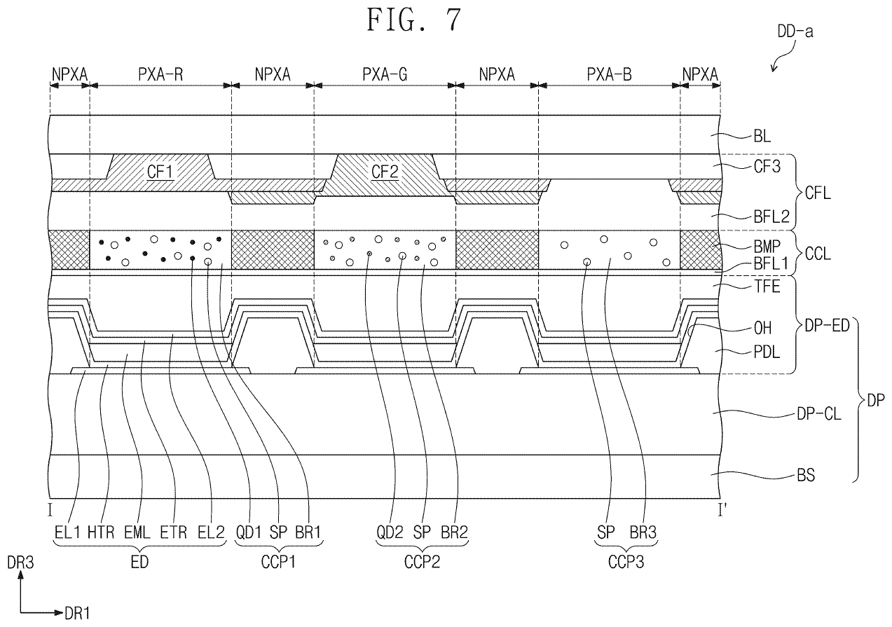

FIG. 7 to FIG. 10 are cross-sectional views on display devices according to one or more embodiments, respectively. In the explanation on the display devices of embodiments referring to FIG. 7 to FIG. 10, the overlapping parts with the explanation on FIG. 1 to FIG. 6 will not be explained again, and the different features will be explained chiefly.

Referring to FIG. 7, the display device DD-a according to one or more embodiments may include a display panel DP including a display device layer DP-ED, a light controlling layer CCL arranged on the display panel DP and a color filter layer CFL. In one or more embodiments shown in FIG. 7, the display panel DP includes a base layer BS, a circuit layer DP-CL provided on the base layer BS and a display device layer DP-ED, and the display device layer DP-ED may include a light emitting element ED.

The light emitting element ED may include a first electrode EL1, a hole transport region HTR arranged on the first electrode EL1, an emission layer EML arranged on the hole transport region HTR, an electron transport region ETR arranged on the emission layer EML, and a second electrode EL2 arranged on the electron transport region ETR. In one or more embodiments, the same structures as the light emitting elements of FIG. 3 to FIG. 6 may be applied to the structure of the light emitting element ED shown in FIG. 7.

The emission layer EML of the light emitting element ED included in the display device DD-a according to one or more embodiments may include the fused polycyclic compound of one or more embodiments described herein.

Referring to FIG. 7, the emission layer EML may be arranged in an opening part OH defined in a pixel definition layer PDL. For example, the emission layer EML divided by the pixel definition layer PDL and correspondingly provided to each of luminous areas PXA-R, PXA-G and PXA-B may be to emit light in substantially the same wavelength region. In the display device DD-a of one or more embodiments, the emission layer EML may be to emit blue light. In one or more embodiments, different from the drawings, in one or more embodiments, the emission layer EML may be provided as a common layer for all luminous areas PXA-R, PXA-G and PXA-B.

The light controlling layer CCL may be arranged on the display panel DP. The light controlling layer CCL may include a light converter. The light converter may be a quantum dot or a phosphor. The light converter may transform the wavelength of light provided and then emit. For example, the light controlling layer CCL may be a layer including a quantum dot or a layer including a phosphor.

The light controlling layer CCL may include multiple light controlling parts CCP1, CCP2 and CCP3. The light controlling parts CCP1, CCP2 and CCP3 may be separated from one another.

Referring to FIG. 7, a partition pattern BMP may be arranged between the separated light controlling parts CCP1, CCP2 and CCP3, but one or more embodiments of the present disclosure is not limited thereto. In FIG. 7, the partition pattern BMP is shown not to be overlapped with the light controlling parts CCP1, CCP2 and CCP3, but at least a portion of the edge of the light controlling parts CCP1, CCP2 and CCP3 may be overlapped with the partition pattern BMP.

The light controlling layer CCL may include a first light controlling part CCP1 including a first quantum dot QD1 converting first color light provided from the light emitting element ED into second color light, a second light controlling part CCP2 including a second quantum dot QD2 converting first color light into third color light, and a third light controlling part CCP3 transmitting first color light. In one or more embodiments, the first light controlling part CCP1 may provide red light which is the second color light, and the second light controlling part CCP2 may provide green light which is the third color light. The third color controlling part CCP3 may be to transmit and provide blue light which is the first color light provided from the light emitting element ED. For example, the first quantum dot QD1 may be a red quantum dot, and the second quantum dot QD2 may be a green quantum dot. On the quantum dots QD1 and QD2, the same contents as those described herein may be applied.

In one or more embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include (e.g., may exclude) a quantum dot but include the scatterer SP.

The scatterer SP may be an inorganic particle. For example, the scatterer SP may include at least one selected from among TiO₂, ZnO, Al₂O₃, SiO₂, and hollow silica. The scatterer SP may include at least one selected from among TiO₂, ZnO, Al₂O₃, SiO₂, and hollow silica, or may be a mixture of two or more materials selected from among TiO₂, ZnO, Al₂O₃, SiO₂, and hollow silica.

Each of the first light controlling part CCP1, the second light controlling part CCP2, and the third light controlling part CCP3 may include base resins BR1, BR2 and BR3 dispersing the quantum dots QD1 and QD2 and the scatterer SP. In one or more embodiments, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3.

The base resins BR1, BR2 and BR3 are mediums in which the quantum dots QD1 and QD2 and the scatterer SP are dispersed, and may be composed of one or more suitable resin compositions which may be generally referred to as a binder. For example, the base resins BR1, BR2 and BR3 may be acrylic resins, urethane-based resins, silicone-based resins, epoxy-based resins, and/or the like. The base resins BR1, BR2 and BR3 may be transparent resins. In one or more embodiments, the first base resin BR1, the second base resin BR2 and the third base resin BR3 may be the same or different from each other.

The light controlling layer CCL may include a barrier layer BFL1. The barrier layer BFL1 may prevent (e.g., play the role of blocking) the penetration of moisture and/or oxygen (hereinafter, will be referred to as “humidity/oxygen”). The barrier layer BFL1 may block or reduce the exposure of the light controlling parts CCP1, CCP2 and CCP3 to humidity/oxygen. In one or more embodiments, the barrier layer BFL1 may cover the light controlling parts CCP1, CCP2 and CCP3. In one or more embodiments, a color filter layer CFL, which will be explained later, may include a barrier layer BFL2 arranged on the light controlling parts CCP1, CCP2 and CCP3.

The barrier layers BFL1 and BFL2 may include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and silicon oxynitride or a metal thin film securing light transmittance. In one or more embodiments, the barrier layers BFL1 and BFL2 may further include an organic layer. The barrier layers BFL1 and BFL2 may be composed of a single layer of multiple layers.

In the display device DD-a of one or more embodiments, the color filter layer CFL may be arranged on the light controlling layer CCL. For example, the color filter layer CFL may be arranged directly on the light controlling layer CCL. In this case, the barrier layer BFL2 may not be provided.

The color filter layer CFL may include filters CF1, CF2 and CF3. Each of the first to third filters CF1, CF2 and CF3 may be arranged corresponding to a red luminous area PXA-R, a green luminous area PXA-G, and a blue luminous area PXA-B, respectively.

The color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment or dye. The first filter CF1 may include a red pigment or dye, the second filter CF2 may include a green pigment or dye, and the third filter CF3 may include a blue pigment or dye.

One or more embodiments of the present disclosure is not limited to the preceding description, for example, the third filter CF3 may not include (e.g., may exclude) the pigment or dye. The third filter CF3 may include a polymer photosensitive resin and not include a pigment or dye. The third filter CF3 may be transparent. The third filter CF3 may be formed utilizing a transparent photosensitive resin.

In one or more embodiments, the first filter CF1 and the second filter CF2 may be yellow filters. The first filter CF1 and the second filter CF2 may be provided in one body without distinction.

In one or more embodiments, the color filter layer CFL may further include a light blocking part. The light blocking part may be a black matrix. The light blocking part may be formed by including an organic light blocking material or an inorganic light blocking material including a black pigment or black dye. The light blocking part may prevent or reduce light leakage phenomenon and divide the boundaries among adjacent filters CF1, CF2 and CF3.

On the color filter layer CFL, a base substrate BL may be arranged. The base substrate BL may be a member providing a base surface on which the color filter layer CFL, the light controlling layer CCL, and/or the like are arranged. The base substrate BL may be a glass substrate, a metal substrate, a plastic substrate, and/or the like. However, embodiments of the present disclosure are not limited thereto, and the base substrate BL may be an inorganic layer, an organic layer or a composite material layer. In one or more embodiments, the base substrate BL may not be provided.

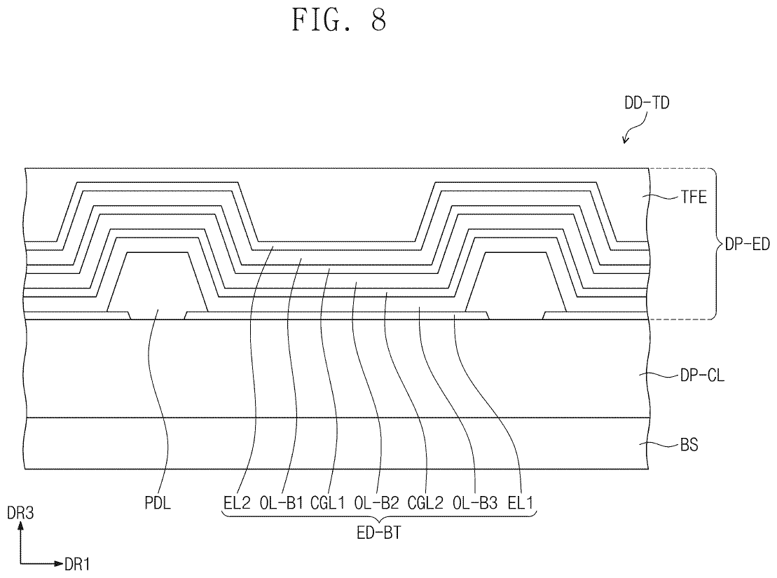

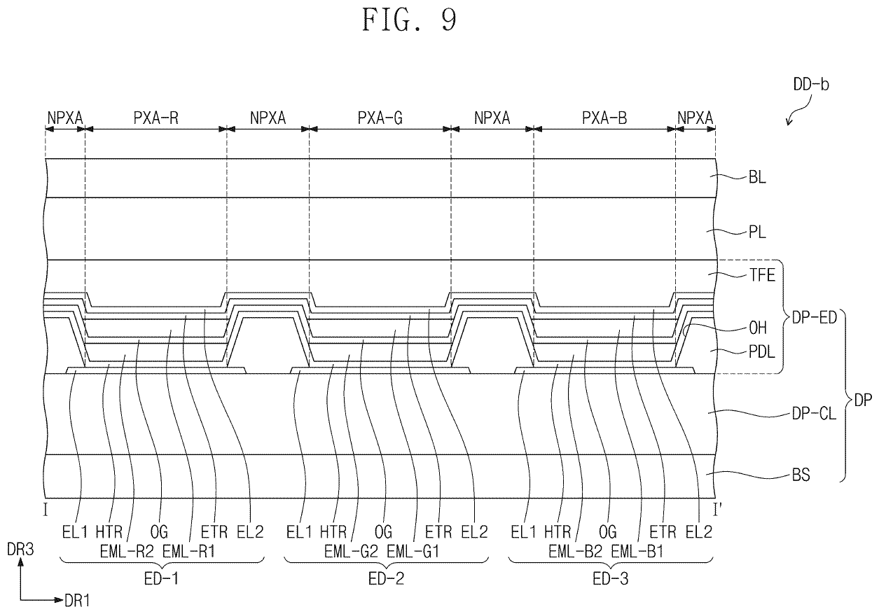

FIG. 8 is a cross-sectional view showing a portion of the display device according to one or more embodiments. In a display device DD-TD of one or more embodiments, the light emitting element ED-BT may include multiple light emitting structures OL-B1, OL-B2 and OL-B3. The light emitting element ED-BT may include oppositely arranged first electrode EL1 and second electrode EL2, and the multiple light emitting structures OL-B1, OL-B2 and OL-B3 stacked in order in a thickness direction and provided between the first electrode EL1 and the second electrode EL2.

Each of the light emitting structures OL-B1, OL-B2 and OL-B3 may include an emission layer EML (FIG. 7), and a hole transport region HTR and an electron transport region ETR arranged with the emission layer EML (FIG. 7) therebetween.

For example, the light emitting element ED-BT included in the display device DD-TD of one or more embodiments may be a light emitting element of a tandem structure including multiple emission layers.

In one or more embodiments shown in FIG. 8, light emitted from the light emitting structures OL-B1, OL-B2 and OL-B3 may be all blue light. However, one or more embodiments of the present disclosure is not limited thereto, and the wavelength regions of light emitted from the light emitting structures OL-B1, OL-B2 and OL-B3 may be different from each other. For example, the light emitting element ED-BT including the multiple light emitting structures OL-B1, OL-B2 and OL-B3 emitting light in different wavelength regions may be to emit white light.

Between neighboring light emitting structures OL-B1, OL-B2 and OL-B3, charge generating layers CGL1 and CGL2 may be arranged. The charge generating layers CGL1 and CGL2 may include a p-type or kind charge generating layer (e.g., p-charge generating layer) and/or an n-type or kind charge generating layer (e.g., n-charge generating layer).

At least one among the light emitting structures OL-B1, OL-B2, and OL-B3 included in the display device DD-TD of one or more embodiments may contain the herein-described fused polycyclic compound of one or more embodiments. For example, at least one among the plurality of emission layers included in the light emitting element ED-BT may include the fused polycyclic compound of one or more embodiments.

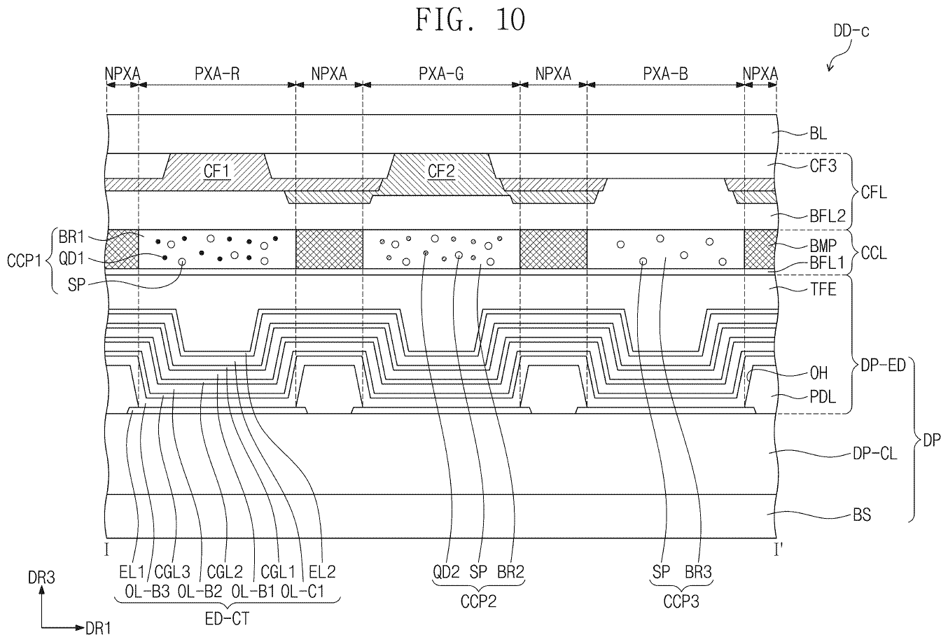

FIG. 9 is a cross-sectional view showing a display device according to one or more embodiments of the present disclosure. FIG. 10 is a cross-sectional view showing a display device according to one or more embodiments of the present disclosure.

Referring to FIG. 9, a display device DD-b according to one or more embodiments may include light emitting elements ED-1, ED-2 and ED-3, formed by stacking two emission layers. Compared to the display device DD of one or more embodiments, shown in FIG. 2, one or more embodiments shown in FIG. 9 is different in that first to third light emitting elements ED-1, ED-2 and ED-3 include two emission layers stacked in a thickness direction, each. In the first to third light emitting elements ED-1, ED-2 and ED-3, two emission layers may be to emit light in substantially the same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. In one or more embodiments, the third light emitting element ED-3 may include a first blue emission layer EML-B1 and a second blue emission layer EML-B2. Between the first red emission layer EML-R1 and the second red emission layer EML-R₂, between the first green emission layer EML-G1 and the second green emission layer EML-G2, and between the first blue emission layer EML-B1 and the second blue emission layer EML-B2, an emission auxiliary part OG may be arranged.

The emission auxiliary part OG may include a single layer or a multilayer. The emission auxiliary part OG may include a charge generating layer. More particularly, the emission auxiliary part OG may include an electron transport region, a charge generating layer, and a hole transport region stacked in order. The emission auxiliary part OG may be provided as a common layer in all of the first to third light emitting elements ED-1, ED-2 and ED-3. However, one or more embodiments of the present disclosure is not limited thereto, and the emission auxiliary part OG may be patterned and provided in an opening part OH defined in a pixel definition layer PDL.

The first red emission layer EML-R1, the first green emission layer EML-G1 and the first blue emission layer EML-B1 may be arranged between the electron transport region ETR and the emission auxiliary part OG. The second red emission layer EML-R2, the second green emission layer EML-G2 and the second blue emission layer EML-B2 may be arranged between the emission auxiliary part OG and the hole transport region HTR.

For example, the first light emitting element ED-1 may include a first electrode EL1, a hole transport region HTR, a second red emission layer EML-R2, an emission auxiliary part OG, a first red emission layer EML-R1, an electron transport region ETR, and a second electrode EL2, stacked in order. The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, stacked in order. The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, stacked in order.

In one or more embodiments, an optical auxiliary layer PL may be arranged on a display device layer DP-ED. The optical auxiliary layer PL may include a polarization layer. The optical auxiliary layer PL may be arranged on a display panel DP and may control reflected light at the display panel DP by external light. Different from the drawings, the optical auxiliary layer PL may not be provided from the display device according to one or more embodiments.

At least one emission layer included in the display device DD-b of one or more embodiments illustrated in FIG. 9 may include the herein-described fused polycyclic compound of one or more embodiments. For example, in one or more embodiments, at least one of the first blue emission layer EML-B1 or the second blue emission layer may include the fused polycyclic compound of one or more embodiments.

Different from FIG. 8 and FIG. 9, a display device DD-c in FIG. 10 is shown to include four light emitting structures OL-B1, OL-B2, OL-B3 and OL-C1. A light emitting element ED-CT may include oppositely arranged first electrode EL1 and second electrode EL2, and first to fourth light emitting structures OL-B1, OL-B2, OL-B3 and OL-C1 stacked in order in a thickness direction between the first electrode EL1 and the second electrode EL2. The third light emitting structures OL-B3, the second light emitting structures OL-B2, the first light emitting structures OL-B1, and the fourth light emitting structures OL-C1 are stacked in order in a thickness direction. Between the first to fourth light emitting structures OL-B1, OL-B2, OL-B3 and OL-C1, charge generating layers CGL1, CGL2 and CGL3 may be arranged. For example, A first charge generating layer CGL1 is arranged between the first light emitting structures OL-B1 and the fourth light emitting structures OL-C1. A second charge generating layer CGL2 is arranged between the first light emitting structures OL-B1 and the second light emitting structures OL-B2. A third charge generating layer CGL3 is arranged between the second light emitting structures OL-B2 and the third light emitting structures OL-B3.

Among the four light emitting structures, the first to third light emitting structures OL-B1, OL-B2 and OL-B3 emit blue light, and the fourth light emitting structure OL-C1 may be to emit green light. However, one or more embodiments of the present disclosure is not limited thereto, and the first to fourth light emitting structures OL-B1, OL-B2, OL-B3 and OL-C1 may be to emit different wavelengths of light.

Charge generating layers CGL1, CGL2 and CGL3 arranged among neighboring light emitting structures OL-B1, OL-B2, OL-B3 and OL-C1 may include a p-type or kind charge generating layer and/or an n-type or kind charge generating layer.

At least one among the light emitting structures OL-B1, OL-B2, OL-B3, and OL-C1 included in the display device DD-c of one or more embodiments may include the herein-described fused polycyclic compound of one or more embodiments. For example, in one or more embodiments, at least one among the first to third light emitting structures OL-B1, OL-B2, and OL-B3 may include the described fused polycyclic compound of one or more embodiments.

The light emitting element ED according to one or more embodiments of the present disclosure may include the herein-described polycyclic compound represented by Formula 1 of one or more embodiments in at least one functional layer arranged between the first electrode EL1 and the second electrode EL2, thereby exhibiting excellent or suitable luminous efficiency and improved service life characteristics. For example, the polycyclic compound according to one or more embodiments may be included in the emission layer EML of the light emitting element ED of one or more embodiments, and the light emitting element of one or more embodiments may exhibit a long service life characteristic.

In one or more embodiments, an electronic apparatus may include a display device including multiple light emitting elements and a control part controlling the display device. The electronic apparatus of one or more embodiments may be an apparatus activated according to electrical signals. The electronic apparatus may include display devices of one or more suitable embodiments. Examples of the electronic apparatus may include televisions, monitors, large-size display devices such as outside billboards, personal computers, laptop computers, personal digital terminals, display devices for automobiles, game consoles, portable electronic devices, medium- and small-size display devices such as cameras.

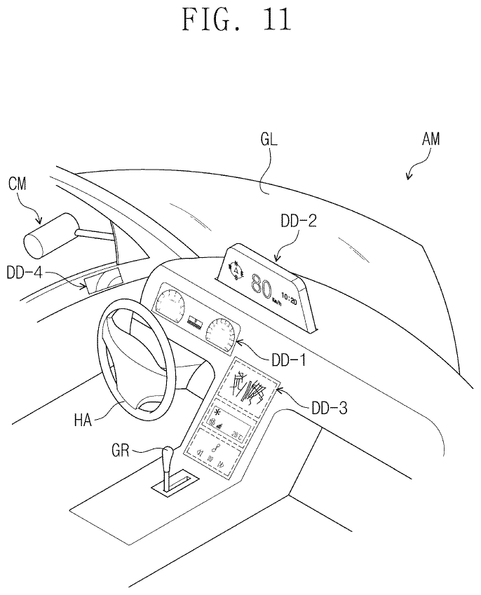

FIG. 11 is a diagram showing an automobile AM in which first to fourth display devices DD-1, DD-2, DD-3 and DD-4 are arranged. At least one selected from among the first to fourth display devices DD-1, DD-2, DD-3 and DD-4 may include the same configurations of the display devices DD, DD-TD, DD-a, DD-b and DD-c of embodiments, explained referring to FIGS. 1, 2, and 7 to 10.

In FIG. 11, a vehicle is shown as an automobile AM, but this is an illustration, and the first to fourth display devices DD-1, DD-2, DD-3 and DD-4 may be arranged on other transport refers to such as bicycles, motorcycles, trains, ships and airplanes. In one or more embodiments, at least one among the first to fourth display devices DD-1, DD-2, DD-3 and DD-4 including the same configurations of the display devices DD, DD-TD, DD-a, DD-b and DD-c may be introduced in personal computers, laptop computers, personal digital terminals, game consoles, portable electronic devices, televisions, monitors, external billboards, and/or the like. In one or more embodiments, these are suggested as examples, and the display device may be introduced in other electronic devices as long as not deviated from the present disclosure.

At least one selected from among the first to fourth display devices DD-1, DD-2, DD-3, and DD-4 may include the light emitting element ED of one or more embodiments as described with reference to FIGS. 3 to 6. The light emitting element ED of one or more embodiments may include a fused polycyclic compound of one or more embodiments. At least one selected from among the first to fourth display devices DD-1, DD-2, DD-3, and DD-4 may include the light emitting element ED including the fused polycyclic compound of one or more embodiments, thereby improving a display service life.

Referring to FIG. 11, an automobile AM may include a steering wheel HA for the operation of the automobile AM and a gear GR. In one or more embodiments, the automobile AM may include a front window GL arranged to face a driver.

A first display device DD-1 may be arranged in a first region overlapping with the steering wheel HA. For example, the first display device DD-1 may be a digital cluster displaying the first information of the automobile AM. The first information may include a first graduation showing the running speed of the automobile AM, a second graduation showing the number of revolution of an engine (i.e., revolutions per minute (RPM)), and images showing a fuel state. First graduation and second graduation may be represented by digital images.

A second display device DD-2 may be arranged in a second region facing a driver's seat and overlapping with the front window GL. The driver's seat may be a seat where the steering wheel HA is arranged. For example, the second display device DD-2 may be a head up display (HUD) showing the second information of the automobile AM. The second display device DD-2 may be optically clear. The second information may include digital numbers showing the running speed of the automobile AM and may further include information including the current time. Different from the drawing, the second information of the second display device DD-2 may be projected and displayed on the front window GL.

A third display device DD-3 may be arranged in a third region adjacent to the gear GR. For example, the third display device DD-3 may be a center information display (CID) for an automobile, arranged between a driver's seat and a passenger seat and showing third information. The passenger seat may be a seat separated from the driver's seat with the gear GR therebetween. The third information may include information on road conditions (for example, navigation information), on playing music or radio, on playing a dynamic image (or image), on the temperature in the automobile AM, and/or the like.

A fourth display device DD-4 may be arranged in a fourth region separated from the steering wheel HA and the gear GR and adjacent to the side of the automobile AM. For example, the fourth display device DD-4 may be a digital wing mirror displaying fourth information. The fourth display device DD-4 may display the external image of the automobile AM, taken by a camera module CM arranged at the outside of the automobile AM. The fourth information may include the external image of the automobile AM.

The herein-described first to fourth information is for illustration, and the first to fourth display devices DD-1, DD-2, DD-3 and DD-4 may further display information on the inside and outside of the automobile. The first to fourth information may include different information from each other. However, one or more embodiments of the present disclosure is not limited thereto, and a portion of the first to fourth information may include the same information.

Hereinafter, with reference to Examples and Comparative Examples, a fused polycyclic compound according to one or more embodiments of the present disclosure and a light emitting element of one or more embodiments will be described in more detail. In one or more embodiments, the following Examples described are only illustrations to assist the understanding of the present disclosure, and the scope of the present disclosure is not limited thereto.

### Examples

### 1. Synthesis of Fused Polycyclic Compound

First, a synthetic method of the fused polycyclic compound according to one or more embodiments will be particularly described by illustrating the synthetic methods of Compounds 2, 3, 64, 71, 81, 88, 99, 103, 106, 107, and 111. In one or more embodiments, the synthetic methods of the fused polycyclic compounds as described are only examples, and the synthetic method of the fused polycyclic compound according to one or more embodiments of the present disclosure is not limited to the following examples.

### (1) Synthesis of Compound 2

Fused polycyclic compound 2 according to one or more embodiments may be synthesized by, for example, the following reaction.

### Synthesis of Intermediate 2-a

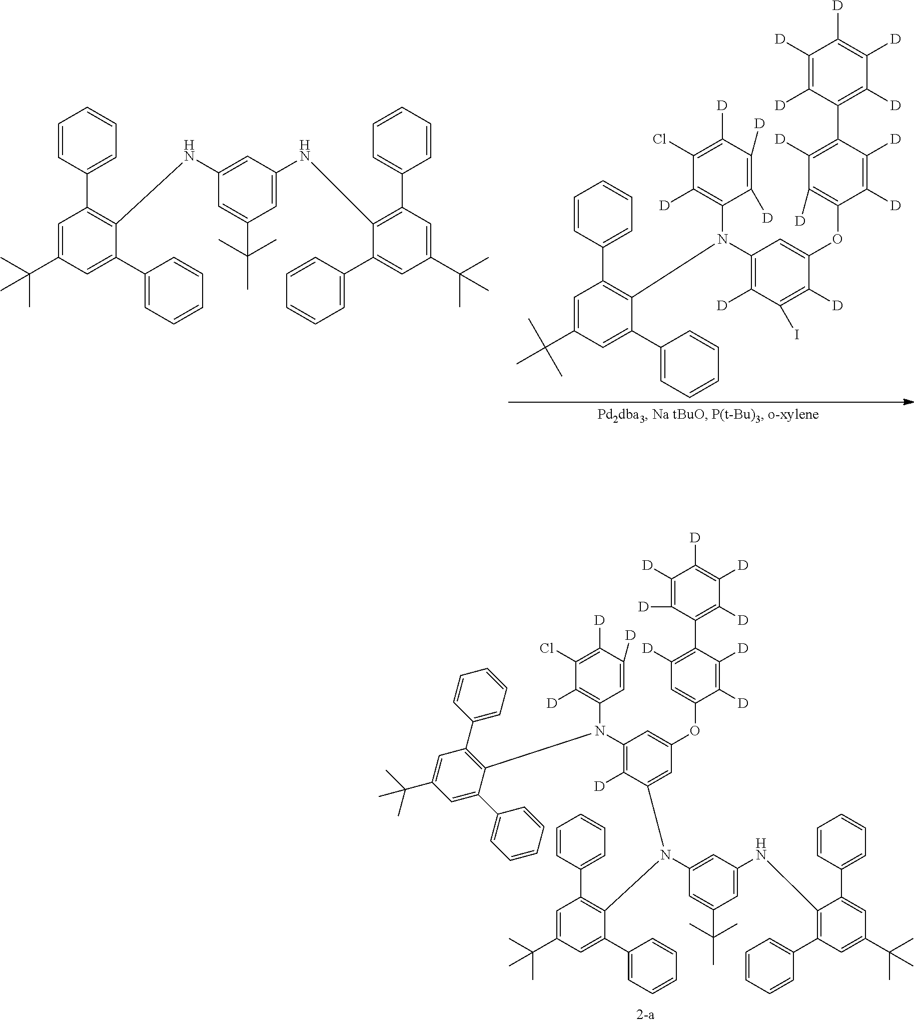

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13.5 millimole (mmol)), N-(3-(([1,1′-biphenyl]-4-yl-d9)oxy)-5-iodophenyl-4,6-d2)-5′-(tert-butyl)-N-(3-chlorophenyl-2,4,5,6-d4)-[1,1′:3′,1″-terphenyl]-2′-amine (10.0 g, 13.5 mmol), Pd₂dba₃ (1.6 g, 1.9 mmol), tris-tert-butyl phosphine (P(t-Bu)₃) (1.6 mL, 3.8 mmol), and sodium tert-butoxide (NatBuO) (11.5 g, 120 mmol) were added and dissolved in 300 milliliter (mL) of o-xylene, and then the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 2-a (white solid, 12 g, yield: 64%).

ESI-LCMS of Intermediate 2-a: [M]⁺: C₁₀₀H₈₀D₁₂ClN₃O. 1397.7077.

### Synthesis of Intermediate 2-b

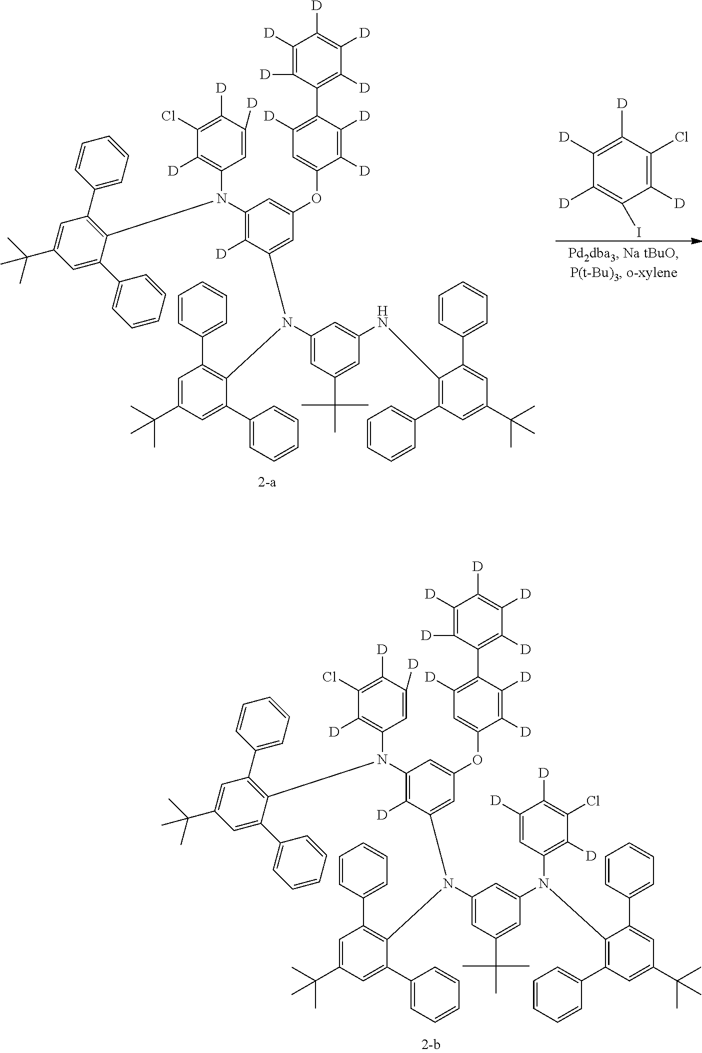

In an argon atmosphere, to a 1-L flask, Intermediate 2-a (12 g, 8.5 mmol), 1-chloro-3-iodobenzene-2,4,5,6-d4 (2.1 g, 8.5 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 2-b (white solid, 9.4 g, yield: 73%).

ESI-LCMS of Intermediate 2-b: [M]⁺: C₁₀₆H₈₀D₁₅Cl₂N₃O. 1510.7811.

### Synthesis of Intermediate 2-c

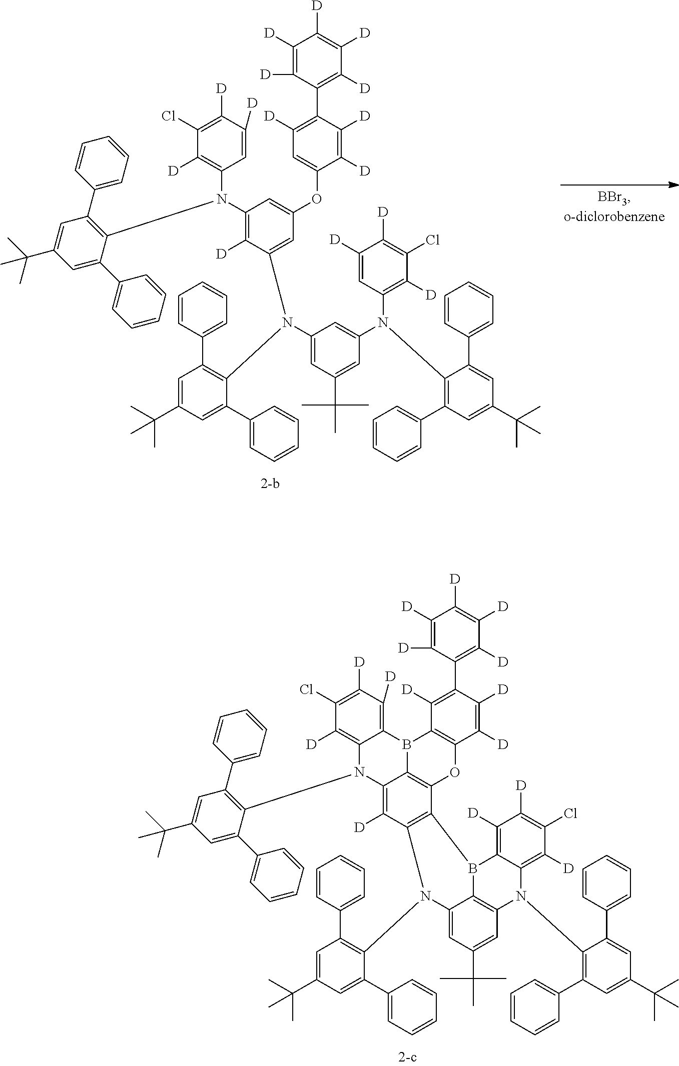

In an argon atmosphere, to a 1-L flask, Intermediate 2-b (9 g, 6 mmol) was added and dissolved in 100 mL of o-dichlorobenzene, and then BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography utilizing CH₂Cl₂ and hexane as eluent to Intermediate 2-c (yellow solid, 2.1 g, yield: 23%).

ESI-LCMS of Intermediate 2-c: [M]⁺: C₁₀₆H₇₄D₁₅B₂Cl₂N₃O. 1526.7511 Synthesis of Compound 2

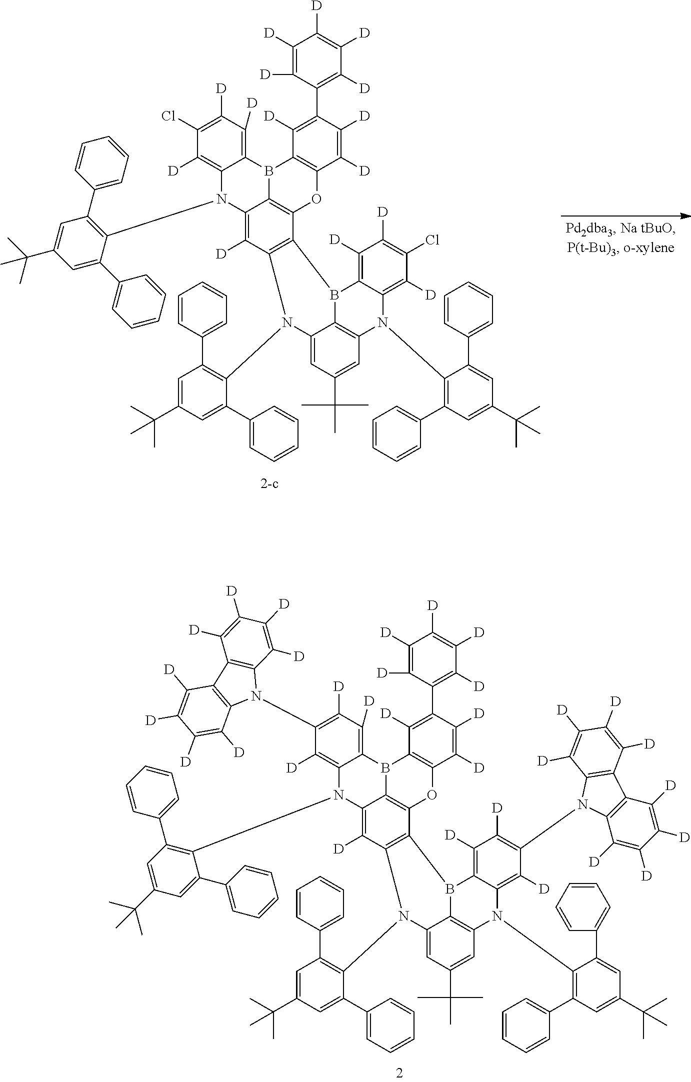

In an argon atmosphere, to a 1-L flask, Intermediate 2-c (2.1 g, 1.4 mmol), 9H-carbazole-1,2,3,4,5,6,7,8-d8 (0.46 g, 2.8 mmol), Pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of o-xylene, and the reaction solution was stirred at about 140° C. for about 12 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Compound 2 (yellow solid, 1.8 g, yield: 71%).

ESI-LCMS of Compound 2: [M]⁺: C₁₃₀H₇₄D₃₁B₂N₅O. 1805.0501

¹H-NMR (CDCl₃) of Compound 2: d=7.44 (s, 6H), 7.22 (m, 18H), 7.05 (m, 12H), 6.92 (s, 2H), 1.32 (s, 18H), 1.28 (s, 9H), 1.14 (s, 9H)

### (2) Synthesis of Compound 3

Fused polycyclic compound 3 according to one or more embodiments may be synthesized by, for example, the following reaction.

### Synthesis of Intermediate 3-a

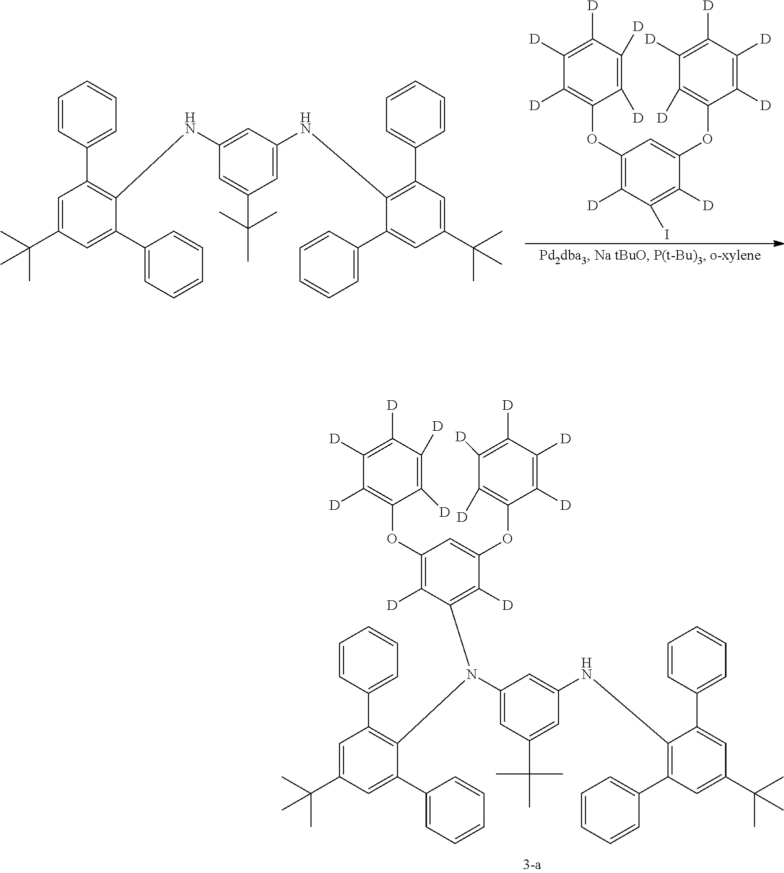

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13.5 mmol), 1,1′-((5-iodo-1,3-phenylene-4,6-d2)bis(oxy))bis(benzene-2,3,4,5,6-d5) (5.4 g, 13.5 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and then the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 3-a (white solid, 8.3 g, yield: 61%).

ESI-LCMS of Intermediate 3-a: [M]⁺: C₇₂H₅₆D₁₂N₂O₂. 1004.6004.

### Synthesis of Intermediate 3-b

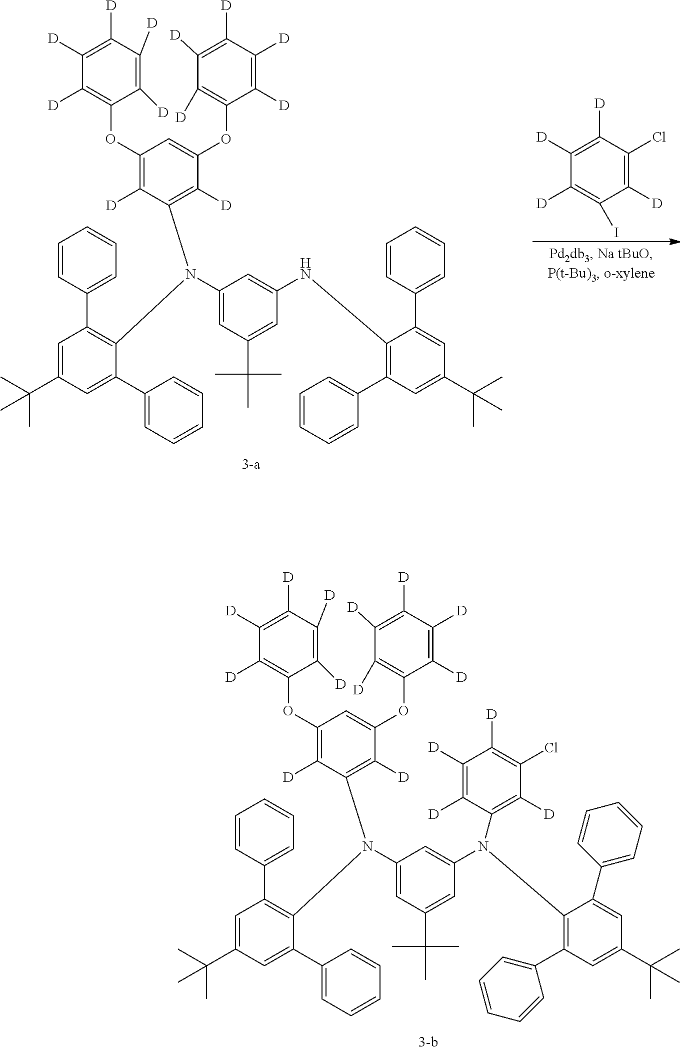

In an argon atmosphere, to a 2-L flask, Intermediate 3-a (8.3 g, 8.3 mmol), 1-chloro-3-iodobenzene-2,4,5,6-d4 (2.1 g, 8.5 mmol), Pd₂dba₃ (1.6 g, 1.9 mmol), tris-tert-butyl phosphine (1.6 mL, 3.8 mmol), and sodium tert-butoxide (10.5 g, 120 mmol) were added and dissolved in 300 mL of o-xylene, and the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 3-b (white solid, 7 g, yield: 70%).

ESI-LCMS of Intermediate 3-b: [M]⁺: C₇₇H₅₅D₁₆ClN₂O₂. 1118.6212.

### Synthesis of Intermediate 3-c

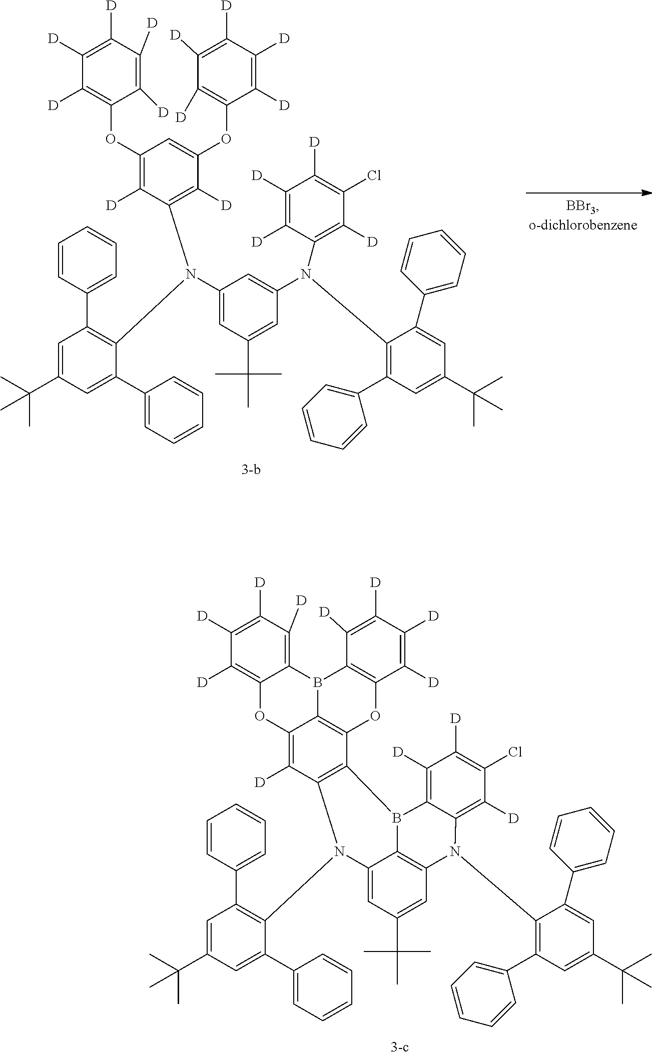

In an argon atmosphere, to a 1-L flask, Intermediate 3-b (7 g, 6.3 mmol) was added and dissolved in 100 mL of o-dichlorobenzene, and then BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography utilizing CH₂Cl₂ and hexane as eluent to Intermediate 3-c (yellow solid, 1.8 g, yield: 25%).

ESI-LCMS of Intermediate 3-c: [M]⁺: C₇₈H₅₃D₁₂B₂ClN₂O₂. 1130.5057 Synthesis of Compound 3

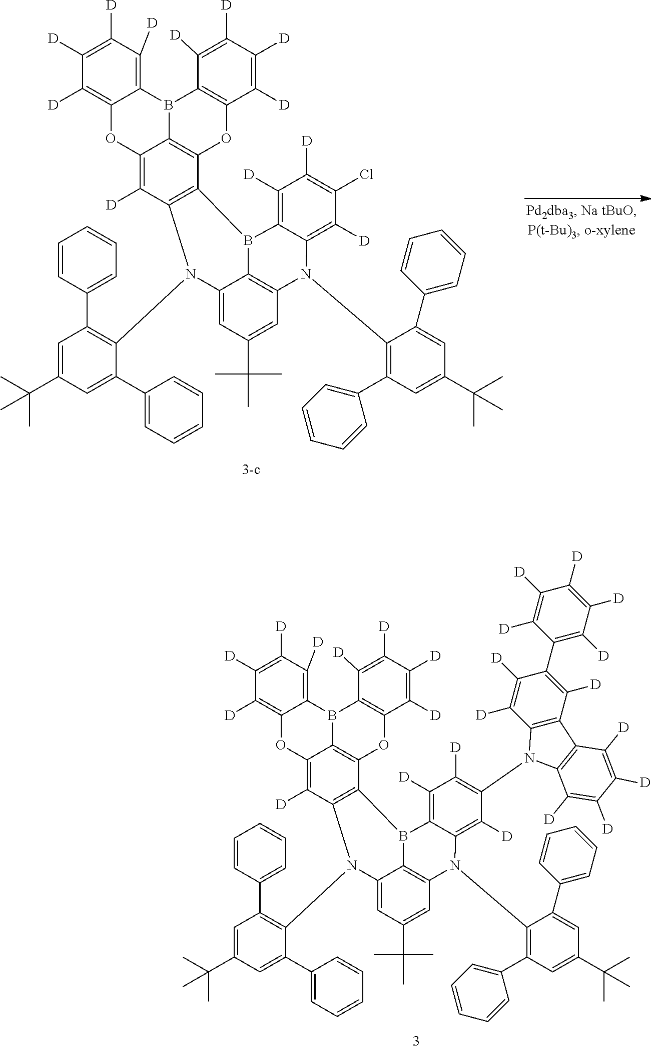

In an argon atmosphere, to a 1-L flask, Intermediate 3-c (1.8 g, 1.6 mmol), 9H-carbazole-1,2,3,4,5,6,7,8-d8 (0.46 g, 2.8 mmol), Pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of o-xylene, and the reaction solution was stirred at about 140° C. for about 12 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Compound 3 (yellow solid, 1.7 g, yield: 81%).

ESI-LCMS of Compound 3: [M]⁺: C₉₆H₅₃D₂₄B₂N₃O₂. 1349.7114

¹H-NMR (CDCl₃) of Compound 3: d=7.43 (s, 4H), 7.27 (m, 12H), 7.08 (m, 8H), 6.88 (s, 2H), 1.32 (s, 18H), 1.28 (s, 9H)

### (3) Synthesis of Compound 64

Fused Polycyclic Compound 64 according to an example may be synthesized by, for example, the following reaction.

### Synthesis of Intermediate 64-a

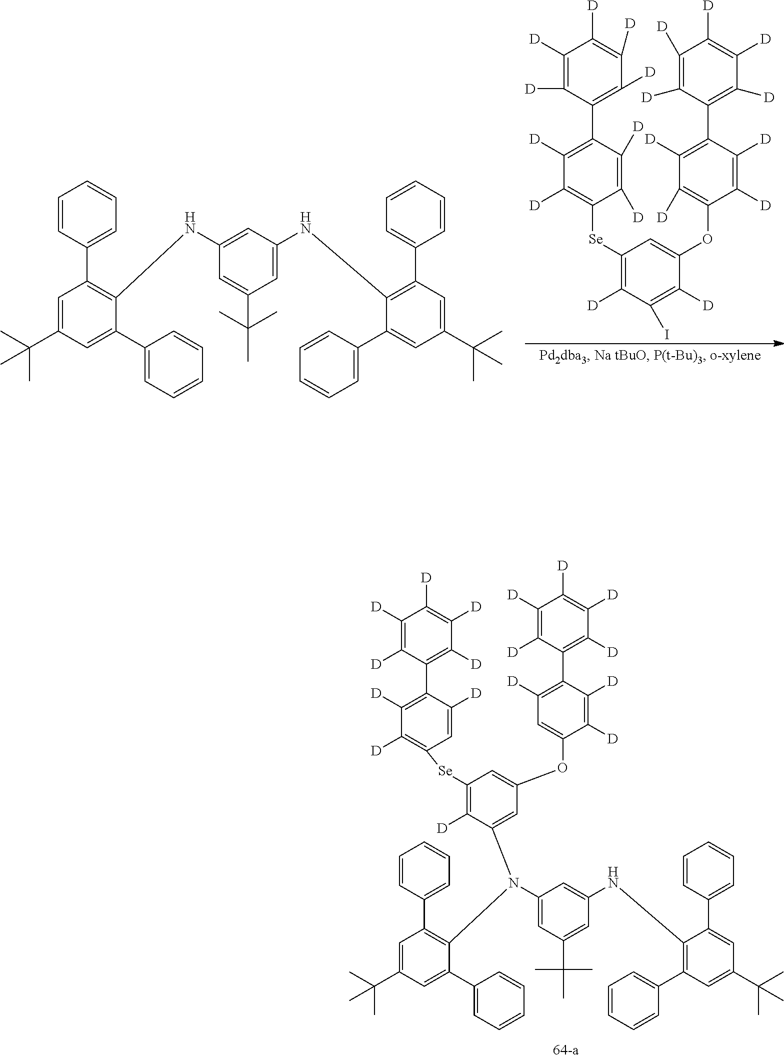

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13.5 mmol), ([1,1′-biphenyl]-4-yl-d9)(3-(([1,1′tert-butyl)-[1,1′:3′,1″-terphenyl]-2′-yl)benzene-1,3-diamine (10 g, 13.5 mmol), ([1,1′-biphenyl]-4-yl-d9)(3-(([1,1′d9)(3-(([1,1′-biphenyl]-4-yl-d9)oxy)-5-iodophenyl-4,6-d2)selane (8.4 g, 13.5 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and then the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 64-a (white solid, 10.7 g, yield: 65%).

ESI-LCMS of Intermediate 64-a: [M]⁺: C₈₄H₅₉D₁₇N₂OSe. 1225.0627.

### Synthesis of Intermediate 64-b

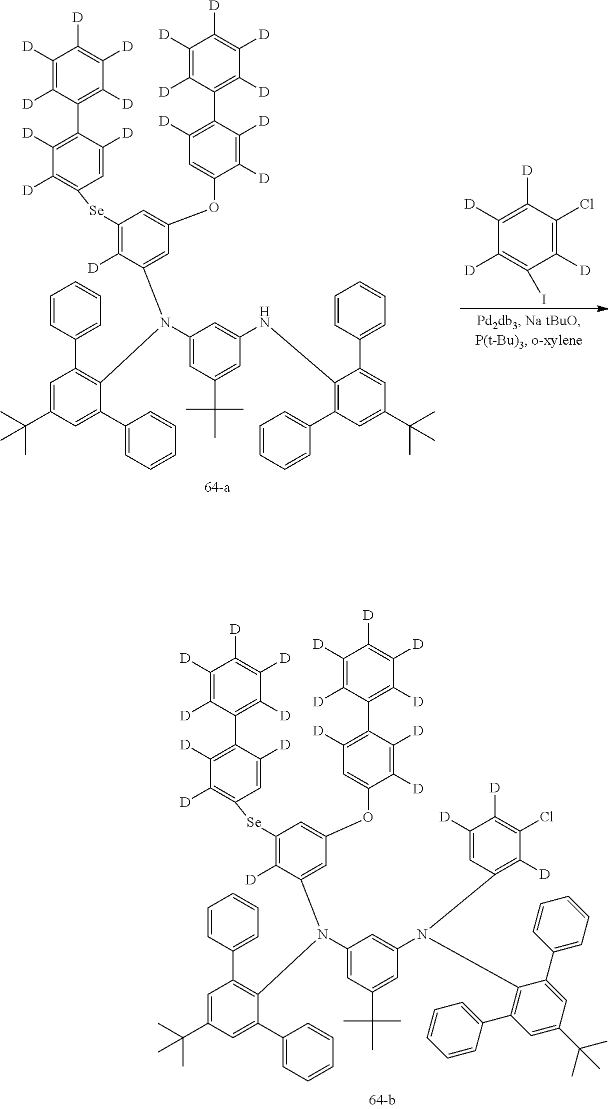

In an argon atmosphere, to a 2-L flask, Intermediate 64-a (10.7 g, 8.3 mmol), 1-chloro-3-iodobenzene-2,4,5,6-d4 (2.1 g, 8.5 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and then the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 64-b (white solid, 8.1 g, yield: 73%).

ESI-LCMS of Intermediate 64-b: [M]⁺: C₉₀H₅₉D₂₀ClN₂OSe. 1338.6313.

### Synthesis of Intermediate 64-c

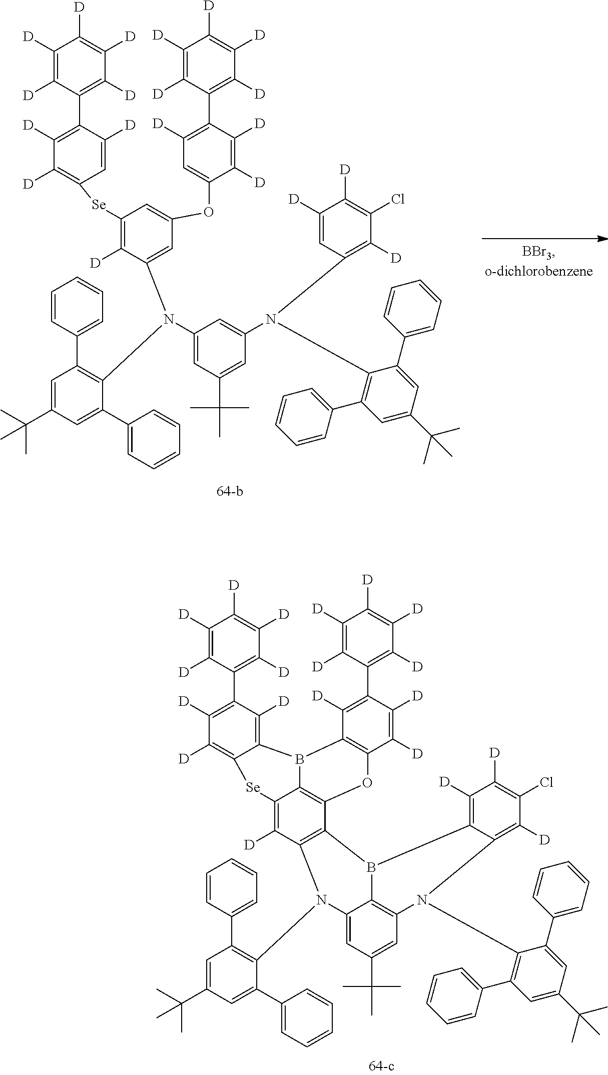

In an argon atmosphere, to a 1-L flask, Intermediate 64-b (8 g, 6.3 mmol) was added and dissolved in 100 mL of o-dichlorobenzene, and then BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography utilizing CH₂Cl₂ and hexane as eluent to Intermediate 64-c (yellow solid, 1.86 g, yield: 23%).

ESI-LCMS of Intermediate 64-c: [M]⁺: C₉₀H₅₃D₂₀B₂ClN₂OSe. 1354.6061

### Synthesis of Compound 64

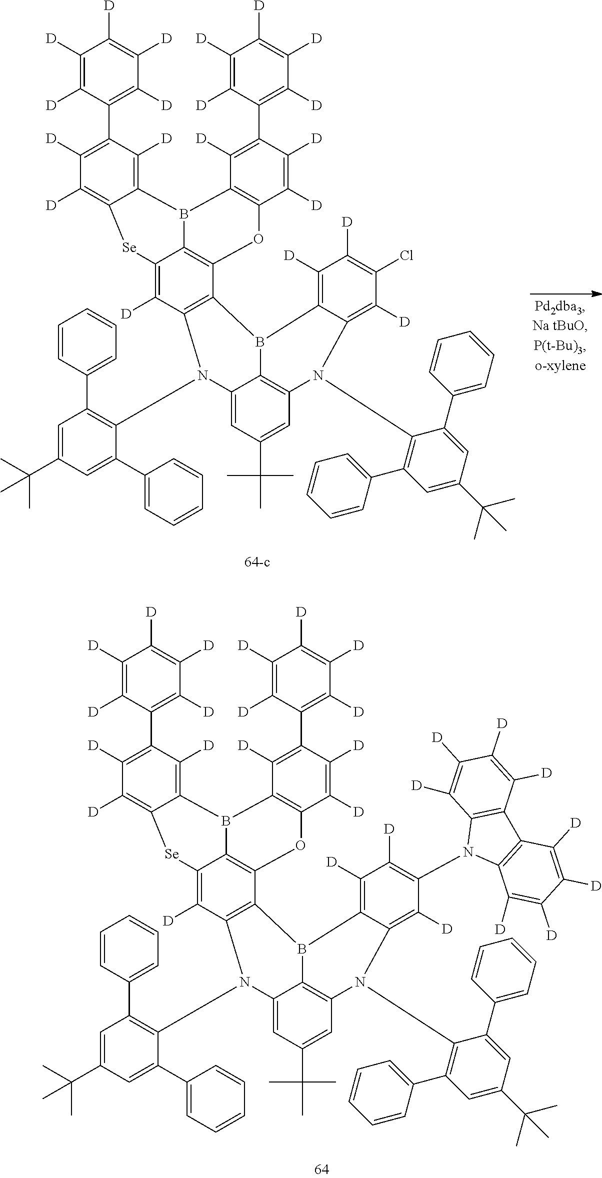

In an argon atmosphere, to a 1-L flask, Intermediate 64-c (1.8 g, 1.3 mmol), 9H-carbazole-1,2,3,4,5,6,7,8-d8 (0.22 g, 1.3 mmol), Pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of o-xylene, and then the reaction solution was stirred at about 140° C. for about 12 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Compound 64 (yellow solid, 1.5 g, yield: 78%).

ESI-LCMS of Compound 64: [M]⁺: C₁₀₂H₅₃D₂₈B₂N3OSe. 1493. 7554

¹H-NMR (CDCl₃) of Compound 64: d=7.47 (s, 4H), 7.23 (m, 12H), 7.03 (m, 8H), 6.85 (s, 2H), 1.38 (s, 18H), 1.14 (s, 9H)

### (4) Synthesis of Compound 71

Fused polycyclic compound 71 according to one or more embodiments may be synthesized by, for example, the following reaction.

### Synthesis of Intermediate 71-a

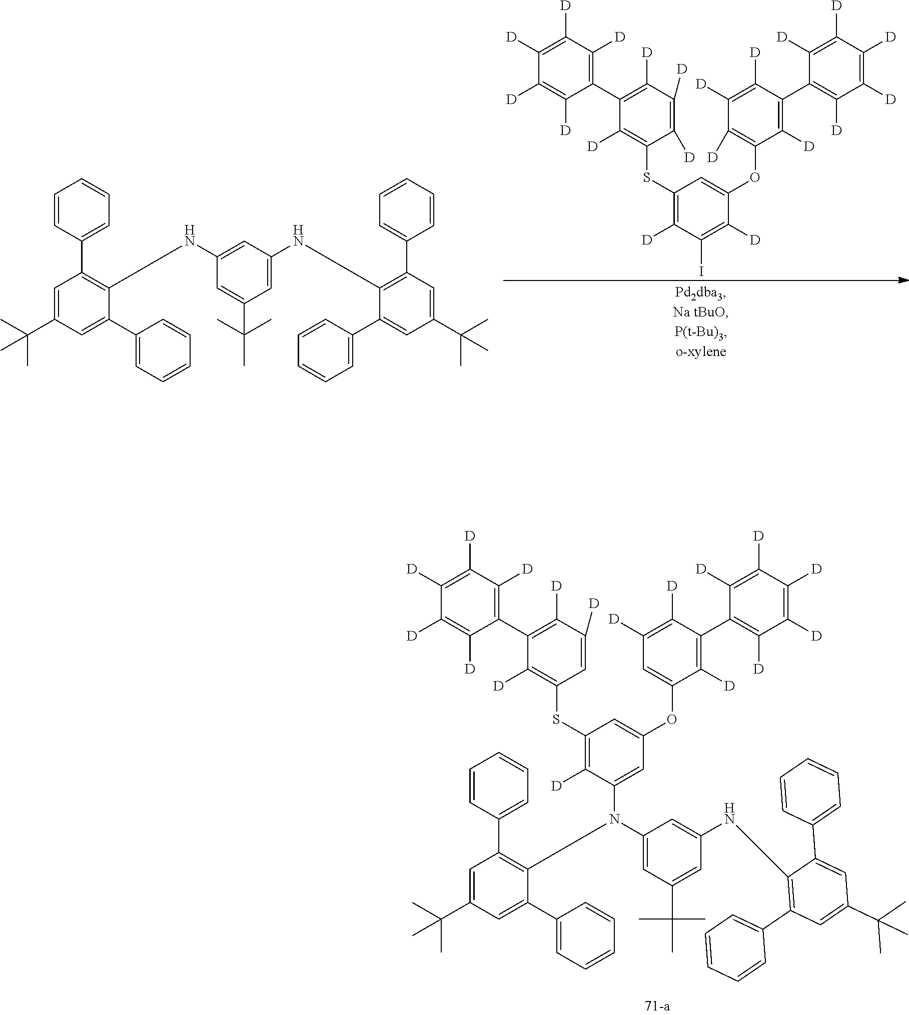

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13.5 mmol), ([1,1′-biphenyl]-3-yl-d9)(3-(([1,1′tert-butyl)-[1,1′:3′,1″-terphenyl]-2′-yl)benzene-1,3-diamine (10 g, 13.5 mmol), ([1,1′-biphenyl]-3-yl-d9)(3-(([1,1′d9)(3-(([1,1′-biphenyl]-4-yi-d9)oxy)-5-iodophenyl-4,6-d2)sulfane (7.8 g, 13.5 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and then the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 71-a (white solid, 11 g, yield: 70%).

ESI-LCMS of Intermediate 71-a: [M]⁺: C₈₄H₅₉D₁₇N₂OS. 1177.7167.

### Synthesis of Intermediate 71-b

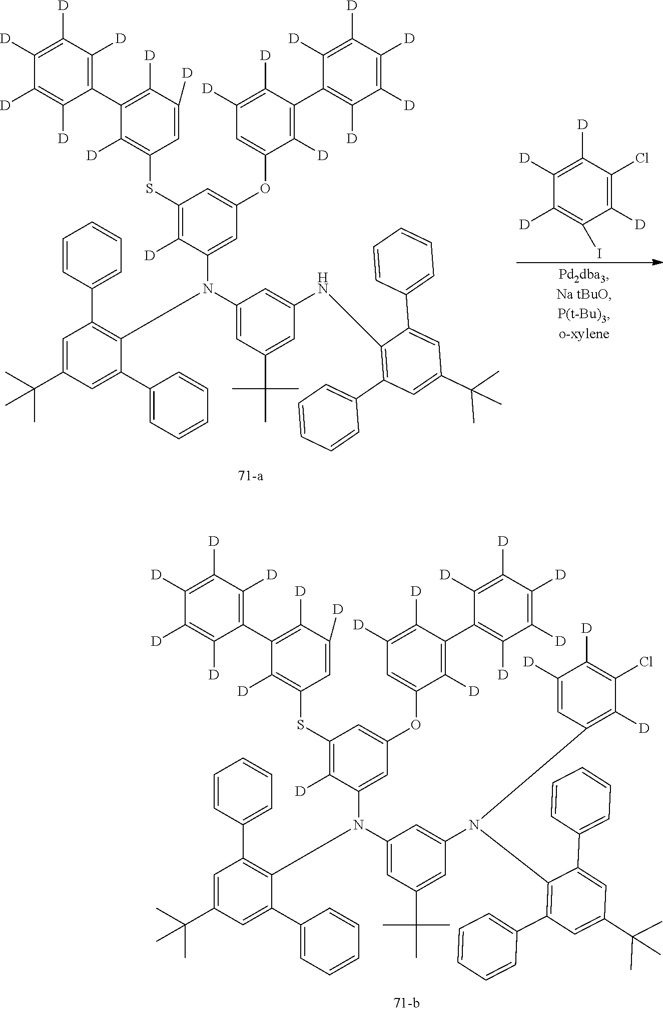

In an argon atmosphere, to a 2-L flask, Intermediate 71-a (11 g, 9.3 mmol), 1-chloro-3-iodobenzene-2,4,5,6-d4 (2.3 g, 9.3 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and then the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 71-b (white solid, 8.6 g, yield: 72%).

ESI-LCMS of Intermediate 71-b: [M]⁺: C₉₀H₅₉D₂₀ClN₂OS. 1290.6912.

### Synthesis of Intermediate 71-c

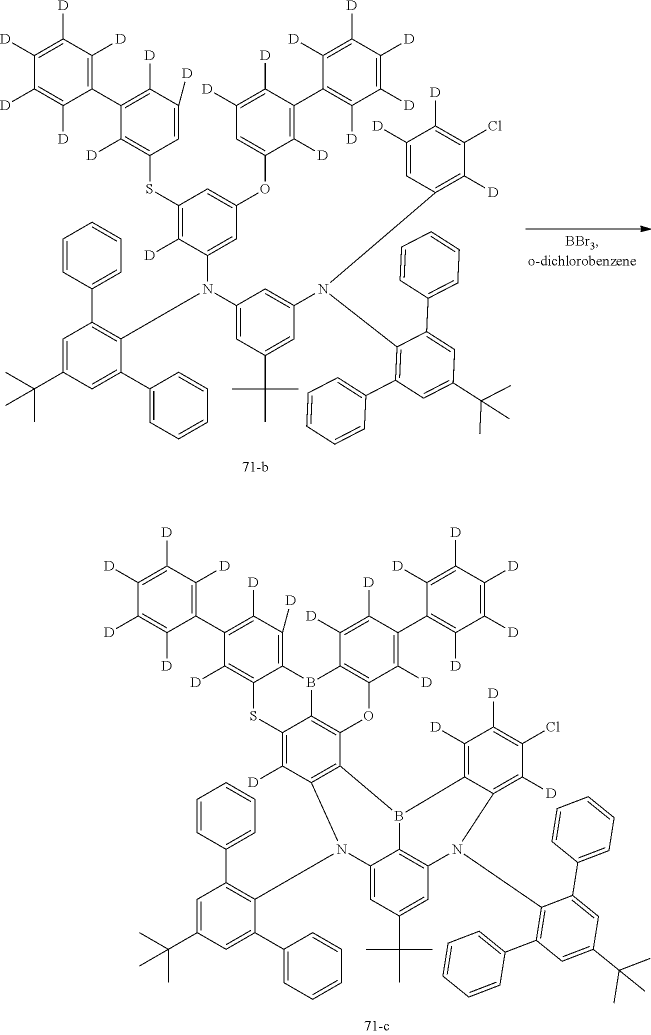

In an argon atmosphere, to a 1-L flask, Intermediate 71-b (8.6 g, 6.6 mmol) was added and dissolved in 100 mL of o-dichlorobenzene, and then BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography utilizing CH₂Cl₂ and hexane as eluent to Intermediate 71-c (yellow solid, 1.9 g, yield: 22%).

ESI-LCMS of Intermediate 71-c: [M]⁺: C₉₀H₅₃D₂₀B₂ClN₂OS. 1306.6114

### Synthesis of Compound 71

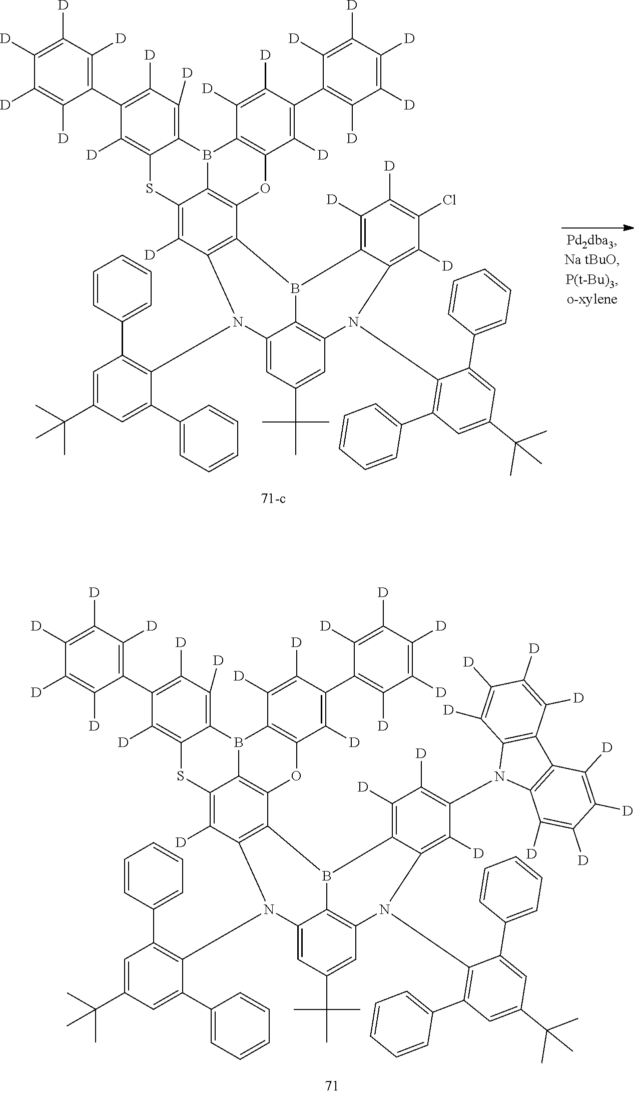

In an argon atmosphere, to a 1-L flask, Intermediate 71-c (1.9 g, 1.45 mmol), 9H-carbazole-1,2,3,4,5,6,7,8-d8 (0.25 g, 1.5 mmol), Pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of o-xylene, and then the reaction solution was stirred at about 140° C. for about 12 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Compound 71 (yellow solid, 1.5 g, yield: 73%).

ESI-LCMS of Compound 71: [M]⁺: C₁₀₂H₅₃D₂₈B₂N₃OS. 1445.8084

¹H-NMR (CDCl₃) of Compound 71: d=7.46 (s, 4H), 7.25 (m, 12H), 7.06 (m, 8H), 6.89 (s, 2H), 1.39 (s, 18H), 1.18 (s, 9H)

### (5) Synthesis of Compound 81

Fused Polycyclic Compound 81 according to an example may be synthesized, for example, by the following reaction.

### Synthesis of Intermediate 81-a

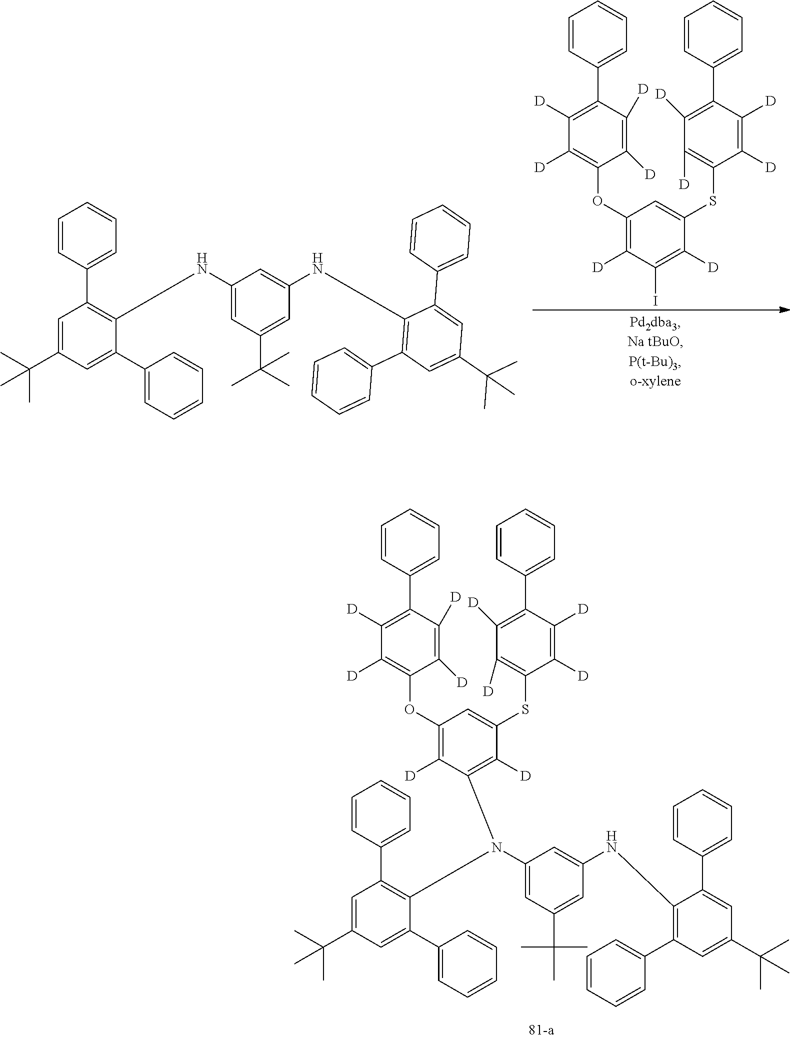

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13.5 mmol), ([1,1′-biphenyl]-4-yl-2,3,5,6-d4)(3-(([1,1′tert-butyl)-[1,1′:3′,1″-terphenyl]-2′-yl)benzene-1,3-diamine (10 g, 13.5 mmol), ([1,1′-biphenyl]-4-yl-2,3,5,6-d4)(3-(([1,1′d4)(3-(([1,1′-biphenyl]-4-yl-2,3,5,6-d4)oxy)-5-iodophenyl-4,6-d2)sulfane (7.6 g, 13.5 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and then the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 81-a (white solid, 11 g, yield: 74%).

ESI-LCMS of Intermediate 81-a: [M]⁺: C₈₄H₆₆D₁₀N₂OS. 1170.6364.

### Synthesis of Intermediate 81-b

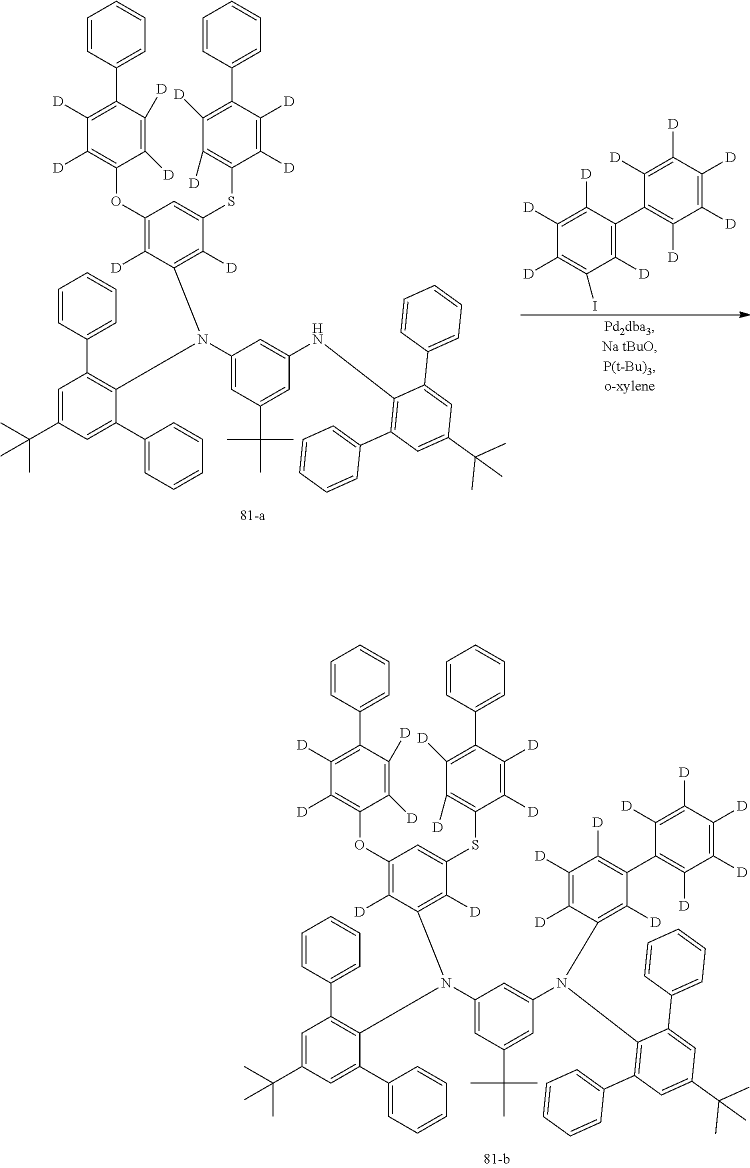

In an argon atmosphere, to a 2-L flask, Intermediate 81-a (11 g, 9.4 mmol), 3-iodo-1,1′-biphenyl-2,2′,3′,4,4′,5,5′,6,6′-d9 (2.7 g, 9.4 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and then the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 81-b (white solid, 9.4 g, yield: 75%).

ESI-LCMS of of Intermediate 81-b: [M]⁺: C₉₆H₆₆D₁₈N₂OS. 1330.7074.

### Synthesis of Compound 81

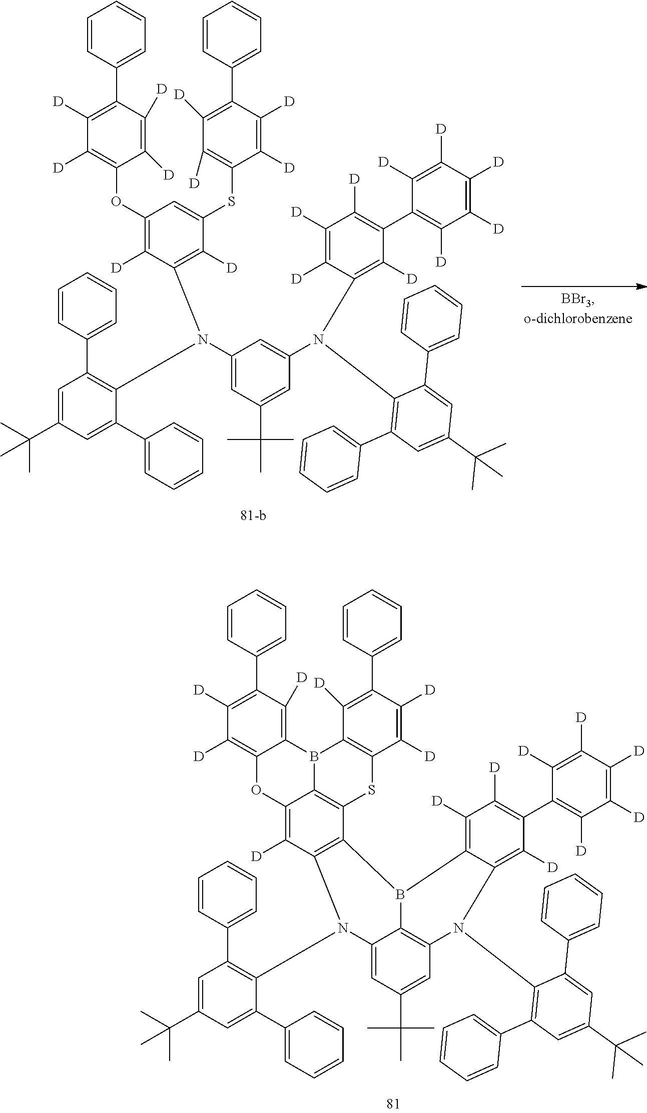

In an argon atmosphere, to a 1-L flask, Intermediate 81-b (9.4 g, 7 mmol) was added and dissolved in 100 mL of o-dichlorobenzene, and then BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid.

The solid thus obtained was purified and separated by silica gel column chromatography utilizing CH₂Cl₂ and hexane as eluent to obtain Compound 81 (yellow solid, 2.37 g, yield: 25%).

ESI-LCMS of Compound 81: [M]⁺: C₉₆H₆₃D₁₅B₂N₂OS. 1343.1718

¹H-NMR (CDCl₃) of Compound 81: d=7.52 (m, 10H), 7.43 (s, 4H), 7.21 (m, 12H), 7.01 (m, 8H), 6.83 (s, 2H), 1.44 (s, 18H), 1.22 (s, 9H)

### (6) Synthesis of Compound 88

Fused Polycyclic Compound 88 according to an example may be synthesized, for example, by the following reaction.

### Synthesis of Intermediate 88-a

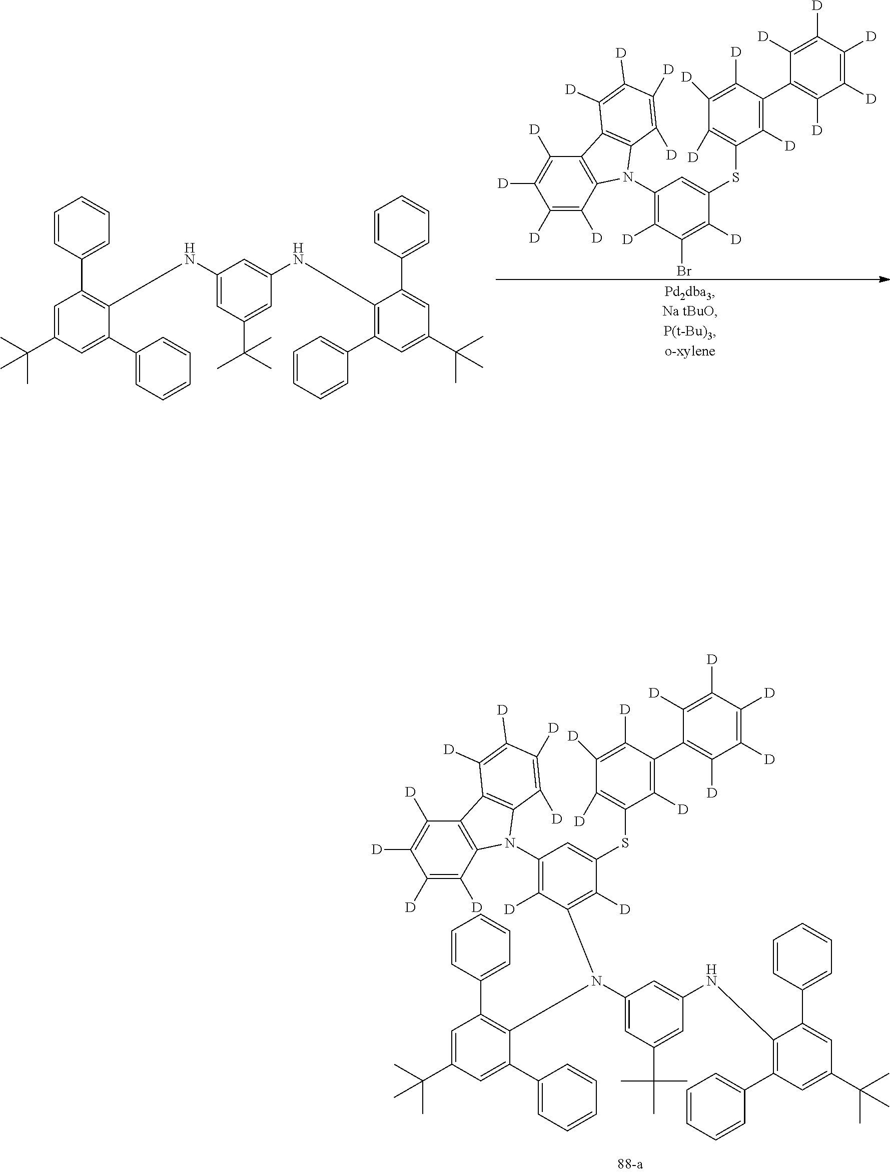

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13.5 mmol), 9-(3-(([1,1′-biphenyl]-3-yl-d9)thio)-5-bromophenyl-4,6-d2)-9H-carbazole-1,2,3,4,5,6,7,8-d8 (7.1 g, 13.5 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and then the reaction solution was stirred at about 1400° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 88-a (white solid, 10.8 g, yield: 68%).

ESI-LCMS of Intermediate 88-a: [M]⁺: C₈₄H₅₆D₁₉N₃S. 1176.0069.

### Synthesis of Intermediate 88-b

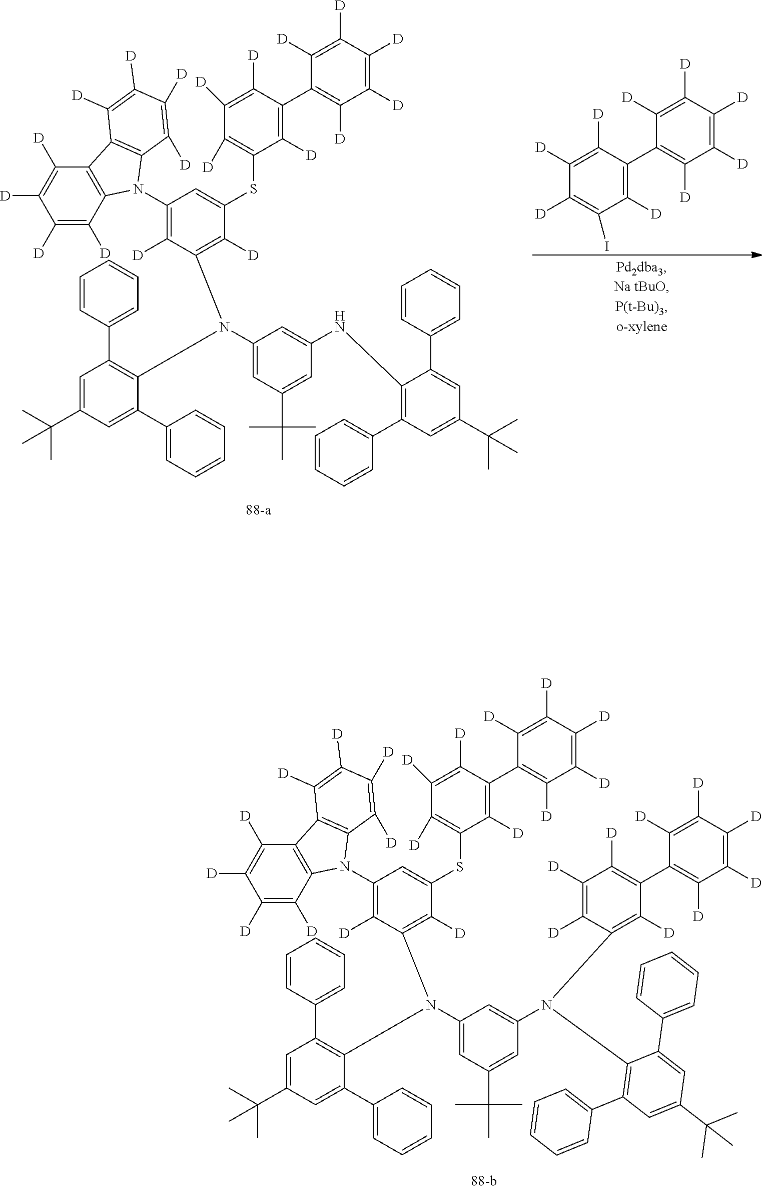

In an argon atmosphere, to a 2-L flask, Intermediate 88-a (10.8 g, 9.2 mmol), 3-iodo-1,1′-biphenyl-2,2′,3′,4,4′,5,5′,6,6′-d9 (2.7 g, 9.2 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and then the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 88-b (white solid, 9.5 g, yield: 77%).

ESI-LCMS of Intermediate 88-b: [M]⁺: C₉₆H₅₅D₂₈N₃S. 1337.8121.

### Synthesis of Compound 88

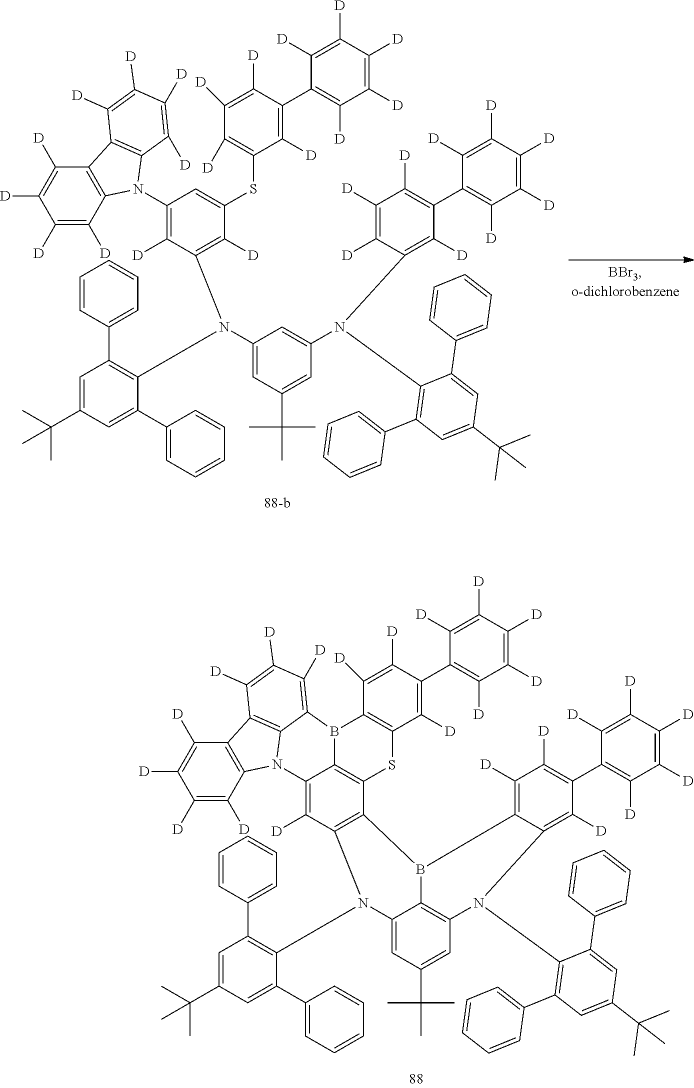

In an argon atmosphere, to a 1-L flask, Intermediate 88-b (9.5 g, 7.1 mmol) was added and dissolved in 100 mL of o-dichlorobenzene, and then BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography utilizing CH₂Cl₂ and hexane as eluent to obtain Compound 88 (yellow solid, 2.3 g, yield: 23%).

ESI-LCMS of Compound 88: [M]⁺: C₉₆H₅₃D₂₄B₂N₃S. 1349.7759

¹H-NMR (CDCl₃) of Compound 88: d=7.40 (s, 4H), 7.15 (m, 12H), 7.07 (m, 8H), 6.99 (s, 2H), 1.36 (s, 18H), 1.21 (s, 9H)

### (7) Synthesis of Compound 99

Fused Polycyclic Compound 99 according to an example may be synthesized, for example, by the following reaction.

### Synthesis of Intermediate 99-a

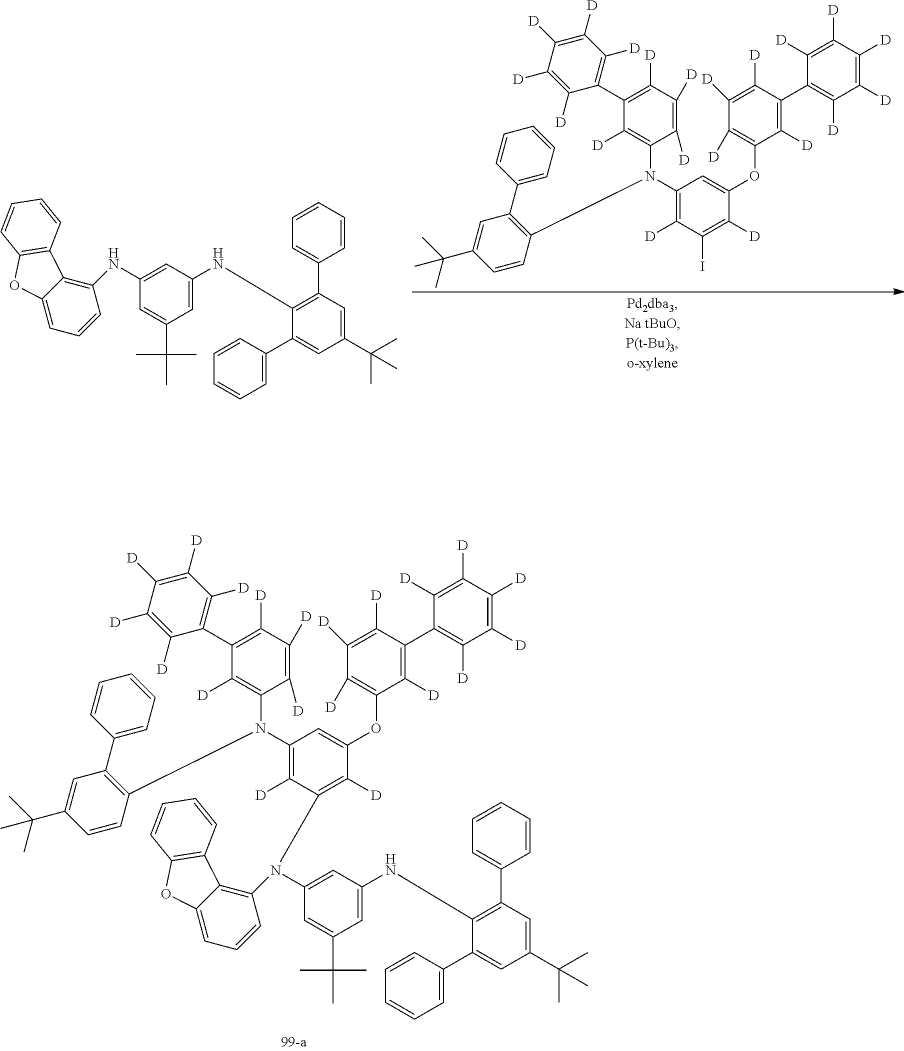

In an argon atmosphere, to a 2-L flask, 5-(tert-butyl)-N1-(5′-(tert-butyl)-[1,1′:3′,1″-terphenyl]-2′-yl)-N3-(dibenzo[b,d]furan-1-yl)benzene-1,3-diamine (10 g, 16 mmol), N-([1,1′-biphenyl]-3-yl-d9)-N-(3-(([1,1′-biphenyl]-3-yl-d9)oxy)-5-iodophenyl-4,6-d2)-5-(tert-butyl)-[1,1′-biphenyl]-2-amine (12.4 g, 16 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and then the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 99-a (white solid, 13.2 g, yield: 65%).

ESI-LCMS of Intermediate 99-a: [M]⁺: C₉₀H₅₉D₂₀N₃O₂. 1253.6574.

### Synthesis of Intermediate 99-b

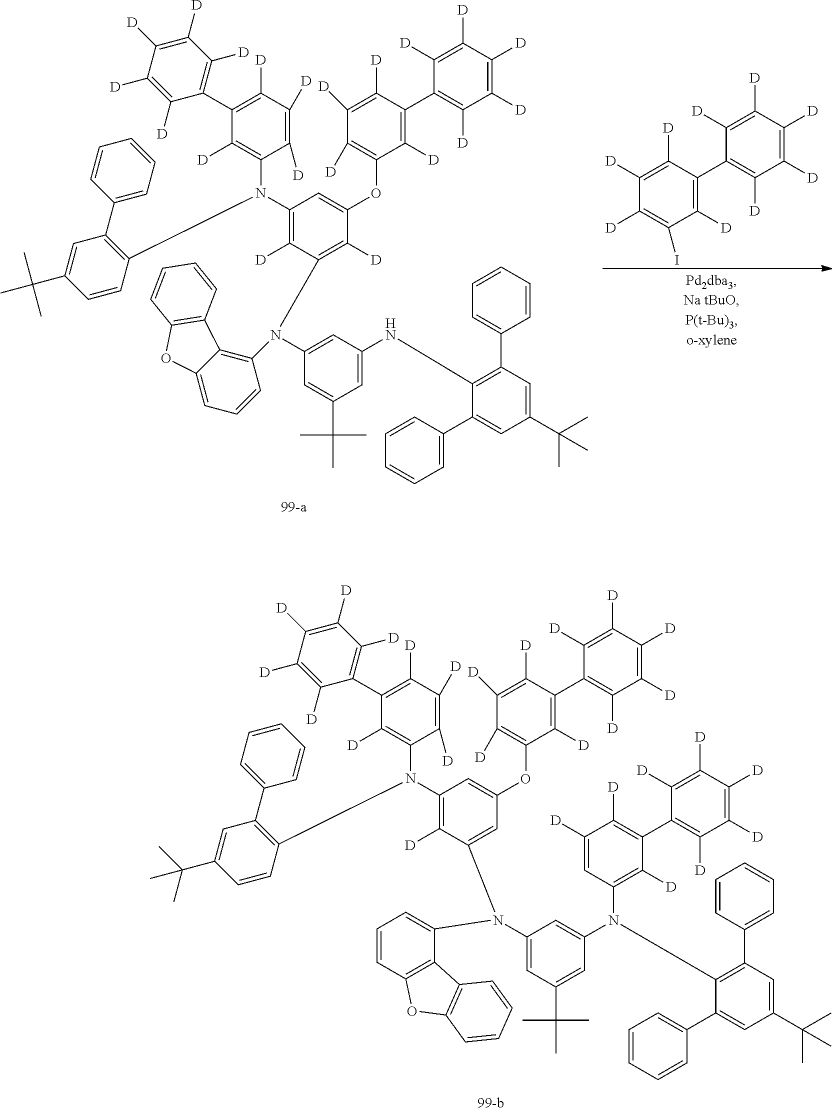

In an argon atmosphere, to a 2-L flask, Intermediate 99-a (13 g, 10 mmol), 3-iodo-1,1′-biphenyl-2,2′,3′,4,4′,5,5′,6,6′-d9 (3 g, 10 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and then the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 99-b (white solid, 10.7 g, yield: 76%).

ESI-LCMS of Intermediate 99-b: [M]⁺: C₁₀₂H₆₀D₂₇N₃O₂. 1412.9958.

### Synthesis of Compound 99

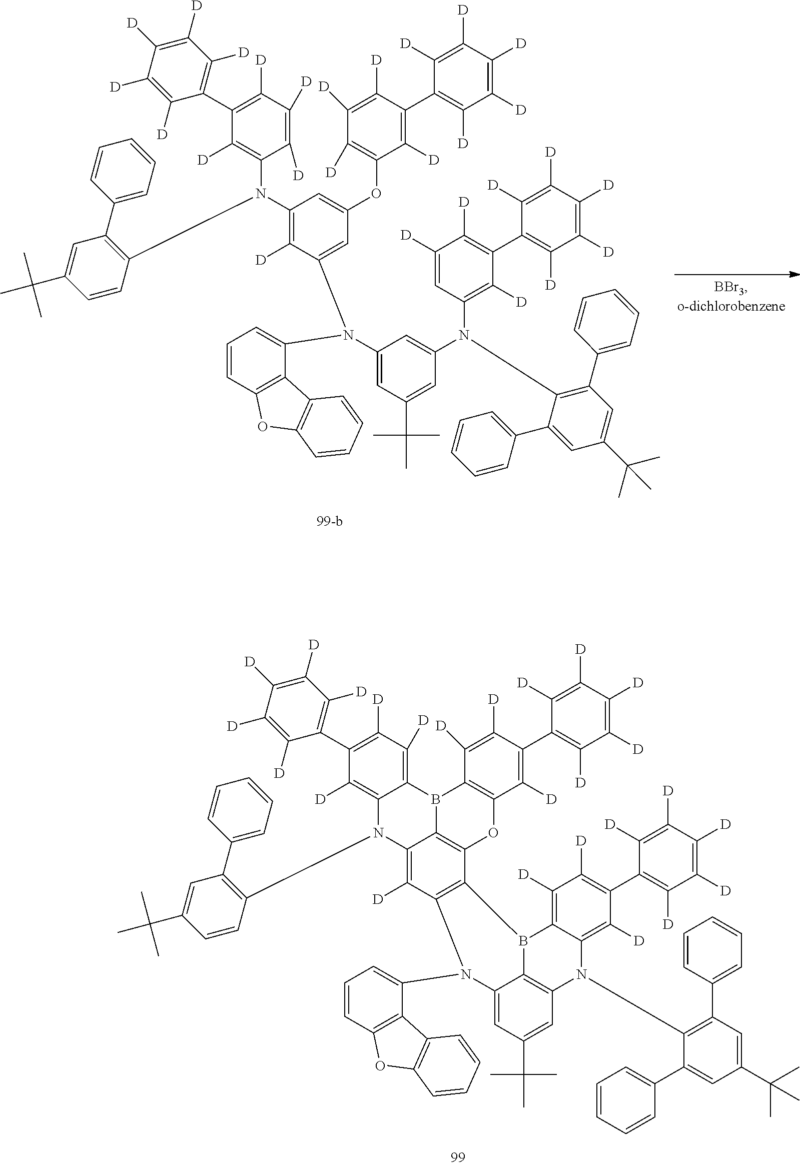

In an argon atmosphere, to a 1-L flask, Intermediate 99-b (10 g, 7 mmol) was added and dissolved in 100 mL of o-dichlorobenzene, and then BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography utilizing CH₂Cl₂ and hexane as eluent to obtain Compound 99 (yellow solid, 2.4 g, yield: 24%).

ESI-LCMS of Compound 99: [M]⁺: C₁₀₂H₅₆D₂₅B₂N₃O₂. 1426.9817

¹H-NMR (CDCl₃) of Compound 99: d=7.88 (d, 1H), 7.65 (d, 1H), 7.50 (s, 1H), 7.45 (s, 2H), 7.38 (m, 6H), 7.20 (m, 6H), 7.08 (m, 6H), 6.95 (d, 1H), 6.87 (s, 2H), 1.39 (s, 18H), 1.19 (s, 9H)

### (8) Synthesis of Compound 103

Fused polycyclic compound 103 according to one or more embodiments may be synthesized by, for example, the following reaction.

### Synthesis of Intermediate 103-a

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13 mmol), 3,3″-((5-iodo-1,3-phenylene)bis(oxy))di-1,1′-biphenyl (7.4 g, 13 mmol), Pd₂dba₃ (1.6 g, 1.9 mmol), tris-tert-butyl phosphine (1.6 mL, 3.8 mmol), and sodium tert-butoxide (4.8 g, 50 mmol) were added and dissolved in 150 mL of o-xylene, and then the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 103-a (white solid, 11 g, yield: 75%).

ESI-LCMS of Intermediate 103-a: [M]⁺: C₈₄H₇₆N₂O₂. 1144.5951.

### Synthesis of Intermediate 103-b

In an argon atmosphere, to a 2-L flask, Intermediate 103-a (10 g, 8.7 mmol), 103-a (10 g, 8.7 mmol), Pd₂dba₃ (1.6 g, 1.9 mmol), tris-tert-butyl phosphine (1.6 mL, 3.8 mmol), and sodium tert-butoxide (4.8 g, 50 mmol) were added and dissolved in 150 mL of o-xylene, and the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 103-b (white solid, 8 g, yield: 66%).

ESI-LCMS Intermediate 103-b: [M]⁺: C₁₀₂H₇₆D₁₁N₃O₂. 1396.7511.

### Synthesis of Compound 103

In an argon atmosphere, to a 1-L flask, Intermediate 103-b (8 g, 5.7 mmol) was added and dissolved in 100 mL of o-dichlorobenzene, and then BBr₃ (2.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography utilizing CH₂Cl₂ and hexane as eluent to Compound 103 (yellow solid, 2.4 g, yield: 24%).

ESI-LCMS of Compound 103: [M]⁺: C₁₀₂H₇₀D₁₁B₂N₃O₂. 1412.7284

¹H-NMR (CDCl₃) of Compound 103: δ=7.84 (d, 2H), 7.75 (d, 2H), 7.49 (m, 6H), 7.43 (m, 2H), 7.38 (s, 4H), 7.27 (m, 12H), 7.08 (m, 8H), 6.88 (s, 2H), 6.58 (s, 1H), 1.35 (s, 18H), 1.23 (s, 9H)

### (9) Synthesis of Compound 106

Fused polycyclic compound 106 according to one or more embodiments may be synthesized by, for example, the following reaction.

### Synthesis of Intermediate 106-a

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13 mmol), N-(3-(3-(9H-carbazol-9-yl)phenoxy)-5-iodophenyl)-N-([1,1′-biphenyl]-4-yl)-[1,1′-biphenyl]-4-amine (10.1 g, 13 mmol), Pd₂dba₃ (1.6 g, 1.9 mmol), tris-tert-butyl phosphine (1.6 mL, 3.8 mmol), and sodium tert-butoxide (4.8 g, 50 mmol) were added and dissolved in 150 mL of o-xylene, and then the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 106-a (white solid, 11.7 g, yield: 77%).

ESI-LCMS of Intermediate 106-a: [M]⁺: C₉₄H₇₂N₄O. 1272.5717.

### Synthesis of Intermediate 106-b

In an argon atmosphere, to a 2-L flask, Intermediate 106-a (10 g, 7.8 mmol), 9-(3-iodophenyl-2,5,6-d3)-9H-carbazole-1,2,3,4,5,6,7,8-d8 (2.2 g, 7.8 mmol), Pd₂dba₃ (1.6 g, 1.9 mmol), tris-tert-butyl phosphine (1.6 mL, 3.8 mmol), and sodium tert-butoxide (4.8 g, 50 mmol) were added and dissolved in 150 mL of o-xylene, and the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 106-b (white solid, 7.8 g, yield: 68%).

ESI-LCMS of Intermediate 106-b: [M]⁺: C₁₀₆H₈₀N₄O. 1424.6383.

### Synthesis of Compound 106

In an argon atmosphere, to a 1-L flask, Intermediate 106-b (8 g, 5.6 mmol) was added and dissolved in 100 mL of o-dichlorobenzene, and then BBr₃ (2.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography utilizing CH₂Cl₂ and hexane as eluent to Compound 106 (yellow solid, 1.8 g, yield: 22%).

ESI-LCMS of Compound 106: [M]⁺: C₁₀₆H₇₄B₂N₄O. 1440.0641

¹H-NMR (CDCl₃) of Compound 106: δ=8.88 (m, 3H), 8.55 (d, 2H), 7.97 (d, 2H), 7.75 (d, 2H), 7.65 (t, 2H), 7.53 (m, 12H), 7.49 (m, 4H), 7.43 (m, 12H), 7.38 (m, 4H), 7.28 (t, 2H), 7.23 (m, 2H), 7.17 (s, 1H), 7.12 (s, 1H), 7.05 (m, 8H), 6.85 (s, 2H), 6.55 (s, 1H), 1.32 (s, 9H)

### (10) Synthesis of Compound 107

Fused polycyclic compound 107 according to one or more embodiments may be synthesized by, for example, the following reaction.

### Synthesis of Intermediate 107-a

In an argon atmosphere, to a 2-L flask, N1,N3-di([1,1′:3′,1″-terphenyl]-2′-yl)-5-(tert-butyl)benzene-1,3-diamine (10 g, 16 mmol), 4,4″-((5-iodo-1,3-phenylene)bis(oxy))di-1,1′-biphenyl (8.7 g, 16 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 150 mL of o-xylene, and then the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 107-a (white solid, 11.5 g, yield: 70%).

ESI-LCMS of Intermediate 107-a: [M]⁺: C₇₆H₆₀N₂O₂. 1032.4771.

### Synthesis of Intermediate 107-b

In an argon atmosphere, to a 2-L flask, Intermediate 107-a (10 g, 9.7 mmol), 3-iodo-1,1′-biphenyl (2.7 g, 9.7 mmol), Pd₂dba₃ (1.6 g, 1.9 mmol), tris-tert-butyl phosphine (1.6 mL, 3.8 mmol), and sodium tert-butoxide (4.8 g, 50 mmol) were added and dissolved in 150 mL of o-xylene, and the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 107-b (white solid, 8.6 g, yield: 75%).

ESI-LCMS of Intermediate 107-b: [M]⁺: C₈₈H₆₈N₂O₂. 1185.5234.

### Synthesis of Compound 107

In an argon atmosphere, to a 1-L flask, Intermediate 107-b (8 g, 6.7 mmol) was added and dissolved in 100 mL of o-dichlorobenzene, and then BBr₃ (2.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography utilizing CH₂Cl₂ and hexane as eluent to Compound 107 (yellow solid, 1.86 g, yield: 23%).

ESI-LCMS of Compound 107: [M]⁺: C₈₈H₆₂B₂N₂O₂. 1201.1010

¹H-NMR (CDCl₃) of Compound 107: δ=8.58 (m, 3H), 7.78 (d, 6H), 7.67 (d, 4H), 7.50 (m, 10H), 7.43 (m, 13H), 7.40 (m, 2H), 7.27 (s, 1H), 7.19 (d, 2H), 7.11 (m, 8H), 7.00 (s, 2H), 6.58 (s, 1H), 1.35 (s, 9H)

### (11) Synthesis of Compound 111

Fused polycyclic compound 111 according to one or more embodiments may be synthesized by, for example, the following reaction.

### Synthesis of Intermediate 111-a

In an argon atmosphere, to a 2-L flask, N1,N3-di([1,1′:3′,1″-terphenyl]-2′-yl)-5-(tert-butyl)benzene-1,3-diamine (10 g, 16 mmol), 3,3′″-((5-iodo-1,3-phenylene)bis(oxy))di-1,1′:3′,1″-terphenyl (11 g, 16 mmol), Pd₂dba₃ (1.6 g, 1.9 mmol), tris-tert-butyl phosphine (1.6 mL, 3.8 mmol), and sodium tert-butoxide (4.8 g, 50 mmol) were added and dissolved in 150 mL of o-xylene, and then the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 111-a (white solid, 12.3 g, yield: 65%).

ESI-LCMS of Intermediate 111-a: [M]⁺: C₈₈H₆₈N₂O₂. 1184.5343.

### Synthesis of Intermediate 111-b

In an argon atmosphere, to a 2-L flask, Intermediate 111-a (10 g, 8.4 mmol), 9-(3-iodophenyl-2,5,6-d3)-9H-carbazole-1,2,3,4,5,6,7,8-d8 (3.2 g, 8.4 mmol), Pd₂dba₃ (1.6 g, 1.9 mmol), tris-tert-butyl phosphine (1.6 mL, 3.8 mmol), and sodium tert-butoxide (4.8 g, 50 mmol) were added and dissolved in 150 mL of o-xylene, and the reaction solution was stirred at about 140° C. for about 2 hours. After cooled, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate 111-b (white solid, 8.6 g, yield: 71%).

ESI-LCMS of Intermediate 111-b: [M]⁺: C₁₀₆H₆₈D₁₁N₃O₂. 1436.6927.

### Synthesis of Compound 111

In an argon atmosphere, to a 1-L flask, Intermediate 111-b (8 g, 5.5 mmol) was added and dissolved in 100 mL of o-dichlorobenzene, and then BBr₃ (2.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography utilizing CH₂Cl₂ and hexane as eluent to Compound 111 (yellow solid, 1.86 g, yield: 23%).

ESI-LCMS of Compound 111: [M]⁺: C₁₀₆H₆₂D₁₁B₂N₃O₂. 1452.6614

¹H-NMR (CDCl₃) of Compound 111: δ=8.66 (m, 3H), 7.97 (s, 2H), 7.73 (m, 6H), 7.61 (m, 4H), 7.49 (m, 6H), 7.42 (m, 14H), 7.36 (m, 2H), 7.29 (s, 2H), 7.10 (m, 8H), 6.88 (s, 2H), 6.55 (s, 1H), 1.38 (s, 9H)

### 2. Manufacture and Evaluation of Light Emitting Elements

The light emitting element of an example including the fused polycyclic compound of an example in an emission layer was manufactured as follows. Fused polycyclic compounds of Compounds 2, 3, 64, 71, 81, 88, 99, 103, 106, 107, and 111, which are Example Compounds as described herein, were utilized as dopant materials for the emission layers to manufacture the light emitting elements of Examples 1 to 11, respectively. Comparative Examples 1 to 4 correspond to the light emitting elements manufactured by utilizing Comparative Example Compounds C1 to C4 as dopant materials for the emission layers, respectively.

### Example Compounds

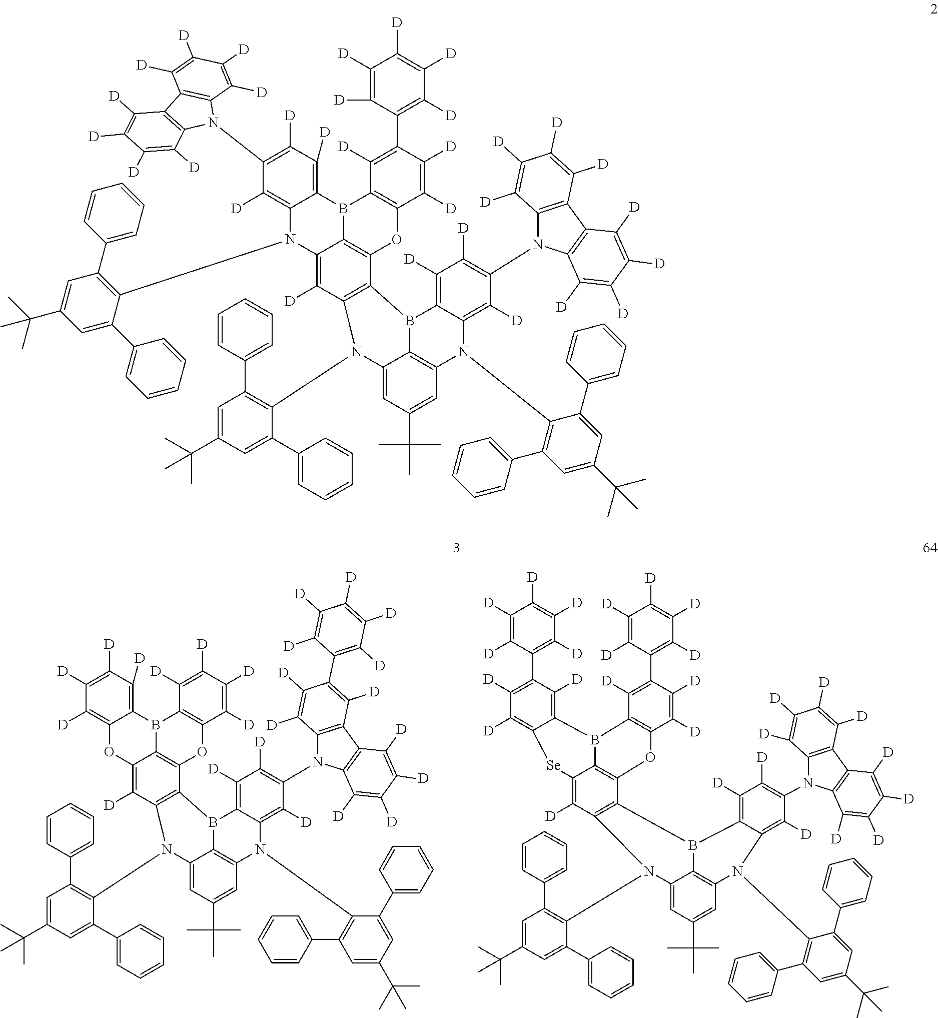

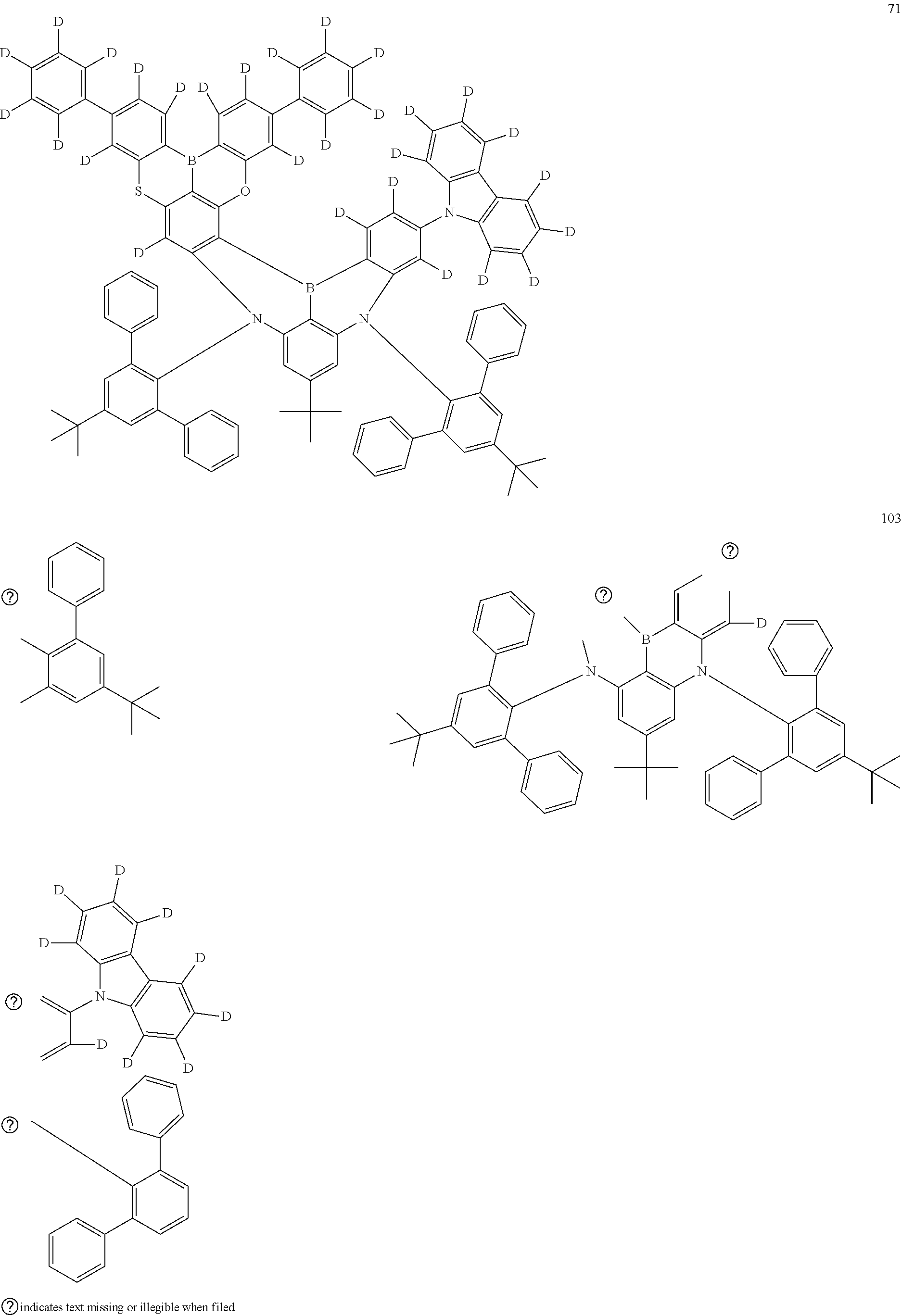

### Comparative Example Compounds

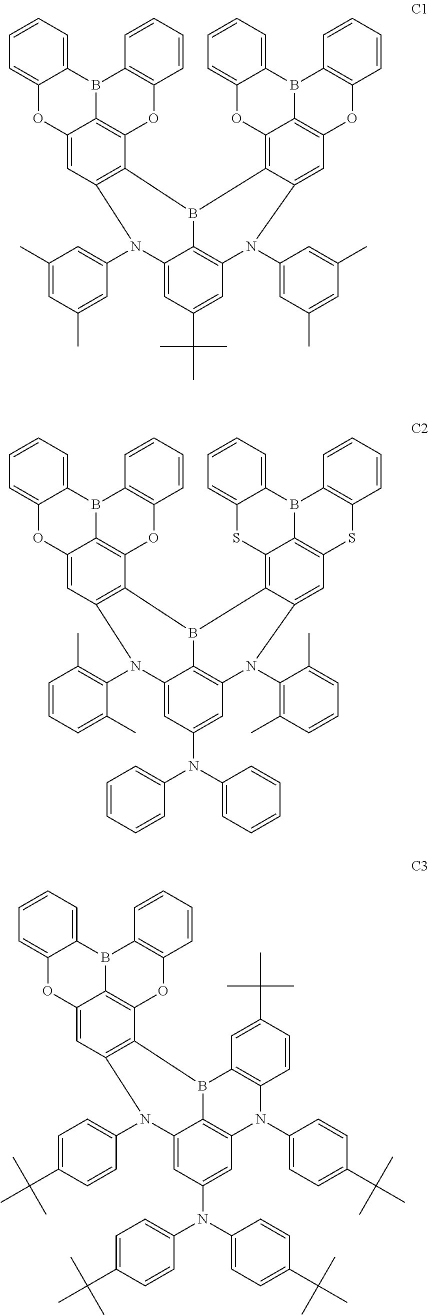 [SMILES: Cc1cc(C)cc(N2c3cc(C(C)(C)C)cc4c3B(c3c2cc2c5c3Oc3ccccc3B5c3ccccc3O2)c2c(cc3c5c2Oc2ccccc2B5c2ccccc2O3)N4c2cc(C)cc(C)c2)c1 ; Cc1cccc(C)c1N1c2cc(N(c3ccccc3)c3ccccc3)cc3c2B(c2c1cc1c4c2Oc2ccccc2B4c2ccccc2O1)c1c(cc2c4c1Sc1ccccc1B4c1ccccc1S2)N3c1c(C)cccc1C ; CC(C)(C)c1ccc(N(c2ccc(C(C)(C)C)cc2)c2cc3c4c(c2)N(c2ccc(C(C)(C)C)cc2)c2cc5c6c(c2B4c2cc(C(C)(C)C)ccc2N3c2ccc(C(C)(C)C)cc2)Oc2ccccc2B6c2ccccc2O5)cc1]

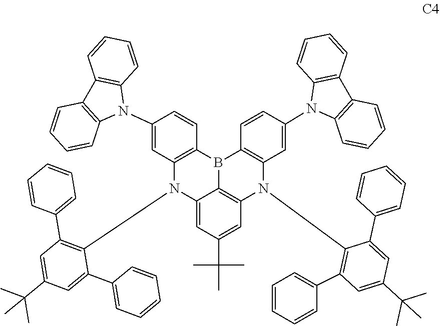 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1]

### Manufacture of Light Emitting Elements

In the light emitting elements of Examples and Comparative Examples, a glass substrate (made by Corning Co.), on which an indium tin oxide (ITO) electrode of about 15 ohm per square centimeter (0/cm²) (about 1200 angstrom (Å)) is formed as an anode, was cut to a size of about 50 millimeter (mm)×50 mm×0.7 mm, cleansed by ultrasonic waves utilizing isopropyl alcohol and pure water for about five minutes each, and then irradiated with ultraviolet rays for about 30 minutes and exposed to ozone and cleansed. The glass substrate was installed on a vacuum deposition apparatus.

NPD was deposited on the upper portion of the anode to form a 300 Å-thick hole injection layer, H-1-19 was then deposited on the upper portion of the hole injection layer to form a 200 Å-thick hole transport layer, and CzSi was then deposited on the upper portion of the hole transport layer to form a 100 Å-thick electron blocking layer.

Then, a host mixture in which the second compound and the third compound according to one or more embodiments were mixed in an amount of about 1:1, the fourth compound, and Example Compound or Comparative Example Compound were co-deposited in a weight ratio of about 85:14:1 to form a 200 Å-thick emission layer, and on the upper portion of the emission layer, TSPO1 was deposited to form a 200 Å-thick hole blocking layer. Then, on the upper portion of the hole blocking layer, TPBi was deposited to form a 300 Å-thick electron transport layer, and then on the upper portion of the electron transport layer, LiF was deposited to form a 10 Å-thick electron injection layer. Al was then utilized to form a 3,000 Å-thick second electrode, thereby forming a LiF/Al electrode. Then, on the upper portion of the electrode, P4 was utilized to form a 700 Å-thick capping layer.

Each layer was formed by a vacuum deposition method. In one or more embodiments, and HT1 among the compounds in Compound Group 2 as described herein was utilized as the second compound, and ETH66 among the compounds in Compound Group 3 as described herein was utilized as the third compound, and AD-39 among the compounds in Compound Group 4 as described herein was utilized as the fourth compound.

Compounds utilized for manufacturing the light emitting elements of Examples and Comparative Examples are disclosed herein. The materials were utilized to manufacture the elements by subjecting commercial products to sublimation purification.

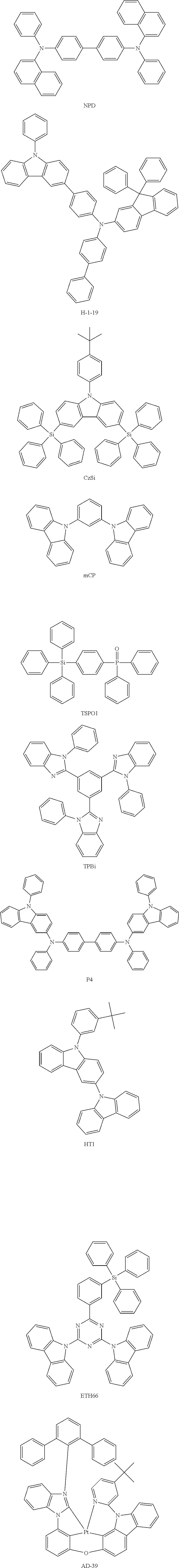

### Evaluation of Light Emitting Element Characteristics

### Evaluation of Physical Properties of Example and Comparative Example Compounds

Physical properties of Compounds 2, 3, 64, 71, 81, 88, 99, 103, 106, 107, and 111, which are Example Compounds, and Comparative Example Compounds C1 to C4, which are Comparative Example Compounds, were evaluated and the results are listed in Table 1.

Highest occupied molecular orbital (HOMO) energy levels, lowest excited singlet energy levels (S1 levels), lowest excited triplet energy levels (T1 levels), DE_{ST}, spin-orbit coupling (SOC) values, absorption wavelengths (λ_{Abs}) and emission wavelengths (λₑₘᵢ) in a solution, Stokes-shift, and luminous efficiencies (photoluminescence quantum yield, PLQY) were measured and the results are listed in Table 1.

In Table 1, λ_{Abs} was measured utilizing Labsolution UV-Vis software with the UV-1800 UV/visible scanning spectrophotometer equipment, made by SHIMADZU Corp., equipped with a deuterium/tungsten-halogen light source and a silicon photodiode. The S1, T1, and λₑₘᵢ were measured utilizing FluorEssence software with fluoromax+ spectrometer equipment, made by HORIBA, Ltd., equipped with a xenon light source and a monochromator. Stokes-shift represents a difference between the maximum wavelength when the energy is absorbed and the maximum wavelength when the energy is emitted. The HOMO energy level was measured utilizing Smart Manager software of SP2 electrochemical workstation equipment made by ZIVE LAB. In Table 1, ΔE_{ST} refers to a difference between the lowest triplet excitation energy level (T1) and the lowest singlet excitation energy level (S1).

The SOC calculation was performed utilizing an unrestricted density functional theory (UDFT). The UDFT calculation was performed utilizing Gaussian09, which is a commercial program, and a 6-311 G(d,p) basis function and a B3LYP exchange-correlation function were utilized. The PLQY was measured utilizing Quantaurus-QY measurement system equipment (C11347-11, Hamamatsu Photonics).

TABLE 1

| | | HOMO | S1 | T1 | ΔE_{ST} | SOC | λ_{Abs} | λₑₘᵢ | Stokes− | PLQY |
|---|---|---|---|---|---|---|---|---|---|---|
| | Dopant | (eV) | (eV) | (eV) | (eV) | (cm⁻¹) | (nm) | (nm) | shift | (%) |
| Example 1 | Compound | −5.42 | 2.71 | 2.68 | 0.03 | 1.91 | 450 | 458 | 8 | 99 |
| | 2 | | | | | | | | | |
| Example 2 | Compound | −5.45 | 2.70 | 2.65 | 0.05 | 1.65 | 445 | 453 | 8 | 98 |
| | 3 | | | | | | | | | |
| Example 3 | Compound | −5.40 | 2.70 | 2.65 | 0.05 | 2.84 | 449 | 459 | 10 | 99 |
| | 64 | | | | | | | | | |
| Example 4 | Compound | −5.40 | 2.71 | 2.55 | 0.06 | 2.05 | 448 | 457 | 9 | 99 |
| | 71 | | | | | | | | | |
| Example 5 | Compound | −5.35 | 2.70 | 2.54 | 0.06 | 2.22 | 449 | 459 | 10 | 98 |
| | 81 | | | | | | | | | |
| Example 6 | Compound | −5.48 | 2.70 | 2.57 | 0.03 | 2.49 | 450 | 458 | 8 | 99 |
| | 88 | | | | | | | | | |
| Example 7 | Compound | −5.40 | 2.70 | 2.55 | 0.05 | 1.98 | 445 | 456 | 11 | 99 |
| | 99 | | | | | | | | | |
| Example 8 | Compound | −5.48 | 2.74 | 2.70 | 0.04 | 2.11 | 444 | 455 | 11 | 98 |
| | 103 | | | | | | | | | |
| Example 9 | Compound | −5.45 | 2.70 | 2.68 | 0.03 | 2.00 | 447 | 458 | 11 | 99 |
| | 106 | | | | | | | | | |
| Example 10 | Compound | −5.35 | 2.72 | 2.67 | 0.05 | 1.88 | 446 | 457 | 11 | 99 |
| | 107 | | | | | | | | | |
| Example 11 | Compound | −5.46 | \|2.73 | 2.70 | 0.03 | 2.12 | 444 | 455 | 11 | 99 |
| | 111 | | | | | | | | | |
| Comparative | Comparative | −5.15 | 2.71 | 2.55 | 0.06 | 1.85 | 433 | 450 | 17 | 81 |
| Example 1 | Example | | | | | | | | | |
| | Compound | | | | | | | | | |
| | C1 | | | | | | | | | |
| Comparative | Comparative | −5.12 | 2.65 | 2.61 | 0.04 | 2.00 | 450 | 463 | 13 | 72 |
| Example 2 | Example | | | | | | | | | |
| | Compound | | | | | | | | | |
| | C2 | | | | | | | | | |
| Comparative | Comparative | −5.09 | 2.74 | \|2.69 \| | 0.05 | 1.84 | 436 | 450 | 14 | 85 |
| Example 3 | Example | | | | | | | | | |
| | Compound | | | | | | | | | |
| | C3 | | | | | | | | | |
| Comparative | Comparative | −5.40 | 2.71 | 2.59 | 0.12 | 0.021 | 448 | 458 | 10 | 99 |
| Example 4 | Example | | | | | | | | | |
| | Compound | | | | | | | | | |
| | C4 | | | | | | | | | |

Element efficiency and element service life of each of the light emitting elements manufactured with Experimental Example Compounds 2, 3, 64, 71, 81, 88, 99, 103, 106, 107, and 111, and Comparative Example Compounds C1 to C4 as described herein were evaluated. Evaluation results of the light emitting elements of Examples 1 to 11 and Comparative Examples 1 to 4 are listed in Table 2. In the characteristic evaluation results of Examples and Comparative Example listed in Table 2, driving voltages and current densities were measured by utilizing V7000 OLED IVL Test System (Polaronix). To evaluate the characteristics of the light emitting elements manufactured in Examples 1 to 11 and Comparative Examples 1 to 4, driving voltages and efficiencies (candela per ampere (cd/A)) at a current density of 10 milliampere per square centimeter (mA/cm²) were measured, and the relative element service life was set as a numerical value in which the deterioration time from an initial value to 95% brightness when the device was continuously operated at a current density of 10 mA/cm² was compared with Comparative Example 4, and then the evaluation was carried out.

TABLE 2

| | Host | | | | | | | |
|---|---|---|---|---|---|---|---|---|
| | (second | | | | | | | |
| | compound: | | | | | | | |
| | third | | | Driving | Top | Luminous | Service | |
| | compound = | Fourth | First | voltage | efficiency | wavelength | life | CIE |
| | 5:5) | compound | compound | (V) | (cd/A/y) | (nm) | (T95) | y |
| Example 1 | HT1/ | AD-39 | Compound | 4.1 | 510 | 460 | 15.4 | 0.050 |
| | ETH66 | | 2 | | | | | |
| Example 2 | HT1/ | AD-39 | Compound | 4.0 | 450 | 458 | 9.1 | 0.048 |
| | ETH66 | | 3 | | | | | |
| Example 3 | HT1/ | AD-39 | Compound | 4.1 | 550 | 460 | 11.4 | 0.051 |
| | ETH66 | | 64 | | | | | |
| Example 4 | HT1/ | AD-39 | Compound | 4.1 | 530 | 460 | 12.5 | 0.049 |
| | ETH66 | | 71 | | | | | |
| Example 5 | HT1/ | AD-39 | Compound | 4.0 | 520 | 460 | 10.4 | 0.051 |
| | ETH66 | | 81 | | | | | |
| Example 6 | HT1/ | AD-39 | Compound | 3.8 | 570 | 460 | 14.5 | 0.050 |
| | ETH66 | | 88 | | | | | |
| Example 7 | HT1/ | AD-39 | Compound | 4.0 | 530 | 458 | 9.8 | 0.048 |
| | ETH66 | | 99 | | | | | |
| Example 8 | HT1/ | AD-39 | Compound | 3.6 | 580 | 456 | 18.5 | 0.043 |
| | ETH66 | | 103 | | | | | |
| Example 9 | HT1/ | AD-39 | Compound | 3.8 | 560 | 460 | 16.4 | 0.050 |
| | ETH66 | | 106 | | | | | |
| Example | HT1/ | AD-39 | Compound | 3.7 | 570 | 458 | 19.9 | 0.048 |
| 10 | ETH66 | | 107 | | | | | |
| Example | HT1/ | AD-39 | Compound | 3.6 | 600 | 456 | 19.8 | 0.043 |
| 11 | ETH66 | | 111 | | | | | |
| Comparative | HT1/ | AD-39 | Comparative | 4.1 | 430 | 452 | 0.01 | 0.047 |
| Example | ETH66 | | Example | | | | | |
| 1 | | | Compound | | | | | |
| | | | C1 | | | | | |
| Comparative | HT1/ | AD-39 | Comparative | 4.2 | 450 | 466 | 0.1 | 0.062 |
| Example | ETH66 | | Example | | | | | |
| 2 | | | Compound | | | | | |
| | | | C2 | | | | | |
| Comparative | HT1/ | AD-39 | Comparative | 4.5 | 410 | 455 | 0.2 | 0.050 |
| Example | ETH66 | | Example | | | | | |
| 3 | | | Compound | | | | | |
| | | | C3 | | | | | |
| Comparative | HT1/ | AD-39 | Comparative | 4.2 | 400 | 463 | 1 | 0.055 |
| Example | ETH66 | | Example | | | | | |
| 4 | | | Compound | | | | | |
| | | | C4 | | | | | |

Referring to the results of Table 2, it may be confirmed that Examples of the light emitting elements, in which the fused polycyclic compounds according to examples of the present disclosure are utilized as a luminescent material, have improved luminous efficiency and service life characteristics as compared with Comparative Examples. The fused polycyclic compound of one or more embodiments has a structure in which two aromatic hydrocarbon rings are fused to the fused polycyclic heterocycle at specific positions via the boron atom and two heteroatoms, thereby increasing the spin-orbit coupling constant and thus achieving high efficiency and long service life. More specifically, one of two heteroatoms linking two aromatic hydrocarbon rings and the fused polycyclic heterocycle is arranged so as to be at the ortho position with respect to the first boron atom of the fused polycyclic heterocycle, and thus the spin-orbit coupling constant between the lowest excited singlet energy level (S1 level) and the lowest excited triplet energy level (T1 level) may be increased, thereby contributing high luminous efficiency and improved service life characteristics of the light emitting element. In one or more embodiments, Example Compounds include the first substituent, and thus may effectively protect the boron atom, thereby achieving high efficiency and long service life. Without being bound by any particular theory, it is believed that Example Compounds have an increase in the luminous efficiency because the intermolecular interaction may be suppressed or reduced by the introduction of the first substituent, thereby controlling the formation of excimer or exciplex. In addition, Example Compounds each have an increase in the distance between adjacent molecules due to the large steric hindrance structure by the first substituent to thereby suppress or reduce the Dexter energy transfer, and thus may suppress or reduce the deterioration of service life due to the increase of triplet concentration. The light emitting element of an example includes the fused polycyclic compound of an example as a light emitting dopant of a thermally activated delayed fluorescence (TADF) light emitting element, and thus may achieve high element efficiency in a blue wavelength region, and improved service life characteristics.

Comparative Examples 1 and 2 exhibited the results that the element service life and efficiency were reduced compared to Examples. Each of Comparative Example Compounds C1 and C2 included in Comparative Examples 1 and 2 includes the fused polycyclic heterocycle centered on one boron atom and two nitrogen atoms, and a structure in which a plurality of benzene rings are linked to the fused polycyclic heterocycle via boron atoms and oxygen atoms to form an additional fused ring. Referring to Tables 1 and 2, it may be confirmed that Comparative Example Compounds C1 and C2 exhibit spin-orbit coupling values similar to those of Example Compounds. Without being bound by any particular theory, it is believed that due to the additional fused ring with a structure in which four rings were additionally fused to benzene rings other than “fused benzene rings” in the fused polycyclic heterocycle, Comparative Example Compounds C1 and C2 thereby deteriorate chemical stability compared to Example Compounds, and thus reduce the luminous efficiency and element service life. In addition, without being bound by any particular theory, it is believed that because Comparative Example Compounds C1 and C2 do not include the first substituent proposed by the present disclosure in the fused ring skeleton, the aspect of sterically protecting boron atoms within the planar structure of the fused ring core is reduced, and it is difficult to expect or achieve intermolecular interaction effects and/or the like. Accordingly, it may be confirmed that when applied to the element, Comparative Example Compounds C1 and C2 has a significant decrease in the service life compared to Examples. Further, referring to Table 1, it may be confirmed that the HOMO energy levels of Comparative Compounds C1 and C2 are shallower than those of Example Compounds. That is, without being bound by any particular theory, it is believed that when the dopant HOMO energy level is shallow, when a hole is injected into the emission layer from the electrode, it is more likely that the hole is trapped in the dopant, which is an emitter, rather than moving to the host, and this leads to direct recombination, which may cause element deterioration. In in the context of present disclosure, when the energy level is “shallow”, it may refer to that the absolute value of the energy level becomes small towards minus from a vacuum level. In the context of present disclosure when the energy level is referred to as being “deep”, it may refer to that the absolute value of the energy level becomes large towards minus from a vacuum level.

Comparative Example 3 exhibited the results that the element service life and efficiency were reduced compared to Examples. Comparative Example Compound C3 included in Comparative Example 3 includes a fused polycyclic heterocycle centered on one boron atom and two nitrogen atoms, and a structure in which two benzene rings are linked to the fused polycyclic heterocycle via boron atoms and oxygen atoms to form an additional fused ring, but does not include the first substituent proposed by the present disclosure, and thus when applied to the element, has a decrease in the luminous efficiency and service life compared to Examples. Without being bound by any particular theory, it is believed that because Comparative Example Compound C3 has a structure in which phenyl groups each substituted with a t-butyl group are linked to nitrogen atoms constituting the fused polycyclic heterocycle and the effect of sterically protecting the fused ring core is insufficient with these substituents, Comparative Example Compound C3 may have a decrease in the aspect of reducing intermolecular interaction or suppressing or reducing Dexter energy transfer, thereby reducing the triplet energy concentration compared to Examples.

Comparative Example 4 exhibited the results that the element service life and efficiency were reduced compared to Examples. It may be confirmed that Comparative Example Compound C4 included in Comparative Example 4 has a structure in which the first substituents, which are ortho-type or kind terphenyl groups, are linked to the fused polycyclic heterocycle centered on one boron atom and two nitrogen atoms, and thus exhibits improved service life characteristics compared to Comparative Examples 1 to 3. However, it may be confirmed that Comparative Example Compound C4 has a structure in which no additional fused ring is formed on the fused polycyclic heterocycle, such that the spin-orbit coupling value is 0.021 inverse centimeter (cm¹), which is significantly lower than those of Example Compounds, and thus, when applied to the element, the luminous efficiency and the element service life are reduced.

The light emitting element of one or more embodiments may exhibit improved element characteristics with high efficiency and a long service life.

The fused polycyclic compound of one or more embodiments may be included in the emission layer of the light emitting element to contribute to high efficiency and a long service life of the light emitting element.

The display device of one or more embodiments may exhibit excellent or suitable display quality.

Although the present disclosure has been described with reference to a embodiment of the present disclosure, it will be understood that the present disclosure should not be limited to these embodiments but one or more suitable changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims, and equivalents thereof.

What is claimed is:

1. A light emitting element comprising:
a first electrode;
a second electrode on the first electrode; and
an emission layer between the first electrode and the second electrode and comprising a first compound represented by Formula 1: 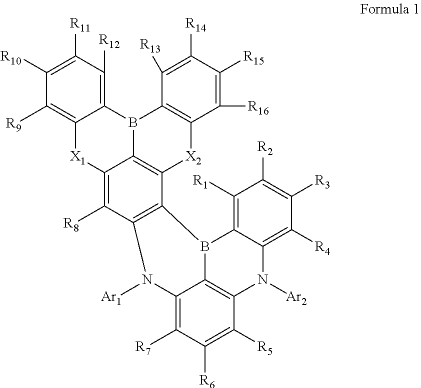
in Formula 1,
X₁ is NR₁₇, O, S, Se, or Te,
X₂ is O, S, or Se,
R₁ to R₇ are each independently a hydrogen atom, a deuterium atom, a halogen atom, a cyano group, a nitro group, a substituted or unsubstituted silyl group, a substituted or unsubstituted germanium group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
R₈ to R₁₆ are each independently a hydrogen atom, a deuterium atom, a halogen atom, a cyano group, a nitro group, a substituted or unsubstituted silyl group, a substituted or unsubstituted germanium group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
R₁₇ is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or is bonded to an adjacent group to form a ring,
Ar₁ and Ar₂ are each independently a substituted or unsubstituted aryl group having 6 to 30 ring-forming carbon atoms, or a substituted or unsubstituted heteroaryl group having 2 to 30 ring-forming carbon atoms, and
at least one of Ar₁ or Ar₂ is represented by Formula S: 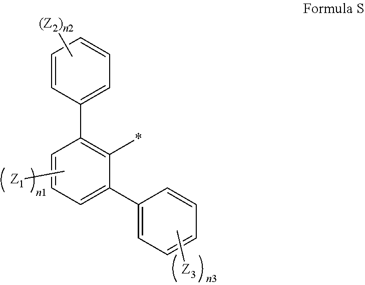
in Formula S,
Z₁ to Z₃ are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
n1 is an integer of 0 to 3,
n2 and n3 are each independently an integer of 0 to 5, and [symbol]
is a position linked to Formula 1.

2. The light emitting element of claim 1, wherein, in Formula 1, at least one selected from among R₁ to R₇ is a substituted or unsubstituted alkyl group having 1 to 10 carbon atoms, or is represented by any one selected from among Formula A-1 to Formula A-4: 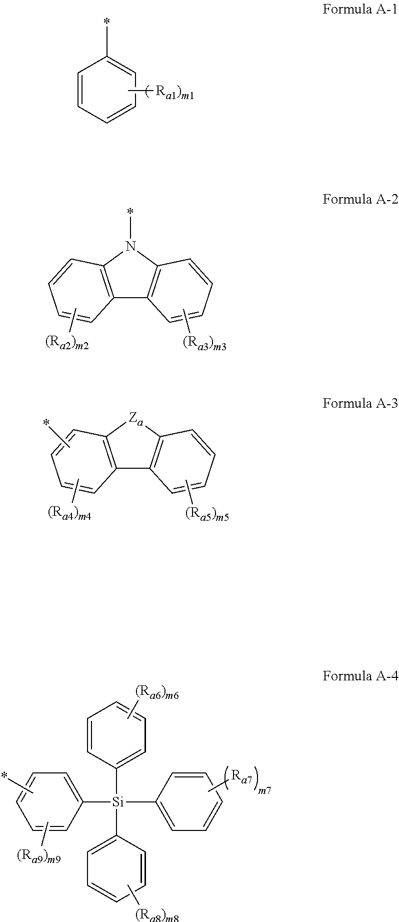
in Formula A-1 to Formula A-4,
Zₐ is NRₐ₁₀, O, S, or Se,
Rₐ₁ to Rₐ₁₀ are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
m1, and m6 to m8 are each independently an integer of 0 to 5,
m2, m3, m5, and m9 are each independently an integer of 0 to 4, and
m4 is an integer of 0 to 3.

3. The light emitting element of claim 1, wherein, in Formula 1, at least one of Ar₁ or Ar₂ is represented by Formula S, and any remaining Ar₁ or Ar₂ is represented by any one selected from among Formula B-1 to Formula B-3: 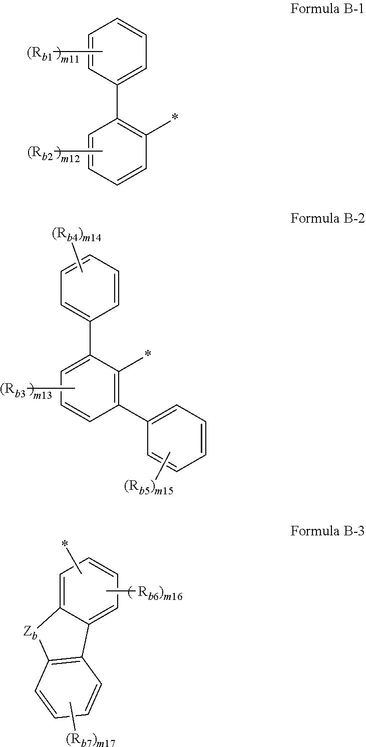
in Formula B-1 to Formula B-3,
Z_{b} is NR_{b8}, O, S, or Se,
R_{b1} to R_{b7} are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
R_{b8} is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
m11, m14 and m15 are each independently an integer of 0 to 5,
m12 and m17 are each independently an integer of 0 to 4,
m13 and m16 are each independently an integer of 0 to 3, and [symbol]
is a position linked to Formula 1.

4. The light emitting element of claim 1, wherein the first compound is represented by Formula 2-1 or Formula 2-2: 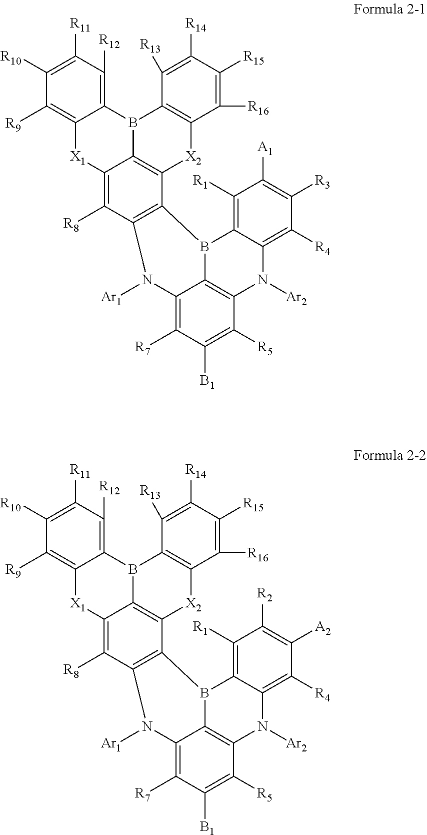
in Formula 2-1 and Formula 2-2,
A₁ and A₂ are each independently represented by any one selected from among Formula A-1 to Formula A-4, and
B₁ is a substituted or unsubstituted alkyl group having 1 to 10 carbon atoms: 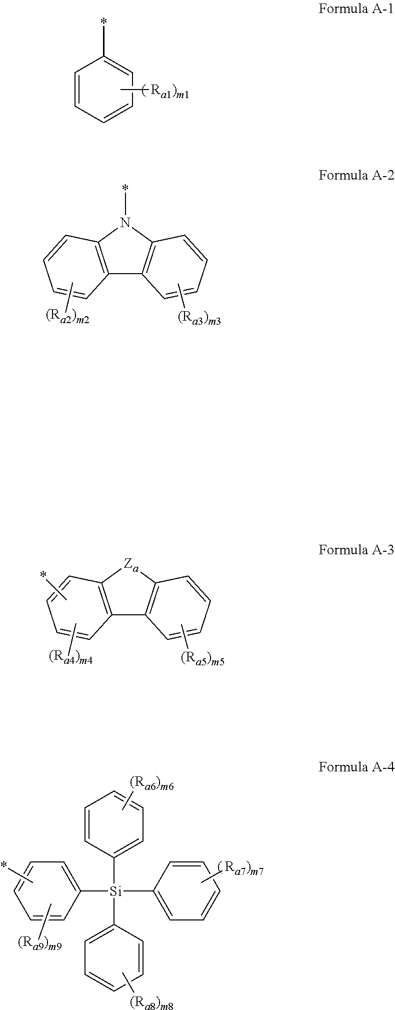
in Formula A-1 to Formula A-4,
Zₐ is NRₐ₁₀, 0, 8, or Se,
Rₐ₁ to Rₐ₁₀ are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
m1, and m6 to m8 are each independently an integer of 0 to 5,
m2, m3, m5, and m9 are each independently an integer of 0 to 4, and
m4 is an integer of 0 to 3, and
in Formula 2-1 and Formula 2-2,
X₁, X₂, Ar₁, Ar₂, R₁ to R₅, and R₇ to R₁₆ are as defined in Formula 1.

5. The light emitting element of claim 1, wherein the first compound is represented by any one selected from among Formula 3-1 to Formula 3-3: 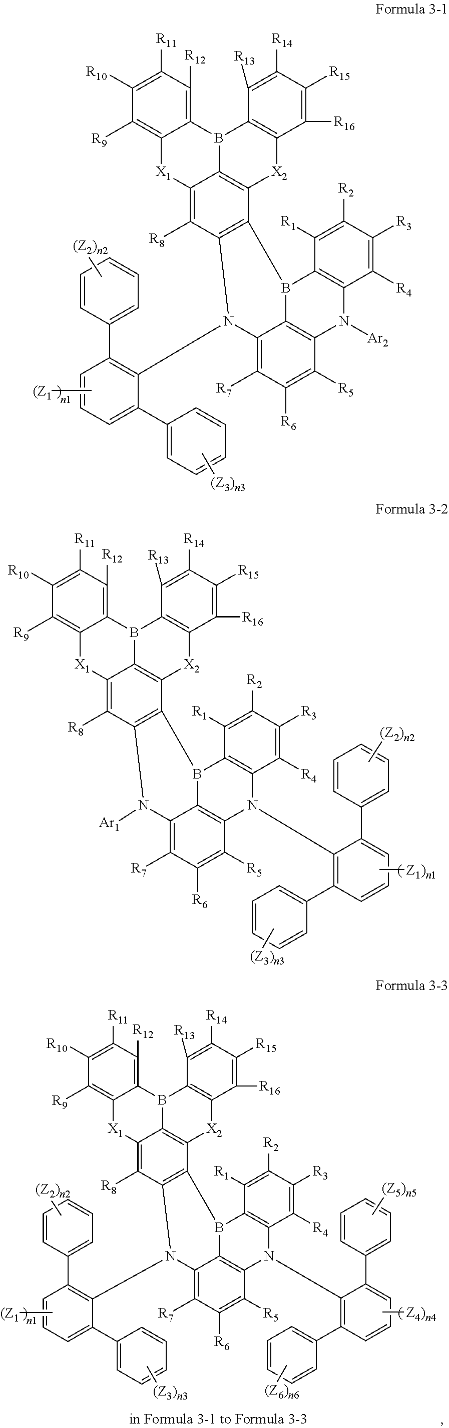
Z₄ to Z₆ are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
n4 is an integer of 0 to 3,
n5 and n6 are each independently an integer of 0 to 5, and
X₁, X₂, Ar₁, Ar₂, R₁ to R₁₆, Z₁ to Z₃, and n1 to n3 are as defined in Formula 1 and Formula S.

6. The light emitting element of claim 1, wherein the first compound is represented by any one selected from among Formula 4-1 to Formula 4-5: 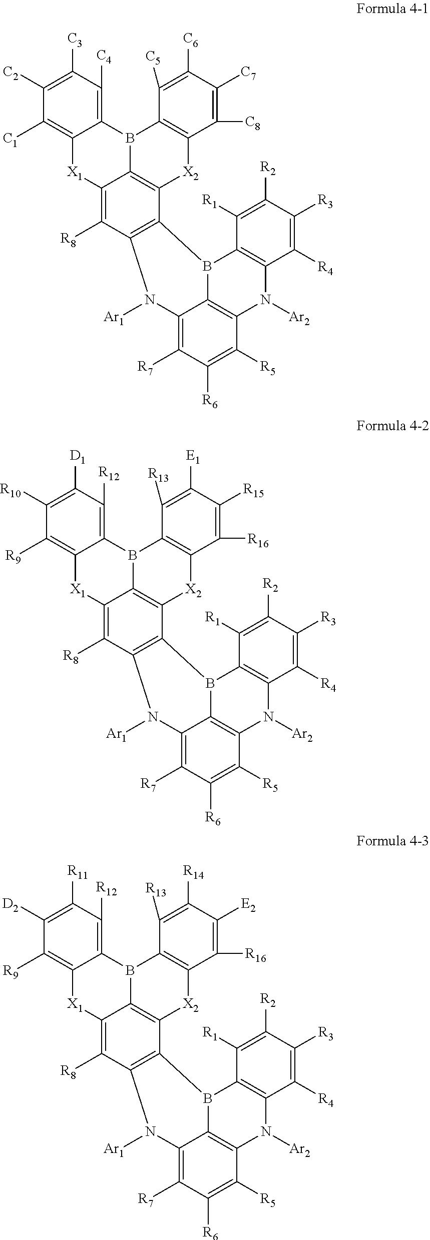 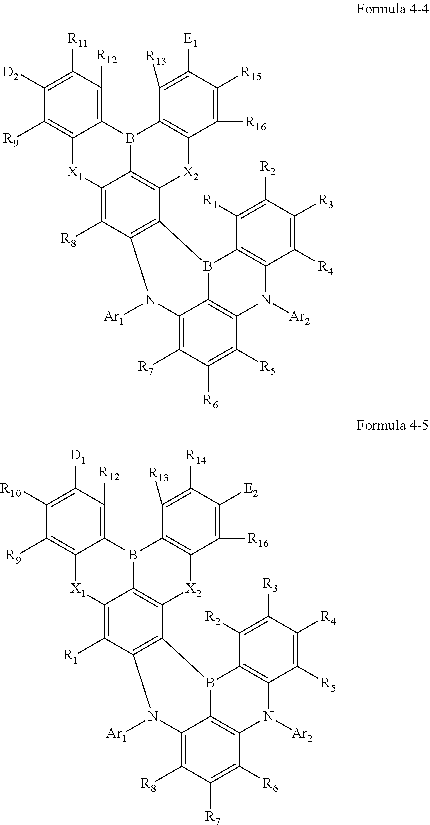
in Formula 4-1 to Formula 4-5,
C1 to C₈ are each independently a hydrogen atom or a deuterium atom, and
D₁, D₂, E₁, and E₂ are each independently a substituted or unsubstituted alkyl group having 1 to 10 carbon atoms, or are represented by one selected from among Formula C-1 to Formula C-5: 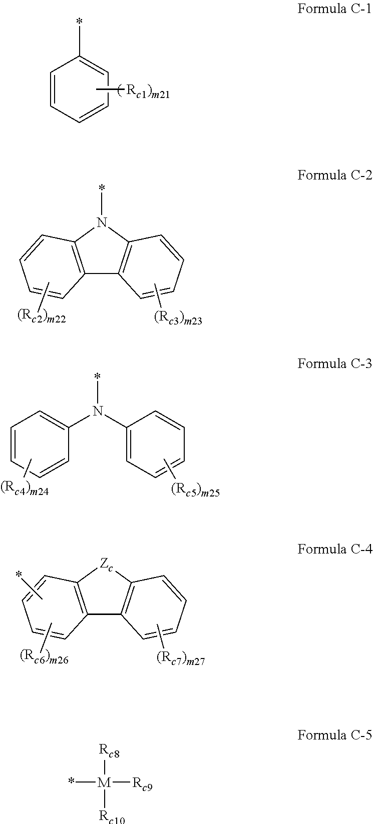
in Formula C-1 to Formula C-5,
Z_{c} is NR_{c11}, O, S, or Se,
M is Si or Ge,
R_{c1} to R_{c7} are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
R_{c8} to R_{c11} are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
m21, m24 and m25 are each independently an integer of 0 to 5,
m22, m23 and m27 are each independently an integer of 0 to 4, and
m26 is an integer of 0 to 3, and
in Formula 4-1 to Formula 4-5,
X₁, X₂, Ar₁, Ar₂, and R₁ to R₁₆ are as defined in Formula 1.

7. The light emitting element of claim 1, wherein the first compound is represented by any one selected from among Formula 5-1 to Formula 5-3: 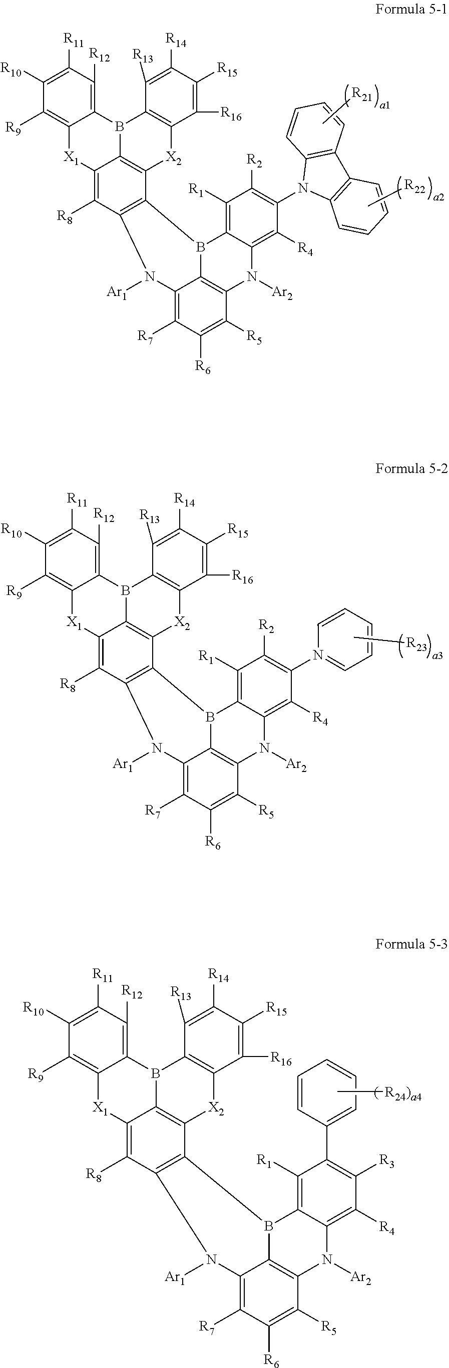
in Formula 5-1 to Formula 5-3,
R₂₁ to R₂₄ are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
a1 and a2 are each independently an integer of 0 to 4,
a3 and a4 are each independently an integer of 0 to 5, and
X₁, X₂, Ar₁, Ar₂, and R₁ to R₁₆ are as defined in Formula 1.

8. The light emitting element of claim 1, wherein the first compound is represented by any one selected from among Formula 6-1 to Formula 6-3: 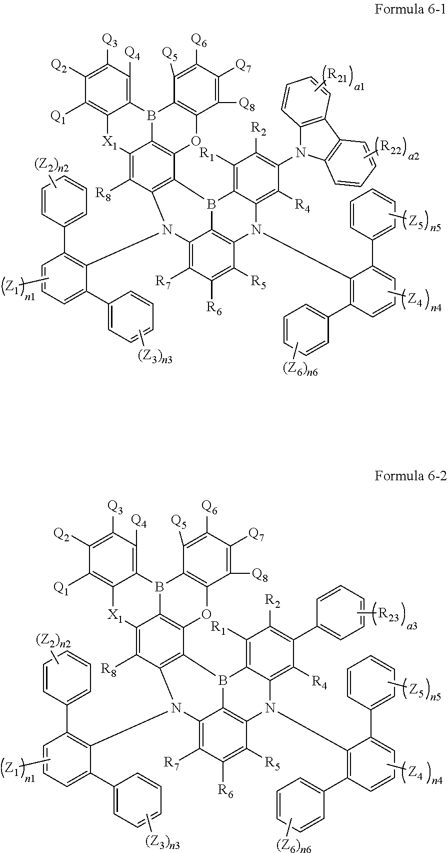 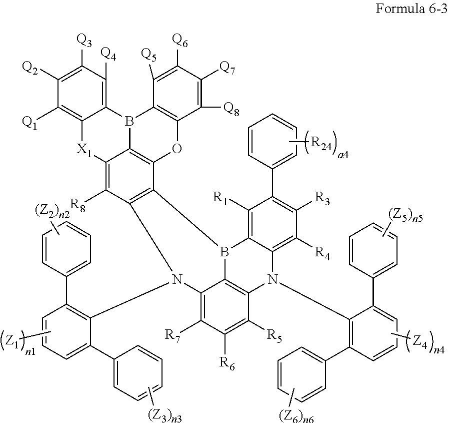
in Formula 6-1 to Formula 6-3,
R₂₁ to R₂₄ are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
Z₄ to Z₆ are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
a1 and a2 are each independently an integer of 0 to 4,
a3, a4, n5, and n6 are each independently an integer of 0 to 5,
n4 is an integer of 0 to 3, and
at least one selected from among Q₁ to Q₅ is represented by any one selected from among Formula C-1 to Formula C-5, and any remaining selected from among Q₁ to Q₅ are each independently a hydrogen atom or a deuterium atom: 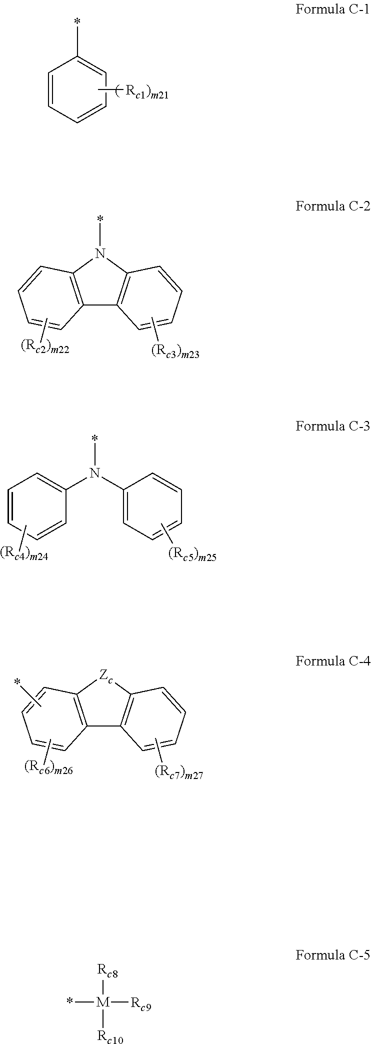
in Formula C-1 to Formula C-5,
Z_{c} is NR_{c11}, O, S, or Se,
M is Si or Ge,
R_{c1} to R_{c7} are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
R_{c8} to R_{c11} are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
m21, m24 and m25 are each independently an integer of 0 to 5,
m22, m23 and m27 are each independently an integer of 0 to 4, and
m26 is an integer of 0 to 3, and
in Formula 6-1 to Formula 6-3,
X₁, R₁ to R₈, Z₁ to Z₃, and n1 to n3 are as defined in Formula 1 and Formula S.

9. The light emitting element of claim 1, wherein at least one selected from among R₁ to R₁₆ is represented by any one selected from among Substituent Group 1:

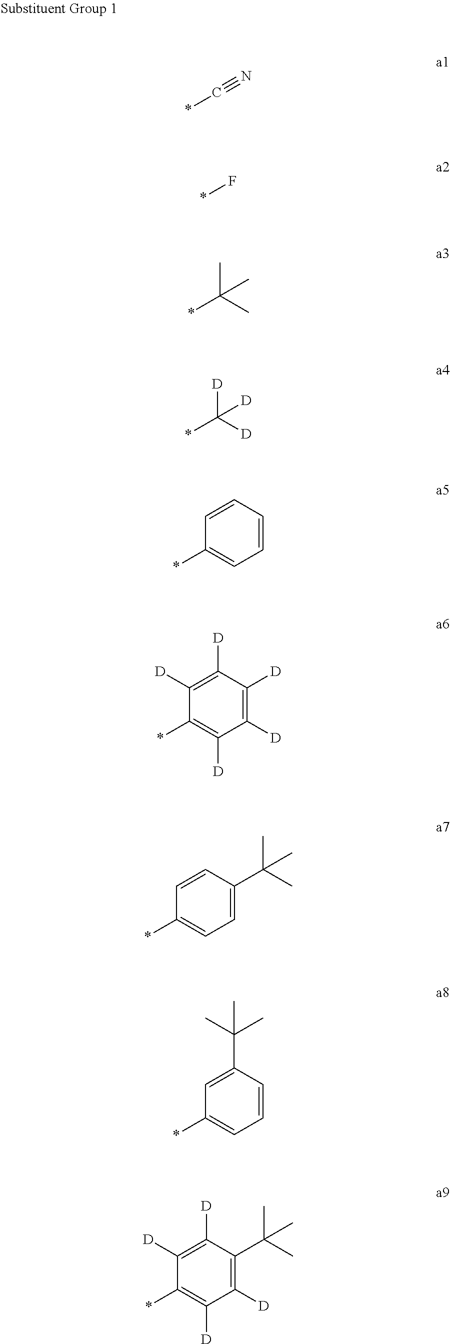

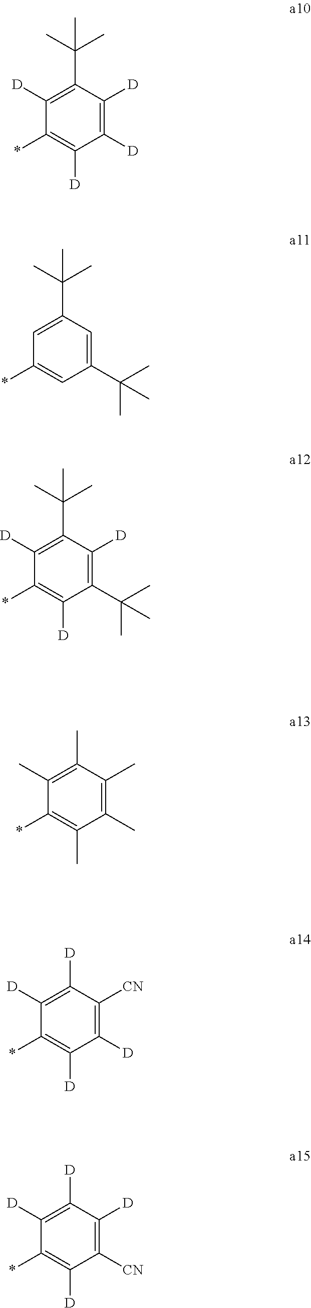 [SMILES: *c1c([2H])c([2H])c([2H])c(C(C)(C)C)c1[2H] ; *c1cc(C(C)(C)C)cc(C(C)(C)C)c1 ; *c1c([2H])c(C(C)(C)C)c([2H])c(C(C)(C)C)c1[2H] ; *c1c(C)c(C)c(C)c(C)c1C ; *c1c([2H])c([2H])c(C#N)c([2H])c1[2H] ; *c1c([2H])c([2H])c([2H])c(C#N)c1[2H]]

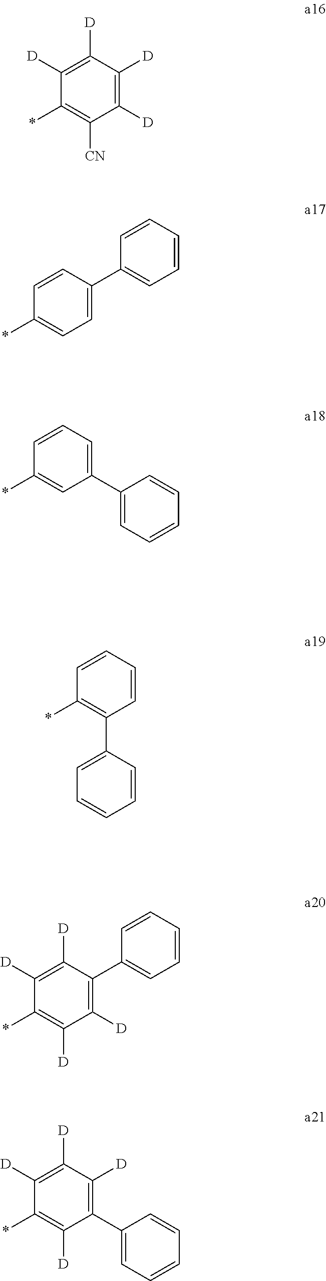 [SMILES: *c1c([2H])c([2H])c([2H])c([2H])c1C#N ; *c1ccc(-c2ccccc2)cc1 ; *c1cccc(-c2ccccc2)c1 ; *c1ccccc1-c1ccccc1 ; *c1c([2H])c([2H])c(-c2ccccc2)c([2H])c1[2H] ; *c1c([2H])c([2H])c([2H])c(-c2ccccc2)c1[2H]]

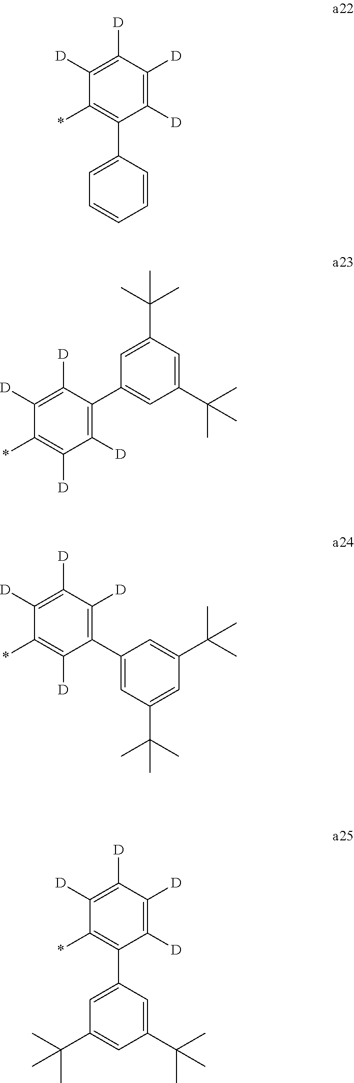

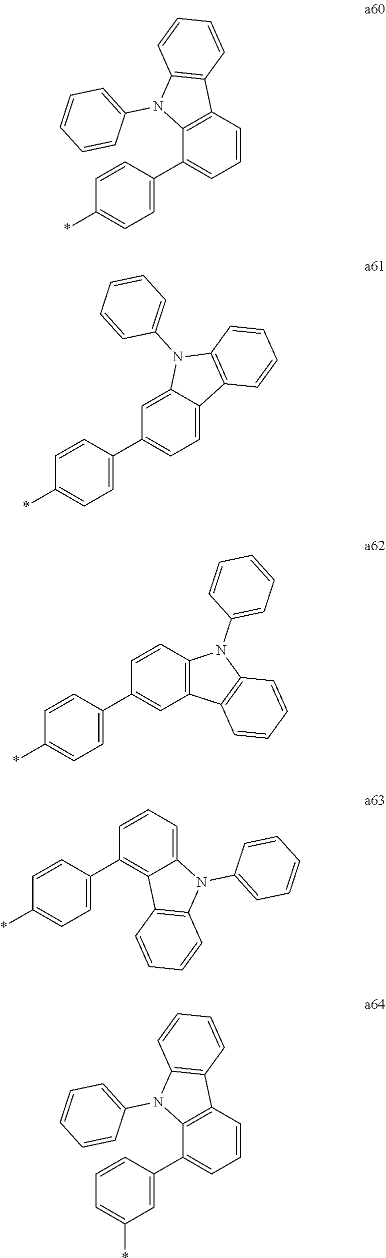

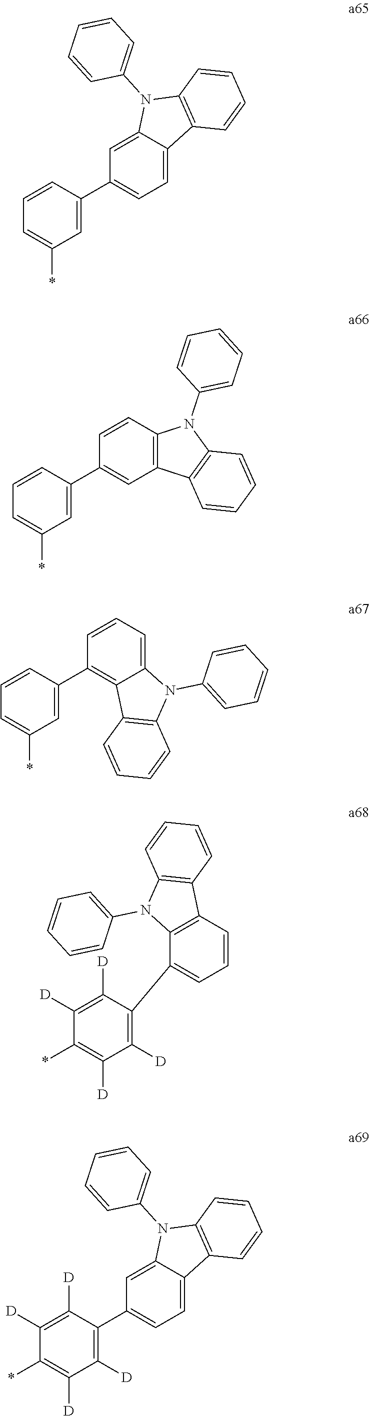

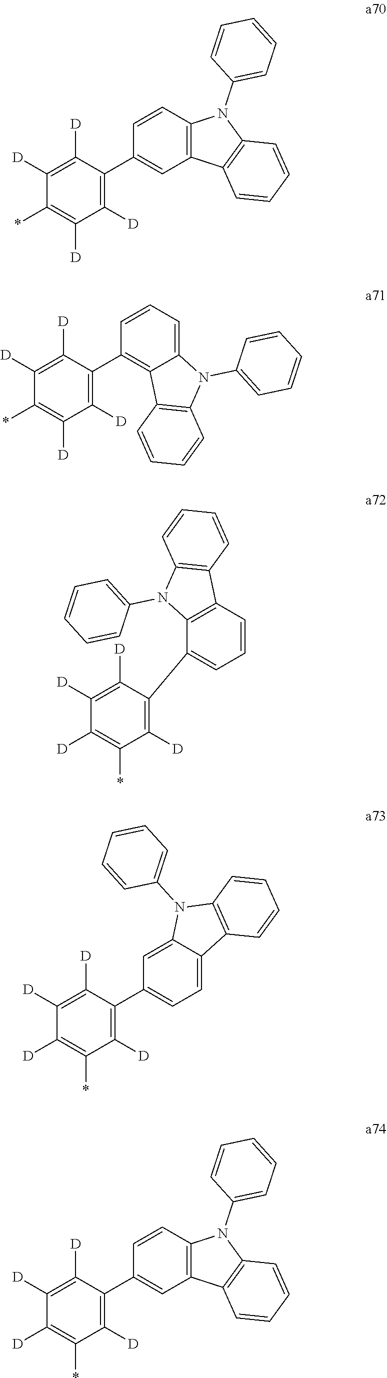

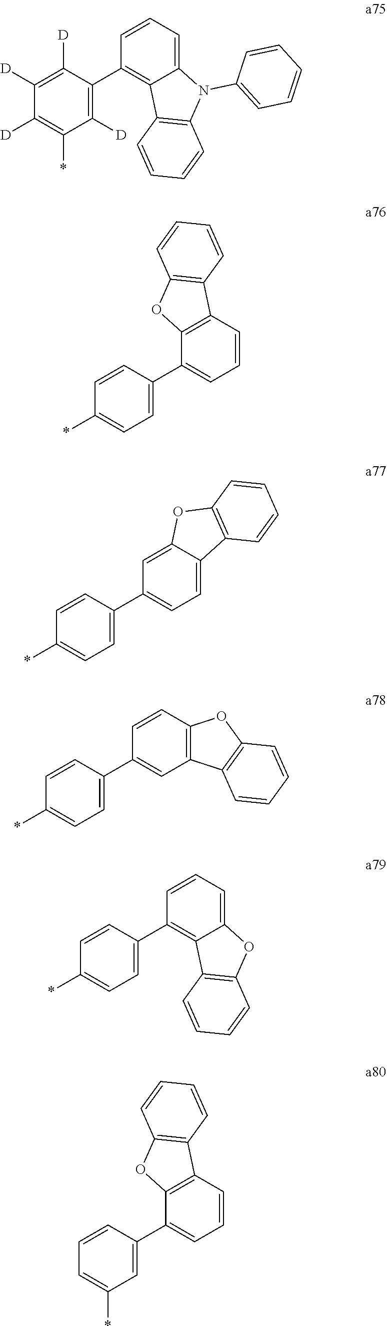

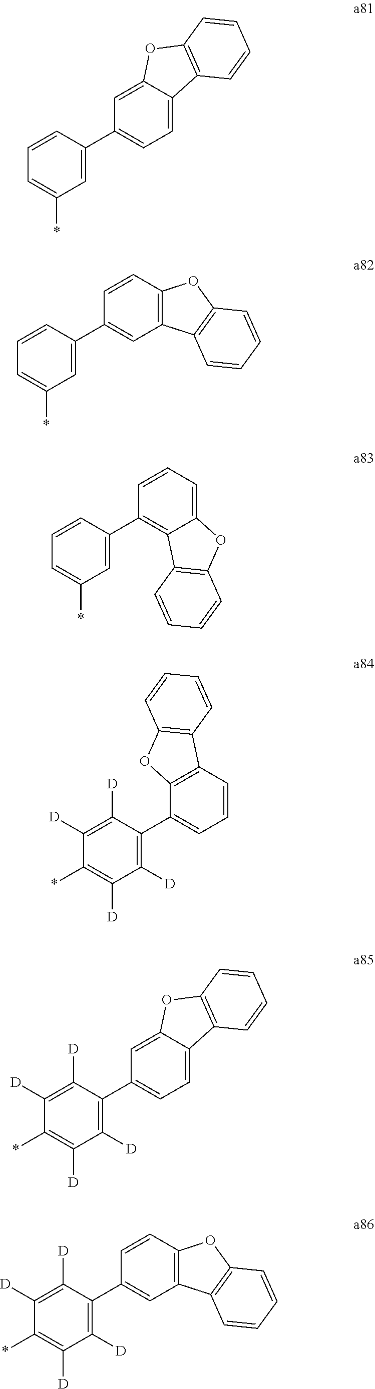 [SMILES: *c1cccc(-c2ccc3c(c2)oc2ccccc23)c1 ; *c1cccc(-c2ccc3oc4ccccc4c3c2)c1 ; *c1cccc(-c2cccc3oc4ccccc4c23)c1 ; *c1c([2H])c([2H])c(-c2cccc3c2oc2ccccc23)c([2H])c1[2H] ; *c1c([2H])c([2H])c(-c2ccc3c(c2)oc2ccccc23)c([2H])c1[2H] ; *c1c([2H])c([2H])c(-c2ccc3oc4ccccc4c3c2)c([2H])c1[2H]]

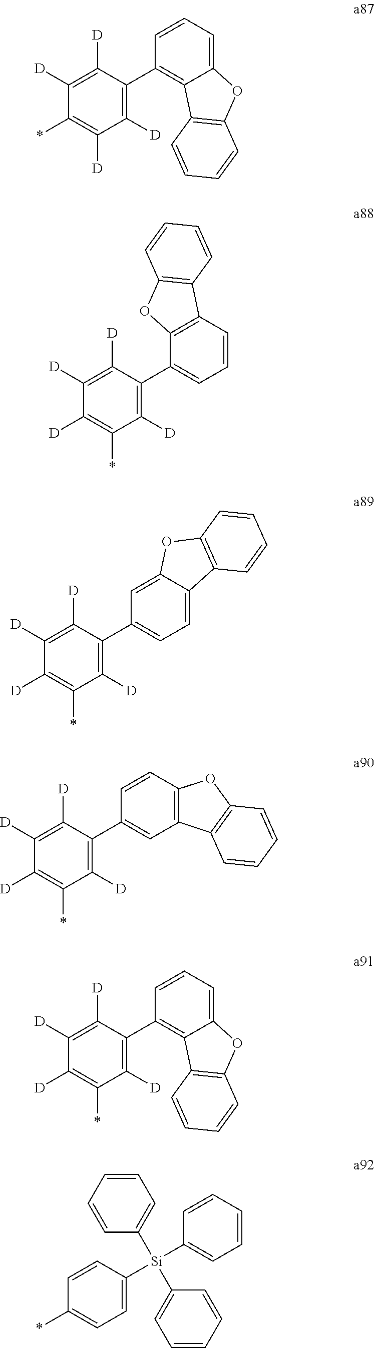 [SMILES: *c1c([2H])c([2H])c(-c2cccc3oc4ccccc4c23)c([2H])c1[2H] ; *c1c([2H])c([2H])c([2H])c(-c2cccc3c2oc2ccccc23)c1[2H] ; *c1c([2H])c([2H])c([2H])c(-c2ccc3c(c2)oc2ccccc23)c1[2H] ; *c1c([2H])c([2H])c([2H])c(-c2ccc3oc4ccccc4c3c2)c1[2H] ; *c1c([2H])c([2H])c([2H])c(-c2cccc3oc4ccccc4c23)c1[2H] ; *c1ccc([Si](c2ccccc2)(c2ccccc2)c2ccccc2)cc1]

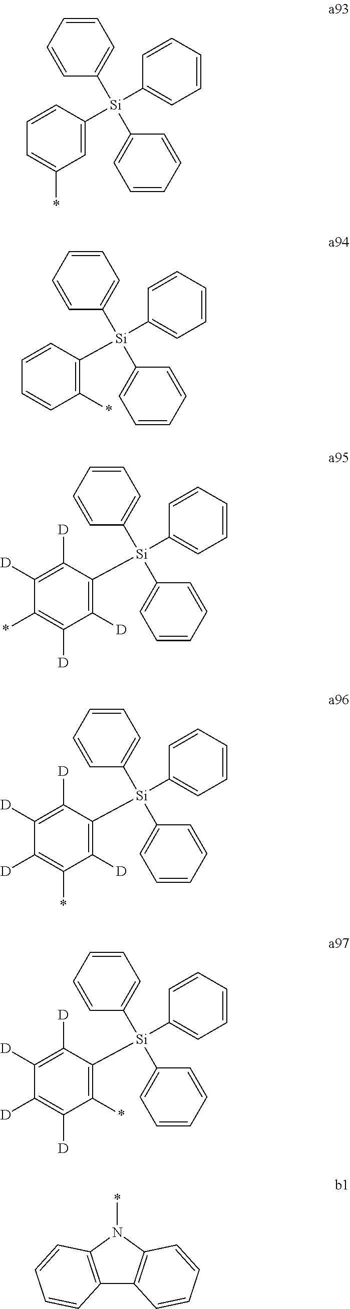

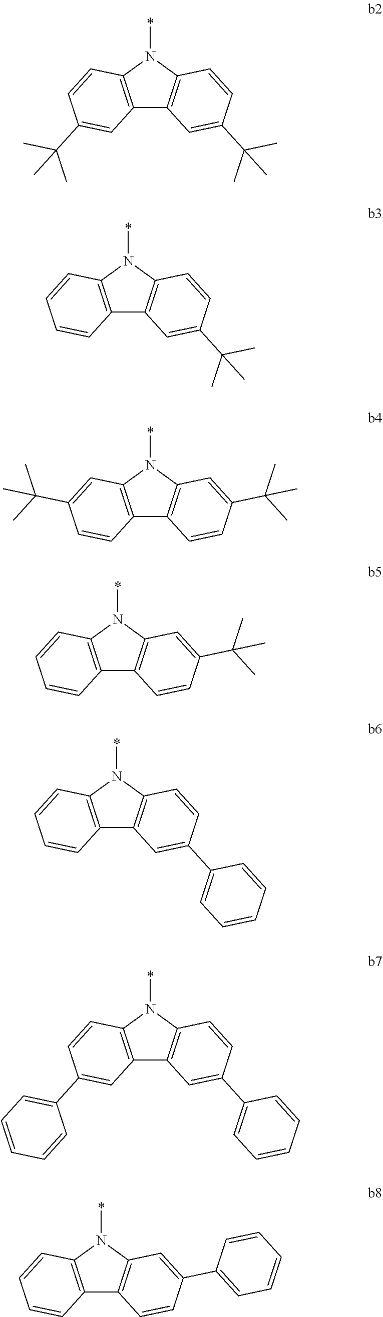

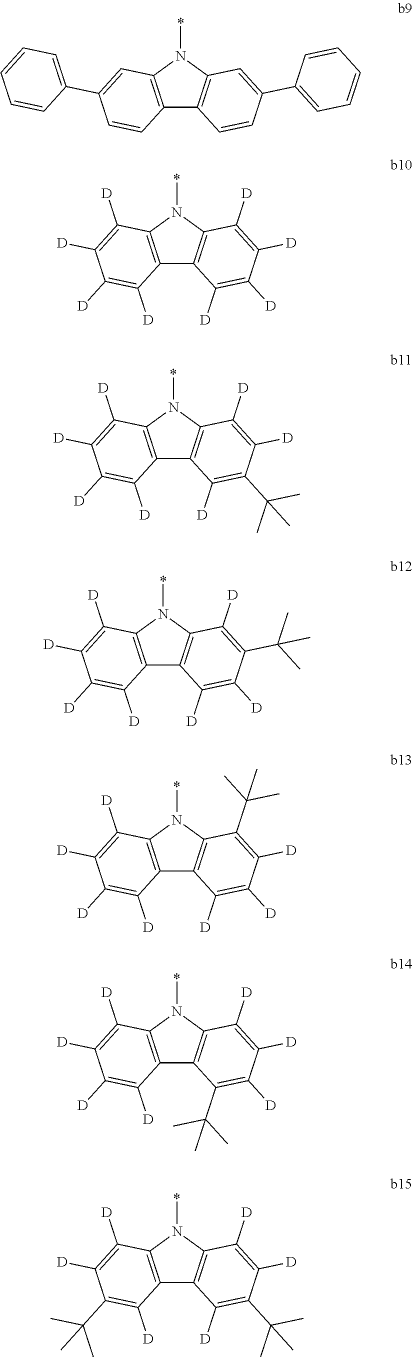

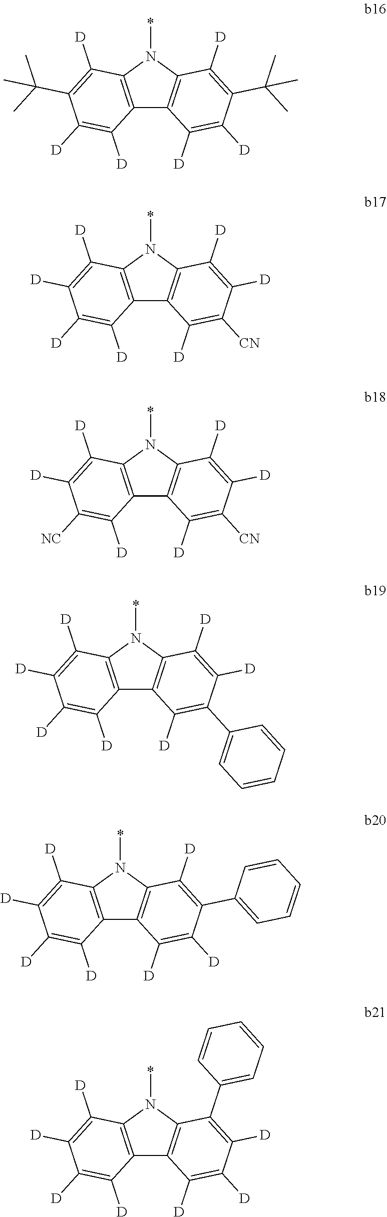 [SMILES: *n1c2c([2H])c(C(C)(C)C)c([2H])c([2H])c2c2c([2H])c([2H])c(C(C)(C)C)c([2H])c21 ; *n1c2c([2H])c([2H])c([2H])c([2H])c2c2c([2H])c(C#N)c([2H])c([2H])c21 ; *n1c2c([2H])c([2H])c(C#N)c([2H])c2c2c([2H])c(C#N)c([2H])c([2H])c21 ; *n1c2c([2H])c([2H])c([2H])c([2H])c2c2c([2H])c(-c3ccccc3)c([2H])c([2H])c21 ; *n1c2c([2H])c([2H])c([2H])c([2H])c2c2c([2H])c([2H])c(-c3ccccc3)c([2H])c21 ; *n1c2c([2H])c([2H])c([2H])c([2H])c2c2c([2H])c([2H])c([2H])c(-c3ccccc3)c21]

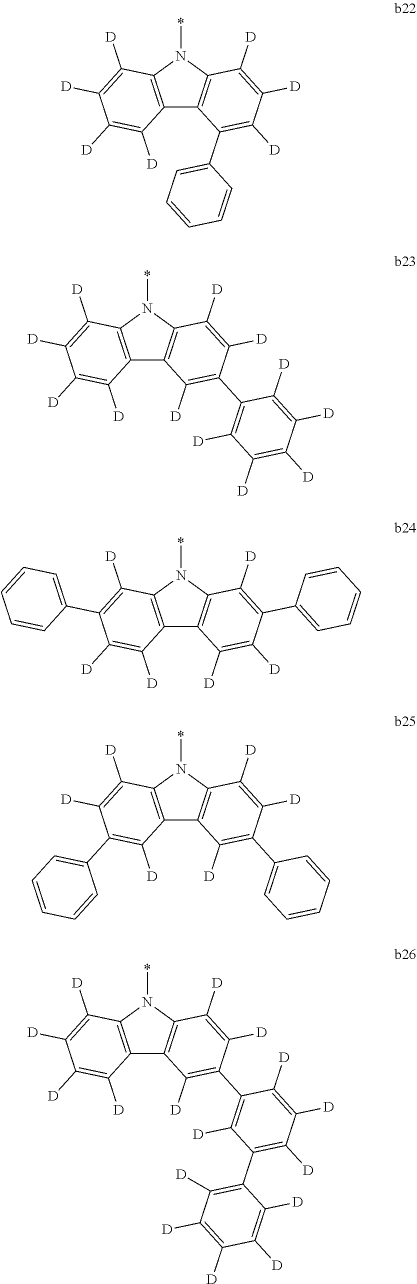 [SMILES: *n1c2c([2H])c([2H])c([2H])c([2H])c2c2c(-c3ccccc3)c([2H])c([2H])c([2H])c21 ; *n1c2c([2H])c([2H])c([2H])c([2H])c2c2c([2H])c(-c3c([2H])c([2H])c([2H])c([2H])c3[2H])c([2H])c([2H])c21 ; *n1c2c([2H])c(-c3ccccc3)c([2H])c([2H])c2c2c([2H])c([2H])c(-c3ccccc3)c([2H])c21 ; *n1c2c([2H])c([2H])c(-c3ccccc3)c([2H])c2c2c([2H])c(-c3ccccc3)c([2H])c([2H])c21 ; *n1c2c([2H])c([2H])c([2H])c([2H])c2c2c([2H])c(-c3c([2H])c([2H])c([2H])c(-c4c([2H])c([2H])c([2H])c([2H])c4[2H])c3[2H])c([2H])c([2H])c21]

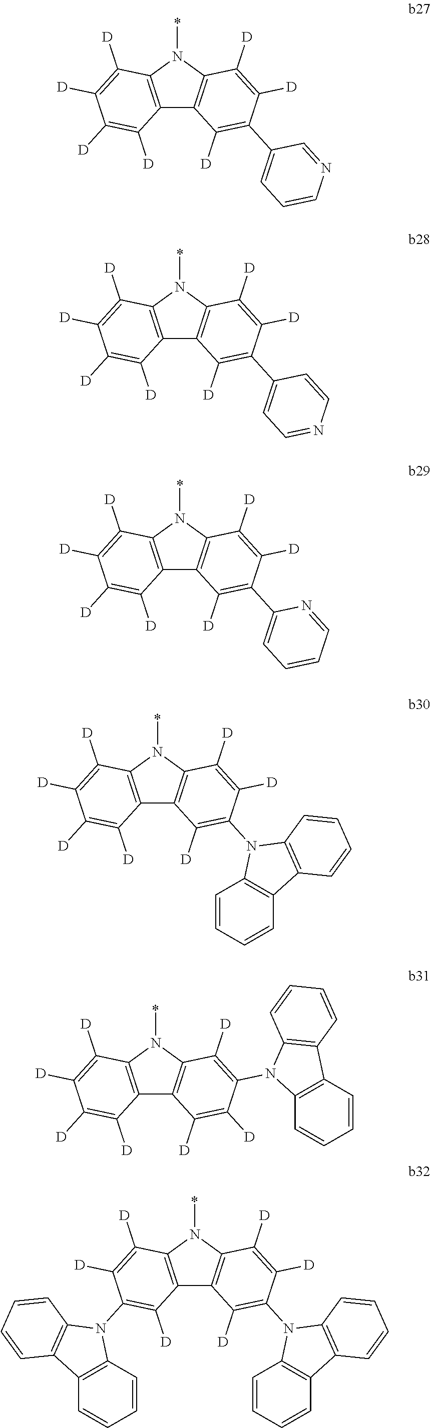

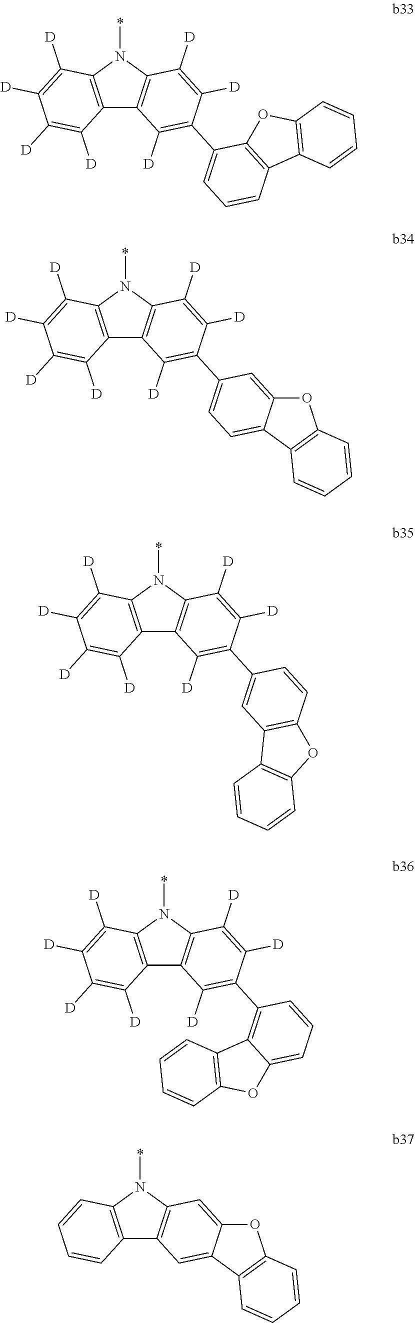 [SMILES: *n1c2c([2H])c([2H])c([2H])c([2H])c2c2c([2H])c(-c3cccc4c3oc3ccccc34)c([2H])c([2H])c21 ; *n1c2c([2H])c([2H])c([2H])c([2H])c2c2c([2H])c(-c3ccc4c(c3)oc3ccccc34)c([2H])c([2H])c21 ; *n1c2c([2H])c([2H])c([2H])c([2H])c2c2c([2H])c(-c3ccc4oc5ccccc5c4c3)c([2H])c([2H])c21 ; *n1c2c([2H])c([2H])c([2H])c([2H])c2c2c([2H])c(-c3cccc4oc5ccccc5c34)c([2H])c([2H])c21 ; *n1c2ccccc2c2cc3c(cc21)oc1ccccc13]

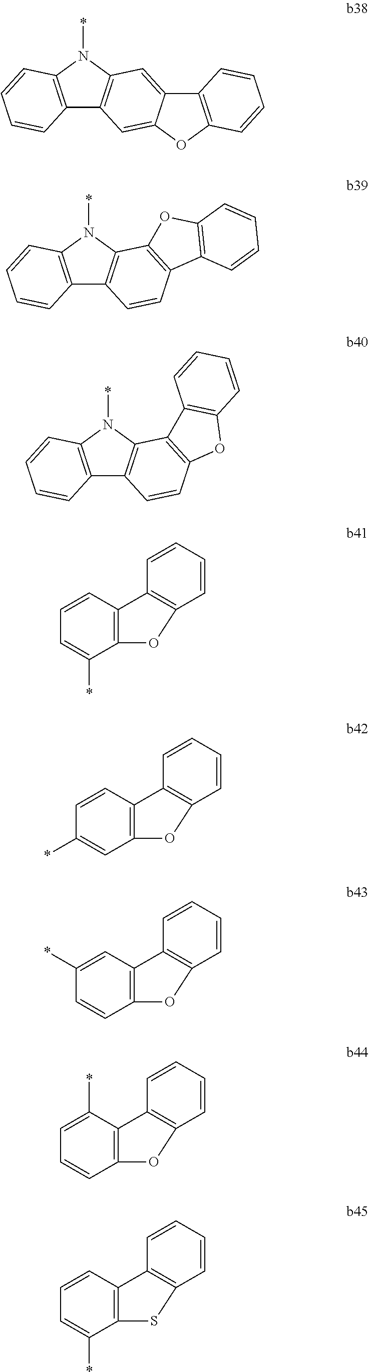

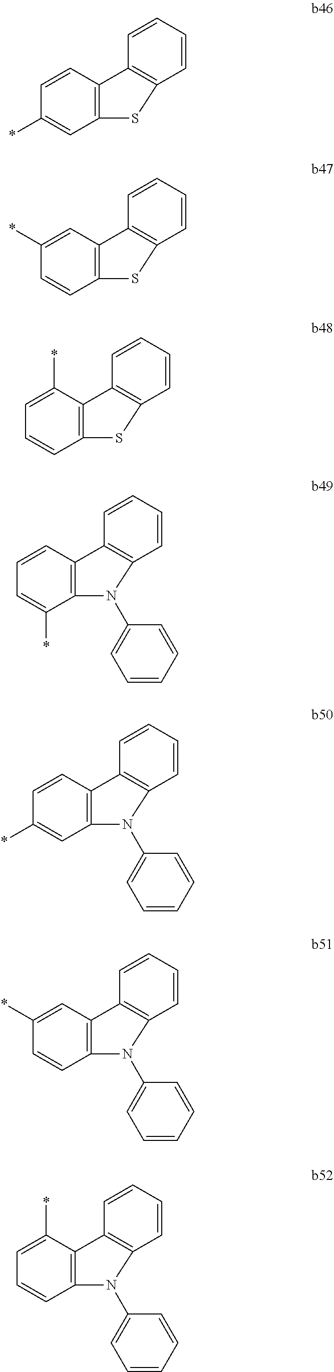

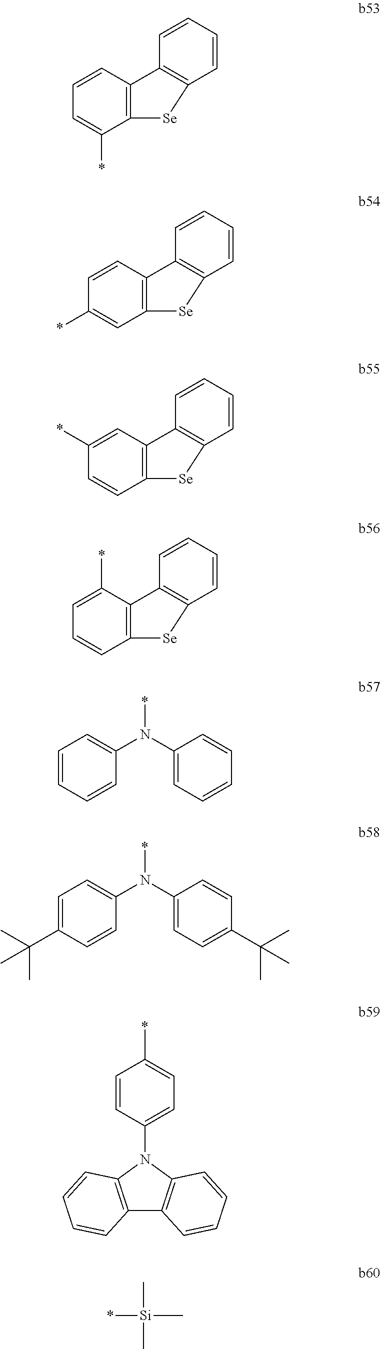

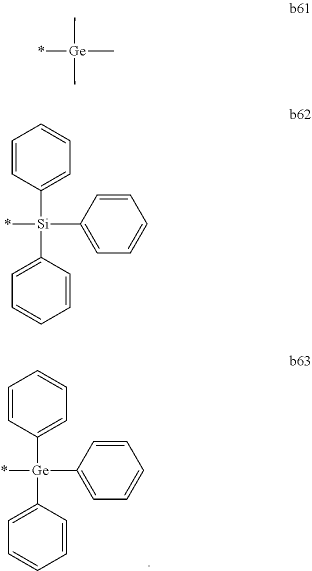

10. The light emitting element of claim 1, wherein the emission layer further comprises at least one of a second compound represented by Formula HT-1, a third compound represented by Formula ET-1, or a fourth compound represented by Formula D-1: 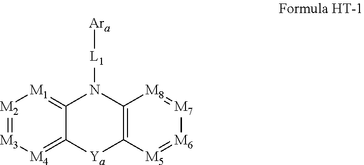
in Formula HT-1,
M₁ to M₈ are each independently N or CR₅₁,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, CR₅₂R₅₃, or SiR₅₄R₅₅,
Arₐ is a substituted or unsubstituted aryl group having 6 to 30 ring-forming carbon atoms, or a substituted or unsubstituted heteroaryl group having 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or are bonded to an adjacent group to form a ring, 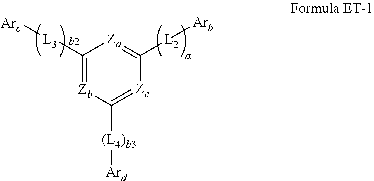
in Formula ET-1,
at least one selected from among Zₐ to Z_{c} is N, and any remaining selected from among Zₐ to Z_{c} are CR₅₆,
R₅₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group of 2 to 60 ring-forming carbon atoms,
b1 to b3 are each independently an integer of 0 to 10, and
Ar_{b} to Ar_{d} are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms: 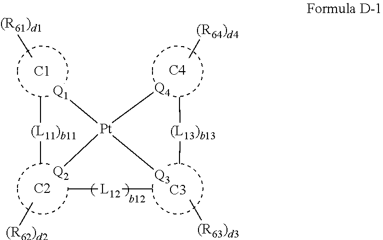
in Formula D-1,
Q₀ to Q₄ are each independently C or N,
C1 to C4 are each independently a substituted or unsubstituted hydrocarbon ring having 5 to 30 ring-forming carbon atoms, or a substituted or unsubstituted heterocycle having 2 to 30 ring-forming carbon atoms,
L₁₁ to L₁₃ are each independently a direct linkage, 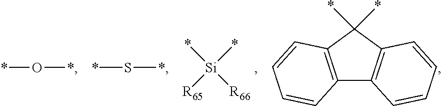
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 are each independently an integer of 0 to 4.

11. A display device comprising:
a base layer;
a circuit layer on the base layer; and
a display element layer on the circuit layer and comprising a light emitting element,
the light emitting element comprising a first electrode, a second electrode on the first electrode, and an emission layer between the first electrode and the second electrode and comprising a first compound represented by Formula 1: 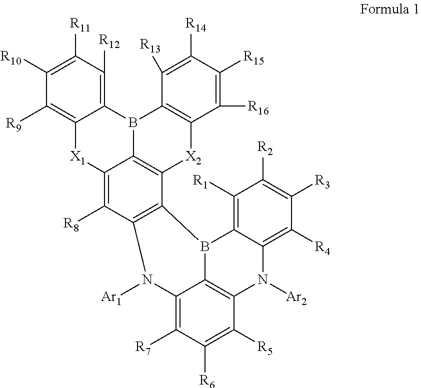
in Formula 1,
X₁ is NR₁₇, O, S, Se, or Te,
X₂ is O, S, or Se,
R₁ to R₇ are each independently a hydrogen atom, a deuterium atom, a halogen atom, a cyano group, a nitro group, a substituted or unsubstituted silyl group, a substituted or unsubstituted germanium group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
R₈ to R₁₆ are each independently a hydrogen atom, a deuterium atom, a halogen atom, a cyano group, a nitro group, a substituted or unsubstituted silyl group, a substituted or unsubstituted germanium group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
R₁₇ is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or is bonded to an adjacent group to form a ring,
Ar₁ and Ar₂ are each independently a substituted or unsubstituted aryl group having 6 to 30 ring-forming carbon atoms, or a substituted or unsubstituted heteroaryl group having 2 to 30 ring-forming carbon atoms, and
at least one of Ar₁ or Ar₂ is represented by Formula S: 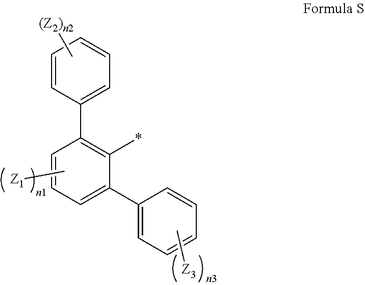
in Formula S,
Z₁ to Z₃ are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
n1 is an integer of 0 to 3,
n2 and n3 are each independently an integer of 0 to 5, and [symbol]
is a position linked to Formula 1.

12. The display device of claim 11, wherein the light emitting element further comprises a capping layer on the second electrode, and
the capping layer has a refractive index of about 1.6 or more with respect to light in a wavelength range of about 550 nanometer (nm) to about 660 nm.

13. The display device of claim 11, further comprising a light control layer on the display device and comprising quantum dots,
the light emitting element being configured to emit a first color light, and
the light control layer comprising:
a first light control part comprising a first quantum dot configured to convert the first color light into a second color light having a wavelength region being longer than a wavelength region of the first color light;
a second light control part comprising a second quantum dot configured to convert the second color light into a third color light having a wavelength region being longer than a wavelength region of the second color light; and
a third light control part configured to transmit the first color light.

14. The display device of claim 13, further comprising a color filter layer on the light control layer,
the color filter layer comprising:
a first filter configured to transmit the second color light;
a second filter configured to transmit the third color light; and
a third filter configured to transmit the first color light.

15. A fused polycyclic compound represented by Formula 1: 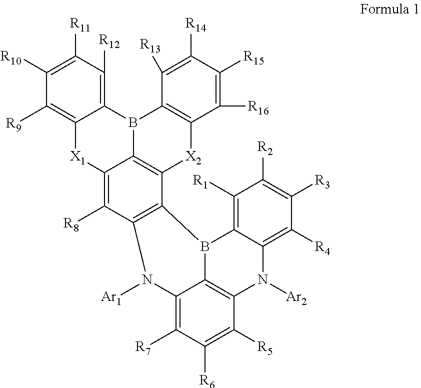
in Formula 1,
X₁ is NR₁₇, O, S, Se, or Te,
X₂ is O, S, or Se,
R₁ to R₇ are each independently a hydrogen atom, a deuterium atom, a halogen atom, a cyano group, a nitro group, a substituted or unsubstituted silyl group, a substituted or unsubstituted germanium group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
R₈ to R₁₆ are each independently a hydrogen atom, a deuterium atom, a halogen atom, a cyano group, a nitro group, a substituted or unsubstituted silyl group, a substituted or unsubstituted germanium group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
R₁₇ is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or is bonded to an adjacent group to form a ring,
Ar₁ and Ar₂ are each independently a substituted or unsubstituted aryl group having 6 to 30 ring-forming carbon atoms, or a substituted or unsubstituted heteroaryl group having 2 to 30 ring-forming carbon atoms, and
at least one of Ar₁ or Ar₂ is represented by Formula S: 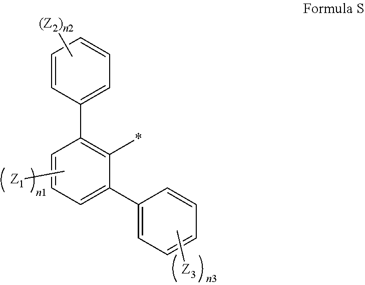
wherein, in Formula S,
Z₁ to Z₃ are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
n1 is an integer of 0 to 3,
n2 and n3 are each independently an integer of 0 to 5, and [symbol]
is a position linked to Formula 1.

16. The fused polycyclic compound of claim 15, wherein the fused polycyclic compound is represented by Formula 2-1 or Formula 2-2: 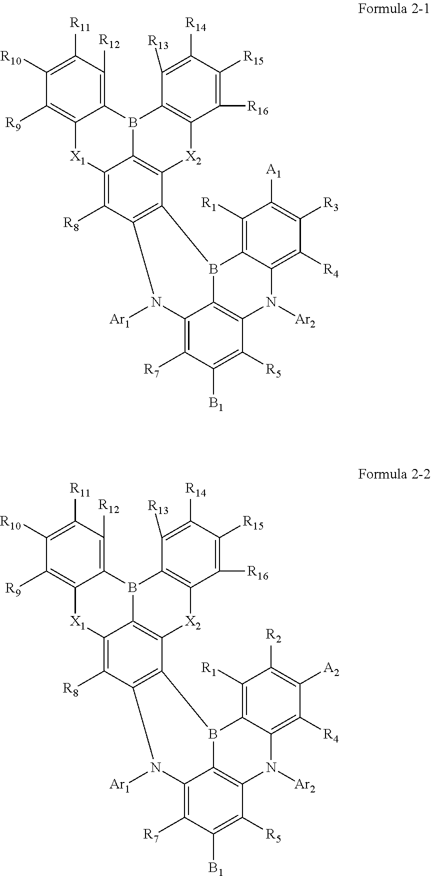
in Formula 2-1 and Formula 2-2,
A₁ and A₂ are each independently represented by any one selected from among Formula A-1 to Formula A-4, and
B₁ is a substituted or unsubstituted alkyl group having 1 to 10 carbon atoms: 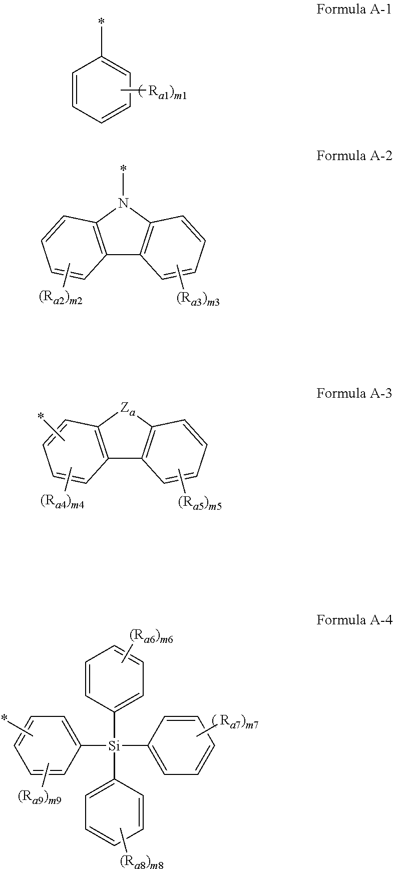
in Formula A-1 to Formula A-4,
Zₐ is NRₐ₁₀, O, S, or Se,
Rₐ₁ to Rₐ₁₀ are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
m1, and m6 to m8 are each independently an integer of 0 to 5,
m2, m3, m5, and m9 are each independently an integer of 0 to 4, and
m4 is an integer of 0 to 3, and
in Formula 2-1 and Formula 2-2,
X₁, X₂, Ar₁, Ar₂, R₁ to R₅, and R₇ to R₁₆ are as defined in Formula 1.

17. The fused polycyclic compound of claim 15, wherein the fused polycyclic compound is represented by any one selected from among Formula 3-1 to Formula 3-3: 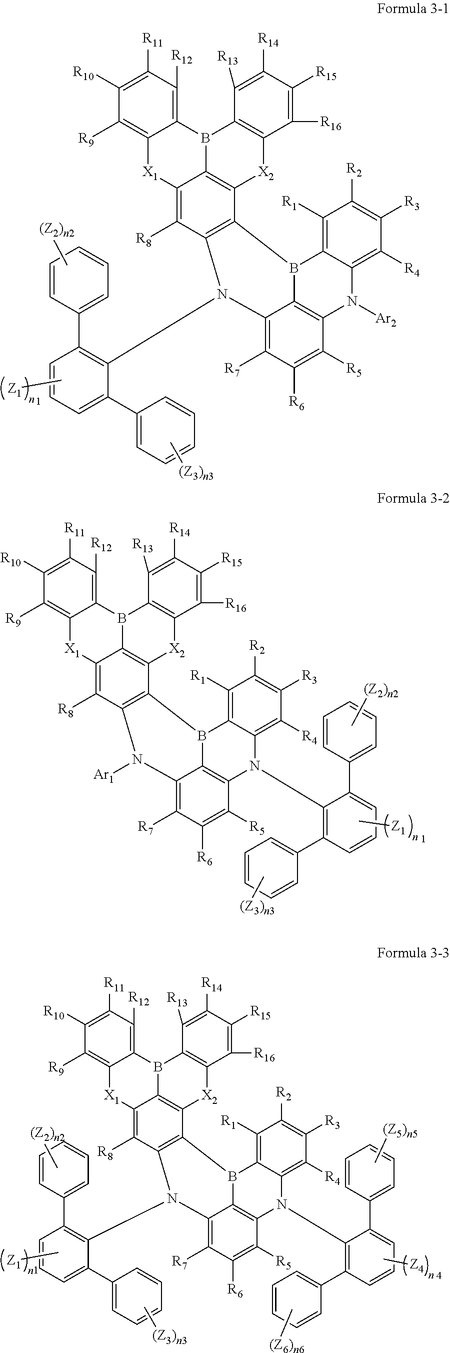
in Formula 3-1 to Formula 3-3,
Z₄ to Z₆ are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
n4 is an integer of 0 to 3,
n5 and n6 are each independently an integer of 0 to 5, and
X₁, X₂, Ar₁, Ar₂, R₁ to R₁₆, Z₁ to Z₃, and n1 to n3 are as defined in Formula 1 and Formula S.

18. The fused polycyclic compound of claim 15, wherein the fused polycyclic compound represented by Formula 1 is represented by any one among Formula 4-1 to Formula 4-5: 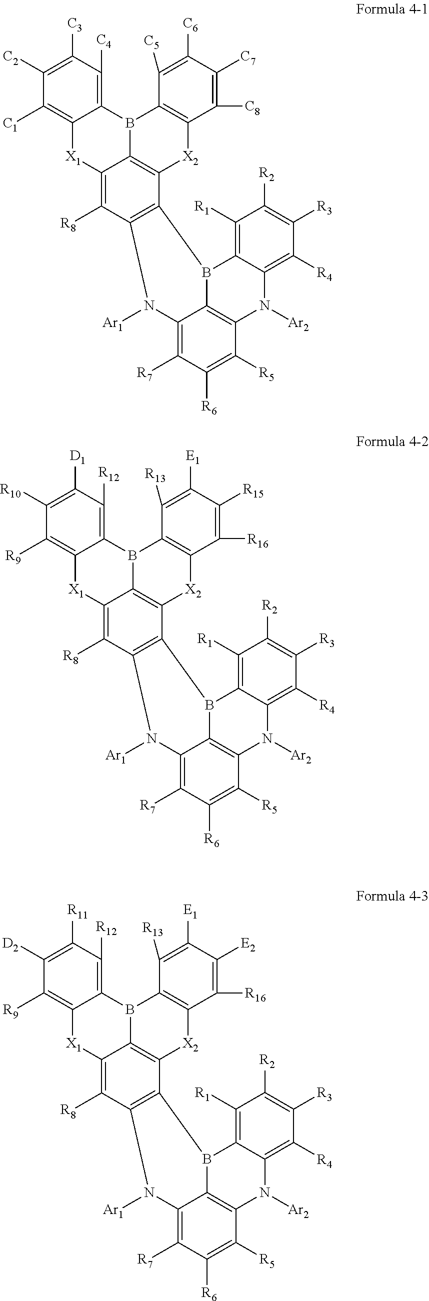 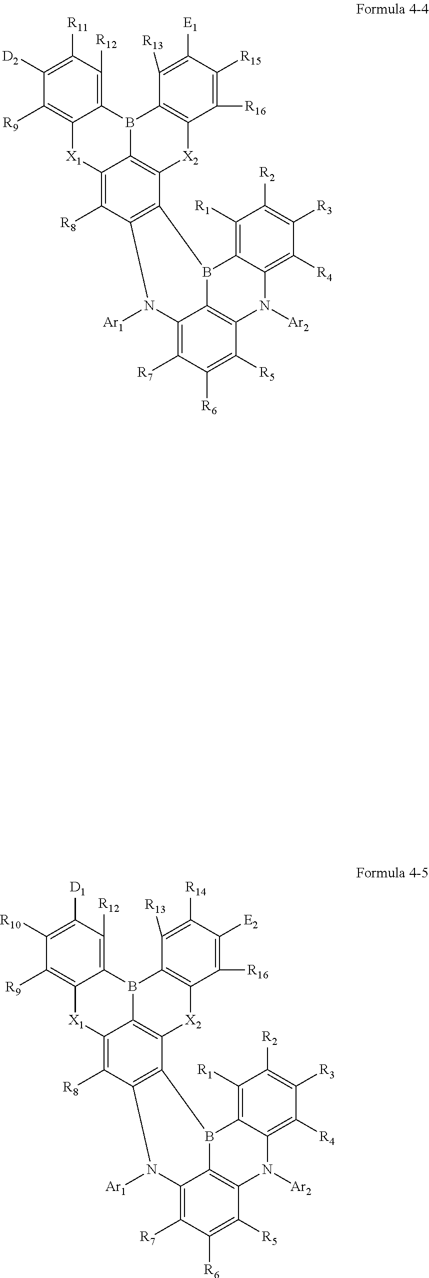
in Formula 4-1 to Formula 4-5,
C₁ to C₈ are each independently a hydrogen atom or a deuterium atom, and
D₁, D₂, E₁, and E₂ are each independently a substituted or unsubstituted alkyl group having 1 to 10 carbon atoms, or are represented by any one selected from among Formula C-1 to Formula C-5: 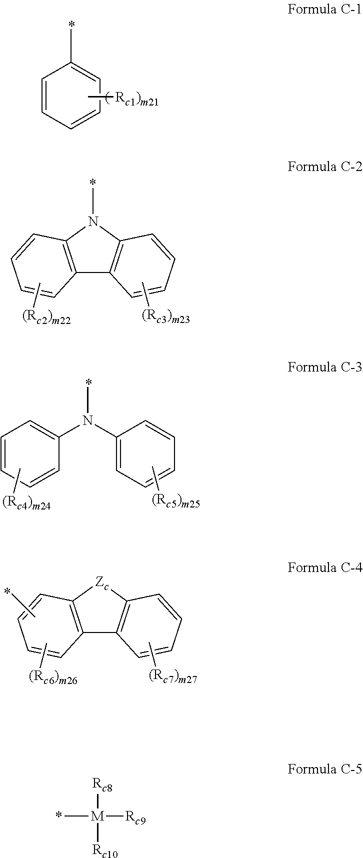
in Formula C-1 to Formula C-5,
Z_{c} is NR_{c11}, O, S, or Se,
M is Si or Ge,
R_{c1} to R_{c7} are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
R_{c8} to R_{c11} are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
m21, m24, and m25 are each independently an integer of 0 to 5,
m22, m23, and m27 are each independently an integer of 0 to 4, and
m26 is an integer of 0 to 3, and
in Formula 4-1 to Formula 4-5,
X₁, X₂, Ar₁, Ar₂, and R₁ to R₁₆ are as defined in Formula 1.

19. The fused polycyclic compound of claim 15, wherein the fused polycyclic compound is represented by any one selected from among Formula 5-1 to Formula 5-3: 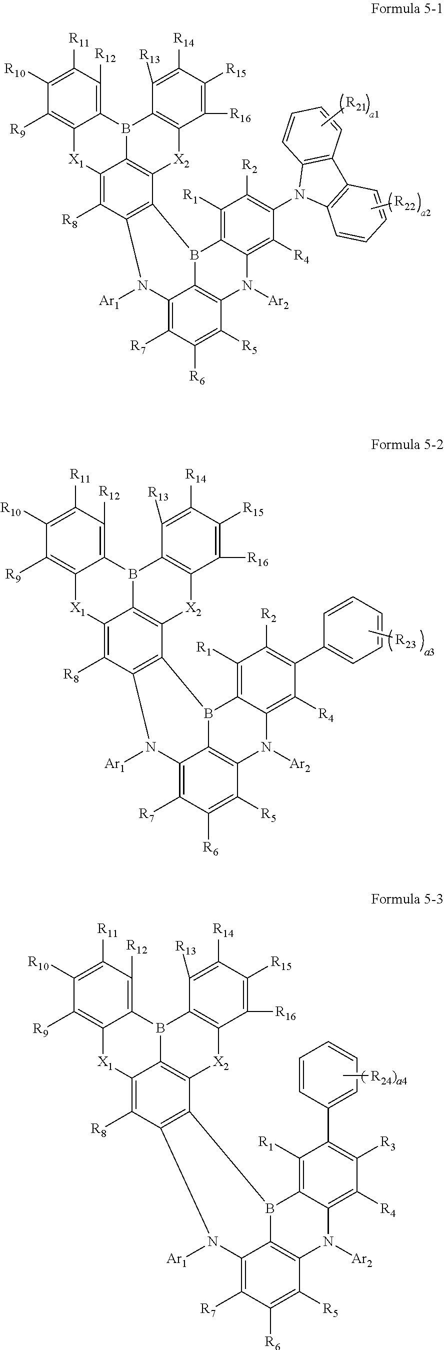
in Formula 5-1 to Formula 5-3,
R₂₁ to R₂₄ are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted thio group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
a1 and a2 are each independently an integer of 0 to 4,
a3 and a4 are each independently an integer of 0 to 5, and
X₁, X₂, Ar₁, Ar₂, and R₁ to R₁₆ are as defined in Formula 1.

20. The fused polycyclic compound of claim 15, wherein the fused polycyclic compound is any one selected from among compounds represented by Compound Group 1: 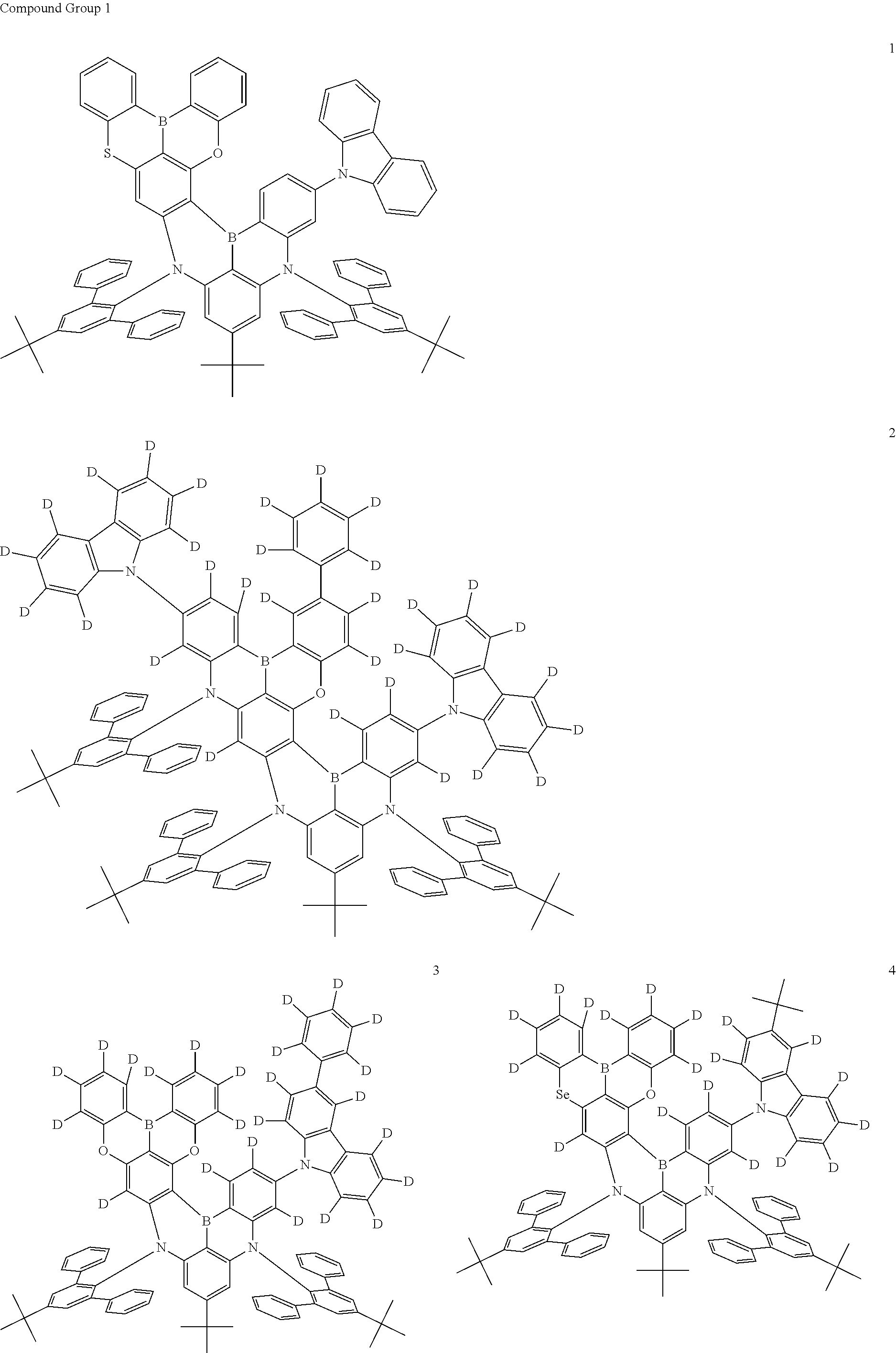 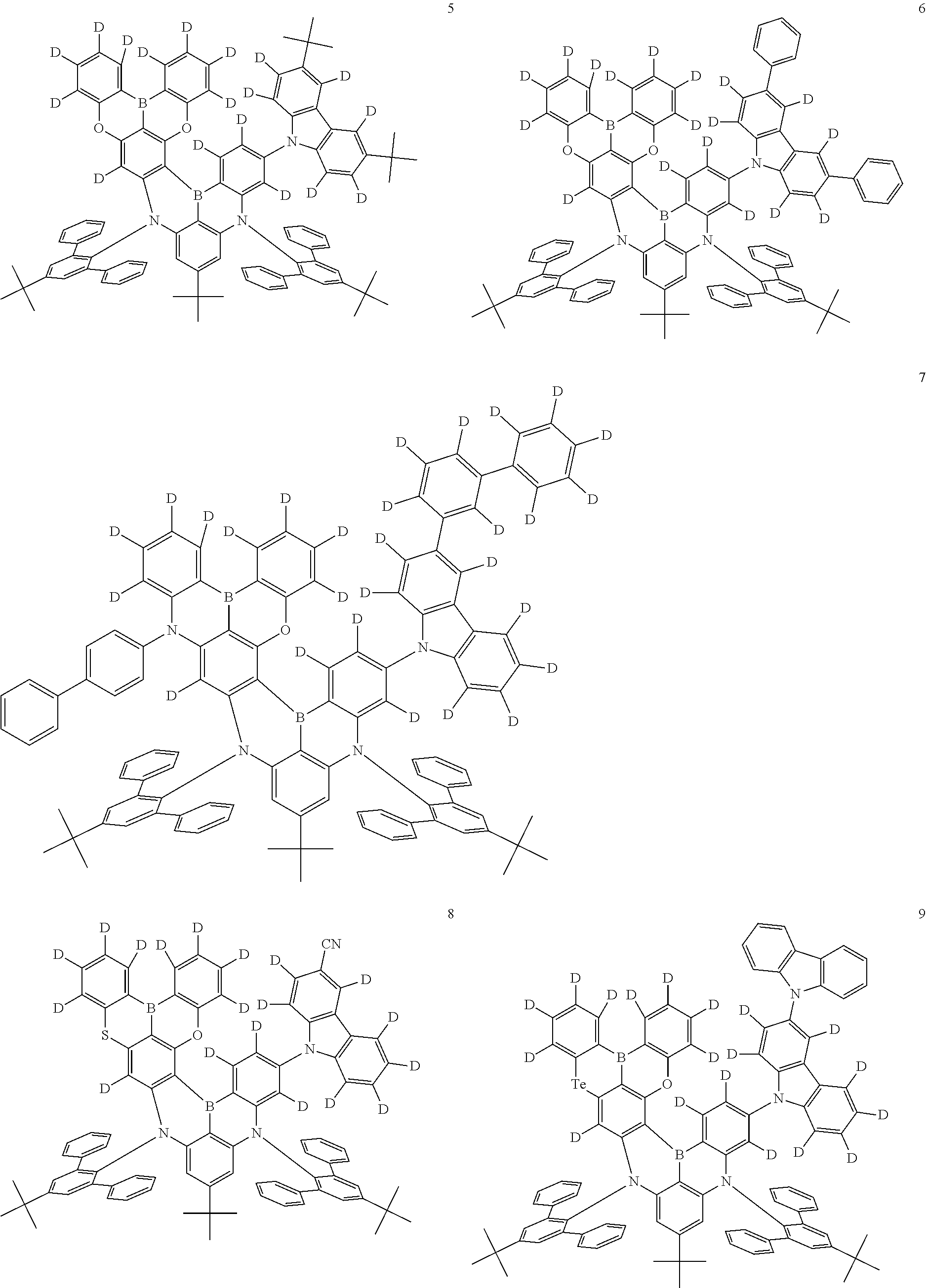 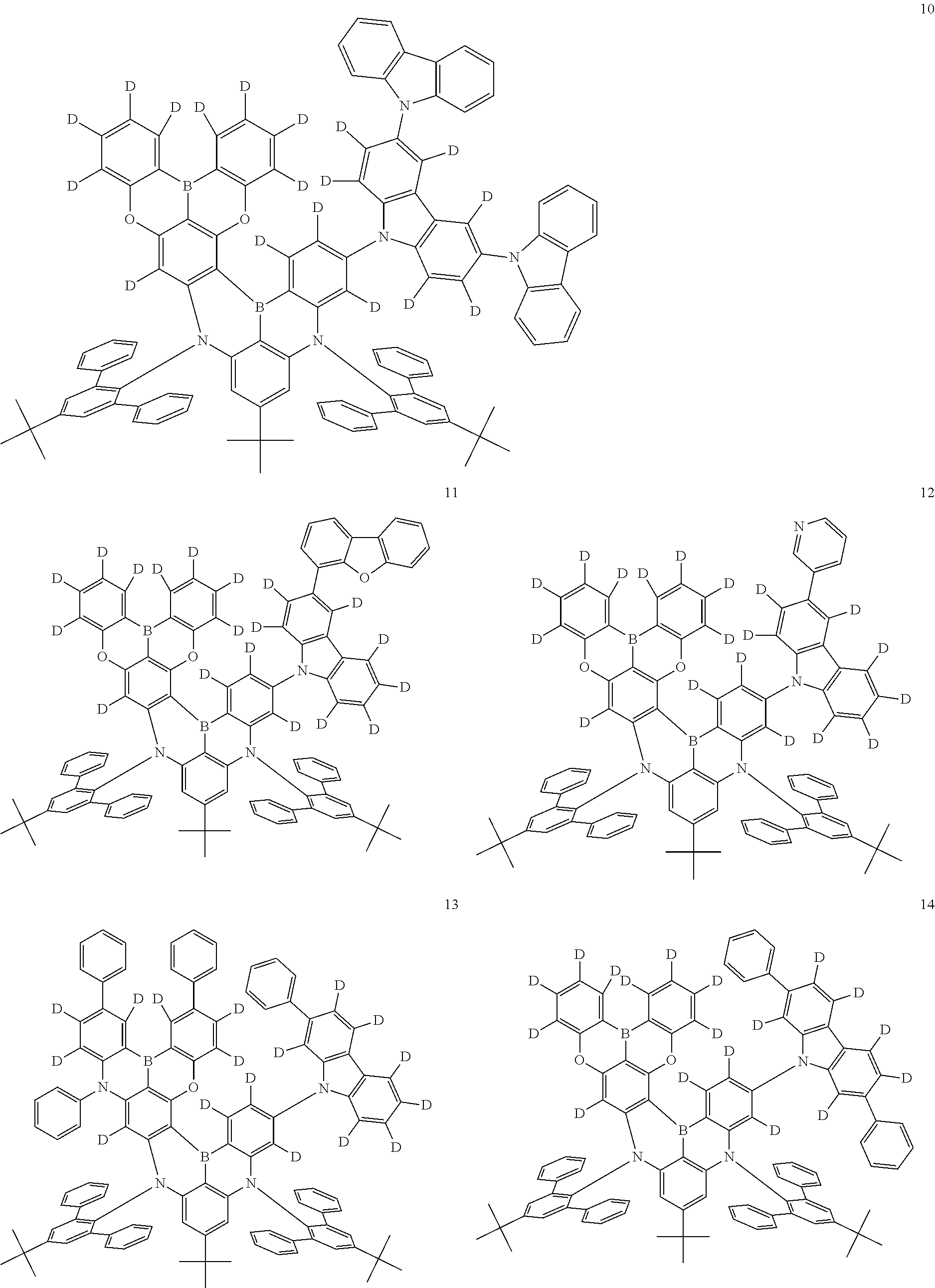 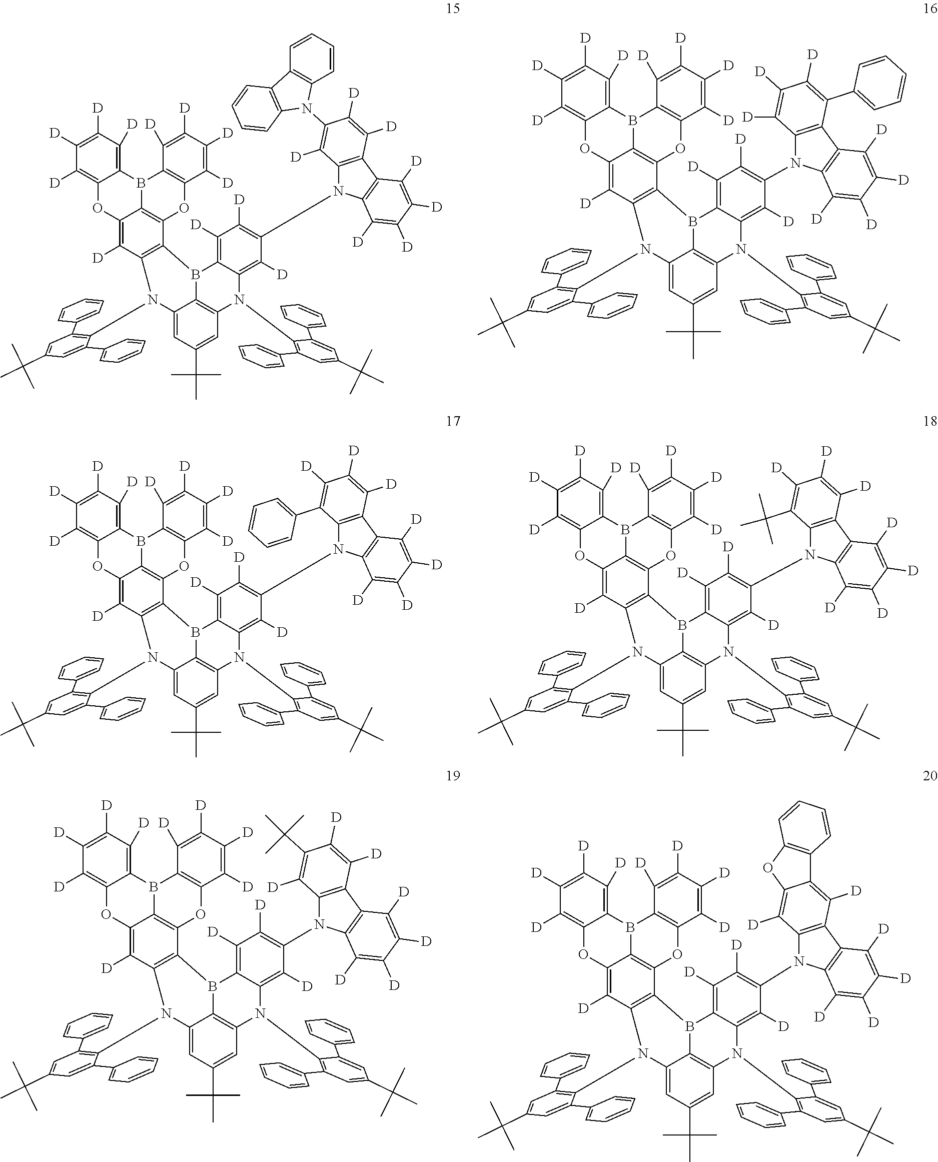 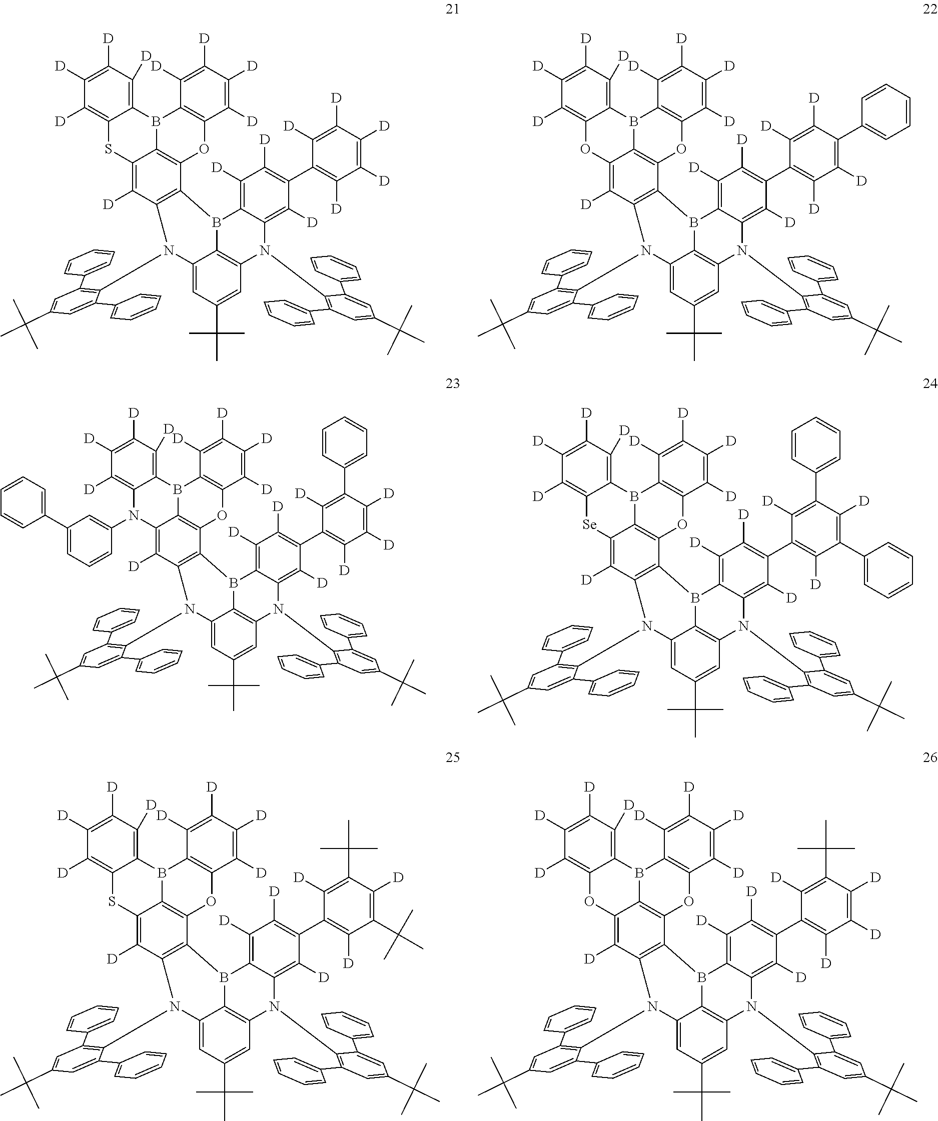 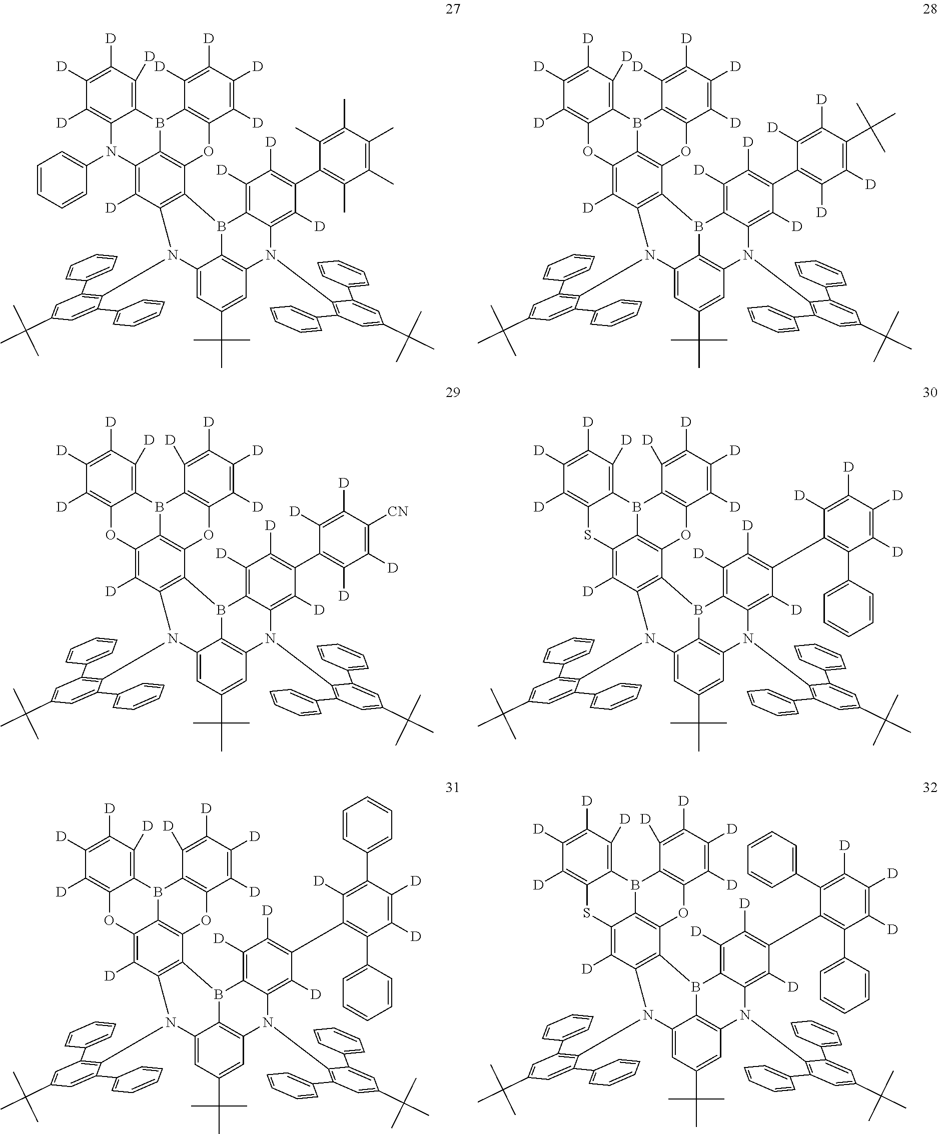 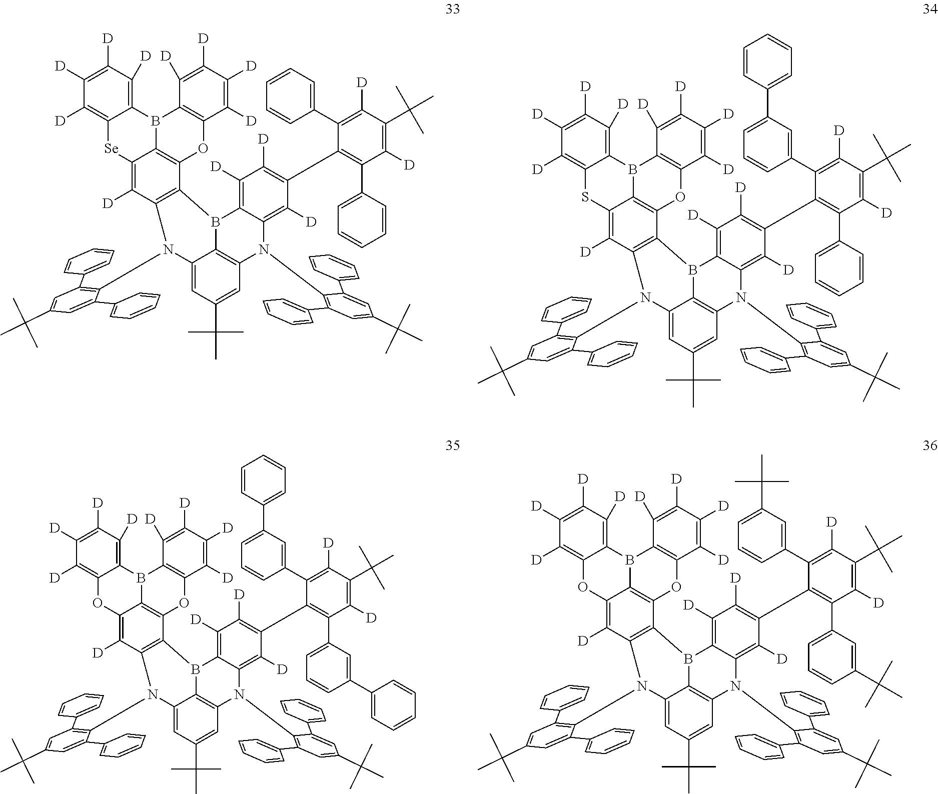 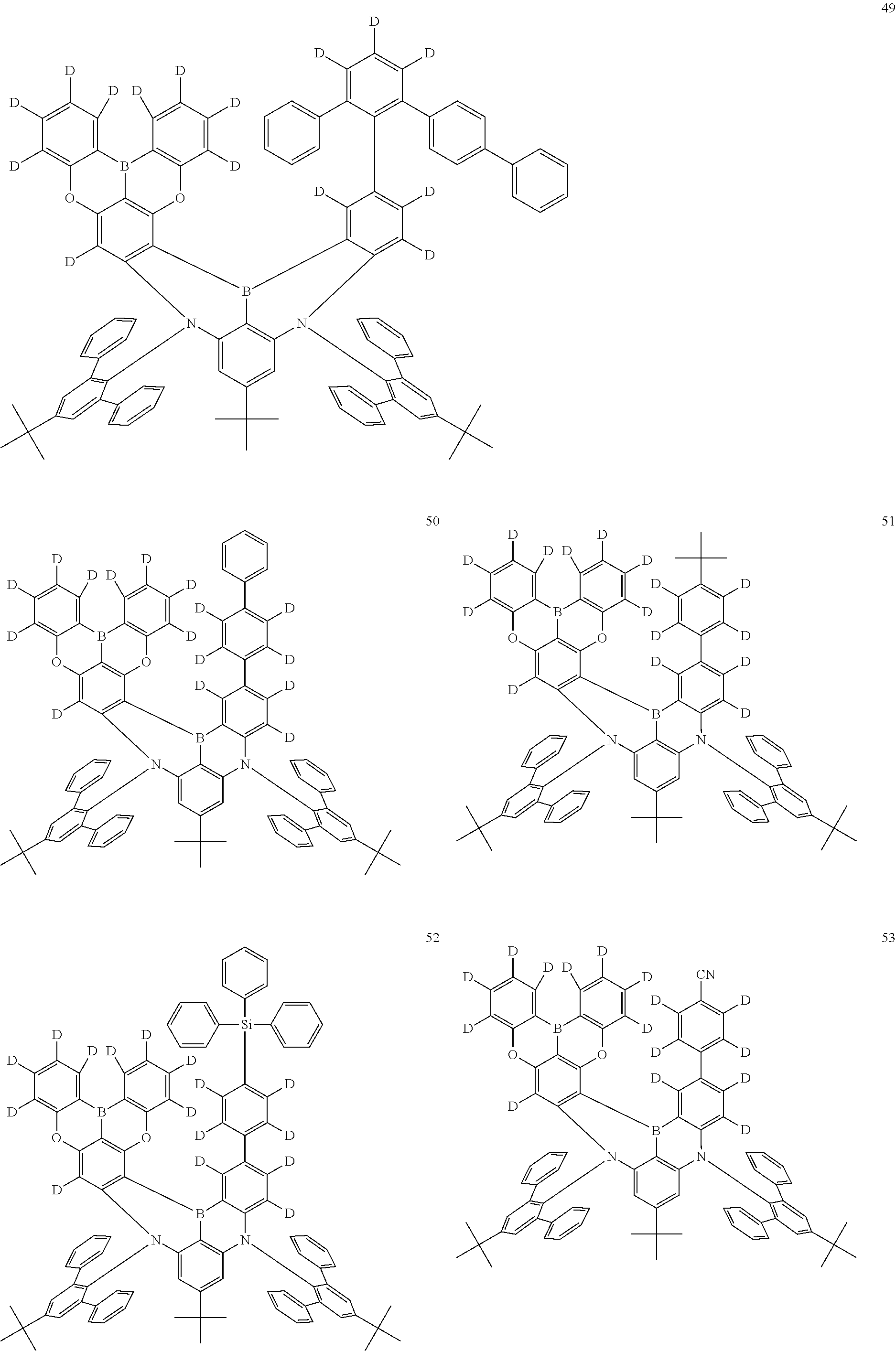 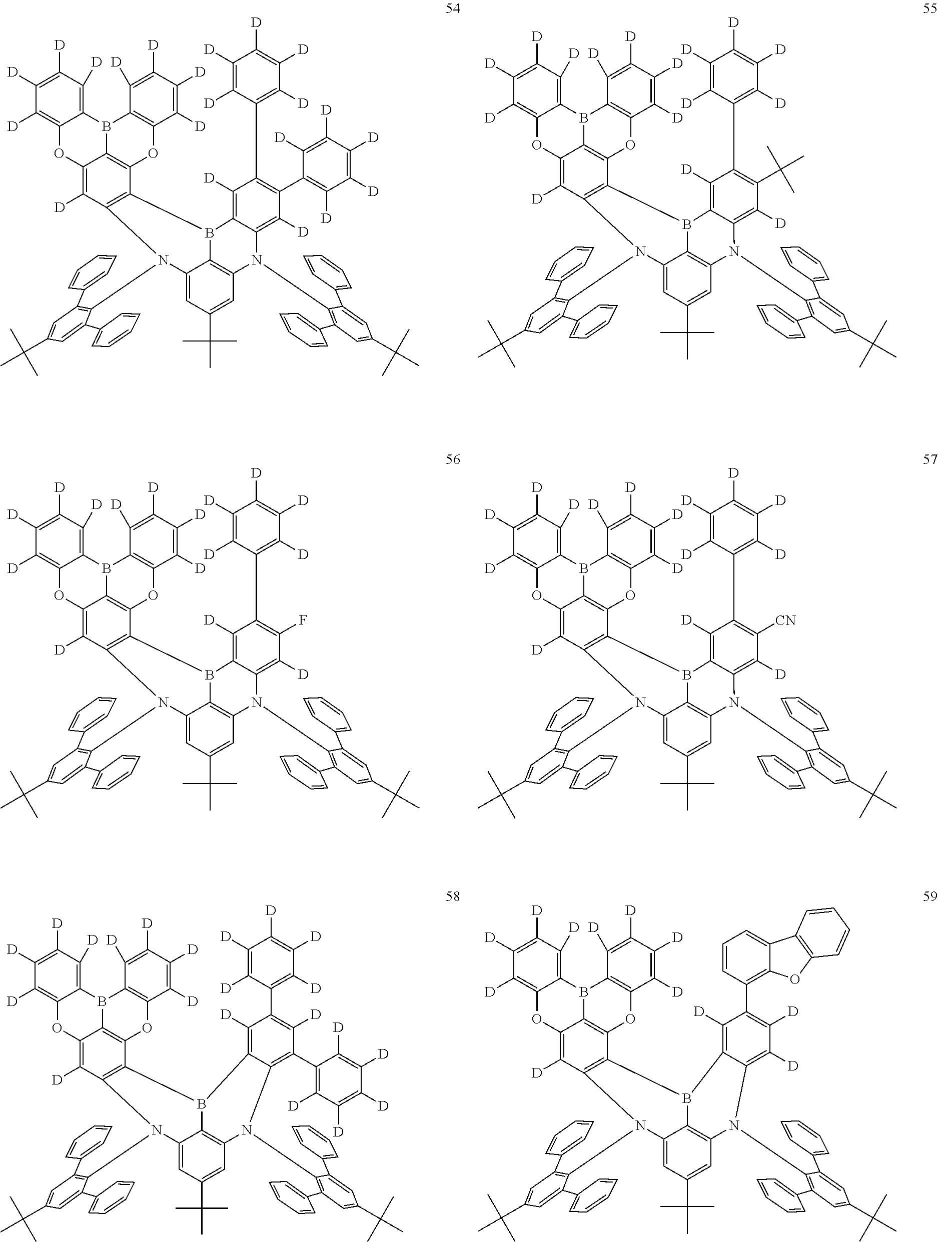 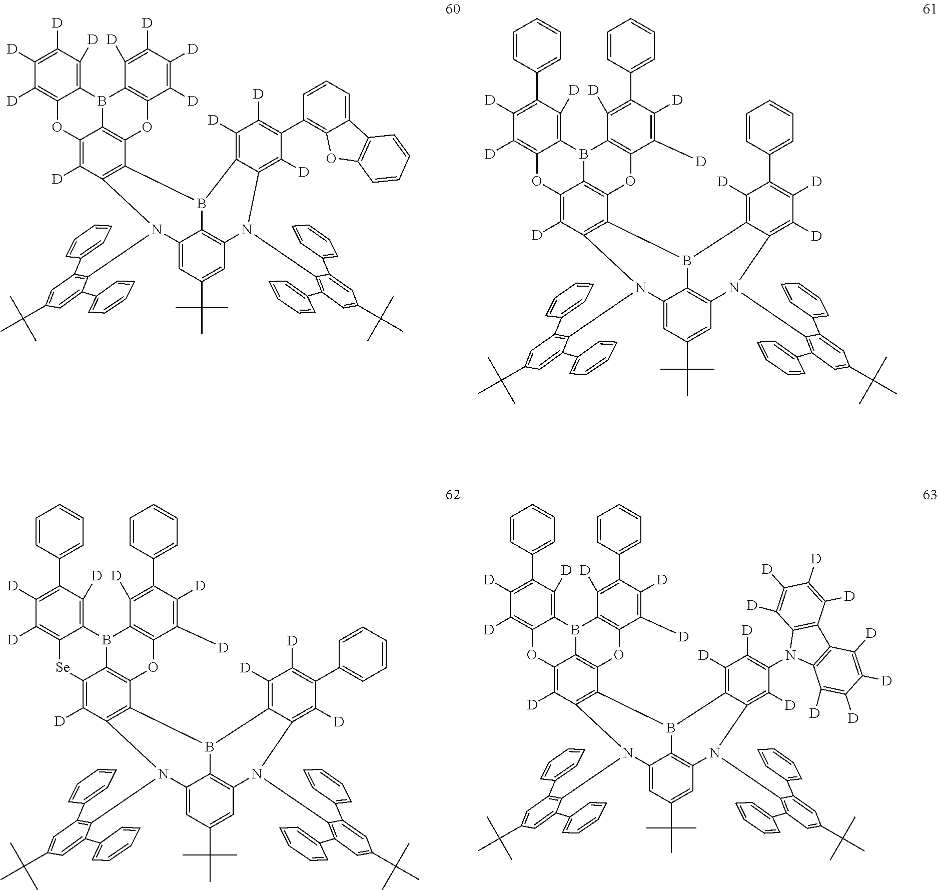 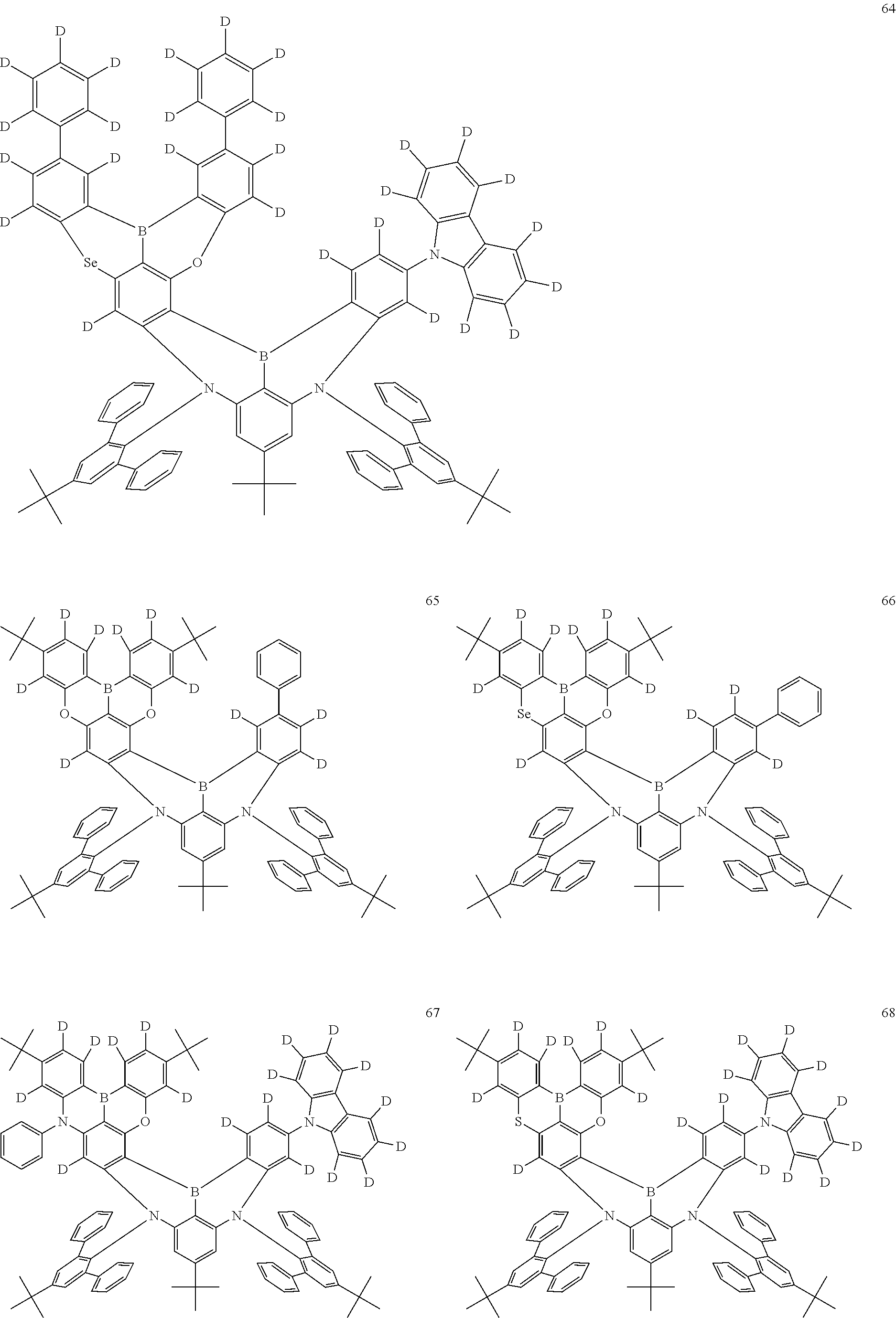 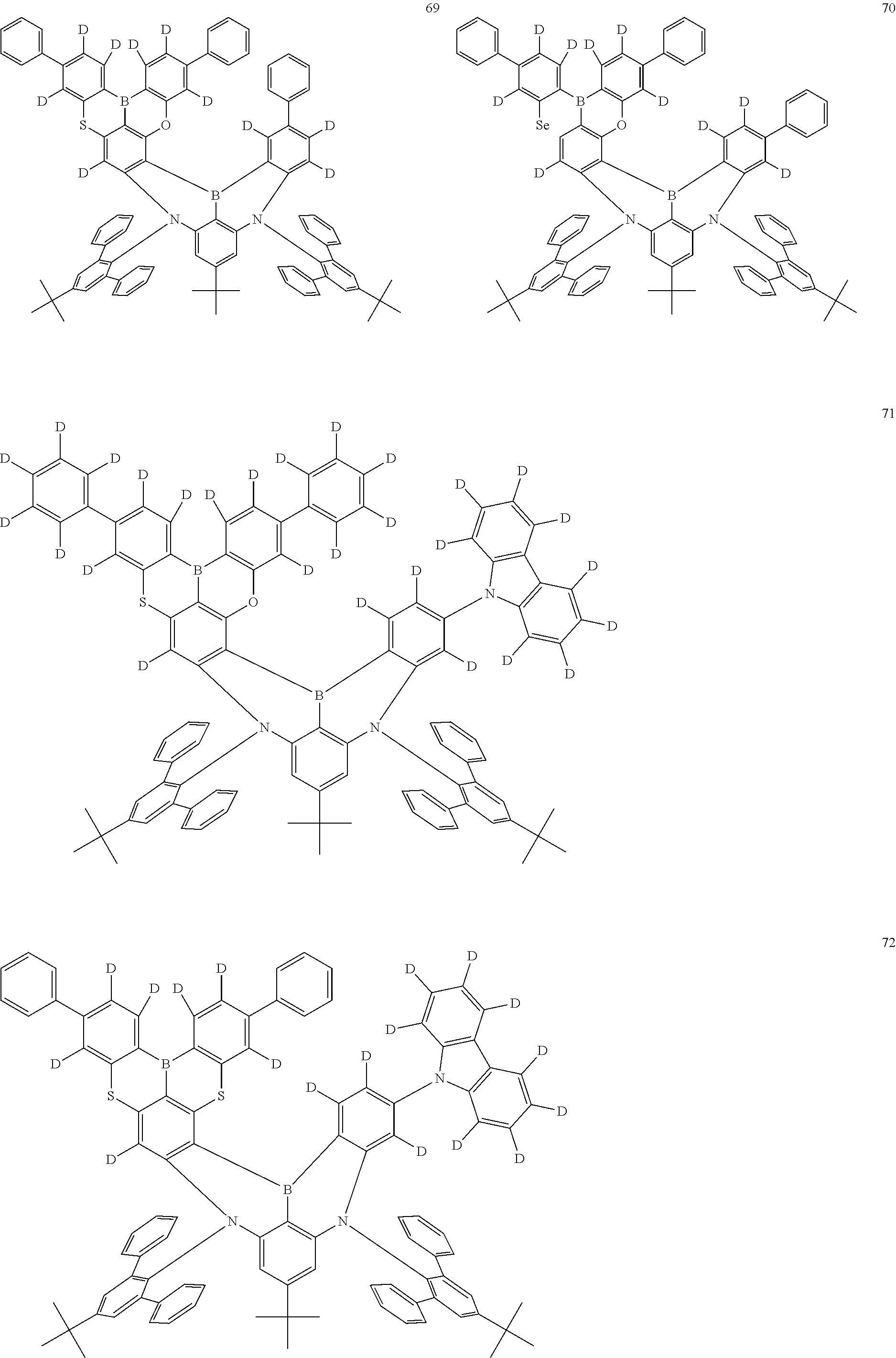 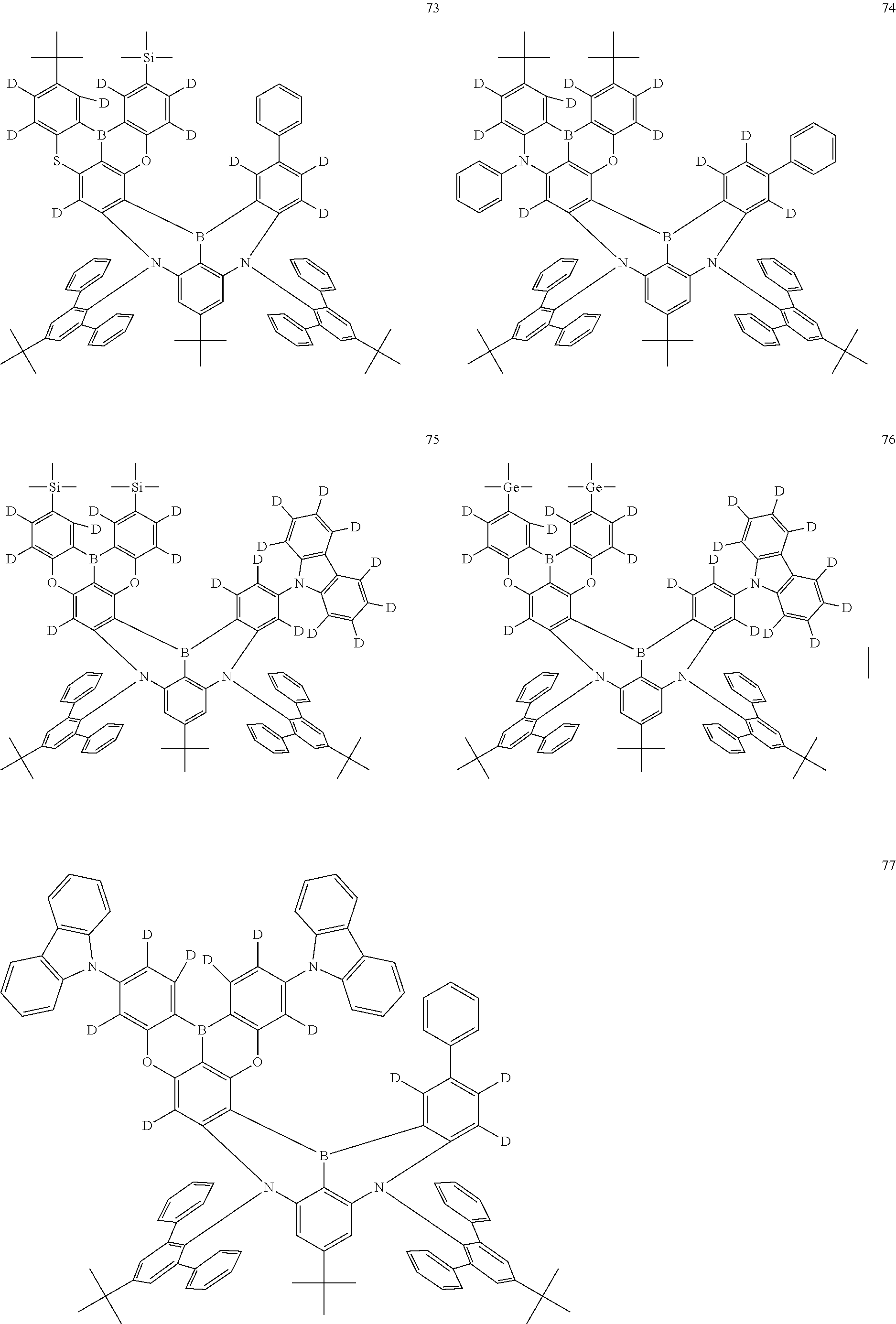 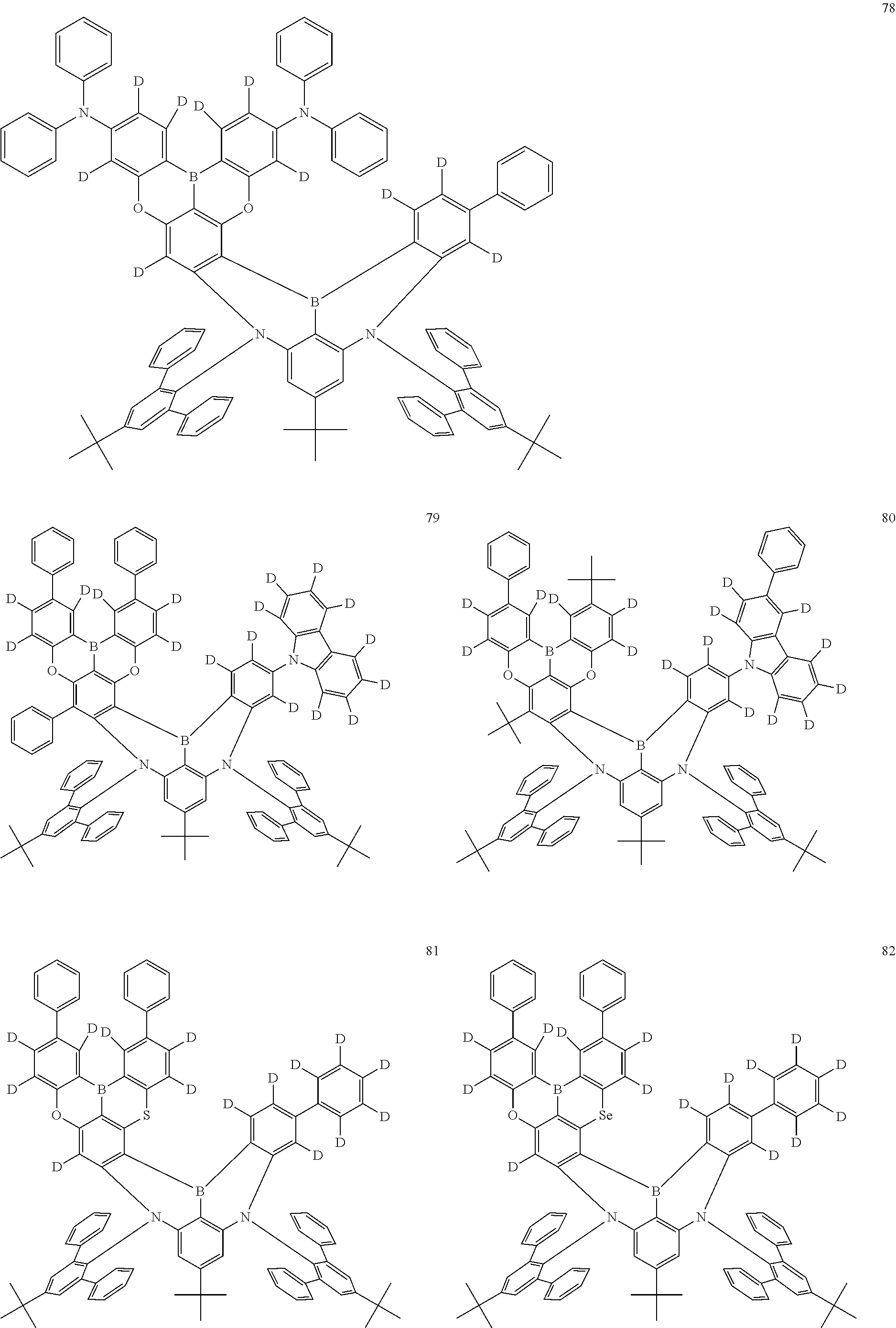 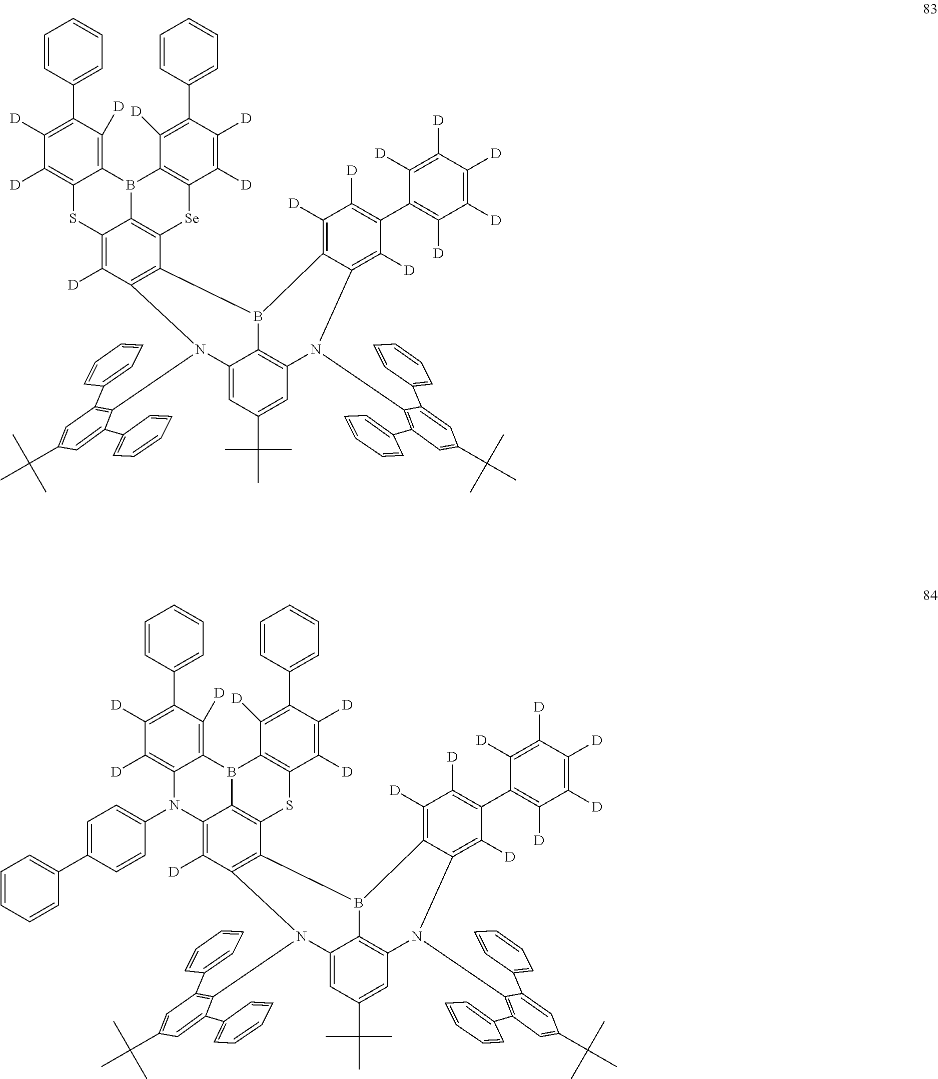 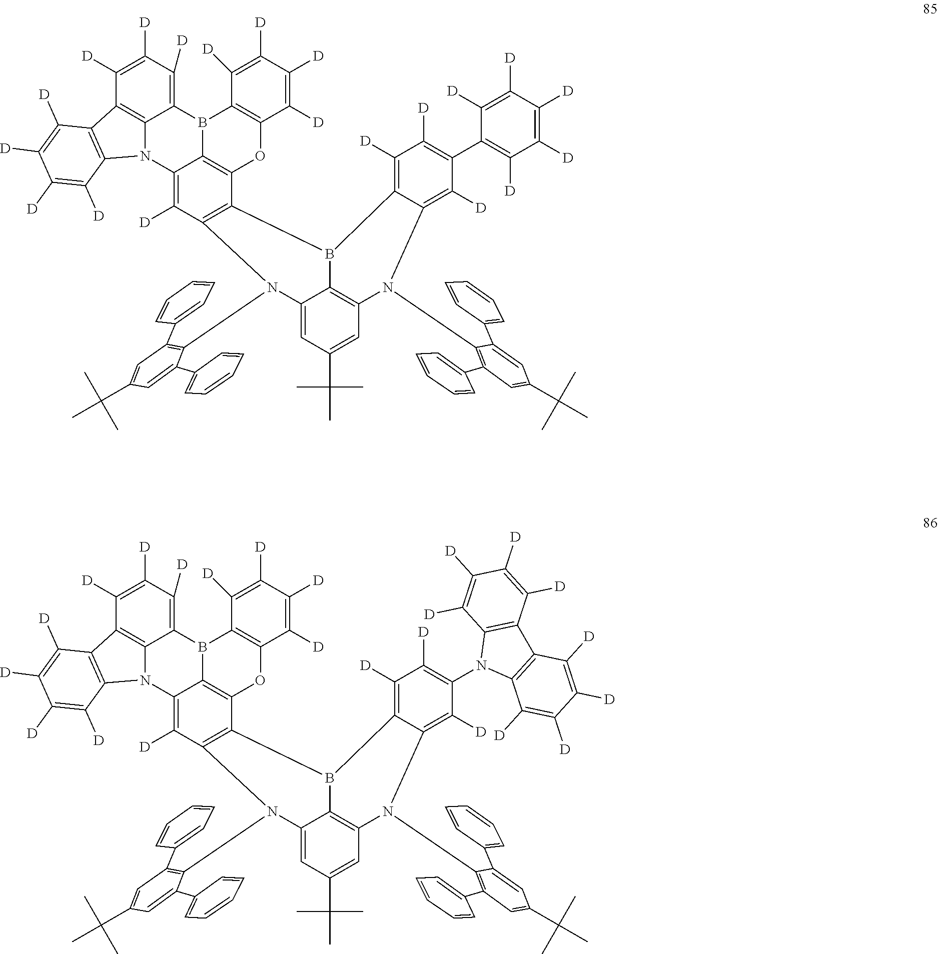 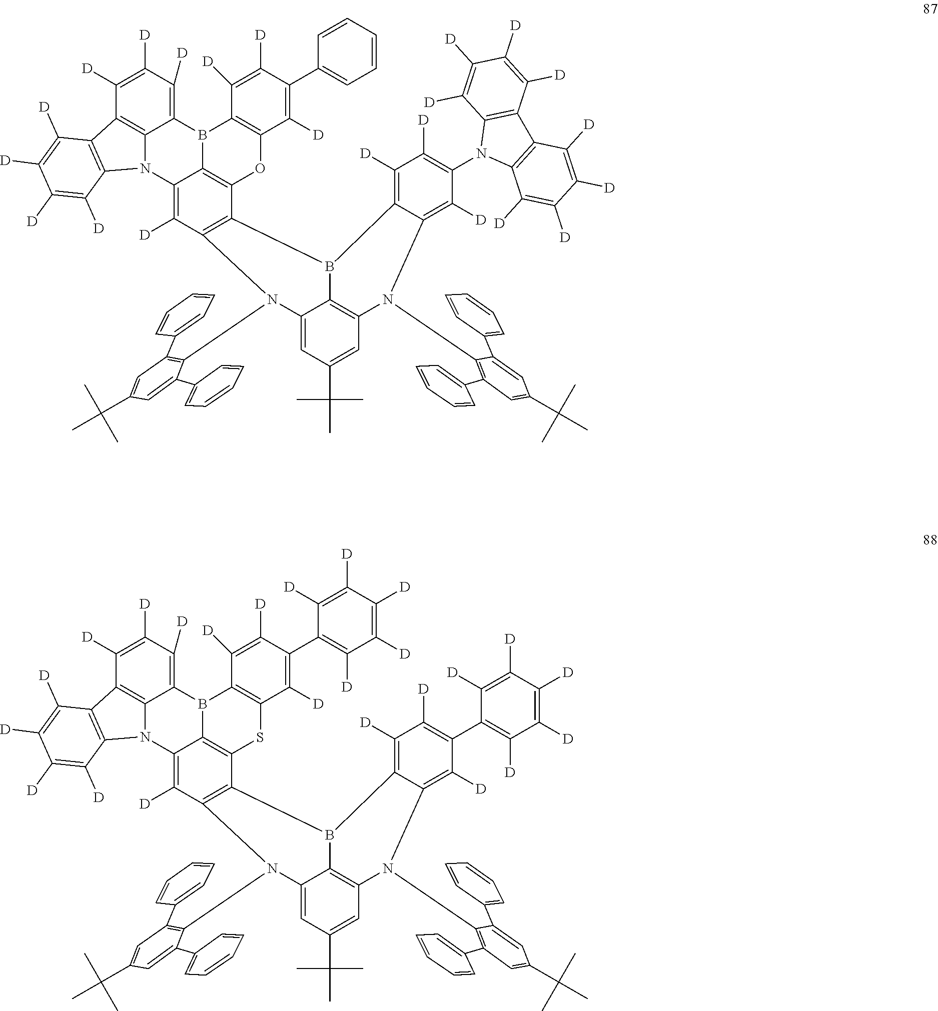 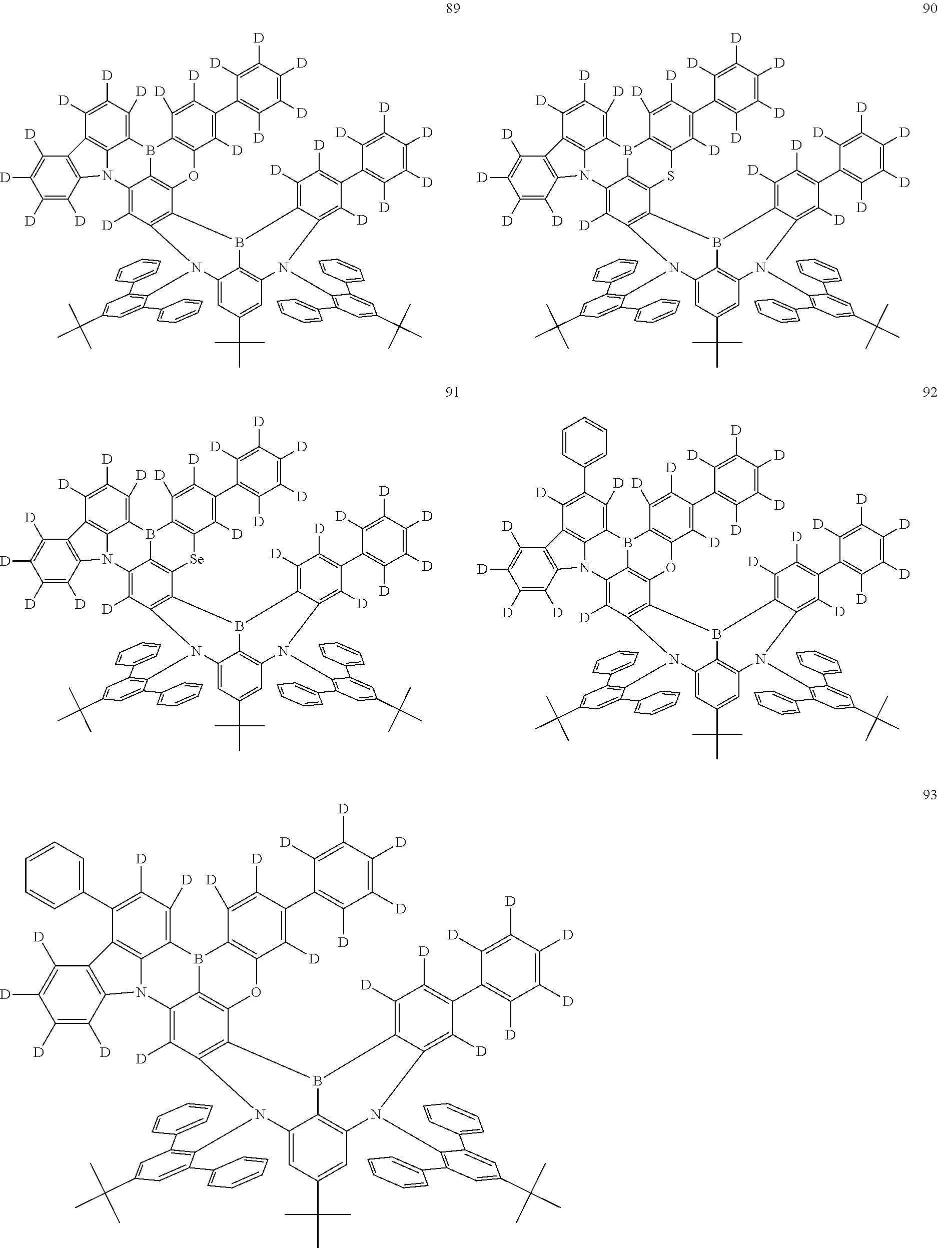 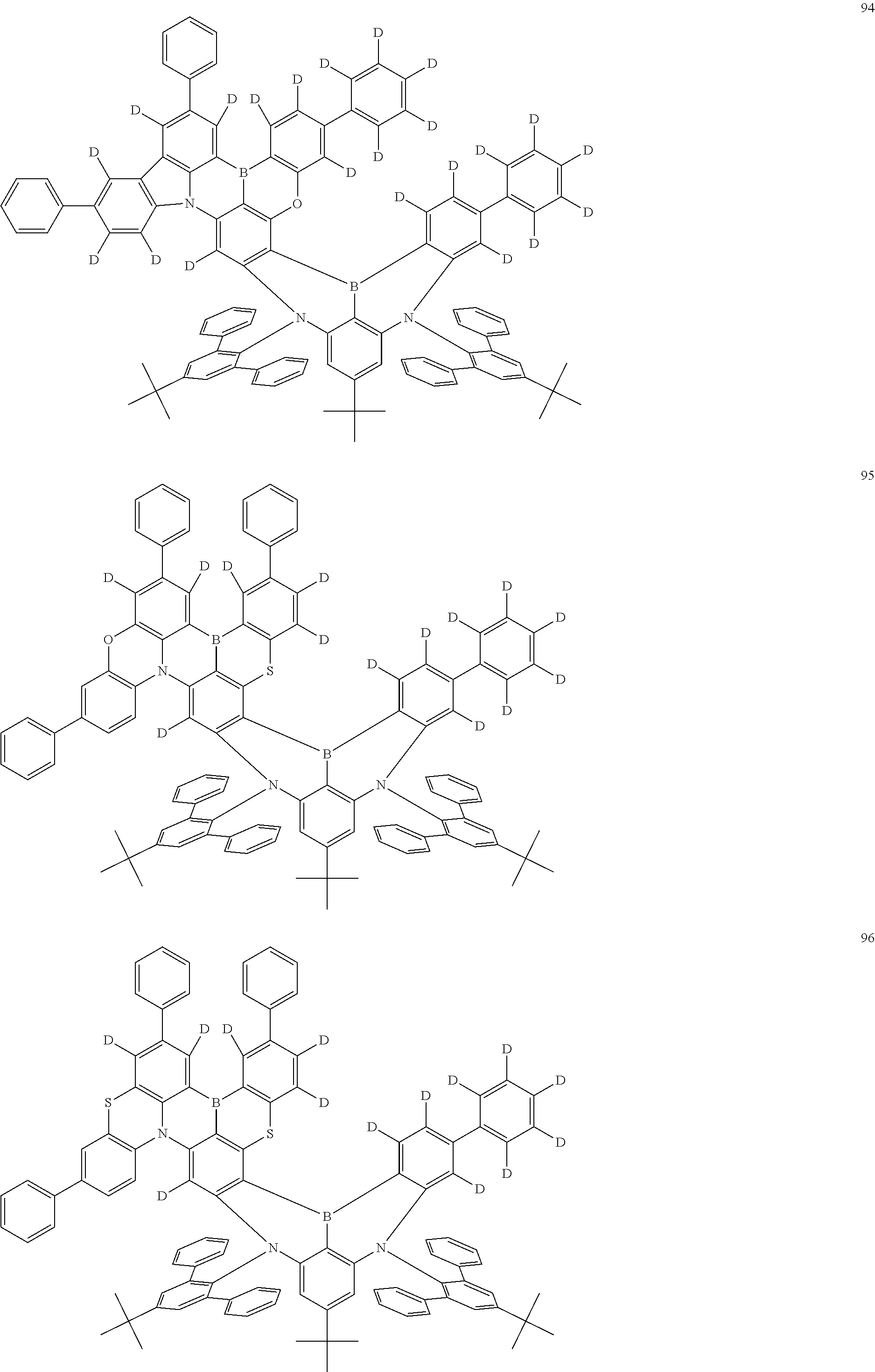 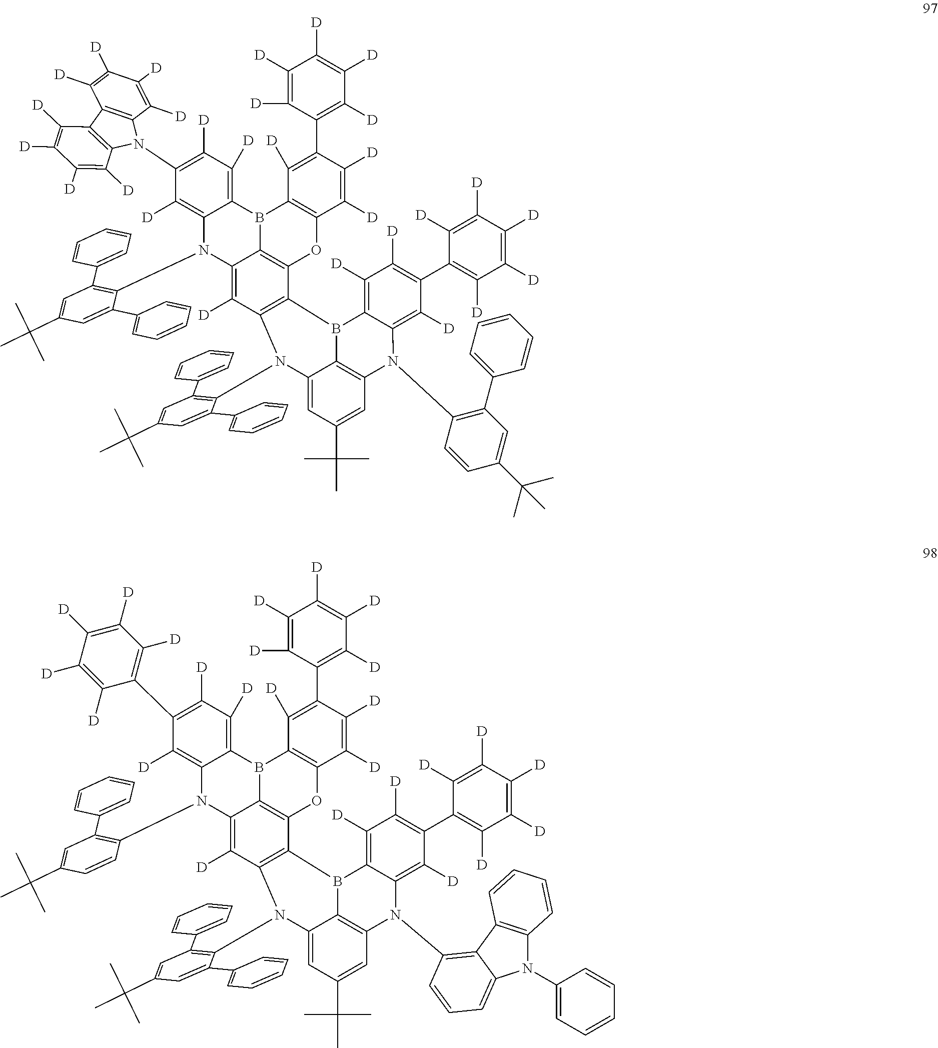 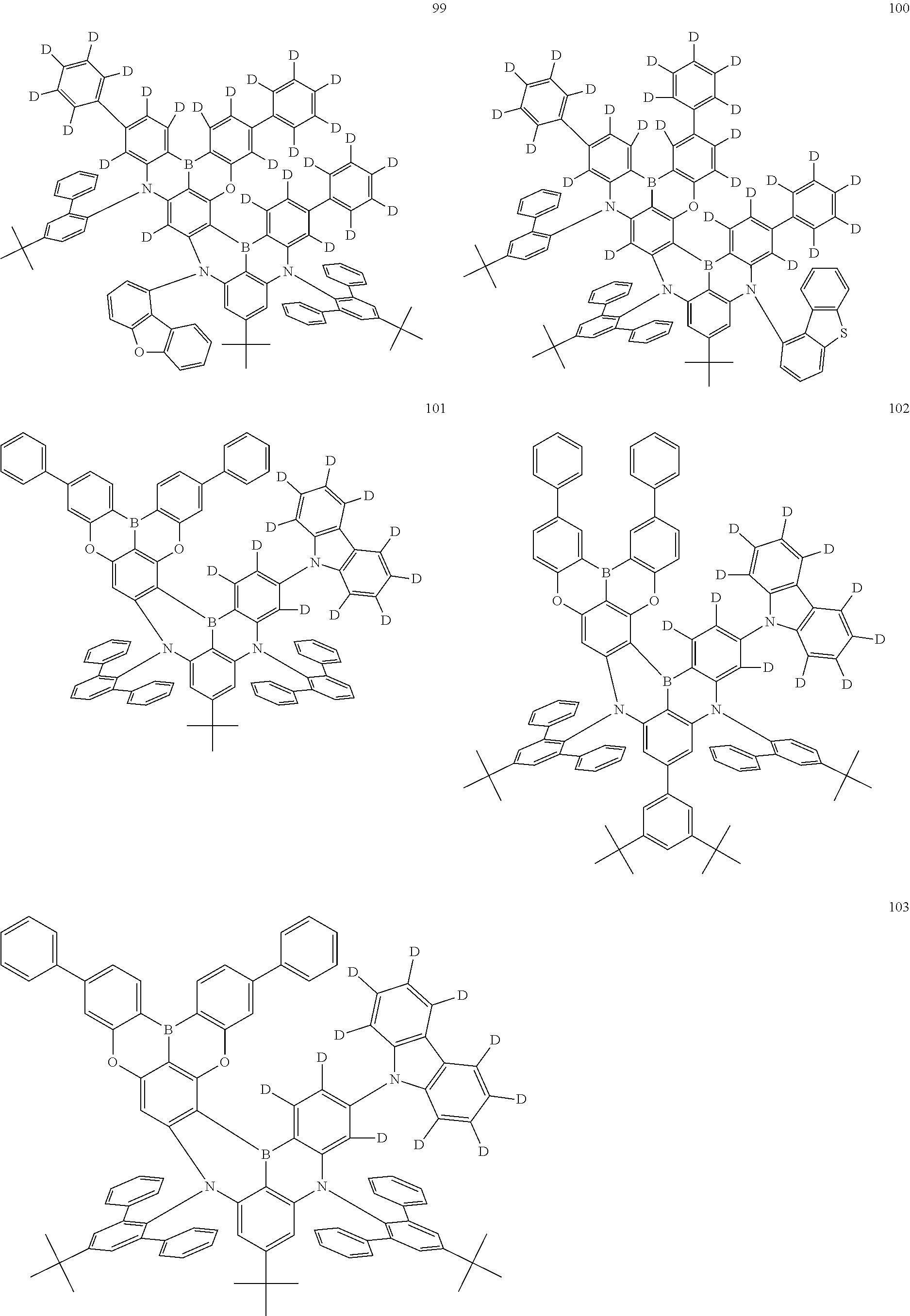 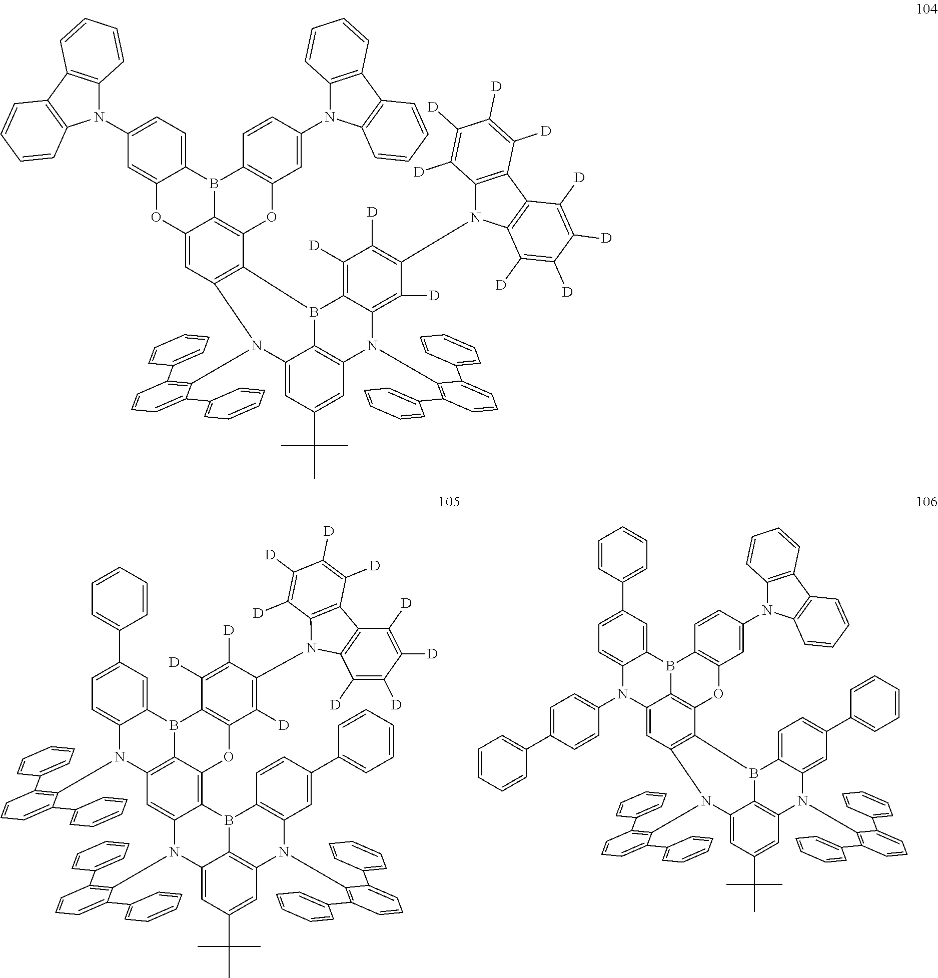 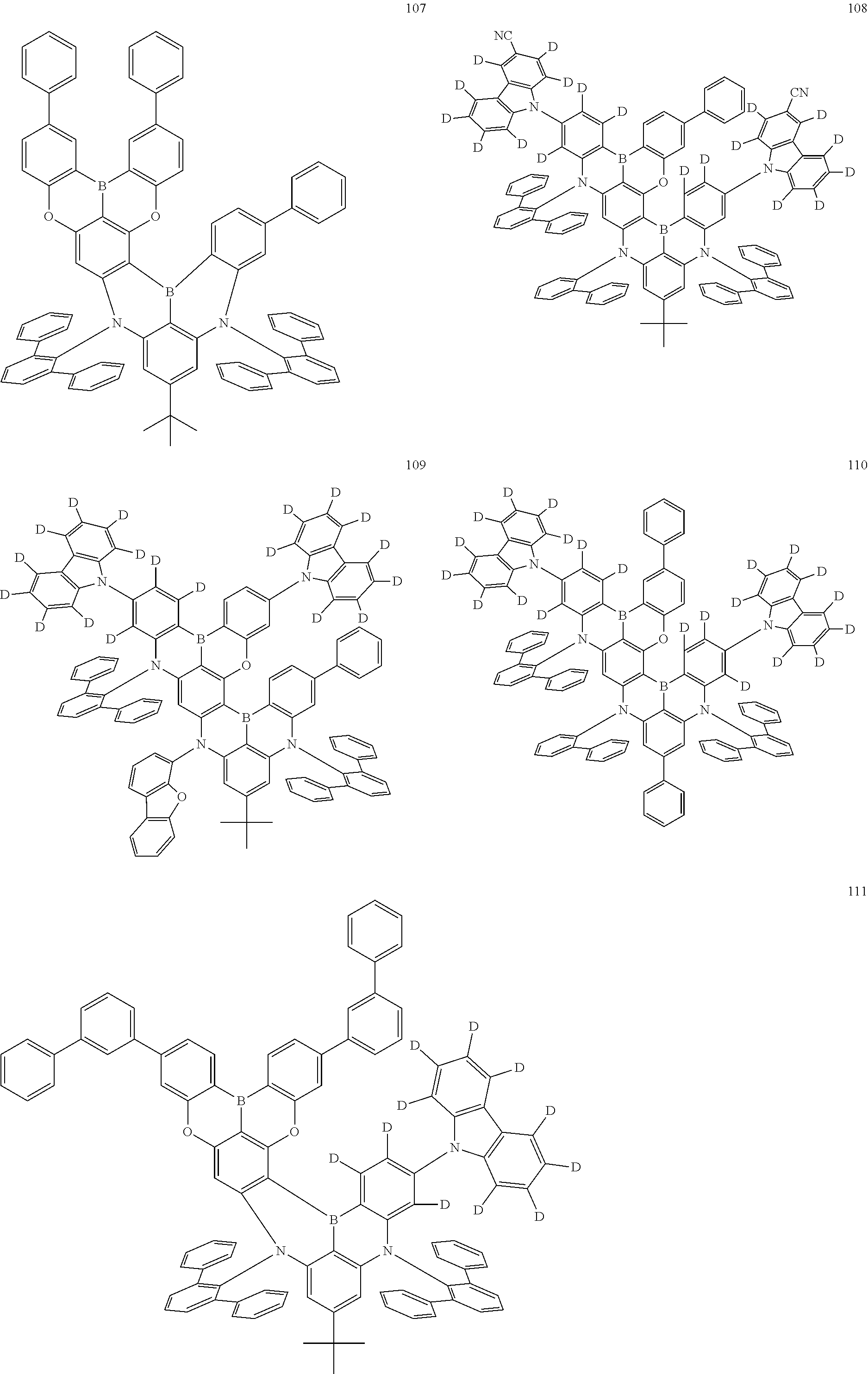 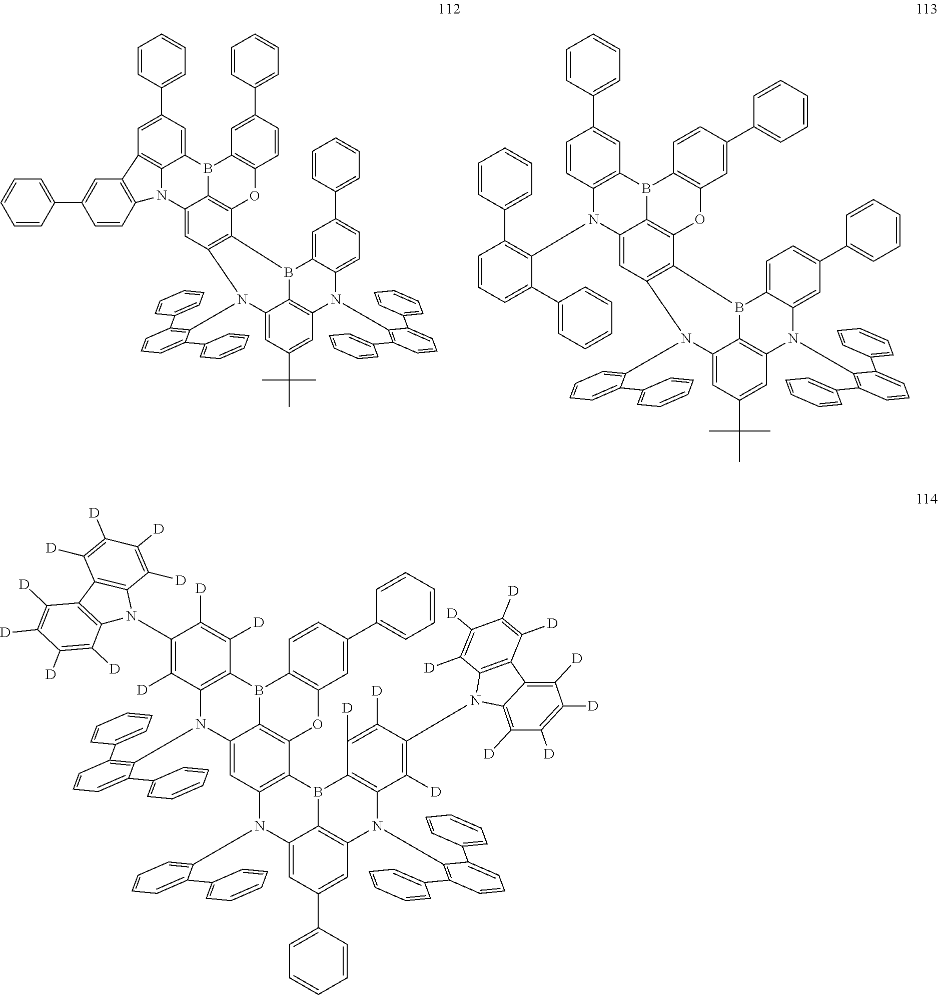 [chemical structure]
